(19) United States
(12) Patent Application Publication
(10) Pub. No.: US 2015/0358032 A1
(43) Pub. Date: Dec. 10, 2015

(54) DATA PROCESSING DEVICE AND DATA PROCESSING METHOD

(71) Applicant: Sony Corporation, Tokyo (JP)

(72) Inventors: Yuji SHINOHARA, Kanagawa (JP); Makiko YAMAMOTO, Tokyo (JP)

(73) Assignee: SONY CORPORATION, Tokyo (JP)

(21) Appl. No.: 14/760,622

(22) PCT Filed: Jan. 27, 2014
(86) PCT No.: PCT/JP2014/051621

§ 371 Date: Jul. 13, 2015

(30) Foreign Application Priority Data
Feb. 8, 2013 (JP) 2013-023880

(51) Int. Cl. H03M 13/11; H03M 13/00

(52) U.S. Cl. CPC H03M 13/1151; H03M 13/616

(57) ABSTRACT

A data processing device including an encoding unit configured to encode an information bit into an LDPC code with a code length of 64800 bits and an encoding rate of 7/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns.

### TECHNICAL FIELD

The present disclosure relates to a data processing device and a data processing method, and, for example, especially relates to a data processing device and data processing method that can provide an LDPC code of an excellent error rate.

### BACKGROUND ART

An LDPC (Low Density Parity Check) code has the high error correction capability and has been recently adopted widely to a transmission system including satellite digital broadcasting such as DVB (Digital Video Broadcasting)-S.2 performed in Europe (for example, refer to Non-Patent Literature 1). In addition, adopting of the LDPC code to next-generation terrestrial digital broadcasting such as DVB-T.2 has been examined.

From a recent study, it is known that performance near a Shannon limit is obtained from the LDPC code when a code length increases, similar to a turbo code. Because the LDPC code has a property that a shortest distance is proportional to the code length, the LDPC code has advantages of a block error probability characteristic being superior and a so-called error floor phenomenon observed in a decoding characteristic of the turbo code being rarely generated, as characteristics thereof.

Hereinafter, the LDPC code will be specifically described. The LDPC code is a linear code and it is not necessary for the LDPC code to be a binary code. However, in this case, it is assumed that the LDPC code is the binary code.

A maximum characteristic of the LDPC code is that a parity check matrix defining the LDPC code is sparse. In this case, the sparse matrix is a matrix in which the number of “1” of elements of the matrix is very small (a matrix in which most elements are 0).

FIG. 1 illustrates an example of a parity check matrix H of the LDPC code.

In the parity check matrix H of FIG. 1, a weight of each column (the column weight) (the number of “1”) becomes “3” and a weight of each row (the row weight) becomes “6”.

In encoding using the LDPC code (LDPC encoding), for example, a generation matrix G is generated on the basis of the parity check matrix H and the generation matrix G is multiplied by binary information bits, so that a code word (LDPC code) is generated.

Specifically, an encoding device that performs the LDPC encoding first calculates the generation matrix G in which an expression GH^{T}=0 is realized, between a transposed matrix H^{T} of the parity check matrix H and the generation matrix G. In this case, when the generation matrix G is a K×N matrix, the encoding device multiplies the generation matrix G with a bit string (vector u) of information bits including K bits and generates a code word c (=uG) including N bits. The code word (LDPC code) that is generated by the encoding device is received at a reception side through a predetermined communication path.

The LDPC code can be decoded by an algorithm called probabilistic decoding suggested by Gallager, that is, a message passing algorithm using belief propagation on a so-called Tanner graph, including a variable node (also referred to as a message node) and a check node. Hereinafter, the variable node and the check node are appropriately referred to as nodes simply.

FIG. 2 illustrates a sequence of decoding of the LDPC code.

Hereinafter, a real value (a reception LLR) that is obtained by representing the likelihood of “0” of a value of an i-th code bit of the LDPC code (one code word) received by the reception side by a log likelihood ratio is appropriately referred to as a reception value u₀ᵢ. In addition, a message output from the check node is referred to as uⱼ and a message output from the variable node is referred to as vᵢ.

First, in decoding of the LDPC code, as illustrated in FIG. 2, in step S11, the LDPC code is received, the message (check node message) uⱼ is initialized to “0”, and a variable k taking an integer as a counter of repetition processing is initialized to “0”, and the processing proceeds to step S12. In step S12, the message (variable node message) vᵢ is calculated by performing an operation (variable node operation) represented by an expression (1), on the basis of the reception value u₀ᵢ obtained by receiving the LDPC code, and the message is calculated by performing an operation (check node operation) represented by an expression (2), on the basis of the message vᵢ.

$$\begin{matrix}[ Math . 1 ] & \\ {v}_{i} = {u}_{0 i} + {\sum }_{j = 1}^{{d}_{v} - 1} {u}_{j} & ( 1 ) \\ [ Math . 2 ] & \\ tanh ( \frac{{u}_{j}}{2} ) = {\prod }_{i = 1}^{{d}_{c} - 1} tanh ( \frac{{v}_{i}}{2} ) & ( 2 )\end{matrix}$$

Here, dᵥ and d_{c} in an expression (1) and expression (2) are respectively parameters which can be arbitrarily selected and illustrates the number of “1” in the longitudinal direction (column) and transverse direction (row) of the parity check matrix H. For example, in the case of an LDPC code ((3, 6) LDPC code) with respect to the parity check matrix H with a column weight of 3 and a row weight of 6 as illustrated in FIG. 1, dᵥ=3 and d_{c}=6 are established.

In the variable node operation of the expression (1) and the check node operation of the expression (2), because a message input from an edge (line coupling the variable node and the check node) for outputting the message is not an operation target, an operation range becomes 1 to dᵥ−1 or 1 to d_{c}−1. The check node operation of the expression (2) is performed actually by previously making a table of a function R (v₁, v₂) represented by an expression (3) defined by one output with respect to two inputs v₁ and v₂ and using the table consecutively (recursively), as represented by an expression (4).

[Math. 3]

x=2 tan h⁻¹{tan h(v₁/2)tan h(v₂/2)}=R(v₁,v₂) (3)

[Math. 4]

uⱼ=R(v₁,R(v₂,R(v₃, . . . R(v_{d}_{_{c}}₋₂,v_{d}_{_{c}}₋₁)))) (4)

In step S12, the variable k is incremented by “1” and the processing proceeds to step S13. In step S13, it is determined whether the variable k is more than the predetermined repetition decoding number of times C. When it is determined in step S13 that the variable k is not more than C, the processing returns to step S12 and the same processing is repeated hereinafter.

When it is determined in step S13 that the variable k is more than C, the processing proceeds to step S14, the message vᵢ that corresponds to a decoding result to be finally output is calculated by performing an operation represented by an expression (5) and is output, and the decoding processing of the LDPC code ends.

$$\begin{matrix}[ Math . 5 ] & \\ {v}_{i} = {u}_{0 i} + {\sum }_{j = 1}^{{d}_{v}} {u}_{j} & ( 5 )\end{matrix}$$

In this case, the operation of the expression (5) is performed using messages uⱼ from all edges connected to the variable node, different from the variable node operation of the expression (1).

FIG. 3 illustrates an example of the parity check matrix H of the (3, 6) LDPC code (an encoding rate of 1/2 and a code length of 12).

In the parity check matrix H of FIG. 3, a weight of a column is set to 3 and a weight of a row is set to 6, similar to FIG. 1.

FIG. 4 illustrates a Tanner graph of the parity check matrix H of FIG. 3.

In FIG. 4, the check node is represented by “+” (plus) and the variable node is represented by “=” (equal). The check node and the variable node correspond to the row and the column of the parity check matrix H. A line that couples the check node and the variable node is the edge and corresponds to “1” of elements of the parity check matrix.

That is, when an element of a j-th row and an i-th column of the parity check matrix is 1, in FIG. 4, an i-th variable node (node of “=”) from the upper side and a j-th check node (node of “+”) from the upper side are connected by the edge. The edge shows that a code bit corresponding to the variable node has a restriction condition corresponding to the check node.

In a sum product algorithm that is a decoding method of the LDPC code, the variable node operation and the check node operation are repetitively performed.

FIG. 5 illustrates the variable node operation that is performed by the variable node.

In the variable node, the message vᵢ that corresponds to the edge for calculation is calculated by the variable node operation of the expression (1) using messages u₁ and u₂ from the remaining edges connected to the variable node and the reception value u₀ᵢ. The messages that correspond to the other edges are also calculated by the same method.

FIG. 6 illustrates the check node operation that is performed by the check node.

In this case, the check node operation of the expression (2) can be rewritten by an expression (6) using a relation of an expression a×b=exp { ln(|a|)+ln(|b|)}×sign(a)×sign(b). However, sign(x) is 1 in the case of x≧0 and is −1 in the case of x<0.

$$\begin{matrix}[ Math . 6 ] & \\ \begin{matrix}{u}_{j} = 2 {tanh}^{- 1} ( {\prod }_{i = 1}^{{d}_{c} - 1} tanh ( \frac{{v}_{i}}{2} ) ) \\ = 2 {tanh}^{- 1} [ exp \{ {\sum }_{i = 1}^{{d}_{c} - 1} ln ( \vert tanh ( \frac{{v}_{i}}{2} ) \vert ) \} \times {\prod }_{i = 1}^{{d}_{c} - 1} sign ( tanh ( \frac{{v}_{i}}{2} ) ) ] \\ = 2 {tanh}^{- 1} [ exp \{ - ( {\sum }_{i = 1}^{{d}_{c} - 1} - ln ( tanh ( \frac{\vert {v}_{i} \vert}{2} ) ) ) \} ] \times {\prod }_{i = 1}^{{d}_{c} - 1} sign ( {v}_{i} )\end{matrix} & ( 6 )\end{matrix}$$

In x≧0, if a function φ(x) is defined as an expression φ(x)=ln(tan h(x/2)), an expression φ⁻¹(x)=2 tan h⁻¹(e^{-x}) is realized. For this reason, the expression (6) can be changed to an expression (7).

$$\begin{matrix}[ Math . 7 ] & \\ {u}_{j} = {φ}^{- 1} ( {\sum }_{i = 1}^{{d}_{c} - 1} φ ( \vert {v}_{i} \vert ) ) \times {\prod }_{i = 1}^{{d}_{c} - 1} sign ( {v}_{i} ) & ( 7 )\end{matrix}$$

In the check node, the check node operation of the expression (2) is performed according to the expression (7).

That is, in the check node, as illustrated in FIG. 6, the message uⱼ that corresponds to the edge for calculation is calculated by the check node operation of the expression (7) using messages v₁, v₂, v₃, v₄, and v₅ from the remaining edges connected to the check node. The messages that correspond to the other edges are also calculated by the same method.

The function φ(x) of the expression (7) can be represented as φ(x)=ln((e^{x}+1)/(e^{x}−1)) and φ(x)=φ⁻¹(x) is satisfied in x>0. When the functions φ(x) and φ⁻¹(x) are mounted to hardware, the functions φ(x) and φ⁻¹(x) may be mounted using an LUT (Look Up Table). However, both the functions φ(x) and φ⁻¹(x) become the same LUT.

### CITATION LIST

### Non-Patent Literature

Non-Patent Literature 1: DVB-S.2: ETSI EN 302 307 V1.2.1 (2009-08)

### SUMMARY OF INVENTION

### Technical Problem

A DVB standard such as the DVB-S.2, DVB-T.2, and DVB-C.2 which adopt the LDPC code makes the LDPC code as a symbol (symbolized) of orthogonal modulation (digital modulation) such as QPSK (Quadrature Phase Shift Keying) and the symbol is mapped to a signal point and is transmitted.

By the way, in recent years, for example, large capacity data such as a so-called 4 k image with resolution of width and length of 3840×2160 pixels about four times full hi-vision and a 3D (Dimention) image is requested to be efficiently transmitted.

However, if the efficiency of data transmission is prioritized, the error rate is deteriorated.

On the other hand, there is a case where it is requested to transmit data in an excellent error rate even if the efficiency of data transmission is somewhat sacrificed.

It is assumed that data transmission in various kinds of efficiency is requested in the future, but, according to an LDPC code, for example, by preparing a plurality of LDPC codes of different encoding rates, it is possible to perform data transmission in various kinds of efficiency.

Therefore, for data transmission, it is desirable to adopt LDPC codes of encoding rates, for which a somewhat large number (for example, the number equal to or greater than the number requested for data transmission) of encoding rates are easily set.

Further, even in a case where an LDPC code of any encoding rate is used, it is desirable that resistance against an error is high (strong), that is, an error rate is excellent.

The present disclosure is made considering such a situation, and can provide an LDPC code of an excellent error rate.

### Solution to Problem

A first processing device or data processing method according to the present technology includes an encoding unit or encoding step of encoding an information bit into an LDPC code with a code length of 64800 bits and an encoding rate of 7/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
548 9528 12205 12770 22023 22082 25884 27421 33215 36046 43580 43953 47539
919 2623 5098 5514 5645 6348 9666 13795 14555 43224 44048 44948 47964
995 7270 17753 21272 29228 29916 31634 34055 35205 37499 37777 47490 49301
645 3803 8836 9470 11054 20253 29417 31243 31990 36468 38715 39932 43045
14572 18646 21100 26617 32033 32410 37195 38586 43833 44577 45584 46453 49515
6004 16982 17829 24616 28056 29646 32944 39051 42517 47086 48585 48772 49247
1306 1447 4898 7781 18587 25724 26672 35062 35202 37080 39781 46111 47595
92 3231 13043 22258 24198 28923 33303 37846 43610 44857 47322 48914 49291
298 12557 13469 14451 21917 23539 26310 29839 37050 38507 41377 46971 48155
12582 13044 21039 30600 34202 34947 37120 39108 39203 43449 46941 48542 49354
871 12218 12680 14152 17171 25797 29021 37783 43728 47519 48794 48898 48980
35 4623 13422 15881 16692 17463 23675 28063 31248 41997 44246 47992 48339
7150 13015 17950 18214 20659 23579 25714 28328 32658 39717 39995 43322 45884
82 11054 11845 19085 24174 26694 41530 45954 46508 46892 48832 49097 49420
5789 13839 18512 25596 26478 26736 29431 32349 33384 41765 46661 49206 49543
13805 17786 17798 29653 30310 34870 40176 40391 43227 45292 46423 46855 49454
12433 27119 34645
32065 34998 44021
5158 16546 34359
44 33285 39929
39032 39296 40317
9885 45251 47640
14383 43446 44478
31280 39945 48472
27961 38221 48391
2927 37404 38716
19461 42462 46162
24909 25915 40636
11029 35538 45381
26880 34179 48775
192 6032 26853
4563 14952 24256
10003 30853 43811
749 36334 41363
100 17006 24982
9507 20228 31214
41691 44310 47083
24070 30411 46982
2727 28251 49289
16689 21167 32590
40813 41198 46175
8336 32714 43075.

A second data processing device or data processing method according to the present technology includes a decoding unit or decoding step of decoding an LDPC code with a code length of 64800 bits and an encoding rate of 7/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
548 9528 12205 12770 22023 22082 25884 27421 33215 36046 43580 43953 47539
919 2623 5098 5514 5645 6348 9666 13795 14555 43224 44048 44948 47964
995 7270 17753 21272 29228 29916 31634 34055 35205 37499 37777 47490 49301
645 3803 8836 9470 11054 20253 29417 31243 31990 36468 38715 39932 43045
14572 18646 21100 26617 32033 32410 37195 38586 43833 44577 45584 46453 49515
6004 16982 17829 24616 28056 29646 32944 39051 42517 47086 48585 48772 49247
1306 1447 4898 7781 18587 25724 26672 35062 35202 37080 39781 46111 47595
92 3231 13043 22258 24198 28923 33303 37846 43610 44857 47322 48914 49291
298 12557 13469 14451 21917 23539 26310 29839 37050 38507 41377 46971 48155
12582 13044 21039 30600 34202 34947 37120 39108 39203 43449 46941 48542 49354
871 12218 12680 14152 17171 25797 29021 37783 43728 47519 48794 48898 48980
35 4623 13422 15881 16692 17463 23675 28063 31248 41997 44246 47992 48339
7150 13015 17950 18214 20659 23579 25714 28328 32658 39717 39995 43322 45884
82 11054 11845 19085 24174 26694 41530 45954 46508 46892 48832 49097 49420
5789 13839 18512 25596 26478 26736 29431 32349 33384 41765 46661 49206 49543
13805 17786 17798 29653 30310 34870 40176 40391 43227 45292 46423 46855 49454
12433 27119 34645
32065 34998 44021
5158 16546 34359
44 33285 39929
39032 39296 40317
9885 45251 47640
14383 43446 44478
31280 39945 48472
27961 38221 48391
2927 37404 38716
19461 42462 46162
24909 25915 40636
11029 35538 45381
26880 34179 48775
192 6032 26853
4563 14952 24256
10003 30853 43811
749 36334 41363
100 17006 24982
9507 20228 31214
41691 44310 47083
24070 30411 46982
2727 28251 49289
16689 21167 32590
40813 41198 46175
8336 32714 43075.

A third data processing device or data processing method according to the present technology includes an encoding unit or encoding step of encoding an information bit into an LDPC code with a code length of 64800 bits and an encoding rate of 8/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
100 3433 4111 9089 13360 24012 26305 30252 31430 31769 34689 34917 36091 40873 41983 42689 43835 44318 47109
3 48 124 2240 7029 21694 24565 29302 39777 42706 43631 43784 46033 47064 47079 47141 47239 47439 47479
2 5675 7056 12715 24128 26596 30571 38210 38586 41138 42272 43336 43444 43917 45812 46840 47245 47286 47510
2103 4285 10068 10702 12693 17619 18711 21309 22191 22999 37432 45646 46275 46338 46777 46860 46963 47432 47472
6827 8209 8606 10412 15670 19469 22205 22215 25425 29565 34843 34985 37686 39277 44625 45016 45623 47069 47250
58 114 1751 7913 24642 26995 40734 41486 43133 44804 45490 45725 46122 46412 47019 47080 47103 47495 47506
96 5952 9078 9786 17738 17888 17986 31657 34430 34763 35450 37276 42395 43223 43283 44261 45648 47014 47276
106 5405 9614 20500 21633 23242 28875 37238 38854 41778 42292 43883 45909 46558 46826 47292 47353 47436 47504
32 11217 12153 26818 27616 38783 39976 40842 43581 43703 44287 44435 44576 44774 46080 46098 46801 46813 47168
65 102 111 3879 11224 11772 23623 27306 28726 34663 34873 36288 39196 42003 45279 45629 46836 47021 47419
77 131 11275 18964 20418 22364 22635 27727 28689 29720 29781 32110 41597 42046 43952 44786 46416 46808 47200
87 8637 10829 23737 24117 26486 29603 34389 35509 35872 38948 40643 42698 45949 46159 46660 47041 47165 47220
2 58 3110 7539 8886 10422 11597 13385 27870 35895 38120 43546 44948 46272 46369 46596 47199 47317 47351
78 16119 27780 32231 38973 39088 40118 40231 43170 44131 44203 44878 45905 46250 47011 47113 47195 47303 47427
2960 6685 8830 11107 11843 12811 30030 36574 36850 36920 37706 38025 41007 43554 44109 44643 45874 46469 46565
125 366 10175 29860
45 17503 44634 45789
6272 19614 34408 37248
14785 41017 44274 46858
19935 22960 44726 44919
15247 17925 33947 37392
34631 39148 43287 45443
8544 26457 30996 38672
11725 31442 42167 45461
22357 41743 46702 47285
13786 26288 41358 43082
7306 21352 43298 47359
77 5188 20988 45572
10334 23790 40878
9304 29379 47450
22048 44762 47300
8529 8825 47443
40831 41328 46415
26715 43038 46498
26925 30797 43181
32434 45624 47460
17989 31811 47215
5624 25501 33016
5024 9037 33642
93 7329 46908
20303 42578 46780
16137 26869 42360
112 3049 46527
23615 29931 47360
23050 24267 44687
60 40754 47114
30217 36283 37445
127 27308 38345.

A fourth data processing device or data processing method according to the present technology includes a decoding unit or decoding step of decoding an LDPC code with a code length of 64800 bits and an encoding rate of 8/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
100 3433 4111 9089 13360 24012 26305 30252 31430 31769 34689 34917 36091 40873 41983 42689 43835 44318 47109
3 48 124 2240 7029 21694 24565 29302 39777 42706 43631 43784 46033 47064 47079 47141 47239 47439 47479
2 5675 7056 12715 24128 26596 30571 38210 38586 41138 42272 43336 43444 43917 45812 46840 47245 47286 47510
2103 4285 10068 10702 12693 17619 18711 21309 22191 22999 37432 45646 46275 46338 46777 46860 46963 47432 47472
6827 8209 8606 10412 15670 19469 22205 22215 25425 29565 34843 34985 37686 39277 44625 45016 45623 47069 47250
58 114 1751 7913 24642 26995 40734 41486 43133 44804 45490 45725 46122 46412 47019 47080 47103 47495 47506
96 5952 9078 9786 17738 17888 17986 31657 34430 34763 35450 37276 42395 43223 43283 44261 45648 47014 47276
106 5405 9614 20500 21633 23242 28875 37238 38854 41778 42292 43883 45909 46558 46826 47292 47353 47436 47504
32 11217 12153 26818 27616 38783 39976 40842 43581 43703 44287 44435 44576 44774 46080 46098 46801 46813 47168
65 102 111 3879 11224 11772 23623 27306 28726 34663 34873 36288 39196 42003 45279 45629 46836 47021 47419
77 131 11275 18964 20418 22364 22635 27727 28689 29720 29781 32110 41597 42046 43952 44786 46416 46808 47200
87 8637 10829 23737 24117 26486 29603 34389 35509 35872 38948 40643 42698 45949 46159 46660 47041 47165 47220
2 58 3110 7539 8886 10422 11597 13385 27870 35895 38120 43546 44948 46272 46369 46596 47199 47317 47351
78 16119 27780 32231 38973 39088 40118 40231 43170 44131 44203 44878 45905 46250 47011 47113 47195 47303 47427
2960 6685 8830 11107 11843 12811 30030 36574 36850 36920 37706 38025 41007 43554 44109 44643 45874 46469 46565
125 366 10175 29860
45 17503 44634 45789
6272 19614 34408 37248
14785 41017 44274 46858
19935 22960 44726 44919
15247 17925 33947 37392
34631 39148 43287 45443
8544 26457 30996 38672
11725 31442 42167 45461
22357 41743 46702 47285
13786 26288 41358 43082
7306 21352 43298 47359
77 5188 20988 45572
10334 23790 40878
9304 29379 47450
22048 44762 47300
8529 8825 47443
40831 41328 46415
26715 43038 46498
26925 30797 43181
32434 45624 47460
17989 31811 47215
5624 25501 33016
5024 9037 33642
93 7329 46908
20303 42578 46780
16137 26869 42360
112 3049 46527
23615 29931 47360
23050 24267 44687
60 40754 47114
30217 36283 37445
127 27308 38345.

A fifth data processing device or data processing method according to the present technology includes an encoding unit or encoding step of encoding an information bit into an LDPC code with a code length of 64800 bits and an encoding rate of 9/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
339 4777 5366 7623 13034 13260 15107 17772 20338 21178 25914 27663 29948 37489 41021
3871 5812 9795 23437 24079 27699 33471 39878 40302 41038 41217 42316 42765 43675 45118
3699 4072 16553 21492 26210 29839 30322 34139 38227 39696 40762 41156 41269 45168 45350
995 12194 12494 16542 20423 21950 23519 26215 26708 30587 38352 38840 39729 41645 43210
3963 4315 6832 11354 21042 21084 21108 25595 33109 34029 34448 35129 38018 39012 44791
164 887 2902 9021 9193 16705 17850 19241 25893 33427 37416 41024 41355 44381 45303
1367 1495 5495 14440 18026 18130 18178 21946 24057 25663 29216 31965 38107 43907 44278
10763 13722 13975 18294 20813 23028 23353 24211 37366 38805 40985 41792 42495 43259 43528
1580 12448 21464 31246 33058 34794 35760 36021 36426 37138 37478 38199 42138 42335 45207
83 112 12225 15224 18205 21345 28488 34362 37195 39660 42371 42814 44509 45201 45244
6836 7635 11644 16591 17121 19307 21456 23544 30596 37887 38141 38581 43607 44246 45097
9174 14934 17131 29762 30243 31656 33251 35498 37106 37655 41462 44002 44649 45032 45230
33 5376 13536 17068 18581 23478 32021 32074 33716 38434 39452 42166 44305 44979 45306
6013 7553 10023 19354 23126 25427 27665 30239 32699 34123 36171 38898 38972 41974 45213
41 98 3088 8522 26252 29602 30009 30138 30948 32190 32428 32498 34273 34955 45311
2000 15664 20677 20792 22980 25111 31491 37611 37981 39872 41668 42336 43602 43828 45329
23 67 97 5339 8121 8583 20647 25425 32305 37158 40968 41578 43492 44929 45273
1643 3496 5121 6546 15643 16423 20602 39950 43178 43252 43683 43992 44001 44611 45125
11093 19172 20548 24518 28289 29246 30148 34884 40403 40745 42723 43064 44448 44723 44812
12748 12799 28567 41605
1965 4087 31879
27178 33638 38344
9580 13096 45337
2672 22800 43869
28287 31407 31975
2823 5108 9945
5891 30848 42082
23 41944 44909
909 2311 45162
24998 37829 44704
35339 40087 45019
16928 26505 35256
26462 27297 37766
19656 35067 38586
6958 17172 41412
72 26012 37231
15259 16044 30243
2879 12148 34601
36173 39731 42668
20670 35816 43266
22570 27213 30404
40284 44171 45313
17765 22514 39347
24711 39892 45132
13741 34633 44535
15209 31692 45280
11189 43771 45303
28294 31110 32287
29085 39876 45246
24285 36009 45347
6882 28921 34504
9256 19267 44194
2132 21404 28687
23809 34383 44540.

A sixth data processing device or data processing method according to the present technology includes a decoding unit or decoding step of decoding an LDPC code with a code length of 64800 bits and an encoding rate of 9/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
339 4777 5366 7623 13034 13260 15107 17772 20338 21178 25914 27663 29948 37489 41021
3871 5812 9795 23437 24079 27699 33471 39878 40302 41038 41217 42316 42765 43675 45118
3699 4072 16553 21492 26210 29839 30322 34139 38227 39696 40762 41156 41269 45168 45350
995 12194 12494 16542 20423 21950 23519 26215 26708 30587 38352 38840 39729 41645 43210
3963 4315 6832 11354 21042 21084 21108 25595 33109 34029 34448 35129 38018 39012 44791
164 887 2902 9021 9193 16705 17850 19241 25893 33427 37416 41024 41355 44381 45303
1367 1495 5495 14440 18026 18130 18178 21946 24057 25663 29216 31965 38107 43907 44278
10763 13722 13975 18294 20813 23028 23353 24211 37366 38805 40985 41792 42495 43259 43528
1580 12448 21464 31246 33058 34794 35760 36021 36426 37138 37478 38199 42138 42335 45207
83 112 12225 15224 18205 21345 28488 34362 37195 39660 42371 42814 44509 45201 45244
6836 7635 11644 16591 17121 19307 21456 23544 30596 37887 38141 38581 43607 44246 45097
9174 14934 17131 29762 30243 31656 33251 35498 37106 37655 41462 44002 44649 45032 45230
33 5376 13536 17068 18581 23478 32021 32074 33716 38434 39452 42166 44305 44979 45306
6013 7553 10023 19354 23126 25427 27665 30239 32699 34123 36171 38898 38972 41974 45213
41 98 3088 8522 26252 29602 30009 30138 30948 32190 32428 32498 34273 34955 45311
2000 15664 20677 20792 22980 25111 31491 37611 37981 39872 41668 42336 43602 43828 45329
23 67 97 5339 8121 8583 20647 25425 32305 37158 40968 41578 43492 44929 45273
1643 3496 5121 6546 15643 16423 20602 39950 43178 43252 43683 43992 44001 44611 45125
11093 19172 20548 24518 28289 29246 30148 34884 40403 40745 42723 43064 44448 44723 44812
12748 12799 28567 41605
1965 4087 31879
27178 33638 38344
9580 13096 45337
2672 22800 43869
28287 31407 31975
2823 5108 9945
5891 30848 42082
23 41944 44909
909 2311 45162
24998 37829 44704
35339 40087 45019
16928 26505 35256
26462 27297 37766
19656 35067 38586
6958 17172 41412
72 26012 37231
15259 16044 30243
2879 12148 34601
36173 39731 42668
20670 35816 43266
22570 27213 30404
40284 44171 45313
17765 22514 39347
24711 39892 45132
13741 34633 44535
15209 31692 45280
11189 43771 45303
28294 31110 32287
29085 39876 45246
24285 36009 45347
6882 28921 34504
9256 19267 44194
2132 21404 28687
23809 34383 44540.

A seventh data processing device or data processing method according to the present technology includes an encoding step of encoding an information bit into an LDPC code with a code length of 64800 bits and an encoding rate of 10/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
867 2733 2978 8947 10214 11810 13566 15922 18838 20543 25845 29179 30055 31284 33447 34330 35081 35605 36268 39563 42331 43174
2765 6017 6394 6769 12351 13567 15195 19900 23094 27077 28626 28914 32219 33106 33662 33905 34878 37861 39749 39862 40976 42690
2343 4231 7603 7789 8396 8783 15636 16221 20591 21538 24008 25117 25663 26817 29692 30937 31472 32070 33793 39506 41763 43172
8536 10705 10960 11206 12513 15399 17108 17224 17512 20180 25288 27824 28958 30600 36792 36828 38891 39575 39581 42342 42914 42961
9 107 681 1195 9957 14055 21420 23279 26129 32044 35750 37065 37092 37165 37179 40127 40835 41476 41564 41571 42576 42910
86 1760 6842 8119 8904 12644 17603 18189 20018 22259 22654 25620 27606 27833 28002 31053 31814 31848 35573 36133 40698 41370
28 115 4354 9276 11229 11252 13848 21112 22851 29912 32453 34693 37344 37420 40926 40992 41063 41762 41856 42012 42642 43045
1589 7190 7221 7668 11805 14071 14367 14629 17087 19579 19861 25505 35471 35514 37495 38375 40286 40330 40402 41662 42638 43126
76 99 3237 5137 7982 9598 13470 14045 26680 27058 32025 32235 34601 35658 36841 38408 40517 40987 41400 41861 42691 42772
54 2470 2728 3177 3484 8267 9351 17523 18513 21119 22947 23771 26569 27308 31217 35887 36449 38529 40424 41873 42146 42706
39 80 385 1386 3397 5234 14733 16955 17656 23262 23463 25340 31638 31676 32683 37130 37641 39064 41839 42193 42495 43063
62 573 11847 14616 16033 16064 16302 18776 19434 23845 23873 25937 27741 32244 32612 33554 38445 38480 38610 40933 42386 42520
33 183 968 5477 6173 7363 10358 12597 14468 18025 23369 23387 24723 25254 28299 28989 31675 32776 35077 40241 41572 42035
36 2529 2543 3891 7108 9002 9481 16496 19796 26687 27343 33300 35495 37070 39247 40126 41758 41892 42124 42622 42738 43100
91 6897 8794 9581 12922 15711 18539 19227 21592 22906 26449 29804 30895 31538 31930 33392 38006 38294 38705 38952 39005 42120
64 76 709 1155 3162 7099 8740 9670 12678 21126 29239 29844 31248 32001 35243 36814 38008 42050 42149 42631 42705 43119
17670 40897 42359
17471 20895 32101
5458 5508 30504
17291 19627 27186
14600 41106 43103
18059 28398 40623
23776 30190 32880
4676 13593 21791
19 2832 27959
6193 21762 42854
64 16088 42982
29425 35004 42209
14338 31982 41789
21572 42838 42923
5 87 6639
5529 42541 43173
15512 31740 35801
44 86 43183
26027 26995 36455
16485 30090 34537
22276 40174 42367
10781 18230 18766
9984 42877 43027
11108 20618 41626
8496 42994 43171
10581 25803 42606
4989 14002 29020
35032 39378 41455
109 11667 42914
12471 14022 35477
31761 34625 36228
1228 6013 43110
22355 37905 40784
12740 21805 31648
4202 28639 32213
10697 31674 42998
4092 23877 34360
54 9459 16450
1 56 33675
18163 31951 42528
50 5655 35891
47 35033 40356
29097 32786 35931
9532 27004 43009.

An eighth data processing device or data processing method according to the present technology includes a decoding unit or decoding step of decoding an LDPC code with a code length of 64800 bits and an encoding rate of 10/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
867 2733 2978 8947 10214 11810 13566 15922 18838 20543 25845 29179 30055 31284 33447 34330 35081 35605 36268 39563 42331 43174
2765 6017 6394 6769 12351 13567 15195 19900 23094 27077 28626 28914 32219 33106 33662 33905 34878 37861 39749 39862 40976 42690
2343 4231 7603 7789 8396 8783 15636 16221 20591 21538 24008 25117 25663 26817 29692 30937 31472 32070 33793 39506 41763 43172
8536 10705 10960 11206 12513 15399 17108 17224 17512 20180 25288 27824 28958 30600 36792 36828 38891 39575 39581 42342 42914 42961
9 107 681 1195 9957 14055 21420 23279 26129 32044 35750 37065 37092 37165 37179 40127 40835 41476 41564 41571 42576 42910
86 1760 6842 8119 8904 12644 17603 18189 20018 22259 22654 25620 27606 27833 28002 31053 31814 31848 35573 36133 40698 41370
28 115 4354 9276 11229 11252 13848 21112 22851 29912 32453 34693 37344 37420 40926 40992 41063 41762 41856 42012 42642 43045
1589 7190 7221 7668 11805 14071 14367 14629 17087 19579 19861 25505 35471 35514 37495 38375 40286 40330 40402 41662 42638 43126
76 99 3237 5137 7982 9598 13470 14045 26680 27058 32025 32235 34601 35658 36841 38408 40517 40987 41400 41861 42691 42772
54 2470 2728 3177 3484 8267 9351 17523 18513 21119 22947 23771 26569 27308 31217 35887 36449 38529 40424 41873 42146 42706
39 80 385 1386 3397 5234 14733 16955 17656 23262 23463 25340 31638 31676 32683 37130 37641 39064 41839 42193 42495 43063
62 573 11847 14616 16033 16064 16302 18776 19434 23845 23873 25937 27741 32244 32612 33554 38445 38480 38610 40933 42386 42520
33 183 968 5477 6173 7363 10358 12597 14468 18025 23369 23387 24723 25254 28299 28989 31675 32776 35077 40241 41572 42035
36 2529 2543 3891 7108 9002 9481 16496 19796 26687 27343 33300 35495 37070 39247 40126 41758 41892 42124 42622 42738 43100
91 6897 8794 9581 12922 15711 18539 19227 21592 22906 26449 29804 30895 31538 31930 33392 38006 38294 38705 38952 39005 42120
64 76 709 1155 3162 7099 8740 9670 12678 21126 29239 29844 31248 32001 35243 36814 38008 42050 42149 42631 42705 43119
17670 40897 42359
17471 20895 32101
5458 5508 30504
17291 19627 27186
14600 41106 43103
18059 28398 40623
23776 30190 32880
4676 13593 21791
19 2832 27959
6193 21762 42854
64 16088 42982
29425 35004 42209
14338 31982 41789
21572 42838 42923
5 87 6639
5529 42541 43173
15512 31740 35801
44 86 43183
26027 26995 36455
16485 30090 34537
22276 40174 42367
10781 18230 18766
9984 42877 43027
11108 20618 41626
8496 42994 43171
10581 25803 42606
4989 14002 29020
35032 39378 41455
109 11667 42914
12471 14022 35477
31761 34625 36228
1228 6013 43110
22355 37905 40784
12740 21805 31648
4202 28639 32213
10697 31674 42998
4092 23877 34360
54 9459 16450
1 56 33675
18163 31951 42528
50 5655 35891
47 35033 40356
29097 32786 35931
9532 27004 43009.

A ninth data processing device or data processing method according to the present technology includes an encoding unit or encoding step of encoding an information bit into an LDPC code with a code length of 64800 bits and an encoding rate of 11/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
3208 6587 9493 9539 12368 12501 14811 15784 17625 18654 18721 19471 19503 20079 20411 20876 21493 22083 22430 27275 29322 32758 33227 33347 33715 34472 34711 38450 39151 39709 39862 40093 40497 40912
42 1118 3086 5466 6379 8483 9051 9330 13250 13898 14055 15033 18094 21429 22652 25251 28709 29909 30233 30472 30635 31367 32603 33614 33708 36404 36530 37039 37782 38115 38307 40225 40597 40822
5939 11990 15027 15162 16503 17171 17806 17902 18031 18077 21216 22134 22660 24170 28558 29364 30003 31128 32674 33103 33361 34196 34435 34626 34991 35974 36022 37459 38170 38709 39774 39960 40571 40858
63 3871 9148 10328 12830 12912 18361 18839 20122 23126 23795 28612 30350 32251 32750 33762 33866 36188 36979 37562 37836 38536 38705 38829 39609 40219 40324 40336 40367 40638 40699 40809 40987 41019
36 70 104 3737 5028 19023 19575 19746 23840 24611 24661 26741 27749 30359 31027 31509 32621 32859 33830 34619 35281 35479 36796 37344 37555 38993 39088 39445 40276 40299 40762 40771 40835 40967
113 2313 4411 5858 9909 10426 18955 21663 21884 24105 24472 26944 27826 28574 28689 29579 30903 32352 33334 36408 36795 36805 37112 37121 38731 39080 39739 40007 40326 40356 40472 40476 40622 40778
54 84 3529 5202 9825 9900 10846 12104 13332 14493 14584 23772 24084 25786 25963 26145 28306 29514 30050 30060 33171 33416 33657 33951 34908 37715 37854 38088 38966 39148 40166 40633 40746 40939
105 8722 10244 12148 13029 16368 18186 19660 19830 21616 22256 22534 23100 23219 25473 26585 29858 32350 33305 34290 34356 34675 35297 37052 37144 37934 38201 39867 40270 40539 40781 40804 40944 40966
53 61 82 96 2665 6552 9517 15693 17214 17588 18347 19039 20679 21962 24255 25861 27117 27919 30691 36195 36379 37031 37309 37535 37793 38198 38212 38595 38808 38911 39474 39677 40135 40935
15 67 723 2962 4991 5285 11583 13398 16301 16338 20996 21510 25697 28214 29143 30539 30573 31108 32500 32506 32727 32755 36134 37226 37655 37799 39219 39626 39980 40093 40105 40628 40634 40816
18854 37884 40104 40772
35209 40379 40447 40508
3049 36078 39403 40402
19118 27981 35730 36649
20465 28570 39076 40910
24047 31275 39790 40126
31041 33526 34162 39092
1152 8976 24071 35698
3 27991 31485 40934
5245 20676 30579 38823
47 11196 38674 38894
14920 15270 16047 40928
23974 30146 39805 40911
8791 16641 25060 31681
1147 4233 34386 37802
58 5354 22265 41018
869 3078 39882 40730
1071 6322 9163 10642
7235 32596 35540 37487
26910 35537 40830 41035
81 11905 16179 19558
29 41 5161 12173
3043 5574 9993 26058
875 36935 39423 40956
3362 19166 20017 39729
12893 16403 33880 37115
9980 27100 28525 36786
3218 12776 40651 40703
7669 25783 32781 34504
25951 34595 39049 40597
11271 35112 35290 40600
5330 38324 40325 40986
58 24777 40560 40835
23895 25427 33552 37472
2811 4731 11601 39912
109 39021 40611 40754
79 15387 30999 40978
31162 34975 38844 39784
34891 37007 39433 40102
42 9072 21526 22610
20243 20499 24418 29056
7951 26469 29729 40956
6 10833 13188 15714
7910 20652 40574 40874
14586 24839 37804 40722
1103 11381 21050 30084
10 9032 20123 28528
19477 29966 37702 37766
131 31352 39069 40971
34 7368 17799 27467
16767 27584 32869 34769
31515 34543 36230 40752
15098 25451 26402 27629
149 10388 24558 40709
6997 7288 23995 29893
346 12245 13843 40402.

A tenth data processing device or data processing method according to the present technology includes a decoding unit or decoding step of decoding an LDPC code with a code length of 64800 bits and an encoding rate of 11/30, based on a parity check matrix of an LDPC (Low Density Parity Check) code. The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns and is expressed as follows
3208 6587 9493 9539 12368 12501 14811 15784 17625 18654 18721 19471 19503 20079 20411 20876 21493 22083 22430 27275 29322 32758 33227 33347 33715 34472 34711 38450 39151 39709 39862 40093 40497 40912
42 1118 3086 5466 6379 8483 9051 9330 13250 13898 14055 15033 18094 21429 22652 25251 28709 29909 30233 30472 30635 31367 32603 33614 33708 36404 36530 37039 37782 38115 38307 40225 40597 40822
5939 11990 15027 15162 16503 17171 17806 17902 18031 18077 21216 22134 22660 24170 28558 29364 30003 31128 32674 33103 33361 34196 34435 34626 34991 35974 36022 37459 38170 38709 39774 39960 40571 40858
63 3871 9148 10328 12830 12912 18361 18839 20122 23126 23795 28612 30350 32251 32750 33762 33866 36188 36979 37562 37836 38536 38705 38829 39609 40219 40324 40336 40367 40638 40699 40809 40987 41019
36 70 104 3737 5028 19023 19575 19746 23840 24611 24661 26741 27749 30359 31027 31509 32621 32859 33830 34619 35281 35479 36796 37344 37555 38993 39088 39445 40276 40299 40762 40771 40835 40967
113 2313 4411 5858 9909 10426 18955 21663 21884 24105 24472 26944 27826 28574 28689 29579 30903 32352 33334 36408 36795 36805 37112 37121 38731 39080 39739 40007 40326 40356 40472 40476 40622 40778
54 84 3529 5202 9825 9900 10846 12104 13332 14493 14584 23772 24084 25786 25963 26145 28306 29514 30050 30060 33171 33416 33657 33951 34908 37715 37854 38088 38966 39148 40166 40633 40746 40939
105 8722 10244 12148 13029 16368 18186 19660 19830 21616 22256 22534 23100 23219 25473 26585 29858 32350 33305 34290 34356 34675 35297 37052 37144 37934 38201 39867 40270 40539 40781 40804 40944 40966
53 61 82 96 2665 6552 9517 15693 17214 17588 18347 19039 20679 21962 24255 25861 27117 27919 30691 36195 36379 37031 37309 37535 37793 38198 38212 38595 38808 38911 39474 39677 40135 40935
15 67 723 2962 4991 5285 11583 13398 16301 16338 20996 21510 25697 28214 29143 30539 30573 31108 32500 32506 32727 32755 36134 37226 37655 37799 39219 39626 39980 40093 40105 40628 40634 40816
18854 37884 40104 40772
35209 40379 40447 40508
3049 36078 39403 40402
19118 27981 35730 36649
20465 28570 39076 40910
24047 31275 39790 40126
31041 33526 34162 39092
1152 8976 24071 35698
3 27991 31485 40934
5245 20676 30579 38823
47 11196 38674 38894
1492015270 16047 40928
23974 30146 39805 40911
8791 16641 25060 31681
1147 4233 34386 37802
58 5354 22265 41018
869 3078 39882 40730
1071 6322 9163 10642
7235 32596 35540 37487
26910 35537 40830 41035
81 11905 16179 19558
29 41 5161 12173
3043 5574 9993 26058
875 36935 39423 40956
3362 19166 20017 39729
12893 16403 33880 37115
9980 27100 28525 36786
3218 12776 40651 40703
7669 25783 32781 34504
25951 34595 39049 40597
11271 35112 35290 40600
5330 38324 40325 40986
58 24777 40560 40835
23895 25427 33552 37472
2811 4731 11601 39912
109 39021 40611 40754
79 15387 30999 40978
31162 34975 38844 39784
34891 37007 39433 40102
42 9072 21526 22610
20243 20499 24418 29056
7951 26469 29729 40956
6 10833 13188 15714
7910 20652 40574 40874
14586 24839 37804 40722
1103 11381 21050 30084
10 9032 20123 28528
19477 29966 37702 37766
131 31352 39069 40971
34 7368 17799 27467
16767 27584 32869 34769
31515 34543 36230 40752
15098 25451 26402 27629
149 10388 24558 40709
6997 7288 23995 29893
346 12245 13843 40402.

According to the present technology, an information bit is encoded into an LDPC code with a code length of 64800 bits and an encoding rate of 7/30, 8/30, 9/30, 10/30, or 11/30 based on a parity check matrix of an LDPC (Low Density Parity Check) code.

According to the present technology, an LDPC code with a code length of 64800 bits and an encoding rate of 7/30, 8/30, 9/30, 10/30, or 11/30 is decoded based on a parity check matrix of an LDPC (Low Density Parity Check) code.

The LDPC code includes an information bit and a parity bit. The parity check matrix includes an information matrix part corresponding to the information bit and a parity matrix part corresponding to the parity bit. The information matrix part is shown by a parity check matrix initial value table. The parity check matrix initial value table is a table showing positions of elements of 1 of the information matrix part every 360 columns.

A parity check matrix initial value table with an encoding rate of 7/30 is expressed as follows
548 9528 12205 12770 22023 22082 25884 27421 33215 36046 43580 43953 47539
919 2623 5098 5514 5645 6348 9666 13795 14555 43224 44048 44948 47964
995 7270 17753 21272 29228 29916 31634 34055 35205 37499 37777 47490 49301
645 3803 8836 9470 11054 20253 29417 31243 31990 36468 38715 39932 43045
14572 18646 21100 26617 32033 32410 37195 38586 43833 44577 45584 46453 49515
6004 16982 17829 24616 28056 29646 32944 39051 42517 47086 48585 48772 49247
1306 1447 4898 7781 18587 25724 26672 35062 35202 37080 39781 46111 47595
92 3231 13043 22258 24198 28923 33303 37846 43610 44857 47322 48914 49291
298 12557 13469 14451 21917 23539 26310 29839 37050 38507 41377 46971 48155
12582 13044 21039 30600 34202 34947 37120 39108 39203 43449 46941 48542 49354
871 12218 12680 14152 17171 25797 29021 37783 43728 47519 48794 48898 48980
35 4623 13422 15881 16692 17463 23675 28063 31248 41997 44246 47992 48339
7150 13015 17950 18214 20659 23579 25714 28328 32658 39717 39995 43322 45884
82 11054 11845 19085 24174 26694 41530 45954 46508 46892 48832 49097 49420
5789 13839 18512 25596 26478 26736 29431 32349 33384 41765 46661 49206 49543
13805 17786 17798 29653 30310 34870 40176 40391 43227 45292 46423 46855 49454
12433 27119 34645
32065 34998 44021
5158 16546 34359
44 33285 39929
39032 39296 40317
9885 45251 47640
14383 43446 44478
31280 39945 48472
27961 38221 48391
2927 37404 38716
19461 42462 46162
24909 25915 40636
11029 35538 45381
26880 34179 48775
192 6032 26853
4563 14952 24256
10003 30853 43811
749 36334 41363
100 17006 24982
9507 20228 31214
41691 44310 47083
24070 30411 46982
2727 28251 49289
16689 21167 32590
40813 41198 46175
8336 32714 43075.

A parity check matrix initial value table with an encoding rate of 8/30 is expressed as follows
100 3433 4111 9089 13360 24012 26305 30252 31430 31769 34689 34917 36091 40873 41983 42689 43835 44318 47109
3 48 124 2240 7029 21694 24565 29302 39777 42706 43631 43784 46033 47064 47079 47141 47239 47439 47479
2 5675 7056 12715 24128 26596 30571 38210 38586 41138 42272 43336 43444 43917 45812 46840 47245 47286 47510
2103 4285 10068 10702 12693 17619 18711 21309 22191 22999 37432 45646 46275 46338 46777 46860 46963 47432 47472
6827 8209 8606 10412 15670 19469 22205 22215 25425 29565 34843 34985 37686 39277 44625 45016 45623 47069 47250
58 114 1751 7913 24642 26995 40734 41486 43133 44804 45490 45725 46122 46412 47019 47080 47103 47495 47506
96 5952 9078 9786 17738 17888 17986 31657 34430 34763 35450 37276 42395 43223 43283 44261 45648 47014 47276
106 5405 9614 20500 21633 23242 28875 37238 38854 41778 42292 43883 45909 46558 46826 47292 47353 47436 47504
32 11217 12153 26818 27616 38783 39976 40842 43581 43703 44287 44435 44576 44774 46080 46098 46801 46813 47168
65 102 111 3879 11224 11772 23623 27306 28726 34663 34873 36288 39196 42003 45279 45629 46836 47021 47419
77 131 11275 18964 20418 22364 22635 27727 28689 29720 29781 32110 41597 42046 43952 44786 46416 46808 47200
87 8637 10829 23737 24117 26486 29603 34389 35509 35872 38948 40643 42698 45949 46159 46660 47041 47165 47220
2 58 3110 7539 8886 10422 11597 13385 27870 35895 38120 43546 44948 46272 46369 46596 47199 47317 47351
78 16119 27780 32231 38973 39088 40118 40231 43170 44131 44203 44878 45905 46250 47011 47113 47195 47303 47427
2960 6685 8830 11107 11843 12811 30030 36574 36850 36920 37706 38025 41007 43554 44109 44643 45874 46469 46565
125 366 10175 29860
45 17503 44634 45789
6272 19614 34408 37248
14785 41017 44274 46858
19935 22960 44726 44919
15247 17925 33947 37392
34631 39148 43287 45443
8544 26457 30996 38672
11725 31442 42167 45461
22357 41743 46702 47285
13786 26288 41358 43082
7306 21352 43298 47359
77 5188 20988 45572
10334 23790 40878
9304 29379 47450
22048 44762 47300
8529 8825 47443
40831 41328 46415
26715 43038 46498
26925 30797 43181
32434 45624 47460
17989 31811 47215
5624 25501 33016
5024 9037 33642
93 7329 46908
20303 42578 46780
16137 26869 42360
112 3049 46527
23615 29931 47360
23050 24267 44687
60 40754 47114
30217 36283 37445
127 27308 38345.

A parity check matrix initial value table with an encoding rate of 9/30 is expressed as follows
339 4777 5366 7623 13034 13260 15107 17772 20338 21178 25914 27663 29948 37489 41021
3871 5812 9795 23437 24079 27699 33471 39878 40302 41038 41217 42316 42765 43675 45118
3699 4072 16553 21492 26210 29839 30322 34139 38227 39696 40762 41156 41269 45168 45350
995 12194 12494 16542 20423 21950 23519 26215 26708 30587 38352 38840 39729 41645 43210
3963 4315 6832 11354 21042 21084 21108 25595 33109 34029 34448 35129 38018 39012 44791
164 887 2902 9021 9193 16705 17850 19241 25893 33427 37416 41024 41355 44381 45303
1367 1495 5495 14440 18026 18130 18178 21946 24057 25663 29216 31965 38107 43907 44278
10763 13722 13975 18294 20813 23028 23353 24211 37366 38805 40985 41792 42495 43259 43528
1580 12448 21464 31246 33058 34794 35760 36021 36426 37138 37478 38199 42138 4233545207
83 112 12225 15224 18205 21345 28488 34362 37195 39660 42371 42814 44509 45201 45244
6836 7635 11644 16591 17121 19307 21456 23544 30596 37887 38141 38581 43607 44246 45097
9174 14934 17131 29762 30243 31656 33251 35498 37106 37655 41462 44002 44649 45032 45230
33 5376 13536 17068 18581 23478 32021 32074 33716 38434 39452 42166 44305 44979 45306
6013 7553 10023 19354 23126 25427 27665 30239 32699 34123 36171 38898 38972 41974 45213
41 98 3088 8522 26252 29602 30009 30138 30948 32190 32428 32498 34273 34955 45311
2000 15664 20677 20792 22980 25111 31491 37611 37981 39872 41668 42336 43602 43828 45329
23 67 97 5339 8121 8583 20647 25425 32305 37158 40968 41578 43492 44929 45273
1643 3496 5121 6546 15643 16423 20602 39950 43178 43252 43683 43992 44001 44611 45125
11093 19172 20548 24518 28289 29246 30148 34884 40403 40745 42723 43064 44448 44723 44812
12748 12799 28567 41605
1965 4087 31879
27178 33638 38344
9580 13096 45337
2672 22800 43869
28287 31407 31975
2823 5108 9945
5891 30848 42082
23 41944 44909
909 2311 45162
24998 37829 44704
35339 40087 45019
16928 26505 35256
26462 27297 37766
19656 35067 38586
6958 17172 41412
72 26012 37231
15259 16044 30243
2879 12148 34601
36173 39731 42668
20670 35816 43266
22570 27213 30404
40284 44171 45313
17765 22514 39347
24711 39892 45132
13741 34633 44535
15209 31692 45280
11189 43771 45303
28294 31110 32287
29085 39876 45246
24285 36009 45347
6882 28921 34504
9256 19267 44194
2132 21404 28687
23809 34383 44540.

A parity check matrix initial value table with an encoding rate of 10/30 is expressed as follows
867 2733 2978 8947 10214 11810 13566 15922 18838 20543 25845 29179 30055 31284 33447 34330 35081 35605 36268 39563 42331 43174
2765 6017 6394 6769 12351 13567 15195 19900 23094 27077 28626 28914 32219 33106 33662 33905 34878 37861 39749 39862 40976 42690
2343 4231 7603 7789 8396 8783 15636 16221 20591 21538 24008 25117 25663 26817 29692 30937 31472 32070 33793 39506 41763 43172
8536 10705 10960 11206 12513 15399 17108 17224 17512 20180 25288 27824 28958 30600 36792 36828 38891 39575 39581 42342 42914 42961
9 107 681 1195 9957 14055 21420 23279 26129 32044 35750 37065 37092 37165 37179 40127 40835 41476 41564 41571 42576 42910
86 1760 6842 8119 8904 12644 17603 18189 20018 22259 22654 25620 27606 27833 28002 31053 31814 31848 35573 36133 40698 41370
28 115 4354 9276 11229 11252 13848 21112 22851 29912 32453 34693 37344 37420 40926 40992 41063 41762 41856 42012 42642 43045
1589 7190 7221 7668 11805 14071 14367 14629 17087 19579 19861 25505 35471 35514 37495 38375 40286 40330 40402 41662 42638 43126
76 99 3237 5137 7982 9598 13470 14045 26680 27058 32025 32235 34601 35658 36841 38408 40517 40987 41400 41861 42691 42772
54 2470 2728 3177 3484 8267 9351 17523 18513 21119 22947 23771 26569 27308 31217 35887 36449 38529 40424 41873 42146 42706
39 80 385 1386 3397 5234 14733 16955 17656 23262 23463 25340 31638 31676 32683 37130 37641 39064 41839 42193 42495 43063
62 573 11847 14616 16033 16064 16302 18776 19434 23845 23873 25937 27741 32244 32612 33554 38445 38480 38610 40933 42386 42520
33 183 968 5477 6173 7363 10358 12597 14468 18025 23369 23387 24723 25254 28299 28989 31675 32776 35077 40241 41572 42035
36 2529 2543 3891 7108 9002 9481 16496 19796 26687 27343 33300 35495 37070 39247 40126 41758 41892 42124 42622 42738 43100
91 6897 8794 9581 12922 15711 18539 19227 21592 22906 26449 29804 30895 31538 31930 33392 38006 38294 38705 38952 39005 42120
64 76 709 1155 3162 7099 8740 9670 12678 21126 29239 29844 31248 32001 35243 36814 38008 42050 42149 42631 42705 43119
17670 40897 42359
17471 20895 32101
5458 5508 30504
17291 19627 27186
14600 41106 43103
18059 28398 40623
23776 30190 32880
4676 13593 21791
19 2832 27959
6193 21762 42854
64 16088 42982
29425 35004 42209
14338 31982 41789
21572 42838 42923
5 87 6639
5529 42541 43173
15512 31740 35801
44 86 43183
26027 26995 36455
16485 30090 34537
22276 40174 42367
10781 18230 18766
9984 42877 43027
11108 20618 41626
8496 42994 43171
10581 25803 42606
4989 14002 29020
35032 39378 41455
109 11667 42914
12471 14022 35477
31761 34625 36228
1228 6013 43110
22355 37905 40784
12740 21805 31648
4202 28639 32213
10697 31674 42998
4092 23877 34360
54 9459 16450
1 56 33675
18163 31951 42528
50 5655 35891
47 35033 40356
29097 32786 35931
9532 27004 43009.

A parity check matrix initial value table with an encoding rate of 11/30 is expressed as follows
3208 6587 9493 9539 12368 12501 14811 15784 17625 18654 18721 19471 19503 20079 20411 20876 21493 22083 22430 27275 29322 32758 33227 33347 33715 34472 34711 38450 39151 39709 39862 40093 40497 40912
42 1118 3086 5466 6379 8483 9051 9330 13250 13898 14055 15033 18094 21429 22652 25251 28709 29909 30233 30472 30635 31367 32603 33614 33708 36404 36530 37039 37782 38115 38307 40225 40597 40822
5939 11990 15027 15162 16503 17171 17806 17902 18031 18077 21216 22134 22660 24170 28558 29364 30003 31128 32674 33103 33361 34196 34435 34626 34991 35974 36022 37459 38170 38709 39774 39960 40571 40858
63 3871 9148 10328 12830 12912 18361 18839 20122 23126 23795 28612 30350 32251 32750 33762 33866 36188 36979 37562 37836 38536 38705 38829 39609 40219 40324 40336 40367 40638 40699 40809 40987 41019
36 70 104 3737 5028 19023 19575 19746 23840 24611 24661 26741 27749 30359 31027 31509 32621 32859 33830 34619 35281 35479 36796 37344 37555 38993 39088 39445 40276 40299 40762 40771 40835 40967
113 2313 4411 5858 9909 10426 18955 21663 21884 24105 24472 26944 27826 28574 28689 29579 30903 32352 33334 36408 36795 36805 37112 37121 38731 39080 39739 40007 40326 40356 40472 40476 40622 40778
54 84 3529 5202 9825 9900 10846 12104 13332 14493 14584 23772 24084 25786 25963 26145 28306 29514 30050 30060 33171 33416 33657 33951 34908 37715 37854 38088 38966 39148 40166 40633 40746 40939
105 8722 10244 12148 13029 16368 18186 19660 19830 21616 22256 22534 23100 23219 25473 26585 29858 32350 33305 34290 34356 34675 35297 37052 37144 37934 38201 39867 40270 40539 40781 40804 40944 40966
53 61 82 96 2665 6552 9517 15693 17214 17588 18347 19039 20679 21962 24255 25861 27117 27919 30691 36195 36379 37031 37309 37535 37793 38198 38212 38595 38808 38911 39474 39677 40135 40935
15 67 723 2962 4991 5285 11583 13398 16301 16338 20996 21510 25697 28214 29143 30539 30573 31108 32500 32506 32727 32755 36134 37226 37655 37799 39219 39626 39980 40093 40105 40628 40634 40816
18854 37884 40104 40772
35209 40379 40447 40508
3049 36078 39403 40402
19118 27981 35730 36649
20465 28570 39076 40910
24047 31275 39790 40126
31041 33526 34162 39092
1152 8976 24071 35698
3 27991 31485 40934
5245 20676 30579 38823
47 11196 38674 38894
1492015270 16047 40928
23974 30146 39805 40911
8791 16641 25060 31681
1147 4233 34386 37802
58 5354 22265 41018
869 3078 39882 40730
1071 6322 9163 10642
7235 32596 35540 37487
26910 35537 40830 41035
81 11905 16179 19558
29 41 5161 12173
3043 5574 9993 26058
875 36935 39423 40956
3362 19166 20017 39729
12893 16403 33880 37115
9980 27100 28525 36786
3218 12776 40651 40703
7669 25783 32781 34504
25951 34595 39049 40597
11271 35112 35290 40600
5330 38324 40325 40986
58 24777 40560 40835
23895 25427 33552 37472
2811 4731 11601 39912
109 39021 40611 40754
79 15387 30999 40978
31162 34975 38844 39784
34891 37007 39433 40102
42 9072 21526 22610
20243 20499 24418 29056
7951 26469 29729 40956
6 10833 13188 15714
7910 20652 40574 40874
14586 24839 37804 40722
1103 11381 21050 30084
10 9032 20123 28528
19477 29966 37702 37766
131 31352 39069 40971
34 7368 17799 27467
16767 27584 32869 34769
31515 34543 36230 40752
15098 25451 26402 27629
149 10388 24558 40709
6997 7288 23995 29893
346 12245 13843 40402.

The data processing device may be an independent device and may be an internal block constituting one device.

### Advantageous Effects of Invention

According to the present disclosure, it is possible to provide an LDPC code of an excellent error rate.

### BRIEF DESCRIPTION OF DRAWINGS

FIG. 1 is an illustration of a parity check matrix H of an LDPC code.

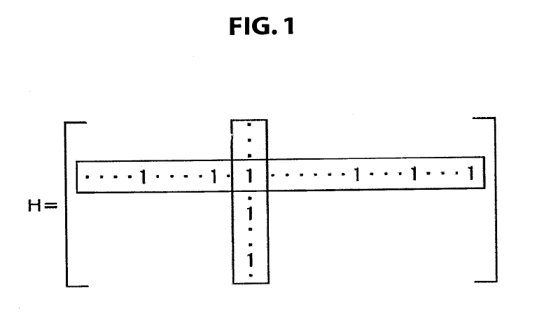

FIG. 2 is a flowchart illustrating a decoding sequence of an LDPC code.

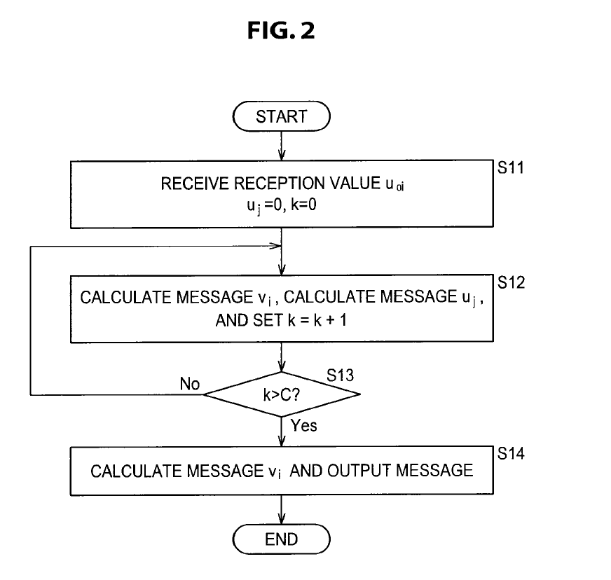

FIG. 3 is an illustration of an example of a parity check matrix of an LDPC code.

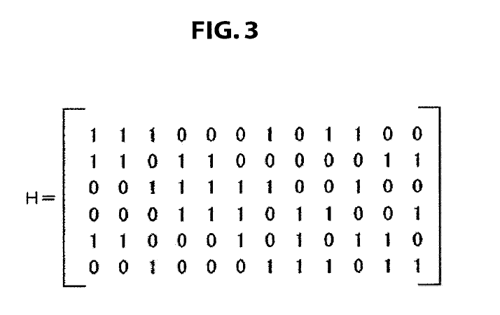

FIG. 4 is an illustration of a Tanner graph of a parity check matrix.

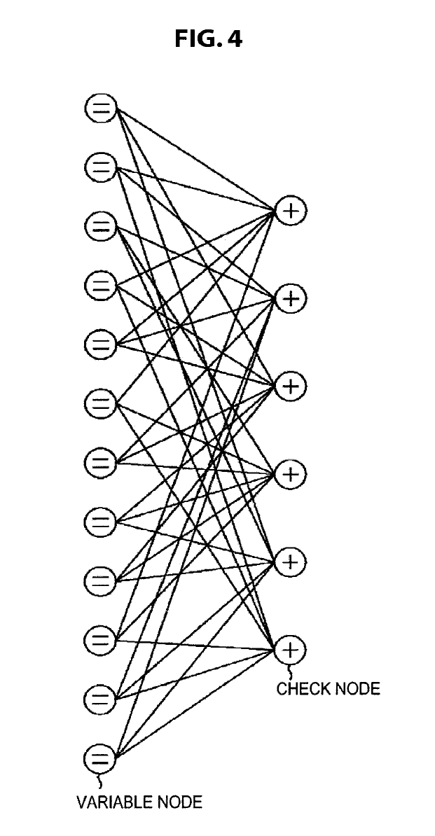

FIG. 5 is an illustration of a variable node.

FIG. 6 is an illustration of a check node.

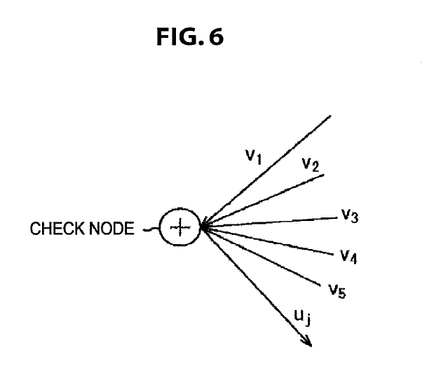

FIG. 7 is an illustration of a configuration example of an embodiment of a transmission system to which the present invention is applied.

FIG. 8 is a block diagram illustrating a configuration example of a transmitting device 11.

FIG. 9 is a block diagram illustrating a configuration example of a bit interleaver 116.

FIG. 10 is an illustration of a parity check matrix.

FIG. 11 is an illustration of a parity matrix.

FIG. 12 is an illustration of a parity check matrix of an LDPC code defined in a standard of DVB-S.2.

FIG. 13 is an illustration of a parity check matrix of an LDPC code defined in a standard of DVB-S.2.

FIG. 14 is an illustration of signal point arrangement of 16QAM.

FIG. 15 is an illustration of signal point arrangement of 64QAM.

FIG. 16 is an illustration of signal point arrangement of 64QAM.

FIG. 17 is an illustration of signal point arrangement of 64QAM.

FIG. 18 is an illustration of signal point arrangement defined in the standard of DVB-S.2.

FIG. 19 is an illustration of signal point arrangement defined in the standard of DVB-S.2.

FIG. 20 is an illustration of signal point arrangement defined in the standard of DVB-S.2.

FIG. 21 is an illustration of signal point arrangement defined in the standard of DVB-S.2.

FIG. 22 is an illustration of processing of a demultiplexer 25.

FIG. 23 is an illustration of processing of a demultiplexer 25.

FIG. 24 is an illustration of a Tanner graph for decoding of an LDPC code.

FIG. 25 is an illustration of a parity matrix H_{T} becoming a staircase structure and a Tanner graph corresponding to the parity matrix H_{T}.

FIG. 26 is an illustration of a parity matrix H_{T} of a parity check matrix H corresponding to an LDPC code after parity interleave.

FIG. 27 is an illustration of a transformed parity check matrix.

FIG. 28 is an illustration of processing of a column twist interleaver 24.

FIG. 29 is an illustration of a column number of a memory 31 necessary for a column twist interleave and an address of a write start position.

FIG. 30 is an illustration of a column number of a memory 31 necessary for a column twist interleave and an address of a write start position.

FIG. 31 is a flowchart illustrating processing executed by a bit interleaver 116 and a QAM encoder 117.

FIG. 32 is an illustration of a model of a communication path adopted by simulation.

FIG. 33 is an illustration of a relation of an error rate obtained by simulation and a Doppler frequency f_{d} of a flutter.

FIG. 34 is an illustration of a relation of an error rate obtained by simulation and a Doppler frequency f_{d} of a flutter.

FIG. 35 is a block diagram illustrating a configuration example of an LDPC encoder 115.

FIG. 36 is a flowchart illustrating processing of an LDPC encoder 115.

FIG. 37 is an illustration of an example of a parity check matrix initial value table in which an encoding rate is 1/4 and a code length is 16200.

FIG. 38 is an illustration of a method of calculating a parity check matrix H from a parity check matrix initial value table.

FIG. 39 is an illustration of the characteristic of BER/FER of an LDPC code whose code length defined in the standard of DVB-S.2 is 64800 bits.

FIG. 40 is an illustration of an example of a parity check matrix initial value table in which an encoding rate is 2/30 and a code length is 64800.

FIG. 41 is an illustration of an example of a parity check matrix initial value table in which an encoding rate is 3/30 and a code length is 64800.

FIG. 42 is an illustration of an example of a parity check matrix initial value table in which an encoding rate is 4/30 and a code length is 64800.

FIG. 43 is an illustration of an example of a parity check matrix initial value table in which an encoding rate is 5/30 and a code length is 64800.

FIG. 44 is an illustration of an example of a parity check matrix initial value table in which an encoding rate is 6/30 and a code length is 64800.

FIG. 45 is an illustration of an example of a parity check matrix initial value table in which an encoding rate is 7/30 and a code length is 64800.

FIG. 46 is an illustration of an example of a parity check matrix initial value table in which an encoding rate is 8/30 and a code length is 64800.

FIG. 47 is an illustration of an example of a parity check matrix initial value table in which an encoding rate is 8/30 and a code length is 64800.

FIG. 48 is an illustration of an example of a parity check matrix initial value table in which an encoding rate is 9/30 and a code length is 64800.

FIG. 49 is an illustration of an example of a parity check matrix initial value table in which an encoding rate is 9/30 and a code length is 64800.

FIG. 50 is an illustration of an example of a parity check matrix initial value table in which an encoding rate is 10/30 and a code length is 64800.

FIG. 51 is an illustration of an example of a parity check matrix initial value table in which an encoding rate is 10/30 and a code length is 64800.

FIG. 52 is an illustration of an example of a parity check matrix initial value table in which an encoding rate is 11/30 and a code length is 64800.

FIG. 53 is an illustration of an example of a parity check matrix initial value table in which an encoding rate is 11/30 and a code length is 64800.

FIG. 54 is an illustration of an example of a parity check matrix initial value table in which an encoding rate is 12/30 and a code length is 64800.

FIG. 55 is an illustration of an example of a parity check matrix initial value table in which an encoding rate is 12/30 and a code length is 64800.

FIG. 56 is an illustration of an example of a parity check matrix initial value table in which an encoding rate is 13/30 and a code length is 64800.

FIG. 57 is an illustration of an example of a parity check matrix initial value table in which an encoding rate is 13/30 and a code length is 64800.

FIG. 58 is an illustration of an example of a parity check matrix initial value table in which an encoding rate is 14/30 and a code length is 64800.

FIG. 59 is an illustration of an example of a parity check matrix initial value table in which an encoding rate is 14/30 and a code length is 64800.

FIG. 60 is an illustration of an example of a parity check matrix initial value table in which an encoding rate is 15/30 and a code length is 64800.

FIG. 61 is an illustration of an example of a parity check matrix initial value table in which an encoding rate is 15/30 and a code length is 64800.

FIG. 62 is an illustration of an example of a parity check matrix initial value table in which an encoding rate is 16/30 and a code length is 64800.

FIG. 63 is an illustration of an example of a parity check matrix initial value table in which an encoding rate is 16/30 and a code length is 64800.

FIG. 64 is an illustration of an example of a parity check matrix initial value table in which an encoding rate is 16/30 and a code length is 64800.

FIG. 65 is an illustration of an example of a parity check matrix initial value table in which an encoding rate is 17/30 and a code length is 64800.

FIG. 66 is an illustration of an example of a parity check matrix initial value table in which an encoding rate is 17/30 and a code length is 64800.

FIG. 67 is an illustration of an example of a parity check matrix initial value table in which an encoding rate is 17/30 and a code length is 64800.

FIG. 68 is an illustration of an example of a parity check matrix initial value table in which an encoding rate is 18/30 and a code length is 64800.

FIG. 69 is an illustration of an example of a parity check matrix initial value table in which an encoding rate is 18/30 and a code length is 64800.

FIG. 70 is an illustration of an example of a parity check matrix initial value table in which an encoding rate is 18/30 and a code length is 64800.

FIG. 71 is an illustration of an example of a parity check matrix initial value table in which an encoding rate is 19/30 and a code length is 64800.

FIG. 72 is an illustration of an example of a parity check matrix initial value table in which an encoding rate is 19/30 and a code length is 64800.

FIG. 73 is an illustration of an example of a parity check matrix initial value table in which an encoding rate is 19/30 and a code length is 64800.

FIG. 74 is an illustration of an example of a parity check matrix initial value table in which an encoding rate is 20/30 and a code length is 64800.

FIG. 75 is an illustration of an example of a parity check matrix initial value table in which an encoding rate is 20/30 and a code length is 64800.

FIG. 76 is an illustration of an example of a parity check matrix initial value table in which an encoding rate is 20/30 and a code length is 64800.

FIG. 77 is an illustration of an example of a parity check matrix initial value table in which an encoding rate is 21/30 and a code length is 64800.

FIG. 78 is an illustration of an example of a parity check matrix initial value table in which an encoding rate is 21/30 and a code length is 64800.

FIG. 79 is an illustration of an example of a parity check matrix initial value table in which an encoding rate is 21/30 and a code length is 64800.

FIG. 80 is an illustration of an example of a parity check matrix initial value table in which an encoding rate is 22/30 and a code length is 64800.

FIG. 81 is an illustration of an example of a parity check matrix initial value table in which an encoding rate is 22/30 and a code length is 64800.

FIG. 82 is an illustration of an example of a parity check matrix initial value table in which an encoding rate is 22/30 and a code length is 64800.

FIG. 83 is an illustration of an example of a parity check matrix initial value table in which an encoding rate is 23/30 and a code length is 64800.

FIG. 84 is an illustration of an example of a parity check matrix initial value table in which an encoding rate is 23/30 and a code length is 64800.

FIG. 85 is an illustration of an example of a parity check matrix initial value table in which an encoding rate is 23/30 and a code length is 64800.

FIG. 86 is an illustration of an example of a parity check matrix initial value table in which an encoding rate is 24/30 and a code length is 64800.

FIG. 87 is an illustration of an example of a parity check matrix initial value table in which an encoding rate is 24/30 and a code length is 64800.

FIG. 88 is an illustration of an example of a parity check matrix initial value table in which an encoding rate is 24/30 and a code length is 64800.

FIG. 89 is an illustration of an example of a parity check matrix initial value table in which an encoding rate is 25/30 and a code length is 64800.

FIG. 90 is an illustration of an example of a parity check matrix initial value table in which an encoding rate is 25/30 and a code length is 64800.

FIG. 91 is an illustration of an example of a parity check matrix initial value table in which an encoding rate is 25/30 and a code length is 64800.

FIG. 92 is an illustration of an example of a parity check matrix initial value table in which an encoding rate is 26/30 and a code length is 64800.

FIG. 93 is an illustration of an example of a parity check matrix initial value table in which an encoding rate is 26/30 and a code length is 64800.

FIG. 94 is an illustration of an example of a parity check matrix initial value table in which an encoding rate is 26/30 and a code length is 64800.

FIG. 95 is an illustration of an example of a parity check matrix initial value table in which an encoding rate is 27/30 and a code length is 64800.

FIG. 96 is an illustration of an example of a parity check matrix initial value table in which an encoding rate is 27/30 and a code length is 64800.

FIG. 97 is an illustration of an example of a parity check matrix initial value table in which an encoding rate is 27/30 and a code length is 64800.

FIG. 98 is an illustration of an example of a parity check matrix initial value table in which an encoding rate is 27/30 and a code length is 64800.

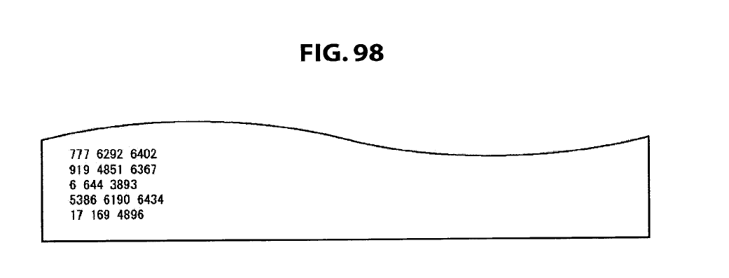

FIG. 99 is an illustration of an example of a parity check matrix initial value table in which an encoding rate is 28/30 and a code length is 64800.

FIG. 100 is an illustration of an example of a parity check matrix initial value table in which an encoding rate is 28/30 and a code length is 64800.

FIG. 101 is an illustration of an example of a parity check matrix initial value table in which an encoding rate is 28/30 and a code length is 64800.

FIG. 102 is an illustration of an example of a parity check matrix initial value table in which an encoding rate is 28/30 and a code length is 64800.

FIG. 103 is an illustration of an example of a parity check matrix initial value table in which an encoding rate is 29/30 and a code length is 64800.

FIG. 104 is an illustration of an example of a parity check matrix initial value table in which an encoding rate is 29/30 and a code length is 64800.

FIG. 105 is an illustration of an example of a parity check matrix initial value table in which an encoding rate is 29/30 and a code length is 64800.

FIG. 106 is an illustration of an example of a parity check matrix initial value table in which an encoding rate is 29/30 and a code length is 64800.

FIG. 107 is an illustration of a Tanner graph of an ensemble of a degree sequence in which the column weight is 3 and the row weight is 6.

FIG. 108 is an illustration of an example of a Tanner graph of an ensemble of a multi-edge type.

FIG. 109 is an illustration of the minimum cycle length and performance threshold of a parity check matrix of an LDPC code with a code length of 64800.

FIG. 110 is an illustration of a parity check matrix of an LDPC code with a code length of 64800.

FIG. 111 is an illustration of a parity check matrix of an LDPC code with a code length of 64800.

FIG. 112 is an illustration of a simulation result of BER/FER of an LDPC code with a code length of 64800.

FIG. 113 is an illustration of a simulation result of BER/FER of an LDPC code with a code length of 64800.

FIG. 114 is an illustration of a simulation result of BER/FER of an LDPC code with a code length of 64800.

FIG. 115 is an illustration of a BCH code used for simulation of BER/FER of an LDPC code with a code length of 64800.

FIG. 116 is a block diagram illustrating a configuration example of a receiving device 12.

FIG. 117 is a block diagram illustrating a configuration example of a bit deinterleaver 165.

FIG. 118 is a flowchart illustrating processing executed by a QAM decoder 164, a bit deinterleaver 165, and an LDPC decoder 166.

FIG. 119 is an illustration of an example of a parity check matrix of an LDPC code.

FIG. 120 is an illustration of a matrix (transformed parity check matrix) obtained by executing row replacement and column replacement with respect to a parity check matrix.

FIG. 121 is an illustration of a transformed parity check matrix divided in a 5×5 unit.

FIG. 122 is a block diagram illustrating a configuration example of a decoding device that collectively performs P node operations.

FIG. 123 is a block diagram illustrating a configuration example of an LDPC decoder 166.

FIG. 124 is an illustration of processing of a multiplexer 54 constituting a bit deinterleaver 165.

FIG. 125 is an illustration of processing of a column twist deinterleaver 55.

FIG. 126 is a block diagram illustrating another configuration example of a bit deinterleaver 165.

FIG. 127 is a block diagram illustrating a first configuration example of a reception system that can be applied to a receiving device 12.

FIG. 128 is a block diagram illustrating a second configuration example of a reception system that can be applied to a receiving device 12.

FIG. 129 is a block diagram illustrating a third configuration example of a reception system that can be applied to a receiving device 12.

FIG. 130 is a block diagram illustrating a configuration example of an embodiment of a computer to which the present technology is applied.

### DESCRIPTION OF EMBODIMENTS

### Configuration Example of Transmission System to which Present Disclosure is Applied

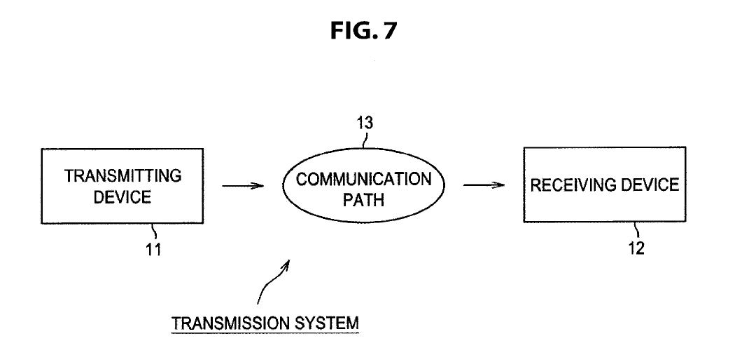

FIG. 7 illustrates a configuration example of an embodiment of a transmission system (a system means a logical gathering of a plurality of devices and a device of each configuration may be arranged or may not be arranged in the same casing) to which the present invention is applied.

In FIG. 7, the transmission system includes a transmitting device 11 and a receiving device 12.

For example, the transmitting device 11 transmits (broadcasts) (transfers) a program of television broadcasting, and so on. That is, for example, the transmitting device 11 encodes target data that is a transmission target such as image data and audio data as a program into LDPC codes, and, for example, transmits them through a communication path 13 such as a satellite circuit, a ground wave and a cable (wire circuit).

The receiving device 12 receives the LDPC code transmitted from the transmitting device 11 through the communication path 13, decodes the LDPC code to obtain the target data, and outputs the target data.

In this case, it is known that the LDPC code used by the transmission system of FIG. 7 shows the very high capability in an AWGN (Additive White Gaussian Noise) communication path.

Meanwhile, in the communication path 13, burst error or erasure may be generated. Especially in the case where the communication path 13 is the ground wave, for example, in an OFDM (Orthogonal Frequency Division Multiplexing) system, power of a specific symbol may become 0 (erasure) according to delay of an echo (paths other than a main path), under a multi-path environment in which D/U (Desired to Undesired Ratio) is 0 dB (power of Undesired=echo is equal to power of Desired=main path).

In the flutter (communication path in which delay is 0 and an echo having a Doppler frequency is added), when D/U is 0 dB, entire power of an OFDM symbol at a specific time may become 0 (erasure) by the Doppler frequency.

In addition, the burst error may be generated due to a situation of a wiring line from a receiving unit (not illustrated in the drawings) of the side of the receiving device 12 such as an antenna receiving a signal from the transmitting device 11 to the receiving device 12 or instability of a power supply of the receiving device 12.

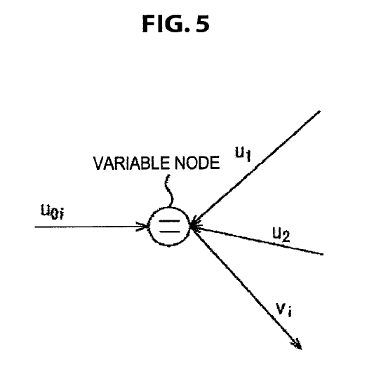

Meanwhile, in decoding of the LDPC code, in the variable node corresponding to the column of the parity check matrix H and the code bit of the LDPC code, as illustrated in FIG. 5 described above, the variable node operation of the expression (1) with the addition of (the reception value u0i of) the code bit of the LDPC code is performed. For this reason, if error is generated in the code bits used for the variable node operation, precision of the calculated message is deteriorated.

In the decoding of the LDPC code, in the check node, the check node operation of the expression (7) is performed using the message calculated by the variable node connected to the check node. For this reason, if the number of check nodes in which error (including erasure) is generated simultaneously in (the code bits of the LDPC codes corresponding to) the plurality of connected variable nodes increases, decoding performance is deteriorated.

That is, if the two or more variable nodes of the variable nodes connected to the check node become simultaneously erasure, the check node returns a message in which the probability of a value being 0 and the probability of a value being 1 are equal to each other, to all the variable nodes. In this case, the check node that returns the message of the equal probabilities does not contribute to one decoding processing (one set of the variable node operation and the check node operation). As a result, it is necessary to increase the repetition number of times of the decoding processing, the decoding performance is deteriorated, and consumption power of the receiving device 12 that performs decoding of the LDPC code increases.

Therefore, in the transmission system of FIG. 7, tolerance against the burst error or the erasure can be improved while performance in the AWGN communication path is maintained.

[Configuration Example of Transmitting Device 11]

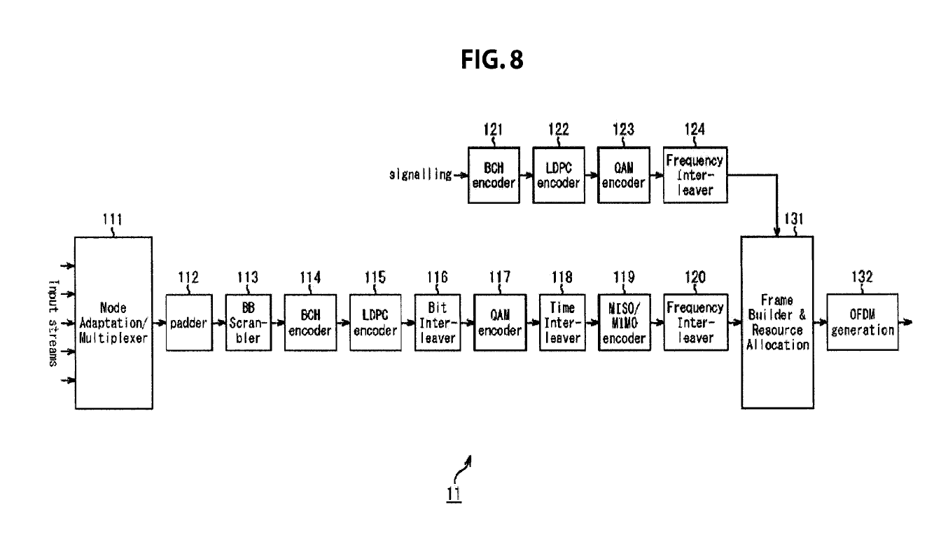

FIG. 8 is a block diagram illustrating a configuration example of the transmitting device 11 of FIG. 7.

In the transmitting device 11, one or more input streams corresponding to target data are supplied to a mode adaptation/multiplexer 111.

The mode adaptation/multiplexer 111 performs mode selection and processes such as multiplexing of one or more input streams supplied thereto, as needed, and supplies data obtained as a result to a padder 112.

The padder 112 performs necessary zero padding (insertion of Null) with respect to the data supplied from the mode adaptation/multiplexer 111 and supplies data obtained as a result to a BB scrambler 113.

The BB scrambler 113 performs base-band scrambling (BB scrambling) with respect to the data supplied from the padder 112 and supplies data obtained as a result to a BCH encoder 114.

The BCH encoder 114 performs BCH encoding with respect to the data supplied from the BB scrambler 113 and supplies data obtained as a result as LDPC target data to be an LDPC encoding target to an LDPC encoder 115.

The LDPC encoder 115 performs LDPC encoding according to a parity check matrix in which a parity matrix to be a portion corresponding to a parity bit of an LDPC code becomes a staircase structure with respect to the LDPC target data supplied from the BCH encoder 114, and outputs an LDPC code in which the LDPC target data is information bits.

That is, the LDPC encoder 115 performs the LDPC encoding to encode the LDPC target data with an LDPC such as the LDPC code (corresponding to the parity check matrix) defined in the predetermined standard of the DVB-S.2, the DVB-T.2, the DVB-C.2 or the like and outputs the predetermined LDPC code (corresponding to the parity check matrix) or the like obtained as a result.

The LDPC code defined in the standard of the DVB-S.2, the DVB-T.2, and the DVB-C.2 is an IRA (Irregular Repeat Accumulate) code and a parity matrix of the parity check matrix of the LDPC code becomes a staircase structure. The parity matrix and the staircase structure will be described later. The IRA code is described in “Irregular Repeat-Accumulate Codes”, H. Jin, A. Khandekar, and R. J. McEliece, in Proceedings of 2nd International Symposium on Turbo codes and Related Topics, pp. 1-8, September 2000, for example.

The LDPC code that is output by the LDPC encoder 115 is supplied to the bit interleaver 116.

The bit interleaver 116 performs bit interleave to be described later with respect to the LDPC code supplied from the LDPC encoder 115 and supplies the LDPC code after the bit interleave to a QAM encoder 117.

The QAM encoder 117 maps the LDPC code supplied from the bit interleaver 116 to a signal point representing one symbol of orthogonal modulation in a unit (symbol unit) of code bits of one or more bits of the LDPC code and performs the orthogonal modulation (multilevel modulation).

That is, the QAM encoder 117 performs maps the LDPC code supplied from the bit interleaver 116 to a signal point determined by a modulation method performing the orthogonal modulation of the LDPC code, on an IQ plane (|Q constellation) defined by an I axis representing an I component of the same phase as a carrier and a Q axis representing a Q component orthogonal to the carrier, and performs the orthogonal modulation.

In this case, as the modulation method of the orthogonal modulation performed by the QAM encoder 117, there are modulation methods including the modulation method defined in the standard of the DVB-S.2, the DVB-T.2, the DVB-C.2 or the like, and other modulation method, that is, BPSK (Binary Phase Shift Keying), QPSK (Quadrature Phase Shift Keying), 16APSK (Amplitude Phase-Shift Keying), 32APSK, 16QAM (Quadrature Amplitude Modulation), 64QAM, 256QAM, 1024QAM, 4096QAM, 4PAM (Pulse Amplitude Modulation), or the like. In the QAM encoder 117, to perform the orthogonal modulation based on which modulation method is previously set according to an operation of an operator of the transmitting device 11.

Data (symbol mapped to the signal point) that is obtained by processing in the QAM encoder 117 is supplied to the time interleaver 118.

The time interleaver 118 performs time interleave (interleave in a time direction) in a unit of symbol with respect to the data (symbol) supplied from the QAM encoder 117 and supplies data obtained as a result to an MISO/MIMO encoder (MISO/MIMO encoder) 119.

The MISO/MIMO encoder 119 performs spatiotemporal encoding with respect to the data (symbol) supplied from the time interleaver 118 and supplies the data to the frequency interleaver 120.

The frequency interleaver 120 performs frequency interleave (interleave in a frequency direction) in a unit of symbol with respect to the data (symbol) supplied from the MISO/MIMO encoder 119 and supplies the data to a frame builder/resource allocation unit 131.

On the other hand, for example, control data (signalling) for transfer control such as BB signaling (Base Band Signalling) (BB Header) is supplied to the BCH encoder 121.

The BCH encoder 121 performs the BCH encoding with respect to the signaling supplied thereto and supplies data obtained as a result to an LDPC encoder 122, similar to the BCH encoder 114.

The LDPC encoder 122 sets the data supplied from the BCH encoder 121 as LDPC target data, performs the LDPC encoding with respect to the data, and supplies an LDPC code obtained as a result to a QAM encoder 123, similar to the LDPC encoder 115.

The QAM encoder 123 maps the LDPC code supplied from the LDPC encoder 122 to a signal point representing one symbol of orthogonal modulation in a unit (symbol unit) of code bits of one or more bits of the LDPC code, performs the orthogonal modulation, and supplies data (symbol) obtained as a result to the frequency interleaver 124, similar to the QAM encoder 117.

The frequency interleaver 124 performs the frequency interleave in a unit of symbol with respect to the data (symbol) supplied from the QAM encoder 123 and supplies the data to the frame builder/resource allocation unit 131, similar to the frequency interleaver 120.

The frame builder/resource allocation unit 131 inserts symbols of pilots into necessary positions of the data (symbols) supplied from the frequency interleavers 120 and 124, configures a frame (for example, a physical layer (PL) frame, a T2 frame, a C2 frame, and so on) including symbols of a predetermined number from data (symbols) obtained as a result, and supplies the frame to an OFDM generating unit 132.

The OFDM generating unit 132 generates an OFDM signal corresponding to the frame from the frame supplied from the frame builder/resource allocation unit 131 and transmits the OFDM signal through the communication path 13 (FIG. 7).

Here, for example, the transmitting device 11 can be configured without including part of the blocks illustrated in FIG. 8 such as the time interleaver 118, the MISO/MIMO encoder 119, the frequency interleaver 120 and the frequency interleaver 124.

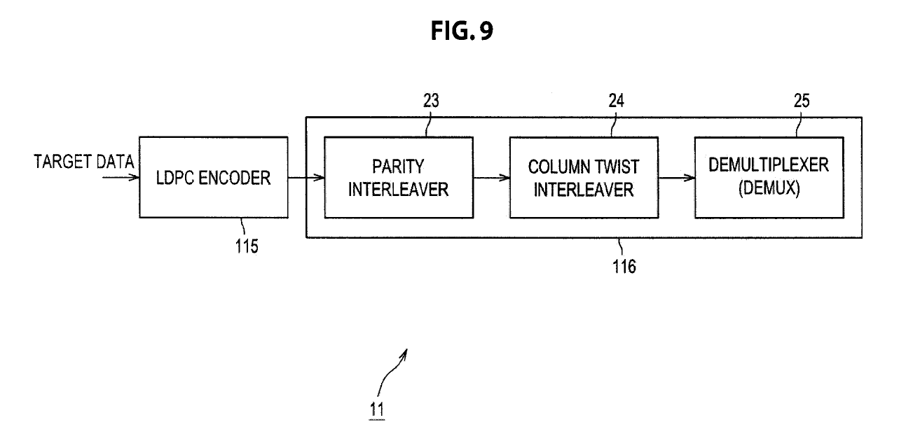

FIG. 9 illustrates a configuration example of the bit interleaver 116 of FIG. 8.

The bit interleaver 116 is a data processing device that interleaves data and includes the parity interleaver 23, the column twist interleaver 24, and a demultiplexer (DEMUX) 25. Here, the bit interleaver 116 can be configured without including one or both of the parity interleaver 23 and the column twist interleaver 24.

The parity interleaver 23 performs parity interleave for interleaving the parity bits of the LDPC code supplied from the LDPC encoder 115 into positions of other parity bits and supplies the LDPC code after the parity interleave to the column twist interleaver 24.

The column twist interleaver 24 performs the column twist interleave with respect to the LDPC code supplied from the parity interleaver 23 and supplies the LDPC code after the column twist interleave to the demultiplexer 25.

That is, in the QAM encoder 117 of FIG. 8, the code bits of one or more bits of the LDPC code are mapped to the signal point representing one symbol of the orthogonal modulation and are transmitted.

In the column twist interleaver 24, the column twist interleave to be described later is performed as rearrangement processing for rearranging the code bits of the LDPC code supplied from the parity interleaver 23, such that a plurality of code bits of the LDPC code corresponding to 1 in any one row of the parity check matrix used by the LDPC encoder 115 are not included in one symbol.

The demultiplexer 25 executes interchange processing for interchanging positions of two or more code bits of the LDPC code becoming the symbol, with respect to the LDPC code supplied from the column twist interleaver 24, and obtains an LDPC code in which tolerance against the AWGN is reinforced. In addition, the demultiplexer 25 supplies two or more code bits of the LDPC code obtained by the interchange processing as the symbol to the QAM encoder 117 (FIG. 8).

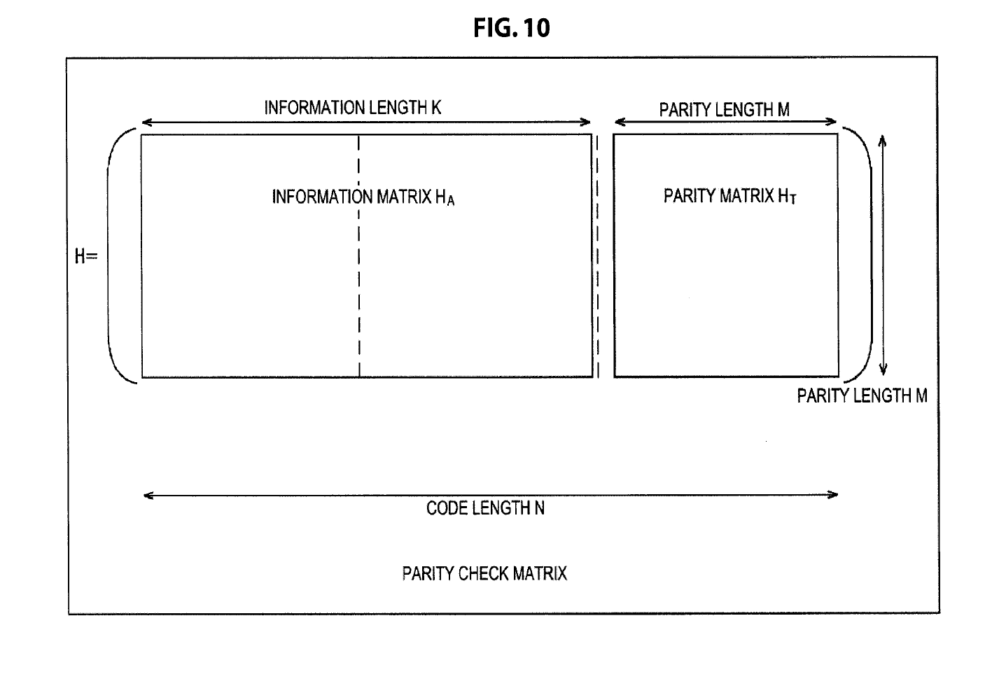

Next, FIG. 10 illustrates the parity check matrix H that is used for LDPC encoding by the LDPC encoder 115 of FIG. 8.

The parity check matrix H becomes an LDGM (Low-Density Generation Matrix) structure and can be represented by an expression H=[H_{A}|H_{T}] (a matrix in which elements of the information matrix H_{A} are set to left elements and elements of the parity matrix H_{T} are set to right elements), using an information matrix H_{A} of a portion corresponding to information bits among the code bits of the LDPC code and a parity matrix H_{T} corresponding to the parity bits.

In this case, a bit number of the information bits among the code bits of one LDPC code (one code word) and a bit number of the parity bits are referred to as an information length K and a parity length M, respectively, and a bit number of the code bits of one LDPC code is referred to as a code length N(=K+M).

The information length K and the parity length M of the LDPC code having the certain code length N are determined by an encoding rate. The parity check matrix H becomes a matrix in which row×column is M×N. The information matrix H_{A} becomes a matrix of M×K and the parity matrix H_{T} becomes a matrix of M×M.

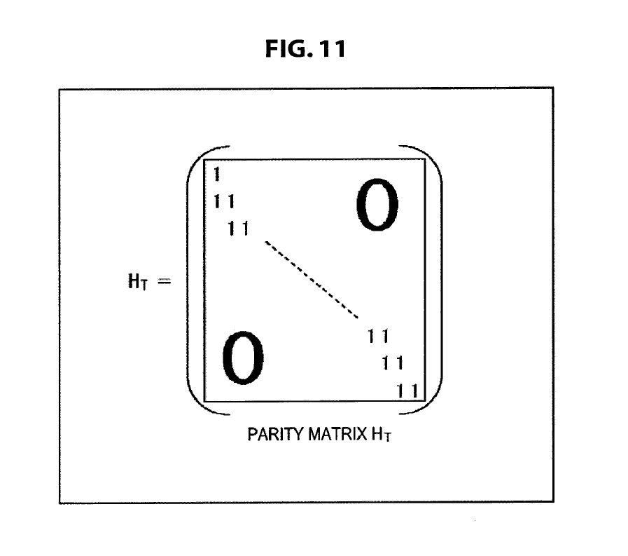

FIG. 11 illustrates the parity matrix H_{T} of the parity check matrix H of the LDPC code that is defined in the standard of the DVB-S.2, the DVB-T.2, and the DVB-C.2.

The parity matrix H_{T} of the parity check matrix H of the LDPC code that is defined in the standard of the DVB-T.2 or the like becomes a staircase structure matrix (lower bidagonal matrix) in which elements of 1 are arranged in a staircase shape, as illustrated in FIG. 11. The row weight of the parity matrix H_{T} becomes 1 with respect to the first row and becomes 2 with respect to the remaining rows. The column weight becomes 1 with respect to the final column and becomes 2 with respect to the remaining columns.

As described above, the LDPC code of the parity check matrix H in which the parity matrix H_{T} becomes the staircase structure can be easily generated using the parity check matrix H.

That is, the LDPC code (one code word) is represented by a row vector c and a column vector obtained by transposing the row vector is represented by C^{T}. In addition, a portion of information bits of the row vector c to be the LDPC code is represented by a row vector A and a portion of the parity bits is represented by a row vector T.

The row vector c can be represented by an expression c=[A|T] (a row vector in which elements of the row vector A are set to left elements and elements of the row vector T are set to right elements), using the row vector A corresponding to the information bits and the row vector T corresponding to the parity bits.

In the parity check matrix H and the row vector c=[A|T] corresponding to the LDPC code, it is necessary to satisfy an expression Hc^{T}=0. The row vector T that corresponds to the parity bits constituting the row vector c=[A|T] satisfying the expression Hc^{T}=0 can be sequentially calculated by setting elements of each row to 0, sequentially (in order) from elements of a first row of the column vector Hc^{T} in the expression Hc^{T}=0, when the parity matrix H_{T} of the parity check matrix H=[H_{A}|H_{T}] becomes the staircase structure illustrated in FIG. 11.

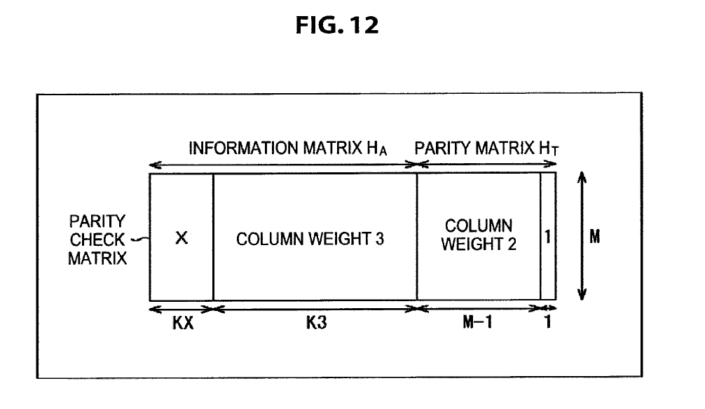

FIG. 12 is an illustration of the parity check matrix H of the LDPC code that is defined in the standard of the DVB-T.2 or the like.

The column weight becomes X with respect KX columns from a first column of the parity check matrix H of the LDPC code defined in the standard of the DVB-T.2 or the like, becomes 3 with respect to the following K3 columns, becomes 2 with respect to the following (M−1) columns, and becomes 1 with respect to a final column.

In this case, KX+K3+M−1+1 is equal to the code length N.

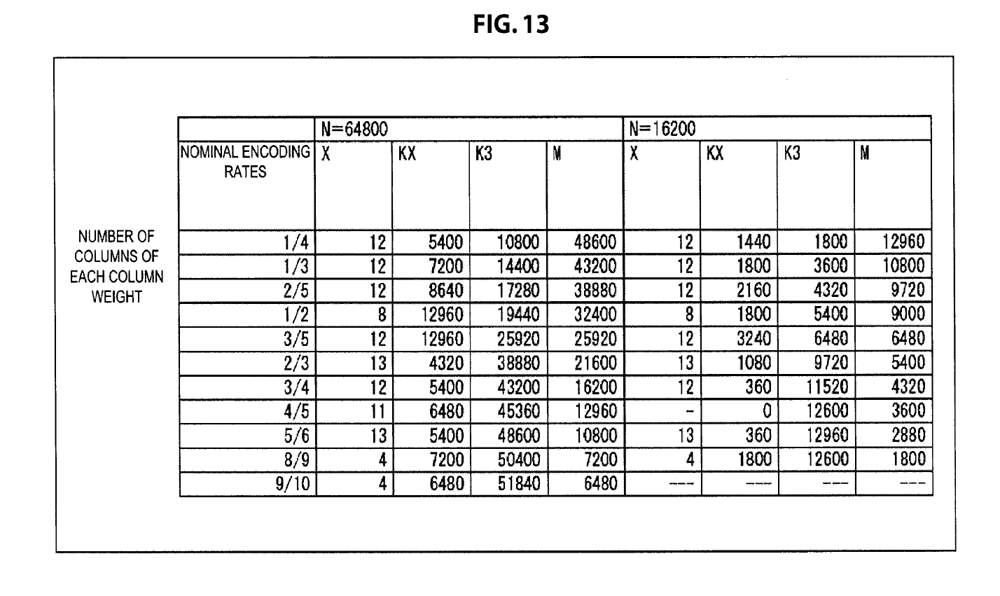

FIG. 13 is an illustration of column numbers KX, K3, and M and a column weight X, with respect to each encoding rate r of the LDPC code defined in the standard of the DVB-T.2 or the like.

In the standard of the DVB-T.2 or the like, LDPC codes that have code lengths N of 64800 bits and 16200 bits are defined.

With respect to the LDPC code having the code length N of 64800 bits, 11 encoding rates (nominal rates) of 1/4, 1/3, 2/5, 1/2, 3/5, 2/3, 3/4, 4/5, 5/6, 8/9, and 9/10 are defined. With respect to the LDPC code having the code length N of 16200 bits, 10 encoding rates of 1/4, 1/3, 2/5, 1/2, 3/5, 2/3, 3/4, 4/5, 5/6, and 8/9 are defined.

Hereinafter, the code length N of the 64800 bits is referred to as 64 kbits and the code length N of the 16200 is referred to as 16 kbits.

With respect to the LDPC code, it is known that an error rate is low in a code bit corresponding to a column of which a column weight of the parity check matrix H is large.

In the parity check matrix H that is illustrated in FIGS. 12 and 13 and is defined in the standard of the DVB-T.2 or the like, a column weight of a column of a head side (left side) tends to be large. Therefore, with respect to the LDPC code corresponding to the parity check matrix H, a code bit of a head side tends to be strong for error (there is tolerance against the error) and a code bit of an ending side tends to be weak for the error.

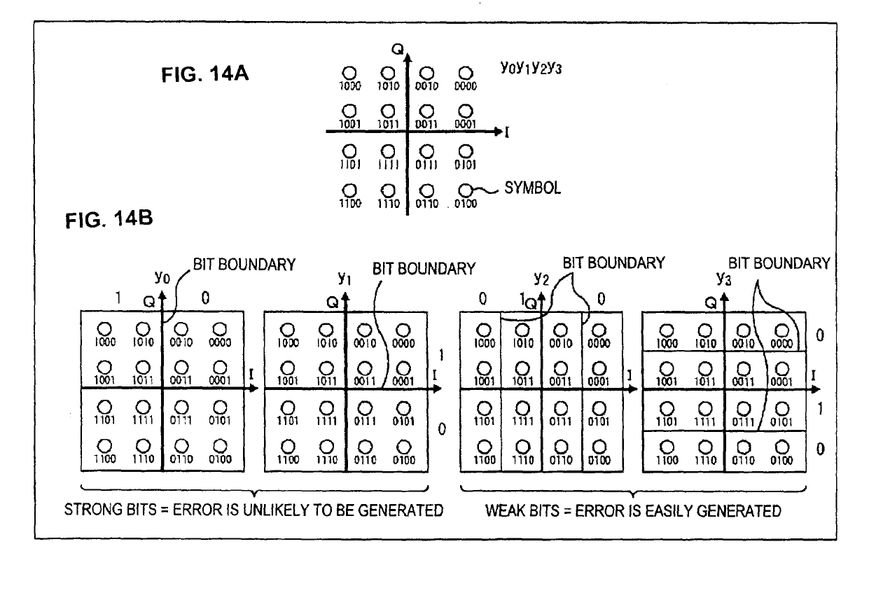

Next, FIG. 14 illustrates an arrangement example of (signal points corresponding to) 16 symbols on an IQ plane, when 16QAM is performed by the QAM encoder 117 of FIG. 8.

That is, A of FIG. 14 illustrates symbols of the 16QAM of the DVB-T.2.

In the 16QAM, one symbol is represented by 4 bits and 16 symbols (=2⁴) exist. The 16 symbols are arranged such that an 1 direction×a Q direction becomes a 4×4 square shape, on the basis of an original point of the IQ plane.

If an (i+1)-th bit from a most significant bit of a bit string represented by one symbol is represented as a bit y₁, the 4 bits represented by one symbol of the 16QAM are can be represented as hits y₀, y₁, y₂, and y₃, respectively, sequentially from the most significant bit. When a modulation method is the 16QAM, 4 bits of code bits of the LDPC code become a symbol (symbol value) of 4 bits y₀ to y₃ (symbolized).

B of FIG. 14 illustrates a bit boundary with respect to each of the 4 bits (hereinafter, referred to as symbol bits) y₀ to y₃ represented by the symbol of the 16QAM.

In this case, a bit boundary with respect to the symbol bit yᵢ (in FIG. 14, i=0, 1, 2, and 3) means a boundary of a symbol of which a symbol bit yᵢ becomes 0 and a symbol of which a symbol bit yᵢ becomes 1.

As illustrated by B of FIG. 14, only one place of the Q axis of the IQ plane becomes a bit boundary with respect to the most significant symbol bit y₀ of the 4 symbol bits y₀ to y₃ represented by the symbol of the 16QAM and only one place of the 1 axis of the IQ plane becomes a bit boundary with respect to the second (second from the most significant bit) symbol bit y₁.

With respect to the third symbol bit y₂, two places of a place between first and second columns from the left side and a place between third and four columns, among the 4×4 symbols, become bit boundaries.

With respect to the fourth symbol bit y₃, two places of a place between first and second rows from the upper side and a place between third and four rows, among the 4×4 symbols, become bit boundaries.

In the symbol bits yᵢ that are represented by the symbols, when the number of symbols apart from the bit boundaries is large, the error is difficult to be generated (the error probability is low) and when the number of symbols close to the bit boundaries is large, the error is easily generated (the error probability is high).

If the bits (strong for the error) in which the error is difficult to be generated are referred to as “strong bits” and the bits (weak for the error) in which the error is easily generated are referred to as “weak bits”, with respect to the 4 symbol bits y₀ to y₃ of the symbol of the 16QAM, the most significant symbol bit y₀ and the second symbol bit y₁ become the strong bits and the third symbol bit y₂ and the fourth symbol bit y₃ become the weak bits.

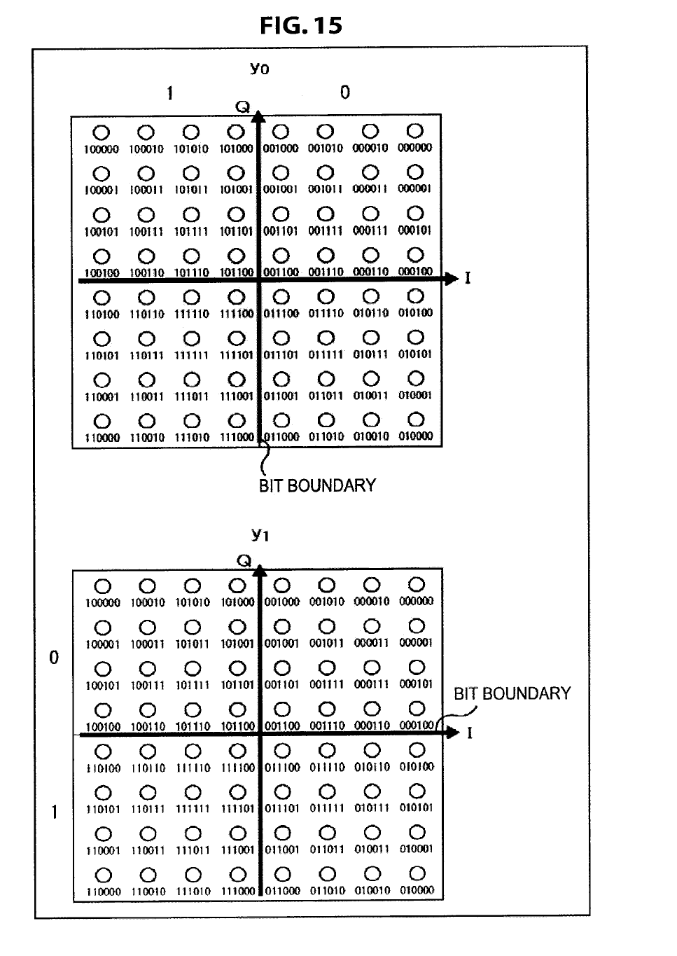

FIGS. 15 to 17 illustrate an arrangement example of (signal points corresponding to) 64 symbols on an IQ plane, that is, symbols of the 16QAM of the DVB-T.2, when the 64QAM is performed by the QAM encoder 117 of FIG. 8.

In the 64QAM, one symbol represents 6 bits and 64 symbols (=2⁶) exist. The 64 symbols are arranged such that an I direction×a Q direction becomes an 8×8 square shape, on the basis of an original point of the IQ plane.

The symbol bits of one symbol of the 64QAM can be represented as y₀, y₁, y₂, y₃, y₄, and y₅, sequentially from the most significant bit. When the modulation method is the 64QAM, 6 bits of code bits of the LDPC code become a symbol of symbol bits y₀ to y₅ of 6 bits.

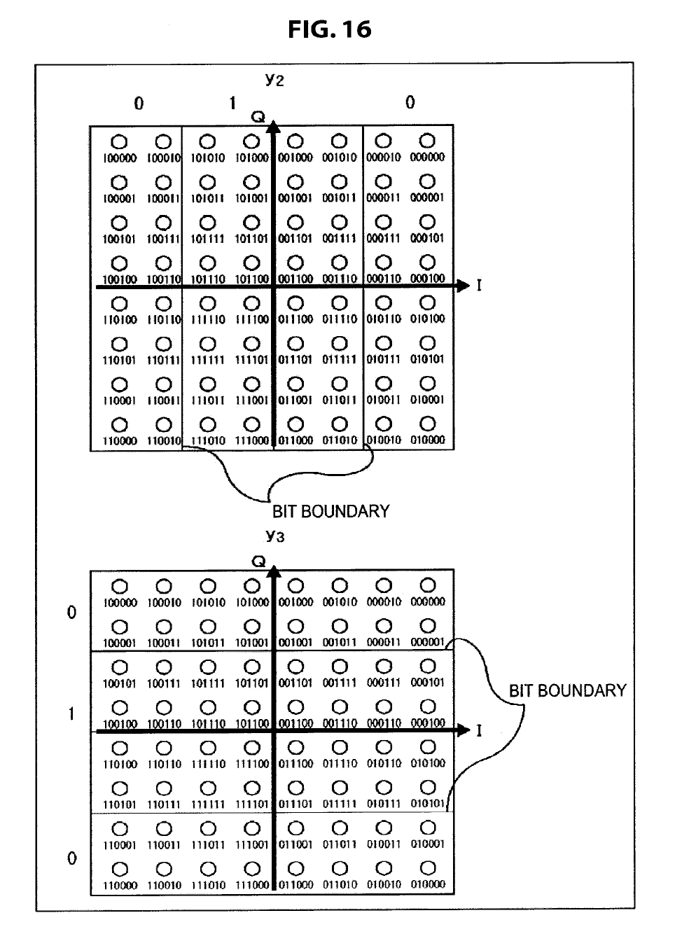

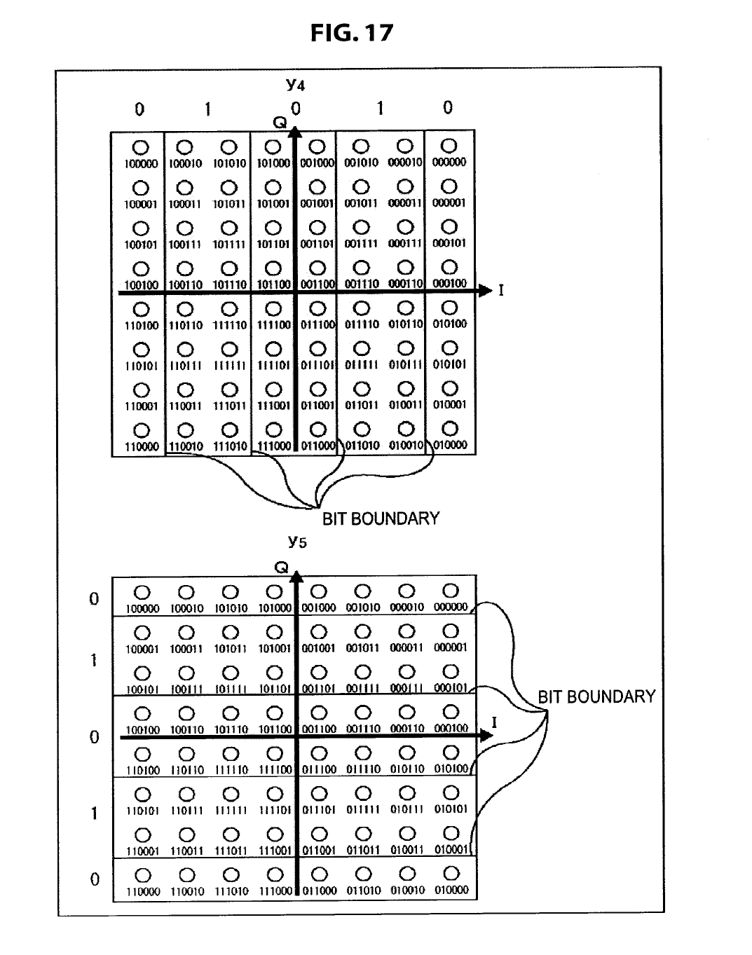

In this case, FIG. 15 illustrates a bit boundary with respect to each of the most significant symbol bit y₀ and the second symbol bit y₁ among the symbol bits y₀ to y₅ of the symbol of the 64QAM, FIG. 16 illustrates a bit boundary with respect to each of the third symbol bit y₂ and the fourth symbol bit y₃, and FIG. 17 illustrates a bit boundary with respect to each of the fifth symbol bit y₄ and the sixth symbol bit y₅.

As illustrated in FIG. 15, the bit boundary with respect to each of the most significant symbol bit y₀ and the second symbol bit y₁ becomes one place. As illustrated in FIG. 16, the bit boundaries with respect to each of the third symbol bit y₂ and the fourth symbol bit y₃ become two places. As illustrated in FIG. 17, the bit boundaries with respect to each of the fifth symbol bit y₄ and the sixth symbol bit y₅ become four places.

Therefore, with respect to the symbol bits y₀ to y₅ of the symbol of the 64QAM, the most significant symbol bit y₀ and the second symbol bit y₁ become strong bits and the third symbol bit y₂ and the fourth symbol bit y₃ become next strong bits. In addition, the fifth symbol bit y₄ and the sixth symbol bit y₅ become weak bits.

From FIGS. 14 and 15 to 17, it can be known that, with respect to the symbol bits of the symbol of the orthogonal modulation, the upper bits tend to become the strong bits and the lower bits tend to become the weak bits.

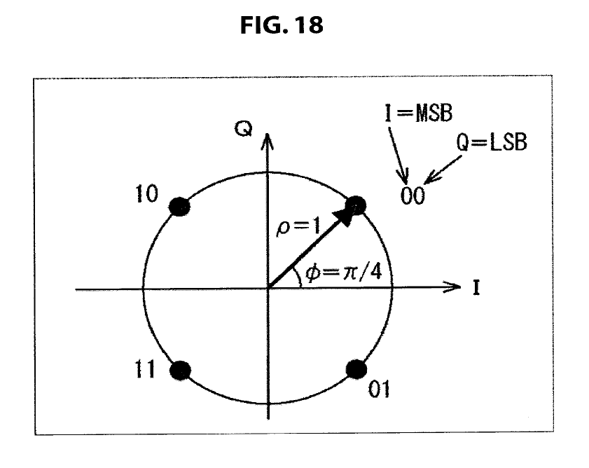

FIG. 18 is an illustration of an example of arrangement on the IQ plane of (signal points corresponding to) 4 symbols in a case where a satellite circuit is adopted as the communication path 13 (FIG. 7) and QPSK is performed in the QAM encoder 117 of FIG. 8, that is, for example, an illustration of symbols of QPSK of DVB-S.2.

In QPSK of DVB-S.2, a symbol is mapped on any of 4 signal points on the circumference of a circle whose radius centering on the origin of the IQ plane is p.

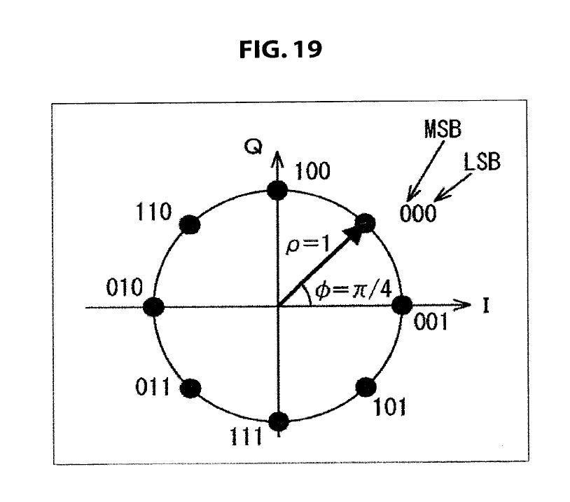

FIG. 19 is an illustration of an example of arrangement on the IQ plane of 8 symbols in a case where a satellite circuit is adopted as the communication path 13 (FIG. 7) and 8PSK is performed in the QAM encoder 117 of FIG. 8, that is, for example, an illustration of symbols of 8PSK of DVB-S.2.

In 8PSK of DVB-S.2, a symbol is mapped on any of 8 signal points on the circumference of a circle whose radius centering on the origin of the IQ plane is p.

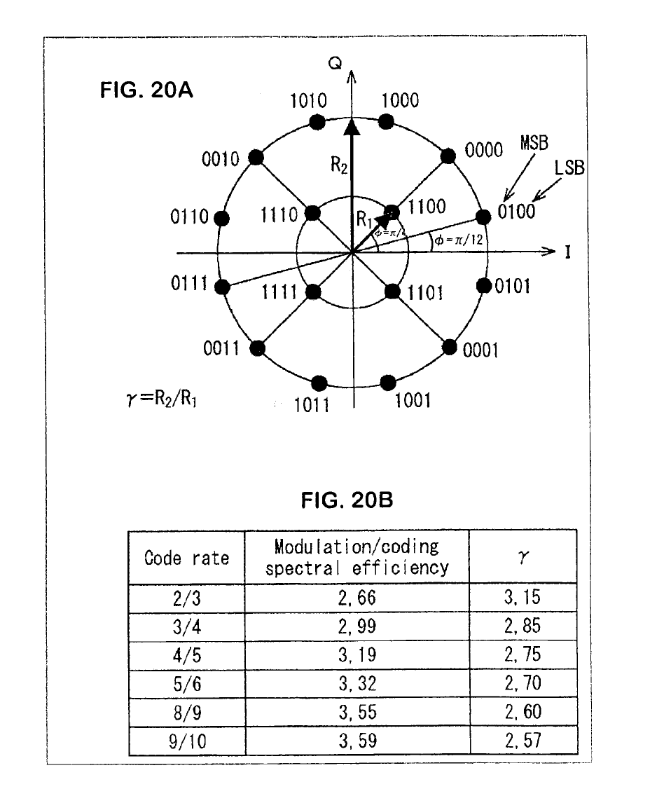

FIG. 20 is an example of arrangement on the IQ plane of 16 symbols in a case where a satellite circuit is adopted as the communication path 13 (FIG. 7) and 16APSK is performed in the QAM encoder 117 of FIG. 8, that is, for example, an illustration of symbols of 16APSK of DVB-S.2.

A of FIG. 20 illustrates the arrangement of signal points of 16APSK of DVB-S.2.

In 16APSK of DVB-S.2, a symbol is mapped on any of totally 16 signal points of 4 signal points on the circumference of a circle whose radius centering on the origin of the IQ plane is R₁ and 12 signal points on the circumference of a circle whose radius is R₂(>R₁).

B of FIG. 20 illustrates γ=R₂/R₁ which is the ratio of radiuses R₂ and R₁ in the arrangement of signal points of 16APSK of DVB-S.2.

In the arrangement of signal points of 16APSK of DVB-S.2, ratio γ of radiuses R₂ and R₁ varies depending on each encoding rate.

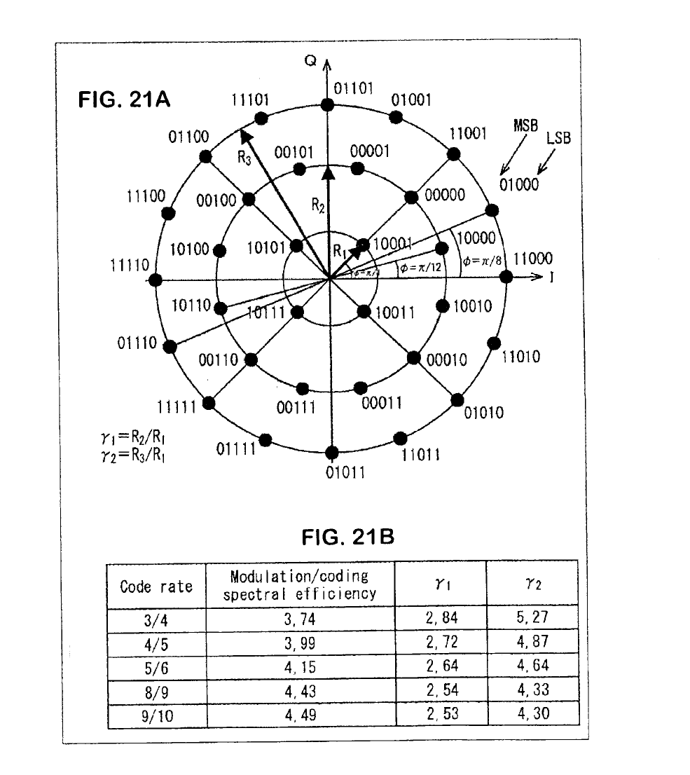

FIG. 21 is an example of arrangement on the IQ plane of 32 symbols in a case where a satellite circuit is adopted as the communication path 13 (FIG. 7) and 32APSK is performed in the QAM encoder 117 of FIG. 8, that is, for example, an illustration of symbols of 32APSK of DVB-S.2.

A of FIG. 21 illustrates the arrangement of signal points of 32APSK of DVB-S.2.

In 32APSK of DVB-S.2, a symbol is mapped on any of totally 32 signal points of 4 signal points on the circumference of a circle whose radius centering on the origin of the IQ plane is R₁, 12 signal points on the circumference of a circle whose radius is R₂ (>R₁) and 16 signal points on the circumference of a circle whose radius is R₃ (>R₂).

B of FIG. 21 illustrates γ₁=R₂/R₁ which is the ratio of radiuses R₂ and R₁ in the arrangement of signal points of 32APSK of DVB-S.2 and y₂=R₃/R₁ which is the ratio of radiuses R₃ and R₁.

In the arrangement of signal points of 32APSK of DVB-S.2, ratio γ₁ of radiuses R₂ and R₁ and ratio γ₂ of radiuses R₃ and R₁ vary depending on each encoding rate.

Even for symbol bits of the symbols of each quadrature modulation (QPSK, 8PSK, 16APSK and 32APSK) of DVB-S.2 illustrating the arrangement of signal points in FIG. 18 to FIG. 21, similar to the cases of FIG. 14 to FIG. 17, there are strong bits and weak bits.

As described in FIGS. 12 and 13, with respect to the LDPC code output by the LDPC encoder 115 (FIG. 8), code bits strong for the error and code bits weak for the error exist.

As described in FIGS. 14 to 21, with respect to the symbol bits of the symbol of the orthogonal modulation performed by the QAM encoder 117, the strong bits and the weak bits exist.

Therefore, if the code bits of the LDPC code strong for the error are allocated to the weak symbol bits of the symbol of the orthogonal modulation, tolerance against the error is lowered as a whole.

Therefore, an interleaver that interleaves the code bits of the LDPC code in such a manner that the code bits of the LDPC code weak for the error are allocated to the strong bits (symbol bits) of the symbol of the orthogonal modulation is suggested.

The demultiplexer 25 of FIG. 9 can execute processing of the interleaver.

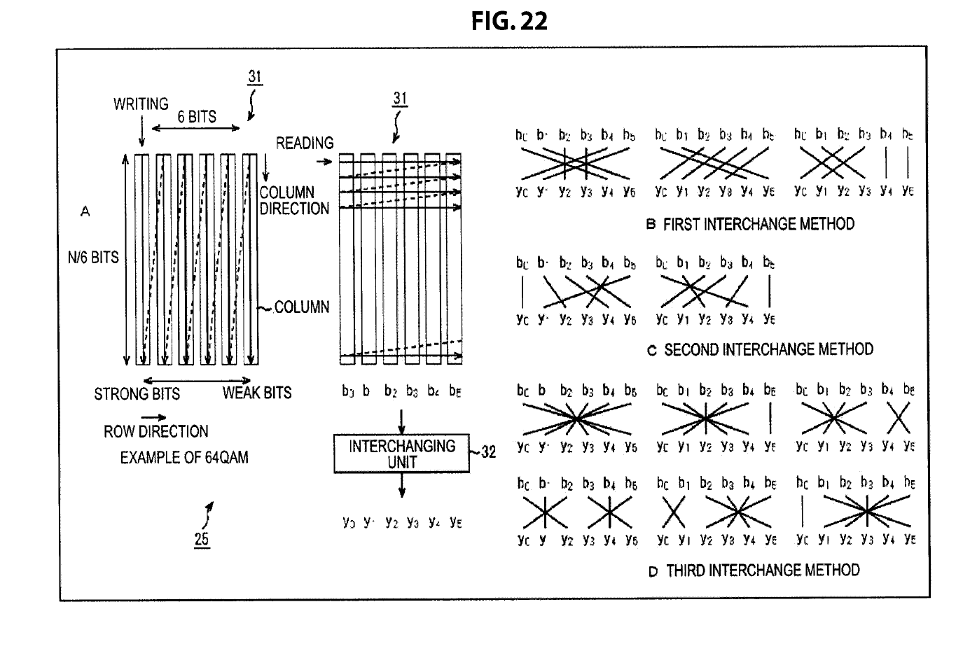

FIG. 22 is an illustration of processing of the demultiplexer 25 of FIG. 9.

That is, A of FIG. 18 illustrates a functional configuration example of the demultiplexer 25.

The demultiplexer 25 includes a memory 31 and an interchanging unit 32.

An LDPC code is supplied from the LDPC encoder 115 to the memory 31.

The memory 31 has a storage capacity to store mb bits in a row (transverse) direction and store N/(mb) bits in a column (longitudinal) direction. The memory 31 writes code bits of the LDPC code supplied thereto in the column direction, reads the code bits in the row direction, and supplies the code bits to the interchanging unit 32.

In this case, N (=information length K+parity length M) represents a code length of the LDPC code, as described above.

In addition, m represents a bit number of the code bits of the LDPC code that becomes one symbol and b represents a multiple that is a predetermined positive integer and is used to perform integral multiplication of m. As described above, the demultiplexer 25 symbolizes the code bits of the LDPC code. However, the multiple b represents the number of symbols obtained by one-time symbolization of the demultiplexer 25.

A of FIG. 22 illustrates a configuration example of the demultiplexer 25 in a case where a modulation method is 64QAM or the like in which mapping is performed on any of 64 signal points, and therefore bit number m of the code bits of the LDPC code becoming one symbol is 6 bits.

In A of FIG. 22, the multiple b becomes 1. Therefore, the memory 31 has a storage capacity in which a column direction x a row direction is N/(6×1)×(6×1) bits.

In this case, a storage region of the memory 31 in which the row direction is 1 bit and which extends in the column direction is appropriately referred to as a column hereinafter. In A of FIG. 22, the memory 31 includes 6 (=6×1) columns.

In the demultiplexer 25, writing of the code bits of the LDPC code in a downward direction (column direction) from the upper side of the columns constituting the memory 31 is performed toward the columns of a rightward direction from the left side.

If writing of the code bits ends to the bottom of the rightmost column, the code bits are read in a unit of 6 bits (mb bits) in the row direction from a first row of all the columns constituting the memory 31 and are supplied to the interchanging unit 32.

The interchanging unit 32 executes interchange processing for interchanging positions of the code bits of the 6 bits from the memory 31 and outputs 6 bits obtained as a result as 6 symbol bits y₀, y₁, y₂, y₃, y₄, and y₅ representing one symbol of the 64QAM.

That is, the code bits of the mb bits (in this case, 6 bits) are read from the memory 31 in the row direction. However, if the i-th (i=0, 1, . . . , and mb−1) bit from the most significant bit, of the code bits of the mb bits read from the memory 31, is represented as a bit bᵢ, the code bits of the 6 bits that are read from the memory 31 in the row direction can be represented as bits b₀, b₁, b₂, b₃, b₄, and b₅, sequentially from the most significant bit.

With the relation of the column weights described in FIGS. 12 and 13, the code bit in a direction of the bit b₀ becomes a code bit strong for the error and the code bit in a direction of the bit b₅ becomes a code bit weak for the error.

In the interchanging unit 32, interchange processing for interchanging the positions of the code bits b₀ to b₅ of the 6 bits from the memory 31, such that the code bits weak for the error among the code bits b₀ to b₅ of the 6 bits from the memory 31 are allocated to the strong bits among the symbol bits y₀ to y₅ of one symbol of the 64QAM, can be executed.

In this case, as interchange methods for interchanging the code bits b₀ to b₅ of the 6 bits from the memory 31 and allocating the code bits b₀ to b₅ of the 6 bits to the 6 symbol bits y₀ to y₅ representing one symbol of the 64QAM, various methods are suggested from individual companies.

B of FIG. 22 illustrates a first interchange method, C of FIG. 22 illustrates a second interchange method, and D of FIG. 22 illustrates a third interchange method.

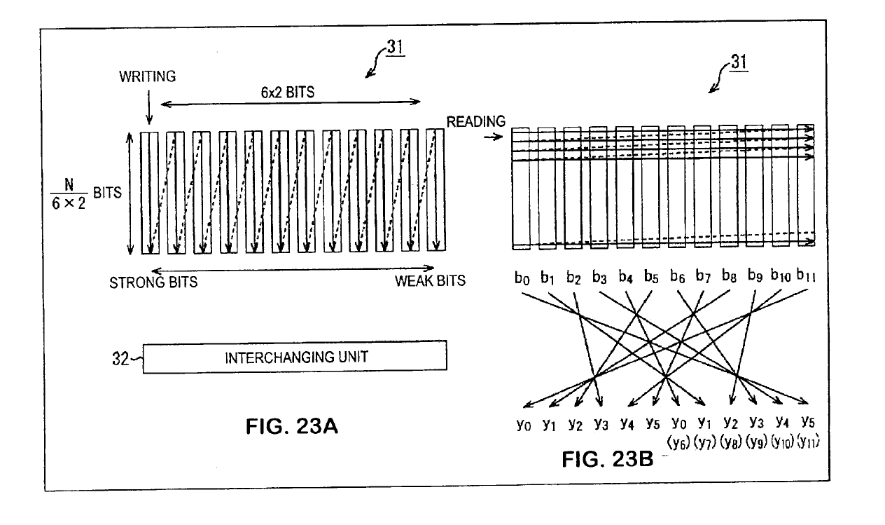

In B of FIG. 22 to D of FIG. 22 (and FIG. 23 to be described later), a line segment coupling the bits bᵢ and yⱼ means that the code bit bᵢ is allocated to the symbol bit yⱼ of the symbol (interchanged with a position of the symbol bit yⱼ).

As the first interchange method of B of FIG. 22, to adopt any one of three kinds of interchange methods is suggested. As the second interchange method of C of FIG. 22, to adopt any one of two kinds of interchange methods is suggested.

As the third interchange method of D of FIG. 22, to sequentially select six kinds of interchange methods and use the interchange method is suggested.

FIG. 23 illustrates a configuration example of the demultiplexer 25 in a case where a modulation method is 64QAM or the like in which mapping is performed on any of 64 signal points (therefore, hit number m of the code bits of the LDPC code mapped on one symbol is 6 bits as well as FIG. 22) and multiple b is 2, and the fourth interchange method.

When the multiple b is 2, the memory 31 has a storage capacity in which a column direction x a row direction is N/(6×2)×(6×2) bits and includes 12 (=6×2) columns.

A of FIG. 23 illustrates a sequence of writing the LDPC code to the memory 31.

In the demultiplexer 25, as described in FIG. 22, writing of the code bits of the LDPC code in a downward direction (column direction) from the upper side of the columns constituting the memory 31 is performed toward the columns of a rightward direction from the left side.

If writing of the code bits ends to the bottom of the rightmost column, the code bits are read in a unit of 12 bits (mb bits) in the row direction from a first row of all the columns constituting the memory 31 and are supplied to the interchanging unit 32.

The interchanging unit 32 executes interchange processing for interchanging positions of the code bits of the 12 bits from the memory 31 using the fourth interchange method and outputs 12 bits obtained as a result as 12 bits representing two symbols (b symbols) of the 64QAM, that is, six symbol bits y₀, y₁, y₂, y₃, y₄, and y₅ representing one symbol of the 64QAM and six symbol bits y₀, y₁, y₂, y₃, y₄, and y₅ representing a next one symbol.

In this case, B of FIG. 23 illustrates the fourth interchange method of the interchange processing by the interchanging unit 32 of A of FIG. 23.

When the multiple b is 2 (or 3 or more), in the interchange processing, the code bits of the mb bits are allocated to the symbol bits of the mb bits of the b consecutive symbols. In the following explanation including the explanation of FIG. 23, the (i+1)-th bit from the most significant bit of the symbol bits of the mb bits of the b consecutive symbols is represented as a bit (symbol bit) yᵢ, for the convenience of explanation.

What kind of code bits are appropriate to be interchanged, that is, the improvement of the error rate in the AWGN communication path is different according to the encoding rate or the code length of the LDPC code and the modulation method.

[Parity Interleave]

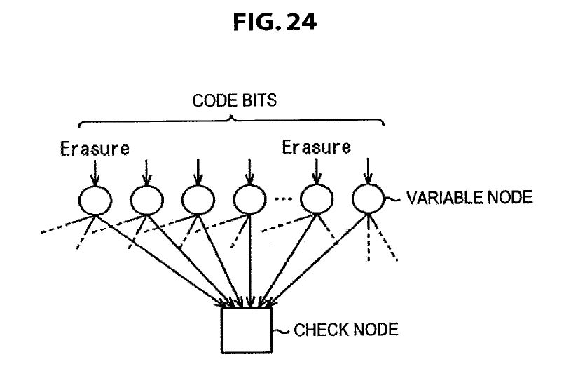

Next, the parity interleave by the parity interleaver 23 of FIG. 9 will be described with reference to FIGS. 24 to 26.

FIG. 24 illustrates (a part of) a Tanner graph of the parity check matrix of the LDPC code.

As illustrated in FIG. 24, if a plurality of, for example, two variable nodes among (the code bits corresponding to) the variable nodes connected to the check node simultaneously become the error such as the erasure, the check node returns a message in which the probability of a value being 0 and the probability of a value being 1 are equal to each other, to all the variable nodes connected to the check node. For this reason, if the plurality of variable nodes connected to the same check node simultaneously become the erasure, decoding performance is deteriorated.

Meanwhile, the LDPC code that is output by the LDPC encoder 115 of FIG. 8 and is defined in the standard of the DVB-S.2 or the like is an IRA code and the parity matrix H_{T} of the parity check matrix H becomes a staircase structure, as illustrated in FIG. 11.

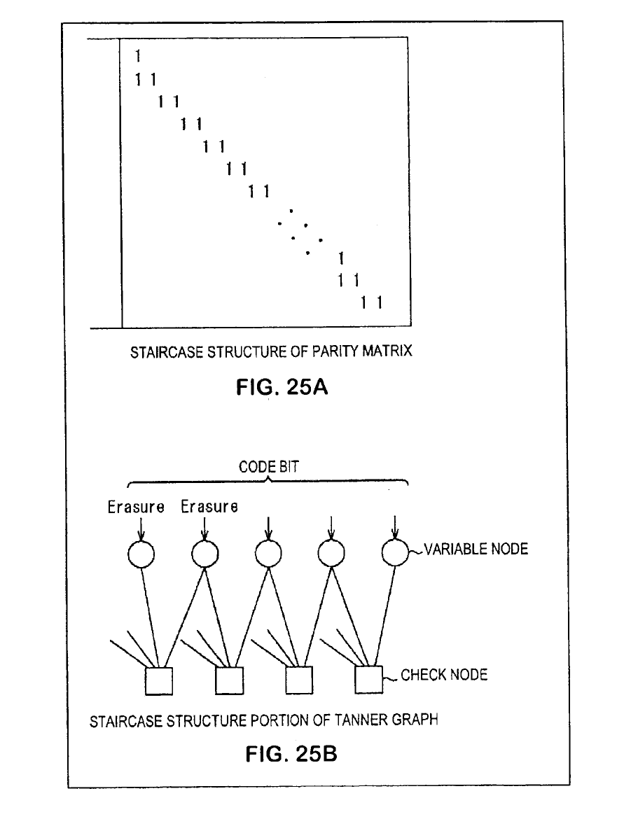

FIG. 25 illustrates the parity matrix H_{T} becoming the staircase structure and a Tanner graph corresponding to the parity matrix H_{T}.

That is, A of FIG. 25 illustrates the parity matrix HT becoming the staircase structure and B of FIG. 25 illustrates the Tanner graph corresponding to the parity matrix HT of A of FIG. 25.

In the parity matrix H_{T} with a staircase structure, elements of 1 are adjacent in each row (excluding the first row). Therefore, in the Tanner graph of the parity matrix H_{T}, two adjacent variable nodes corresponding to a column of two adjacent elements in which the value of the parity matrix H_{T} is 1 are connected with the same check node.

Therefore, when parity bits corresponding to two above-mentioned adjacent variable nodes become errors at the same time by burst error and erasure, and so on, the check node connected with two variable nodes (variable nodes to find a message by the use of parity bits) corresponding to those two parity bits that became errors returns message that the probability with a value of 0 and the probability with a value of 1 are equal probability, to the variable nodes connected with the check node, and therefore the performance of decoding is deteriorated. Further, when the burst length (bit number of parity bits that continuously become errors) becomes large, the number of check nodes that return the message of equal probability increases and the performance of decoding is further deteriorated.

Therefore, the parity interleaver 23 (FIG. 9) performs the parity interleave for interleaving the parity bits of the LDPC code from the LDPC encoder 115 into positions of other parity bits, to prevent the decoding performance from being deteriorated.

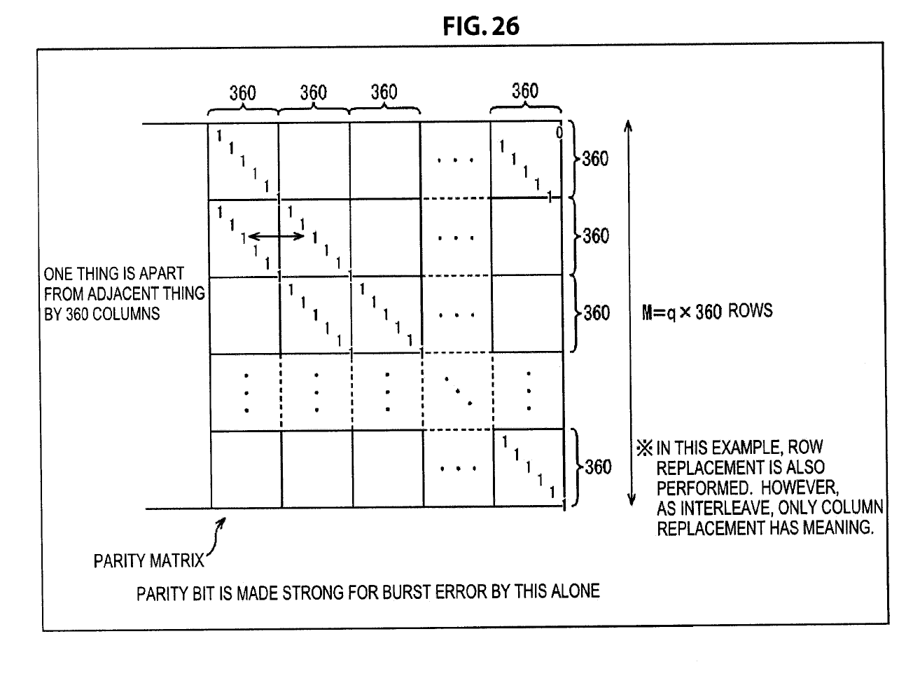

FIG. 26 illustrates the parity matrix H_{T} of the parity check matrix H corresponding to the LDPC code after the parity interleave performed by the parity interleaver 23 of FIG. 9.

In this case, the information matrix H_{A} of the parity check matrix H corresponding to the LDPC code that is output by the LDPC encoder 115 and is defined in the standard of the DVB-S.2 or the like becomes a cyclic structure.

The cyclic structure means a structure in which a certain column is matched with a column obtained by cyclically shifting another column. For example, the cyclic structure includes a structure in which a position of 1 of each row of P columns becomes a position obtained by cyclically shifting a first column of the P columns in a column direction by a value proportional to a value q obtained by dividing a parity length M, for every P columns. Hereinafter, the P columns in the cyclic structure are appropriately referred to as a column number of a unit of the cyclic structure.

As an LDPC code defined in a standard such as DVB-S.2, as described in FIG. 12 and FIG. 13, there are two kinds of LDPC codes whose code length N is 64800 bits and 16200 bits, and, for both of those two kinds of LDPC codes, the column number P which is a unit of a cyclic structure is defined as 360 which is one of divisors excluding 1 and M among the divisors of the parity length M.

The parity length M becomes a value other than primes represented by an expression M=q×P=q×360, using a value q different according to the encoding rate. Therefore, similar to the column number P of the unit of the cyclic structure, the value q is one other than 1 and M among the divisors of the parity length M and is obtained by dividing the parity length M by the column number P of the unit of the cyclic structure (the product of P and q to be the divisors of the parity length M becomes the parity length M).

As described above, when information length is assumed to be K, an integer equal to or greater than 0 and less than P is assumed to be x and an integer equal to or greater than 0 and less than q is assumed to be y, the parity interleaver 23 interleaves the K+qx+y+1-th code bit among code bits of an LDPC code of N bits to the position of the K+Py+x+1-th code bit as parity interleave.

Since both of the K+qx+y+1-th code bit and the K+Py+x+1-th code bit are code bits after the K+1-th one, they are parity bits, and therefore the positions of the parity bits of the LDPC code are moved according to the parity interleave.

According to the parity interleave, (the parity bits corresponding to) the variable nodes connected to the same check node are separated by the column number P of the unit of the cyclic structure, that is, 360 bits in this case. For this reason, when the burst length is less than 360 bits, the plurality of variable nodes connected to the same check node can be prevented from simultaneously becoming the error. As a result, tolerance against the burst error can be improved.

The LDPC code after the interleave for interleaving the (K+qx+y+1)-th code bit into the position of the (K+Py+x+1)-th code bit is matched with an LDPC code of a parity check matrix (hereinafter, referred to as a transformed parity check matrix) obtained by performing column replacement for replacing the (K+qx+y+1)-th column of the original parity check matrix H with the (K+Py+x+1)-th column.

In the parity matrix of the transformed parity check matrix, as illustrated in FIG. 26, a pseudo cyclic structure that uses the P columns (in FIG. 26, 360 columns) as a unit appears.

In this case, the pseudo cyclic structure means a structure in which a cyclic structure is formed except for a part thereof. The transformed parity check matrix that is obtained by performing the column replacement corresponding to the parity interleave with respect to the parity check matrix of the LDPC code defined in the standard of the DVB-S.2 or the like becomes the pseudo cyclic structure, not the (perfect) cyclic structure, because the number of elements of 1 is less than 1 (elements of 0 exist) in a portion (shifted matrix to be described later) of 360 rows×360 columns of a right corner portion thereof.

The transformed parity check matrix of FIG. 26 becomes a matrix that is obtained by performing the column replacement corresponding to the parity interleave and replacement (row replacement) of a row to configure the transformed parity check matrix with a constitutive matrix to be described later, with respect to the original parity check matrix H.

[Column Twist Interleave]

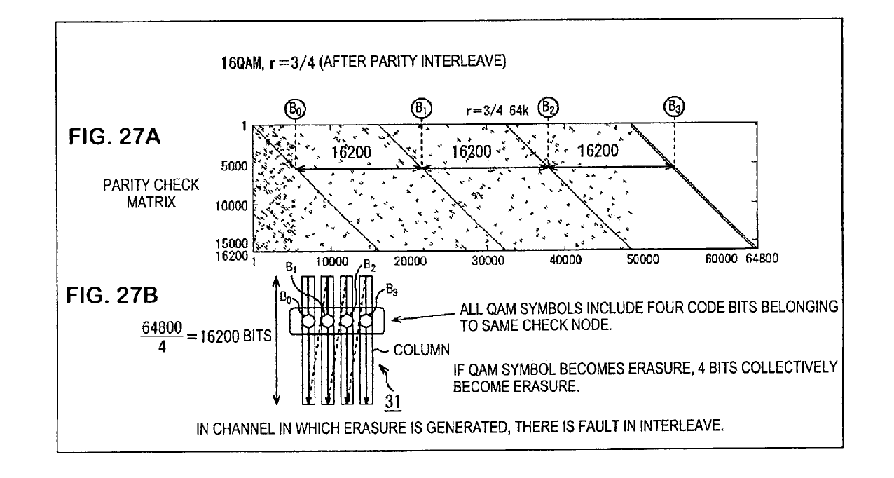

Next, column twist interleave corresponding to rearrangement processing by the column twist interleaver 24 of FIG. 9 will be described with reference to FIGS. 27 to 30.

In the transmitting device 11 of FIG. 8, one or more bits of the code bits of the LDPC code are transmitted as one symbol. That is, when two bits of the code bits are set as one symbol, the QPSK is used as the modulation method and when four bits of the code bits are set as one symbol, the APSK or the 16QAM is used as the modulation method.

As such, when the two or more bits of the code bits are transmitted as one symbol, if the erasure is generated in a certain symbol, all of the code bits of the symbol become the error (erasure).

Therefore, it is necessary to prevent the variable nodes corresponding to the code bits of one symbol from being connected to the same check node, in order to decrease the probability of (the code bits corresponding to) the plurality of variable nodes connected to the same check node simultaneously becoming the erasure to improve the decoding performance.

Meanwhile, as described above, in the parity check matrix H of the LDPC code that is output by the LDPC encoder 115 and is defined in the standard of the DVB-S.2 or the like, the information matrix H_{A} has the cyclic structure and the parity matrix H_{T} has the staircase structure. As described in FIG. 26, in the transformed parity check matrix to be the parity check matrix of the LDPC code after the parity interleave, the cyclic structure (in fact, the pseudo cyclic structure as described above) appears in the parity matrix.

FIG. 27 illustrates a transformed parity check matrix.

That is, A of FIG. 27 illustrates a transformed parity check matrix of a parity check matrix H of an LDPC code in which a code length N is 64800 bits and an encoding rate (r) is 3/4.

In A of FIG. 27, in the transformed parity check matrix, a position of an element of which a value becomes 1 is shown by a point (.).

B of FIG. 27 illustrates processing executed by the demultiplexer 25 (FIG. 9), with respect to the LDPC code of the transformed parity check matrix of A of FIG. 27, that is, the LDPC code after the parity interleave.

In B of FIG. 27, with an assumption that a modulation method is a method in which a symbol is mapped on any of 16 signal points such as 16APSK and 16QAM, the code bits of the LDPC code after the parity interleave are written in four columns forming the memory 31 of the demultiplexer 25 in the column direction.

The code bits that are written in the column direction in the four columns constituting the memory 31 are read in a unit of four bits in the row direction and become one symbol.

In this case, code bits B₀, B₁, B₂, and B₃ of the four bits that become one symbol may become code bits corresponding to 1 in any one row of the transformed parity check matrix of A of FIG. 27. In this case, the variable nodes that correspond to the code bits B₀, B₁, B₂, and B₃ are connected to the same check node.

Therefore, when the code bits B₀, B₁, B₂, and B₃ of the four bits of one symbol become the code bits corresponding to 1 in any one row of the transformed parity check matrix, if the erasure is generated in the symbol, an appropriate message may not be calculated in the same check node to which the variable nodes corresponding to the code bits B₀, B₁, B₂, and B₃ are connected. As a result, the decoding performance is deteriorated.

With respect to the encoding rates other than 3/4, the plurality of code bits corresponding to the plurality of variable nodes connected to the same check node may become one symbol of the APSK or the 16QAM, similar to the above case.

Therefore, the column twist interleaver 24 performs the column twist interleave for interleaving the code bits of the LDPC code after the parity interleave from the parity interleaver 23, such that the plurality of code bits corresponding to 1 in any one row of the transformed parity check matrix are not included in one symbol.

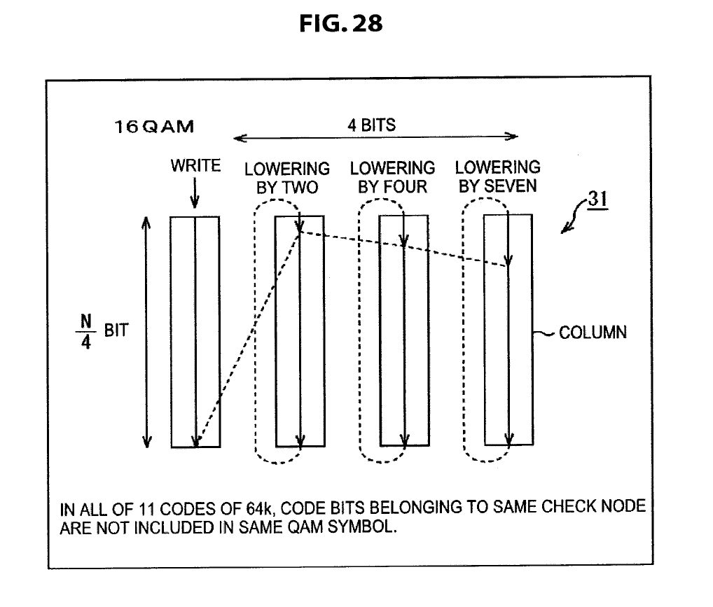

FIG. 28 is an illustration of the column twist interleave.

That is, FIG. 28 illustrates the memory 31 (FIGS. 22 and 23) of the demultiplexer 25.

As described in FIG. 22, the memory 31 has a storage capacity to store mb bits in the column (longitudinal) direction and store N/(mb) bits in the row (transverse) direction and includes mb columns. The column twist interleaver 24 writes the code bits of the LDPC code in the column direction with respect to the memory 31, controls a write start position when the code bits are read in the row direction, and performs the column twist interleave.

That is, in the column twist interleaver 24, the write start position to start writing of the code bits is appropriately changed with respect to each of the plurality of columns, such that the plurality of code bits read in the row direction and becoming one symbol do not become the code bits corresponding to 1 in any one row of the transformed parity check matrix (the code bits of the LDPC code are rearranged such that the plurality of code bits corresponding to 1 in any one row of the parity check matrix are not included in the same symbol).

In this case, FIG. 28 illustrates a configuration example of the memory 31 when the modulation method is the 16 APSK or the 16QAM and the multiple b described in FIG. 22 is 1. Therefore, the bit number m of the code bits of the LDPC code becoming one symbol is 4 bits and the memory 31 includes 4 (=mb) columns.

The column twist interleaver 24 performs writing of the code bits of the LDPC code (instead of the demultiplexer 25 of FIG. 22) in the downward direction (column direction) from the upper side of the four columns constituting the memory 31, toward the columns of the rightward direction from the left side.

If writing of the code bits ends to the rightmost column, the column twist interleaver 24 reads the code bits in a unit of four bits (mb bits) in the row direction from the first row of all the columns constituting the memory 31 and outputs the code bits as the LDPC code after the column twist interleave to the interchanging unit 32 (FIGS. 22 and 23) of the demultiplexer 25.

However, in the column twist interleaver 24, if an address of a position of a head (top) of each column is set to 0 and an address of each position of the column direction is represented by an ascending integer, a write start position is set to a position of which an address is 0, with respect to a leftmost column. A write start position is set to a position of which an address is 2, with respect to a second (from the left side) column. A write start position is set to a position of which an address is 4, with respect to a third column. A write start position is set to a position of which an address is 7, with respect to a fourth column.

With respect to the columns in which the write start positions are the positions other than the position of which the address is 0, after the code bits are written to a lowermost position, the position returns to the head (the position of which the address is 0) and writing is performed to the position immediately before the write start position. Then, writing with respect to a next (right) column is performed.

By performing the column twist interleave described above, with respect to the LDPC codes that are defined in the standard of the DVB-T.2 or the like, the plurality of code bits corresponding to the plurality of variable nodes connected to the same check node can be prevented from becoming one symbol of the APSK or the 16QAM (being included in the same symbol). As a result, decoding performance in a communication path in which the erasure exists can be improved.

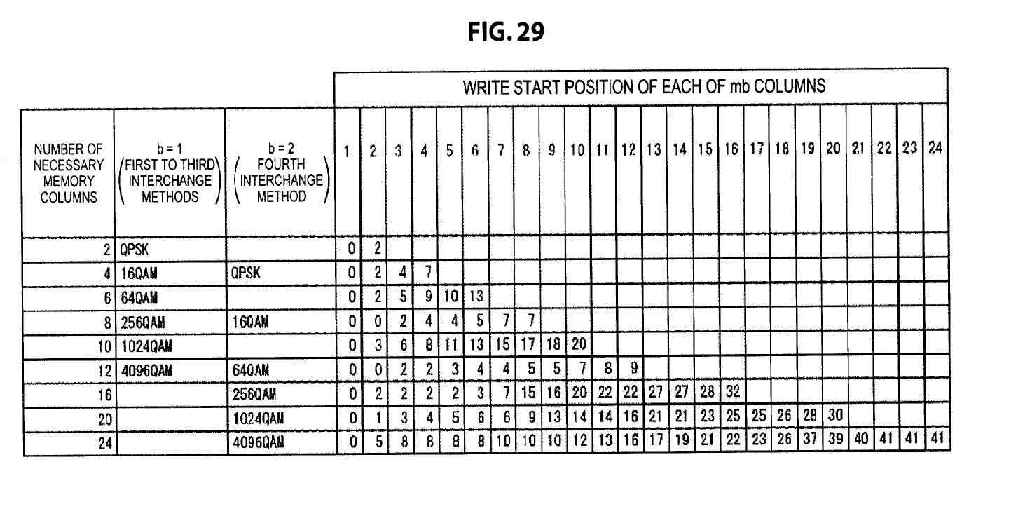

FIG. 29 illustrates a column number of the memory 31 necessary for the column twist interleave and an address of a write start position for each modulation method, with respect to LDPC codes of 11 encoding rates defined in the standard of the DVB-T.2 and having a code length N of 64800.

When the multiple b is 1, the QPSK is adopted as the modulation method, and a bit number m of one symbol is 2 bits, according to FIG. 29, the memory 31 has two columns to store 2×1 (=mb) bits in the row direction and stores 64800/(2×1) bits in the column direction.

A write start position of a first column of the two columns of the memory 31 becomes a position of which an address is 0 and a write start position of a second column becomes a position of which an address is 2.

For example, when any one of the first to third interchange methods of FIG. 22 is adopted as the interchange method of the interchange processing of the demultiplexer 25 (FIG. 9), the multiple b becomes 1.

When the multiple b is 2, the QPSK is adopted as the modulation method, and a bit number m of one symbol is 2 bits, according to FIG. 29, the memory 31 has four columns to store 2×2 bits in the row direction and stores 64800/(2×2) bits in the column direction.

A write start position of a first column of the four columns of the memory 31 becomes a position of which an address is 0, a write start position of a second column becomes a position of which an address is 2, a write start position of a third column becomes a position of which an address is 4, and a write start position of a fourth column becomes a position of which an address is 7.

For example, when the fourth interchange method of FIG. 23 is adopted as the interchange method of the interchange processing of the demultiplexer 25 (FIG. 9), the multiple b becomes 2.

When the multiple b is 1, the 16QAM is adopted as the modulation method, and a bit number m of one symbol is 4 bits, according to FIG. 29, the memory 31 has four columns to store 4×1 bits in the row direction and stores 64800/(4×1) bits in the column direction.

A write start position of a first column of the four columns of the memory 31 becomes a position of which an address is 0, a write start position of a second column becomes a position of which an address is 2, a write start position of a third column becomes a position of which an address is 4, and a write start position of a fourth column becomes a position of which an address is 7.

When the multiple b is 2, the 16QAM is adopted as the modulation method, and a bit number m of one symbol is 4 bits, according to FIG. 29, the memory 31 has eight columns to store 4×2 bits in the row direction and stores 64800/(4×2) bits in the column direction.

A write start position of a first column of the eight columns of the memory 31 becomes a position of which an address is 0, a write start position of a second column becomes a position of which an address is 0, a write start position of a third column becomes a position of which an address is 2, a write start position of a fourth column becomes a position of which an address is 4, a write start position of a fifth column becomes a position of which an address is 4, a write start position of a sixth column becomes a position of which an address is 5, a write start position of a seventh column becomes a position of which an address is 7, and a write start position of a eighth column becomes a position of which an address is 7.

When the multiple b is 1, the 64QAM is adopted as the modulation method, and a bit number m of one symbol is 6 bits, according to FIG. 29, the memory 31 has six columns to store 6×1 bits in the row direction and stores 64800/(6×1) bits in the column direction.

A write start position of a first column of the six columns of the memory 31 becomes a position of which an address is 0, a write start position of a second column becomes a position of which an address is 2, a write start position of a third column becomes a position of which an address is 5, a write start position of a fourth column becomes a position of which an address is 9, a write start position of a fifth column becomes a position of which an address is 10, and a write start position of a sixth column becomes a position of which an address is 13.

When the multiple b is 2, the 64QAM is adopted as the modulation method, and a bit number m of one symbol is 6 bits, according to FIG. 29, the memory 31 has twelve columns to store 6×2 bits in the row direction and stores 64800/(6×2) bits in the column direction.

A write start position of a first column of the twelve columns of the memory 31 becomes a position of which an address is 0, a write start position of a second column becomes a position of which an address is 0, a write start position of a third column becomes a position of which an address is 2, a write start position of a fourth column becomes a position of which an address is 2, a write start position of a fifth column becomes a position of which an address is 3, a write start position of a sixth column becomes a position of which an address is 4, a write start position of a seventh column becomes a position of which an address is 4, a write start position of a eighth column becomes a position of which an address is 5, a write start position of a ninth column becomes a position of which an address is 5 a write start position of a tenth column becomes a position of which an address is 7, a write start position of a eleventh column becomes a position of which an address is 8, and a write start position of a twelfth column becomes a position of which an address is 9.

When the multiple b is 1, the 256QAM is adopted as the modulation method, and a bit number m of one symbol is 8 bits, according to FIG. 29, the memory 31 has eight columns to store 8×1 bits in the row direction and stores 64800/(8×2) bits in the column direction.

A write start position of a first column of the eight columns of the memory 31 becomes a position of which an address is 0, a write start position of a second column becomes a position of which an address is 0, a write start position of a third column becomes a position of which an address is 2, a write start position of a fourth column becomes a position of which an address is 4, a write start position of a fifth column becomes a position of which an address is 4, a write start position of a sixth column becomes a position of which an address is 5, a write start position of a seventh column becomes a position of which an address is 7, and a write start position of a eighth column becomes a position of which an address is 7.

When the multiple b is 2, the 256QAM is adopted as the modulation method, and a bit number m of one symbol is 8 bits, according to FIG. 29, the memory 31 has sixteen columns to store 8×2 bits in the row direction and stores 64800/(8×2) bits in the column direction.

A write start position of a first column of the sixteen columns of the memory 31 becomes a position of which an address is 0, a write start position of a second column becomes a position of which an address is 2, a write start position of a third column becomes a position of which an address is 2, a write start position of a fourth column becomes a position of which an address is 2, a write start position of a fifth column becomes a position of which an address is 2, a write start position of a sixth column becomes a position of which an address is 3, a write start position of a seventh column becomes a position of which an address is 7, a write start position of a eighth column becomes a position of which an address is 15, a write start position of a ninth column becomes a position of which an address is 16 a write start position of a tenth column becomes a position of which an address is 20, a write start position of a eleventh column becomes a position of which an address is 22, a write start position of a twelfth column becomes a position of which an address is 22, a write start position of a thirteenth column becomes a position of which an address is 27, a write start position of a fourteenth column becomes a position of which an address is 27, a write start position of a fifteenth column becomes a position of which an address is 28, and a write start position of a sixteenth column becomes a position of which an address is 32.

When the multiple b is 1, the 1024QAM is adopted as the modulation method, and a bit number m of one symbol is 10 bits, according to FIG. 29, the memory 31 has ten columns to store 10×1 bits in the row direction and stores 64800/(10×1) bits in the column direction.

A write start position of a first column of the ten columns of the memory 31 becomes a position of which an address is 0, a write start position of a second column becomes a position of which an address is 3, a write start position of a third column becomes a position of which an address is 6, a write start position of a fourth column becomes a position of which an address is 8, a write start position of a fifth column becomes a position of which an address is 11, a write start position of a sixth column becomes a position of which an address is 13, a write start position of a seventh column becomes a position of which an address is 15, a write start position of a eighth column becomes a position of which an address is 17, a write start position of a ninth column becomes a position of which an address is 18 and a write start position of a tenth column becomes a position of which an address is 20.

When the multiple b is 2, the 1024QAM is adopted as the modulation method, and a bit number m of one symbol is 10 bits, according to FIG. 29, the memory 31 has twenty columns to store 10×2 bits in the row direction and stores 64800/(10×2) bits in the column direction.

A write start position of a first column of the twenty columns of the memory 31 becomes a position of which an address is 0, a write start position of a second column becomes a position of which an address is 1, a write start position of a third column becomes a position of which an address is 3, a write start position of a fourth column becomes a position of which an address is 4, a write start position of a fifth column becomes a position of which an address is 5, a write start position of a sixth column becomes a position of which an address is 6, a write start position of a seventh column becomes a position of which an address is 6, a write start position of a eighth column becomes a position of which an address is 9, a write start position of a ninth column becomes a position of which an address is 13 a write start position of a tenth column becomes a position of which an address is 14, a write start position of a eleventh column becomes a position of which an address is 14, a write start position of a twelfth column becomes a position of which an address is 16, a write start position of a thirteenth column becomes a position of which an address is 21, a write start position of a fourteenth column becomes a position of which an address is 21, a write start position of a fifteenth column becomes a position of which an address is 23, a write start position of a sixteenth column becomes a position of which an address is 25, a write start position of a seventeenth column becomes a position of which an address is 25, a write start position of a eighteenth column becomes a position of which an address is 26, a write start position of a nineteenth column becomes a position of which an address is 28, and a write start position of a twentieth column becomes a position of which an address is 30.

When the multiple b is 1, the 4096QAM is adopted as the modulation method, and a bit number m of one symbol is 12 bits, according to FIG. 29, the memory 31 has twelve columns to store 12×1 bits in the row direction and stores 64800/(12×1) bits in the column direction.

A write start position of a first column of the twelve columns of the memory 31 becomes a position of which an address is 0, a write start position of a second column becomes a position of which an address is 0, a write start position of a third column becomes a position of which an address is 2, a write start position of a fourth column becomes a position of which an address is 2, a write start position of a fifth column becomes a position of which an address is 3, a write start position of a sixth column becomes a position of which an address is 4, a write start position of a seventh column becomes a position of which an address is 4, a write start position of a eighth column becomes a position of which an address is 5, a write start position of a ninth column becomes a position of which an address is 5 a write start position of a tenth column becomes a position of which an address is 7, a write start position of a eleventh column becomes a position of which an address is 8, and a write start position of a twelfth column becomes a position of which an address is 9.

When the multiple b is 2, the 4096QAM is adopted as the modulation method, and a bit number in of one symbol is 12 bits, according to FIG. 29, the memory 31 has twenty four columns to store 12×2 bits in the row direction and stores 64800/(12×2) bits in the column direction.

A write start position of a first column of the twenty four columns of the memory 31 becomes a position of which an address is 0, a write start position of a second column becomes a position of which an address is 5, a write start position of a third column becomes a position of which an address is 8, a write start position of a fourth column becomes a position of which an address is 8, a write start position of a fifth column becomes a position of which an address is 8, a write start position of a sixth column becomes a position of which an address is 8, a write start position of a seventh column becomes a position of which an address is 10, a write start position of a eighth column becomes a position of which an address is 10, a write start position of a ninth column becomes a position of which an address is 10 a write start position of a tenth column becomes a position of which an address is 12, a write start position of a eleventh column becomes a position of which an address is 13, a write start position of a twelfth column becomes a position of which an address is 16, a write start position of a thirteenth column becomes a position of which an address is 17, a write start position of a fourteenth column becomes a position of which an address is 19, a write start position of a fifteenth column becomes a position of which an address is 21, a write start position of a sixteenth column becomes a position of which an address is 22, a write start position of a seventeenth column becomes a position of which an address is 23, a write start position of a eighteenth column becomes a position of which an address is 26, a write start position of a nineteenth column becomes a position of which an address is 37, a write start position of a twentieth column becomes a position of which an address is 39, a write start position of a twenty first column becomes a position of which an address is 40, a write start position of a twenty second column becomes a position of which an address is 41, a write start position of a twenty third column becomes a position of which an address is 41, and a write start position of a twenty fourth column becomes a position of which an address is 41.

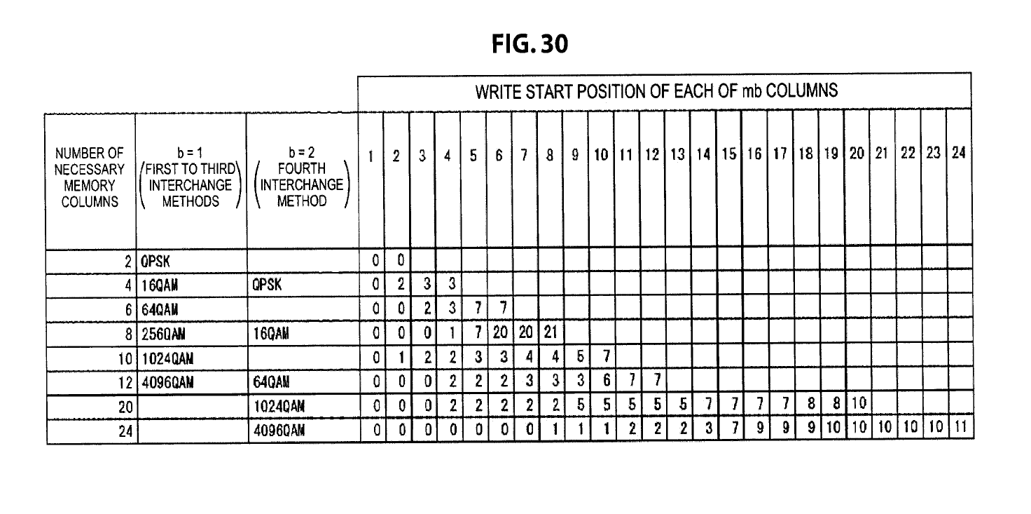

FIG. 30 illustrates a column number of the memory 31 necessary for the column twist interleave and an address of a write start position for each modulation method, with respect to LDPC codes of 10 encoding rates defined in the standard of the DVB-T.2 and having a code length N of 16200.

When the multiple b is 1, the QPSK is adopted as the modulation method, and a bit number m of one symbol is 2 bits, according to FIG. 30, the memory 31 has two columns to store 2×1 bits in the row direction and stores 16200/(2×1) bits in the column direction.

A write start position of a first column of the two columns of the memory 31 becomes a position of which an address is 0 and a write start position of a second column becomes a position of which an address is 0.

When the multiple b is 2, the QPSK is adopted as the modulation method, and a bit number m of one symbol is 2 bits, according to FIG. 30, the memory 31 has four columns to store 2×2 (=mb) bits in the row direction and stores 16200/(2×2) bits in the column direction.

A write start position of a first column of the four columns of the memory 31 becomes a position of which an address is 0, a write start position of a second column becomes a position of which an address is 2, a write start position of a third column becomes a position of which an address is 3, and a write start position of a fourth column becomes a position of which an address is 3.

When the multiple b is 1, the 16QAM is adopted as the modulation method, and a bit number m of one symbol is 4 bits, according to FIG. 30, the memory 31 has four columns to store 4×1 bits in the row direction and stores 16200/(4×1) bits in the column direction.

A write start position of a first column of the four columns of the memory 31 becomes a position of which an address is 0, a write start position of a second column becomes a position of which an address is 2, a write start position of a third column becomes a position of which an address is 3, and a write start position of a fourth column becomes a position of which an address is 3.

When the multiple b is 2, the 16QAM is adopted as the modulation method, and a bit number m of one symbol is 4 bits, according to FIG. 30, the memory 31 has eight columns to store 4×2 bits in the row direction and stores 16200/(4×2) bits in the column direction.

A write start position of a first column of the eight columns of the memory 31 becomes a position of which an address is 0, a write start position of a second column becomes a position of which an address is 0, a write start position of a third column becomes a position of which an address is 0, a write start position of a fourth column becomes a position of which an address is 1, a write start position of a fifth column becomes a position of which an address is 7, a write start position of a sixth column becomes a position of which an address is 20, a write start position of a seventh column becomes a position of which an address is 20, and a write start position of a eighth column becomes a position of which an address is 21.

When the multiple b is 1, the 64QAM is adopted as the modulation method, and a bit number m of one symbol is 6 bits, according to FIG. 30, the memory 31 has six columns to store 6×1 bits in the row direction and stores 16200/(6×1) bits in the column direction.

A write start position of a first column of the six columns of the memory 31 becomes a position of which an address is 0, a write start position of a second column becomes a position of which an address is 0, a write start position of a third column becomes a position of which an address is 2, a write start position of a fourth column becomes a position of which an address is 3, a write start position of a fifth column becomes a position of which an address is 7, and a write start position of a sixth column becomes a position of which an address is 7.

When the multiple b is 2, the 64QAM is adopted as the modulation method, and a bit number m of one symbol is 6 bits, according to FIG. 30, the memory 31 has twelve columns to store 6×2 bits in the row direction and stores 16200/(6×2) bits in the column direction.

A write start position of a first column of the twelve columns of the memory 31 becomes a position of which an address is 0, a write start position of a second column becomes a position of which an address is 0, a write start position of a third column becomes a position of which an address is 0, a write start position of a fourth column becomes a position of which an address is 2, a write start position of a fifth column becomes a position of which an address is 2, a write start position of a sixth column becomes a position of which an address is 2, a write start position of a seventh column becomes a position of which an address is 3, a write start position of a eighth column becomes a position of which an address is 3, a write start position of a ninth column becomes a position of which an address is 3 a write start position of a tenth column becomes a position of which an address is 6, a write start position of a eleventh column becomes a position of which an address is 7, and a write start position of a twelfth column becomes a position of which an address is 7.

When the multiple b is 1, the 256QAM is adopted as the modulation method, and a bit number m of one symbol is 8 bits, according to FIG. 30, the memory 31 has eight columns to store 8×1 bits in the row direction and stores 16200/(8×1) bits in the column direction.

A write start position of a first column of the eight columns of the memory 31 becomes a position of which an address is 0, a write start position of a second column becomes a position of which an address is 0, a write start position of a third column becomes a position of which an address is 0, a write start position of a fourth column becomes a position of which an address is 1, a write start position of a fifth column becomes a position of which an address is 7, a write start position of a sixth column becomes a position of which an address is 20, a write start position of a seventh column becomes a position of which an address is 20, and a write start position of a eighth column becomes a position of which an address is 21.

When the multiple b is 1, the 1024QAM is adopted as the modulation method, and a bit number m of one symbol is 10 bits, according to FIG. 30, the memory 31 has ten columns to store 10×1 bits in the row direction and stores 16200/(10×1) bits in the column direction.

A write start position of a first column of the ten columns of the memory 31 becomes a position of which an address is 0, a write start position of a second column becomes a position of which an address is 1, a write start position of a third column becomes a position of which an address is 2, a write start position of a fourth column becomes a position of which an address is 2, a write start position of a fifth column becomes a position of which an address is 3, a write start position of a sixth column becomes a position of which an address is 3, a write start position of a seventh column becomes a position of which an address is 4, a write start position of a eighth column becomes a position of which an address is 4, a write start position of a ninth column becomes a position of which an address is 5, and a write start position of a tenth column becomes a position of which an address is 7.

When the multiple b is 2, the 1024QAM is adopted as the modulation method, and a bit number m of one symbol is 10 bits, according to FIG. 30, the memory 31 has twenty columns to store 10×2 bits in the row direction and stores 16200/(10×2) bits in the column direction.

A write start position of a first column of the twenty columns of the memory 31 becomes a position of which an address is 0, a write start position of a second column becomes a position of which an address is 0, a write start position of a third column becomes a position of which an address is 0, a write start position of a fourth column becomes a position of which an address is 2, a write start position of a fifth column becomes a position of which an address is 2, a write start position of a sixth column becomes a position of which an address is 2, a write start position of a seventh column becomes a position of which an address is 2, a write start position of a eighth column becomes a position of which an address is 2, a write start position of a ninth column becomes a position of which an address is 5 a write start position of a tenth column becomes a position of which an address is 5, a write start position of a eleventh column becomes a position of which an address is 5, a write start position of a twelfth column becomes a position of which an address is 5, a write start position of a thirteenth column becomes a position of which an address is 5, a write start position of a fourteenth column becomes a position of which an address is 7, a write start position of a fifteenth column becomes a position of which an address is 7, a write start position of a sixteenth column becomes a position of which an address is 7, a write start position of a seventeenth column becomes a position of which an address is 7, a write start position of a eighteenth column becomes a position of which an address is 8, a write start position of a nineteenth column becomes a position of which an address is 8, and a write start position of a twentieth column becomes a position of which an address is 10.

When the multiple b is 1, the 4096QAM is adopted as the modulation method, and a bit number m of one symbol is 12 bits, according to FIG. 30, the memory 31 has twelve columns to store 12×1 bits in the row direction and stores 16200/(12×1) bits in the column direction.

A write start position of a first column of the twelve columns of the memory 31 becomes a position of which an address is 0, a write start position of a second column becomes a position of which an address is 0, a write start position of a third column becomes a position of which an address is 0, a write start position of a fourth column becomes a position of which an address is 2, a write start position of a fifth column becomes a position of which an address is 2, a write start position of a sixth column becomes a position of which an address is 2, a write start position of a seventh column becomes a position of which an address is 3, a write start position of a eighth column becomes a position of which an address is 3, a write start position of a ninth column becomes a position of which an address is 3 a write start position of a tenth column becomes a position of which an address is 6, a write start position of a eleventh column becomes a position of which an address is 7, and a write start position of a twelfth column becomes a position of which an address is 7.

When the multiple b is 2, the 4096QAM is adopted as the modulation method, and a bit number m of one symbol is 12 bits, according to FIG. 30, the memory 31 has twenty four columns to store 12×2 bits in the row direction and stores 16200/(12×2) bits in the column direction.

A write start position of a first column of the twenty four columns of the memory 31 becomes a position of which an address is 0, a write start position of a second column becomes a position of which an address is 0, a write start position of a third column becomes a position of which an address is 0, a write start position of a fourth column becomes a position of which an address is 0, a write start position of a fifth column becomes a position of which an address is 0, a write start position of a sixth column becomes a position of which an address is 0, a write start position of a seventh column becomes a position of which an address is 0, a write start position of a eighth column becomes a position of which an address is 1, a write start position of a ninth column becomes a position of which an address is 1 a write start position of a tenth column becomes a position of which an address is 1, a write start position of a eleventh column becomes a position of which an address is 2, a write start position of a twelfth column becomes a position of which an address is 2, a write start position of a thirteenth column becomes a position of which an address is 2, a write start position of a fourteenth column becomes a position of which an address is 3, a write start position of a fifteenth column becomes a position of which an address is 7, a write start position of a sixteenth column becomes a position of which an address is 9, a write start position of a seventeenth column becomes a position of which an address is 9, a write start position of a eighteenth column becomes a position of which an address is 9, a write start position of a nineteenth column becomes a position of which an address is 10, a write start position of a twentieth column becomes a position of which an address is 10, a write start position of a twenty first column becomes a position of which an address is 10, a write start position of a twenty second column becomes a position of which an address is 10, a write start position of a twenty third column becomes a position of which an address is 10, and a write start position of a twenty fourth column becomes a position of which an address is 11.

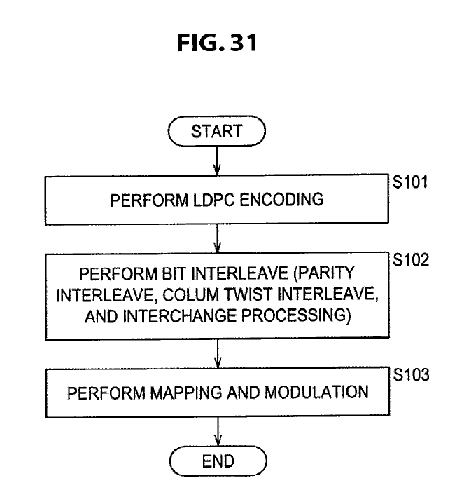

FIG. 31 is a flowchart illustrating processing executed by the LDPC encoder 115, the bit interleaver 116, and the QAM encoder 117 of FIG. 8.

The LDPC encoder 115 awaits supply of the LDPC target data from the BCH encoder 114. In step S101, the LDPC encoder 115 encodes the LDPC target data with the LDPC code and supplies the LDPC code to the bit interleaver 116. The processing proceeds to step S102.

In step S102, the bit interleaver 116 performs bit interleave with respect to the LDPC code supplied from the LDPC encoder 115 and supplies a symbol obtained by symbolizing the LDPC code after the bit interleave to the QAM encoder 117. The processing proceeds to step S103.

That is, in step S102, in the bit interleaver 116 (FIG. 9), the parity interleaver 23 performs parity interleave with respect to the LDPC code supplied from the LDPC encoder 115 and supplies the LDPC code after the parity interleave to the column twist interleaver 24.

The column twist interleaver 24 performs column twist interleave with respect to the LDPC code supplied from the parity interleaver 23 and supplies the LDPC code to the demultiplexer 25.

The demultiplexer 25 executes interchange processing for interchanging the code bits of the LDPC code after the column twist interleave by the column twist interleaver 24 and making the code bits after the interchange become symbol bits (bits representing a symbol) of the symbol.

Here, the interchange processing by the demultiplexer 25 can be performed according to the first or fourth interchange methods illustrated in FIG. 22 and FIG. 23, and, moreover, can be performed according to a predetermined allocation rule defined beforehand to allocate a symbol bit showing a symbol to a code bit of the LDPC code.

The symbol that is obtained by the interchange processing by the demultiplexer 25 is supplied from the demultiplexer 25 to the QAM encoder 117.

In step S103, the QAM encoder 117 maps the symbol supplied from the demultiplexer 25 to a signal point determined by the modulation method of the orthogonal modulation performed by the QAM encoder 117, performs the orthogonal modulation, and supplies data obtained as a result to the time interleaver 118.

As described above, the parity interleave or the column twist interleave is performed, so that tolerance against the erasure or the burst error when the plurality of code bits of the LDPC code are transmitted as one symbol can be improved.

In FIG. 9, the parity interleaver 23 to be a block to perform the parity interleave and the column twist interleaver 24 to be a block to perform the column twist interleave are individually configured for the convenience of explanation. However, the parity interleaver 23 and the column twist interleaver 24 can be integrally configured.

That is, both the parity interleave and the column twist interleave can be performed by writing and reading of the code bits with respect to the memory and can be represented by a matrix to convert an address (write address) to perform writing of the code bits into an address (read address) to perform reading of the code bits.

Therefore, if a matrix obtained by multiplying a matrix representing the parity interleave and a matrix representing the column twist interleave is calculated, the code bits are converted by the matrix, the parity interleave is performed, and a column twist interleave result of the LDPC code after the parity interleave can be obtained.

In addition to the parity interleaver 23 and the column twist interleaver 24, the demultiplexer 25 can be integrally configured.

That is, the interchange processing executed by the demultiplexer 25 can be represented by the matrix to convert the write address of the memory 31 storing the LDPC code into the read address.

Therefore, if a matrix obtained by multiplying the matrix representing the parity interleave, the matrix representing the column twist interleave, and the matrix representing the interchange processing is calculated, the parity interleave, the column twist interleave, and the interchange processing can be collectively executed by the matrix.

Only one of the parity interleave and the column twist interleave may be performed or both the parity interleave and the column twist interleave may not be performed. For example, like DVB-S.2, in a case where the communication path 13 (FIG. 7) is a satellite circuit or the like which is different from AWGN and for which burst error and flutter, and so on, do not have to be considered so much, it is possible to cause the parity interleave and the column twist interleave not to be performed.

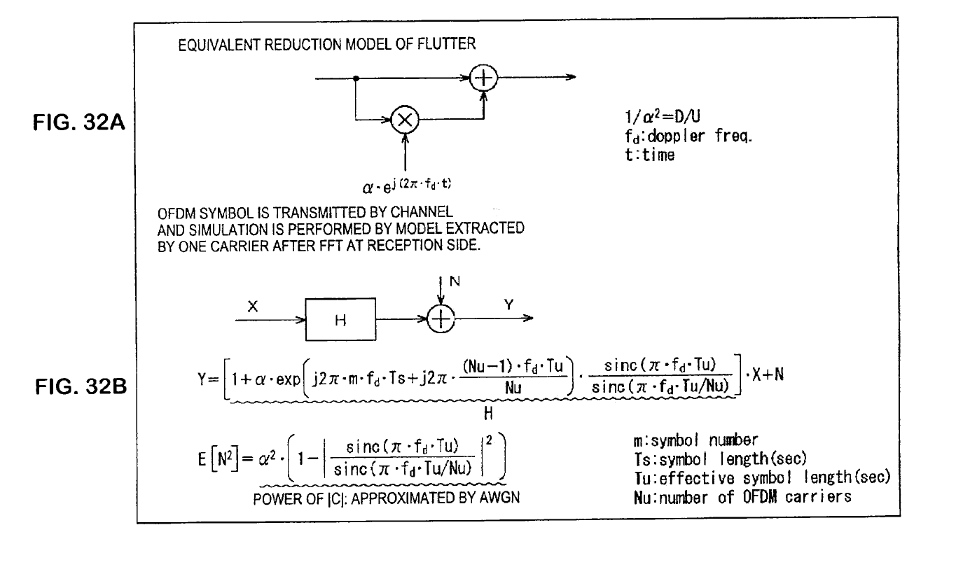

Next, simulation to measure an error rate (bit error rate) that is performed with respect to the transmitting device 11 of FIG. 8 will be described with reference to FIGS. 32 to 34.

The simulation is performed by adopting a communication path in which a flutter having D/U of 0 dB exists.

FIG. 32 illustrates a model of a communication path that is adopted by the simulation.

That is, A of FIG. 32 illustrates a model of a flutter that is adopted by the simulation.

In addition, B of FIG. 32 illustrates a model of a communication path in which the flutter represented by the model of A of FIG. 32 exists.

In B of FIG. 32, H represents the model of the flutter of A of FIG. 32. In B of FIG. 32, N represents ICI (Inter Carrier Interference). In the simulation, an expectation value E[N²] of power is approximated by the AWGN.

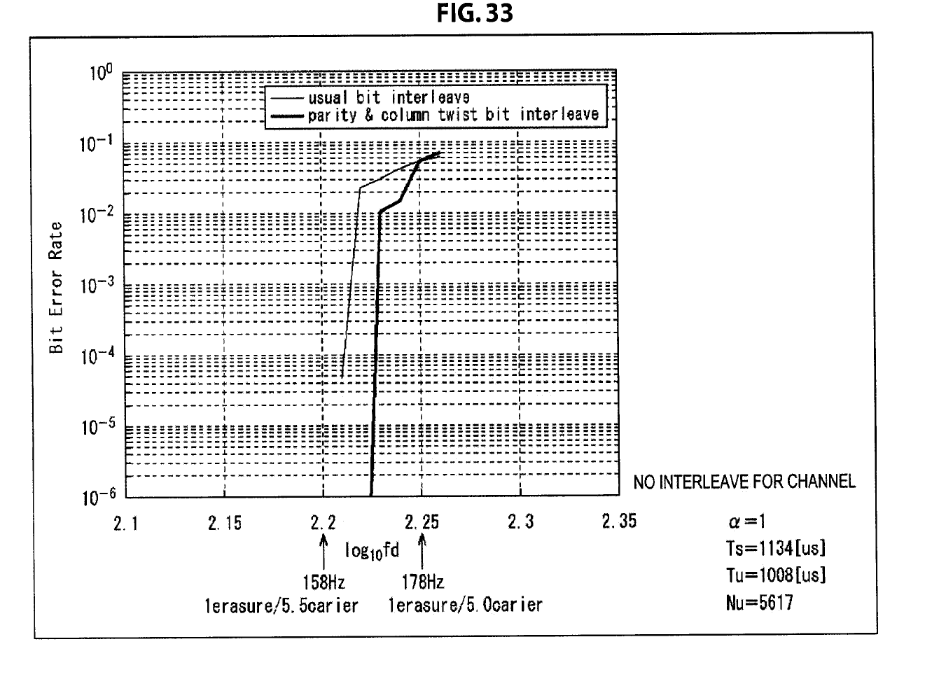

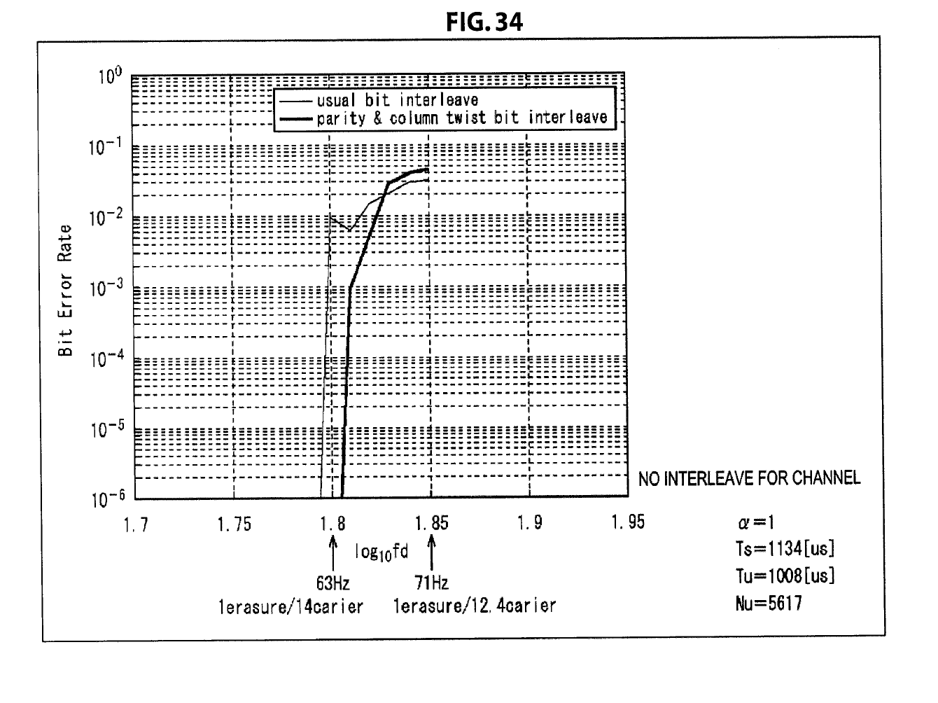

FIGS. 33 and 34 illustrate a relation of an error rate obtained by the simulation and a Doppler frequency f_{d} of the flutter.

FIG. 33 illustrates a relation of the error rate and the Doppler frequency f_{d} when a modulation method is the 16QAM, an encoding rate (r) is (3/4), and an interchange method is the first interchange method. FIG. 34 illustrates a relation of the error rate and the Doppler frequency f_{d} when the modulation method is the 64QAM, the encoding rate (r) is (5/6), and the interchange method is the first interchange method.

In FIGS. 33 and 34, a thick line shows a relation of the error rate and the Doppler frequency f_{d} when all of the parity interleave, the column twist interleave, and the interchange processing are performed and a thin line shows a relation of the error rate and the Doppler frequency f_{d} when only the interchange processing among the parity interleave, the column twist interleave, and the interchange processing is performed.

In both FIGS. 33 and 34, it can be known that the error rate is further improved (decreased) when all of the parity interleave, the column twist interleave, and the interchange processing are performed, as compared with when only the interchange processing is executed.

[Configuration Example of LDPC Encoder 115]

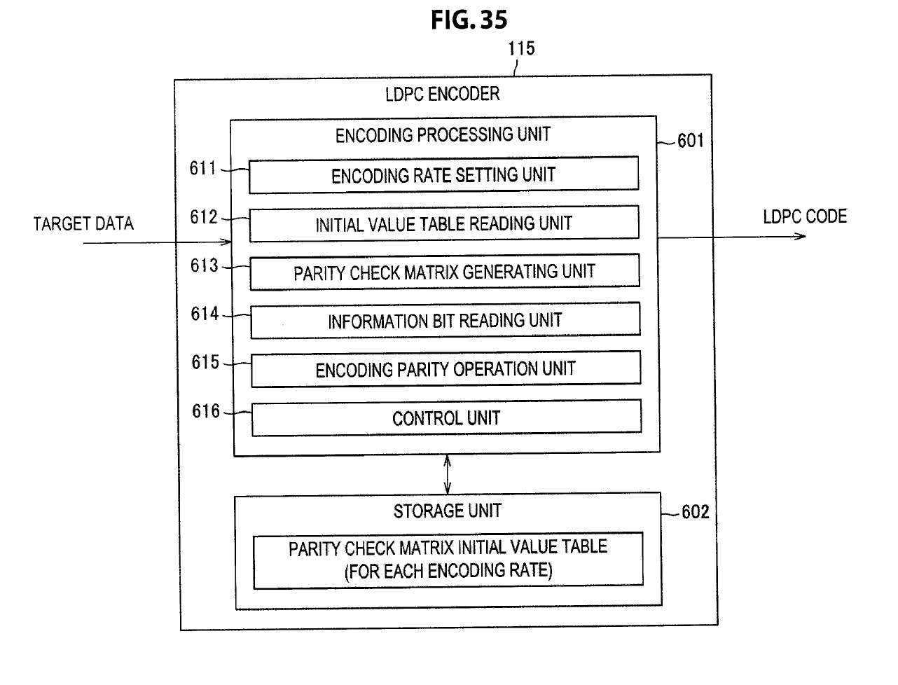

FIG. 35 is a block diagram illustrating a configuration example of the LDPC encoder 115 of FIG. 8.

The LDPC encoder 122 of FIG. 8 is also configured in the same manner.

As described in FIGS. 12 and 13, in the standard of the DVB-S.2 or the like, the LDPC codes that have the two code lengths N of 64800 bits and 16200 bits are defined.

With respect to the LDPC code having the code length N of 64800 bits, 11 encoding rates of 1/4, 1/3, 2/5, 1/2, 3/5, 2/3, 3/4, 4/5, 5/6, 8/9, and 9/10 are defined. With respect to the LDPC code having the code length N of 16200 bits, 10 encoding rates of 1/4, 1/3, 2/5, 1/2, 3/5, 2/3, 3/4, 4/5, 5/6, and 8/9 are defined (FIGS. 12 and 13).

For example, the LDPC encoder 115 can perform encoding (error correction encoding) using the LDPC code of each encoding rate having the code length N of 64800 bits or 16200 bits, according to the parity check matrix H prepared for each code length N and each encoding rate.

The LDPC encoder 115 includes an encoding processing unit 601 and a storage unit 602.

The encoding processing unit 601 includes an encoding rate setting unit 611, an initial value table reading unit 612, a parity check matrix generating unit 613, an information bit reading unit 614, an encoding parity operation unit 615, an a control unit 616. The encoding processing unit 601 performs the LDPC encoding of LDPC target data supplied to the LDPC encoder 115 and supplies an LDPC code obtained as a result to the bit interleaver 116 (FIG. 8).

That is, the encoding rate setting unit 611 sets the code length N and the encoding rate of the LDPC code, according to an operation of an operator.

The initial value table reading unit 612 reads a parity check matrix initial value table to be described later, which corresponds to the code length N and the encoding rate set by the encoding rate setting unit 611, from the storage unit 602.

The parity check matrix generating unit 613 generates a parity check matrix H by arranging elements of 1 of an information matrix H_{A} corresponding to an information length K (=information length N−parity length M) according to the code length N and the encoding rate set by the encoding rate setting unit 611 in the column direction with a period of 360 columns (column number P of a unit of the cyclic structure), on the basis of the parity check matrix initial value table read by the initial value table reading unit 612, and stores the parity check matrix H in the storage unit 602.

The information bit reading unit 614 reads (extracts) information bits corresponding to the information length K, from the LDPC target data supplied to the LDPC encoder 115.

The encoding parity operation unit 615 reads the parity check matrix H generated by the parity check matrix generating unit 613 from the storage unit 602, and generates a code word (LDPC code) by calculating parity bits for the information bits read by the information bit reading unit 614 on the basis of a predetermined expression using the parity check matrix H.

The control unit 616 controls each block constituting the encoding processing unit 601.

In the storage unit 602, a plurality of parity check matrix initial value tables that correspond to the plurality of encoding rates illustrated in FIGS. 12 and 13, with respect to the code lengths N such as the 64800 bits and 16200 bits, are stored. In addition, the storage unit 602 temporarily stores data that is necessary for processing of the encoding processing unit 601.

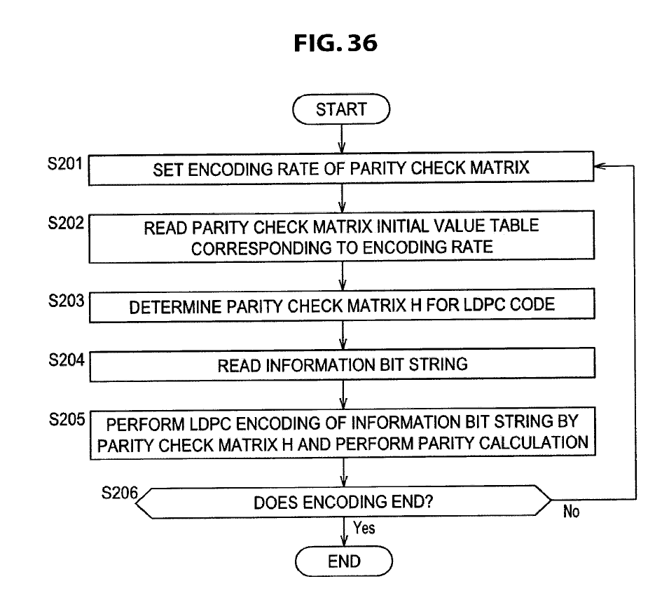

FIG. 36 is a flowchart illustrating processing of the LDPC encoder 115 of FIG. 35.

In step S201, the encoding rate setting unit 611 determines (sets) the code length N and the encoding rate r to perform the LDPC encoding.

In step S202, the initial value table reading unit 612 reads the previously determined parity check matrix initial value table corresponding to the code length N and the encoding rate r determined by the encoding rate setting unit 611, from the storage unit 602.

In step S203, the parity check matrix generating unit 613 calculates (generates) the parity check matrix H of the LDPC code of the code length N and the encoding rate r determined by the encoding rate setting unit 611, using the parity check matrix initial value table read from the storage unit 602 by the initial value table reading unit 612, supplies the parity check matrix to the storage unit 602, and stores the parity check matrix in the storage unit.

In step S204, the information bit reading unit 614 reads the information bits of the information length K (=N×r) corresponding to the code length N and the encoding rate r determined by the encoding rate setting unit 611, from the LDPC target data supplied to the LDPC encoder 115, reads the parity check matrix H calculated by the parity check matrix generating unit 613 from the storage unit 602, and supplies the information bits and the parity check matrix to the encoding parity operation unit 615.

In step S205, the encoding parity operation unit 615 sequentially operates parity bits of a code word c that satisfies an expression (8) using the information bits and the parity check matrix H that have been read from the information bit reading unit 614.

Hc^{T}=0 (8)

In the expression (8), c represents a row vector as the code word (LDPC code) and c^{T} represents transposition of the row vector c.

As described above, when a portion of the information bits of the row vector c as the LDPC code (one code word) is represented by a row vector A and a portion of the parity bits is represented by a row vector T, the row vector c can be represented by an expression c=[A/T], using the row vector A as the information bits and the row vector T as the parity bits.

In the parity check matrix H and the row vector c=[A|T] corresponding to the LDPC code, it is necessary to satisfy an expression Hc^{T}=0. The row vector T that corresponds to the parity bits constituting the row vector c=[A|T] satisfying the expression Hc^{T}=0 can be sequentially calculated by setting elements of each row to 0, sequentially from elements of a first row of the column vector Hc^{T} in the expression Hc^{T}=0, when the parity matrix H_{T} of the parity check matrix H=[H_{A}|H_{T}] becomes the staircase structure illustrated in FIG. 11.

If the encoding parity operation unit 615 calculates the parity bits T with respect to the information bits A from the information bit reading unit 614, the encoding parity operation unit 615 outputs the code word c=[A/T] represented by the information bits A and the parity bits T as an LDPC encoding result of the information bits A.

Then, in step S206, the control unit 616 determines whether the LDPC encoding ends. When it is determined in step S206 that the LDPC encoding does not end, that is, when there is LDPC target data to perform the LDPC encoding, the processing returns to step S201 (or step S204). Hereinafter, the processing of steps S201 (or step S204) to S206 is repeated.

When it is determined in step S206 that the LDPC encoding ends, that is, there is no LDPC target data to perform the LDPC encoding, the LDPC encoder 115 ends the processing.

As described above, the parity check matrix initial value table corresponding to each code length N and each encoding rate r is prepared and the LDPC encoder 115 performs the LDPC encoding of the predetermined code length N and the predetermined encoding rate r, using the parity check matrix H generated from the parity check matrix initial value table corresponding to the predetermined code length N and the predetermined encoding rate r.

[Example of the Parity Check Matrix Initial Value Table]

The parity check matrix initial value table is a table that represents positions of elements of 1 of the information matrix H_{A} (FIG. 10) of the parity check matrix H corresponding to the information length K according to the code length N and the encoding rate r of the LDPC code (LDPC code defined by the parity check matrix H) for every 360 columns (column number P of a unit of the cyclic structure) and is previously made for each parity check matrix H of each code length N and each encoding rate r.

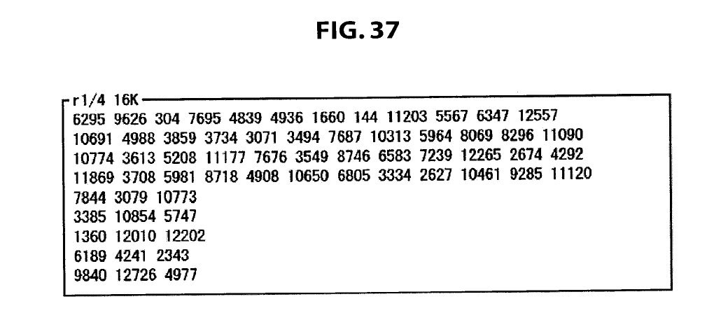

FIG. 37 is an illustration of an example of the parity check matrix initial value table.

That is, FIG. 37 illustrates a parity check matrix initial value table with respect to the parity check matrix H that is defined in the standard of the DVB-T.2 and has the code length N of 16200 bits and the encoding rate (an encoding rate of notation of the DVB-T.2) r of 1/4.

The parity check matrix generating unit 613 (FIG. 35) calculates the parity check matrix H using the parity check matrix initial value table, as follows.

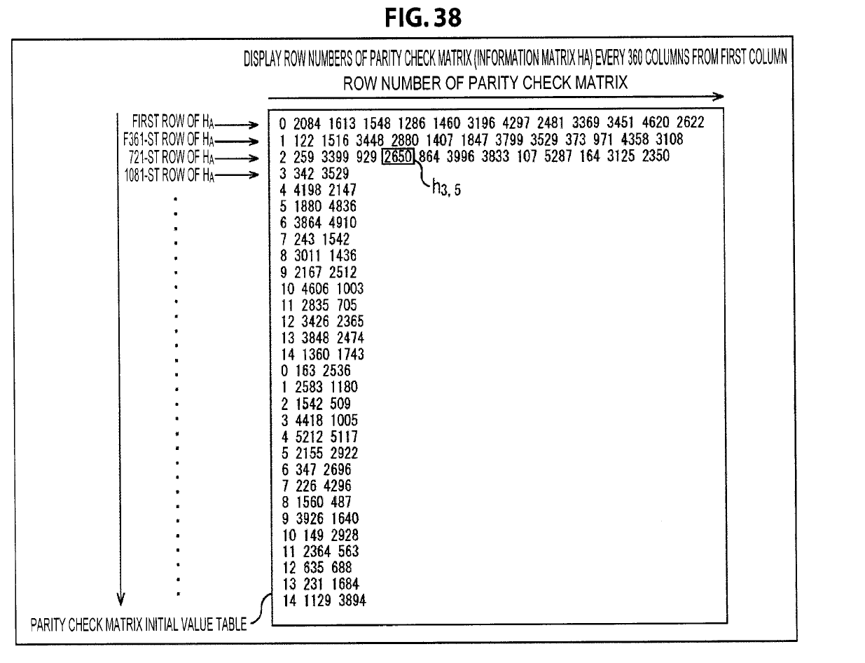

That is, FIG. 38 illustrates a method of calculating the parity check matrix H from the parity check matrix initial value table.

The parity check matrix initial value table in FIG. 38 illustrates a parity check matrix initial value table with respect to the parity check matrix H that is defined in the standard of the DVB-T.2 and has the code length N of 16200 bits and the encoding rate r of 2/3.

As described above, the parity check matrix initial value table is the table that represents the positions of the elements of 1 of the information matrix H_{A} (FIG. 10) corresponding to the information length K according to the code length N and the encoding rate r of the LDPC code for every 360 columns (column number P of a unit of the cyclic structure). In the i-th row thereof, row numbers (row numbers when a row number of a first row of the parity check matrix H is set to 0) of elements of 1 of a (1+360×(i−1)-th column of the parity check matrix H are arranged by a number of column weights of the (1+360×(i−1)-th column.

In this case, because the parity matrix H_{T} (FIG. 10) of the parity check matrix H corresponding to the parity length M is determined as illustrated in FIG. 25, according to the parity check matrix initial value table, the information matrix H_{A} (FIG. 10) of the parity check matrix H corresponding to the information length K is calculated.

A row number k+1 of the parity check matrix initial value table is different according to the information length K.

A relation of an expression (9) is realized between the information length K and the row number k+1 of the parity check matrix initial value table.

K=(k+1)×360 (9)

In this case, 360 of the expression (9) is the column umber P of the unit of the cyclic structure described in FIG. 26.

In the parity check matrix initial value table of FIG. 38, 13 numerical values are arranged from the first row to the third row and 3 numerical values are arranged from the fourth row to the (k+1)-th row (in FIG. 38, the 30th row).

Therefore, the column weights of the parity check matrix H that are calculated from the parity check matrix initial value table of FIG. 38 are 13 from the first column to the (1+360×(3−1)−1)-th column and are 3 from the (1+360×(3−1))-th column to the K-th column.

The first row of the parity check matrix initial value table of FIG. 38 becomes 0, 2084, 1613, 1548, 1286, 1460, 3196, 4297, 2481, 3369, 3451, 4620, and 2622, which shows that elements of rows having row numbers of 0, 2084, 1613, 1548, 1286, 1460, 3196, 4297, 2481, 3369, 3451, 4620, and 2622 are 1 (and the other elements are 0), in the first column of the parity check matrix H.

The second row of the parity check matrix initial value table of FIG. 38 becomes 1, 122, 1516, 3448, 2880, 1407, 1847, 3799, 3529, 373, 971, 4358, and 3108, which shows that elements of rows having row numbers of 1, 122, 1516, 3448, 2880, 1407, 1847, 3799, 3529, 373, 971, 4358, and 3108 are 1, in the 361 (=1+360×(2−1))-th column of the parity check matrix H.

As described above, the parity check matrix initial value table represents positions of elements of 1 of the information matrix H_{A} of the parity check matrix H for every 360 columns.

The columns other than the (1+360×(i−1))-th column of the parity check matrix H, that is, the individual columns from the (2+360×(i−1))-th column to the (360×i)-th column are arranged by cyclically shifting elements of 1 of the (1+360×(i−1))-th column determined by the parity check matrix initial value table periodically in a downward direction (downward direction of the columns) according to the parity length M.

That is, the (2+360×(i−1))-th column is obtained by cyclically shifting (1+360×(i−1))-th column in the downward direction by M/360 (=q) and the next (3+360×(i−1))-th column is obtained by cyclically shifting (1+360×(i−1))-th column in the downward direction by 2×M/360 (=2×q) (obtained by cyclically shifting (2+360×(i−1))-th column in the downward direction by M/360 (=q)).

If a numerical value of a j-th column (j-th column from the left side) of an i-th row (i-th row from the upper side) of the parity check matrix initial value table is represented as h_{i,j} and a row number of the j-th element of 1 of the w-th column of the parity check matrix H is represented as H_{w-j}, the row number of the element of 1 of the w-th column to be a column other than the (1+360×(i−1))-th column of the parity check matrix H can be calculated by an expression (10).

H_{w-j}=mod {h_{i,j}+mod((w−1),P)×q,M) (10)

In this case, mod(x, y) means a remainder that is obtained by dividing x by y.

In addition, P is a column number of a unit of the cyclic structure described above. For example, in the standard of the DVB-S.2, the DVB-T.2, and the DVB-C.2, P is 360 as described above. In addition, q is a value M/360 that is obtained by dividing the parity length M by the column number P (=360) of the unit of the cyclic structure.

The parity check matrix generating unit 613 (FIG. 35) specifies the row numbers of the elements of 1 of the (1+360×(i−1))-th column of the parity check matrix H by the parity check matrix initial value table.

The parity check matrix generating unit 613 (FIG. 35) calculates the row number H_{w-j} of the element of 1 of the w-th column to be the column other than the (1+360×(i−1))-th column of the parity check matrix H, according to the expression (10), and generates the parity check matrix H in which the element of the obtained row number is set to 1.

[New LDPC Code]

By the way, the suggestion of a standard that improves DVB-S.2 (which may be called DVB-Sx below) is requested.

In CfT (Call for Technology) submitted to a standardization conference of DVB-Sx, a predetermined number of ModCod (combination of a modulation method (Modulation) and an LDPC code (Code)) is requested for each range (range) of C/N (Carrier to Noise ratio) (SNR (Signal to Noise Ratio)) according to the use case.

That is, in CfT, as the first request, it is requested that 20 pieces of ModCod are prepared in a range of 7 dB in which C/N is from 5 dB to 12 dB, for the usage of DTH (Direct To Home).

In addition, in CfT, as the second request, it is requested that 22 pieces of ModCod are prepared in a range of 12 dB in which C/N is from 12 dB to 24 dB, as the third request, it is requested that 12 pieces of ModCod are prepared in a range of 8 dB in which C/N is from −3 dB to 5 dB, and, as the fourth request, it is requested that 5 pieces of ModCod are prepared in a range of 7 dB in which C/N is from −10 dB to −3 dB.

Moreover, in CfT, it is requested that FER (Frame Error Rate) of ModCod in the first or fourth requests becomes about 10⁻⁵ (or less).

Here, in CfT, the priority of the first request is “1” which is the highest, and the priority of any of the second to fourth requests is “2” which is lower than the first request.

Therefore, in the present disclosure, at least in CfT, (a parity check matrix of) an LDPC code that can satisfy the first request of the highest priority is provided as a new LDPC code.

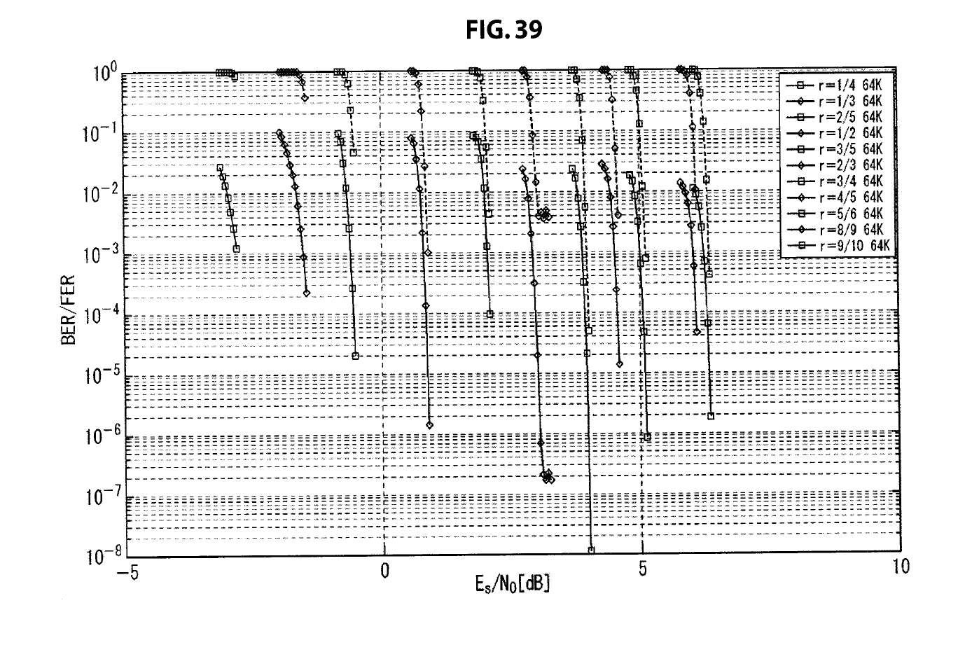

FIG. 39 illustrates a BER/FER curve in a case where QPSK is adopted as a modulation method, for LDPC codes of 11 encoding rates with a code length N of 64 k.

In FIG. 39, the horizontal axis shows Eₛ/N₀ (signal-to-noise power ratio per symbol) corresponding to C/N, and the vertical axis shows FER/BER. Here, in FIG. 39, the solid line shows FER and the dotted line shows BER (Bit Error Rate).

In FIG. 39, there is a FER (BER) curve in a case where QPSK is adopted as a code method, for LSPC codes of 11 encoding rates with a code length N of 64 k defined in DVB-S.2, in a range in which Eₛ/N₀ is 10 dB.

That is, in FIG. 39, there are 11 FER curves of ModCod in which a modulation method is fixed to QPSK, in a range of about 10 dB of Eₛ/N₀ from about −3 dB to about 7 dB.

Therefore, as for LSPC codes of 11 encoding rates with a code length N of 64 k defined in DVB-S.2, the average interval of FER curves of ModCod (which may be called an average interval below) is about 1 dB (≈10 dB/(10−1))

Meanwhile, since it is requested to prepare 20 pieces of ModCod in a range in which Eₛ/N₀ (C/N) is 7 dB in the first request of CfT, the average interval of FER curves of ModCod is about 0.3 dB (≈7 dB/(20−1)).

In a case where a modulation method is fixed to one kind such as QPSK to take margin, as compared with the case of DVB-S.2 in which ModCod with an average interval of about 1 dB can be obtained by LDPC codes of 11 encoding rates, LDPC codes of the number about three times of 11 encoding rates 1 dB/0.3 dB), that is, LDPC codes of about 30 encoding rates only have to be provided to acquire ModCod with an average interval of 0.3 dB to satisfy the first request of CIT.

Therefore, the present disclosure prepares an LDPC code with an encoding rate of i/30 (where i denotes a positive integer less than 30) and a code length of 64 k as an LDPC code of an encoding rate for which about 30 encoding rates are easily set, and provides it as a new LDPC code that satisfies at least the first request with the highest priority in CIT.

Here, as for the new LDPC code, from the viewpoint that the affinity (compatibility) with DVB-S.2 is maintained as much as possible, similar to an LDPC code defined in DVB-S.2, parity matrix H_{T} of the parity check matrix 11 is assumed to have a staircase structure (FIG. 11).

In addition, as for the new LDPC code, similar to the LDPC code defined in DVB-S.2, the information matrix H_{A} of the parity check matrix H is assumed to be a cyclic structure and column number P which is the unit of the cyclic structure is assumed to be 360.

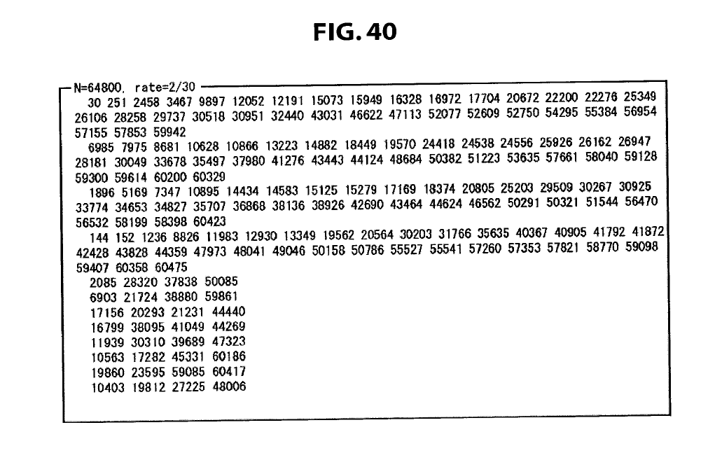

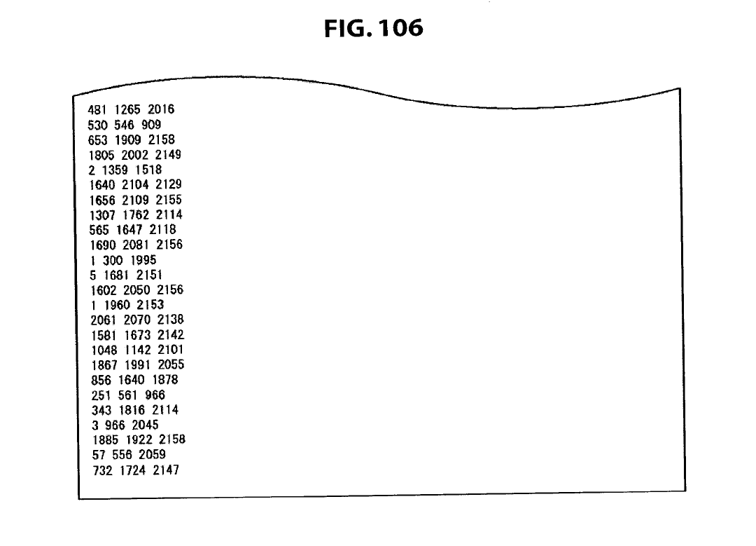

FIG. 40 to FIG. 106 are diagrams illustrating examples of a parity check matrix initial value table of a new LDPC code with a code length N of 64 k bits and an encoding rate of i/30 as described above.

Here, since the new LDPC code is an LDPC code in which the encoding rate is expressed by i/30, there are LDPC codes with 29 encoding rates of 1/30, 2/30, 3/30 . . . 28/30 and 29/30 at maximum.

However, as for an LDPC code with an encoding rate of 1/30, there is a possibility that the use is restricted in respect of efficiency. Moreover, as for an LDPC code with an encoding rate of 29/30, the use may be restricted in respect of the error rate (BER/FER).

Therefore, one or both of the LDPC code with an encoding rate of 1/30 and the LDPC code with an encoding rate of 29/30 among the LDPC codes with 29 encoding rates of encoding rates 1/30 to 29/30 can be assumed not to be treated as a new LDPC code.

Here, for example, LDPC codes with 28 encoding rates of encoding rates 2/30 to 29/30 among encoding rates 1/30 to 29/30 are assumed as new LDPC codes, and a parity check matrix initial value table with respect to the parity check matrix H of the new LDPC codes are shown below.

FIG. 40 illustrates a parity check matrix initial value table with respect to the parity check matrix H of the LDPC code with a code length N of 64 k bits and an encoding rate of 2/30.

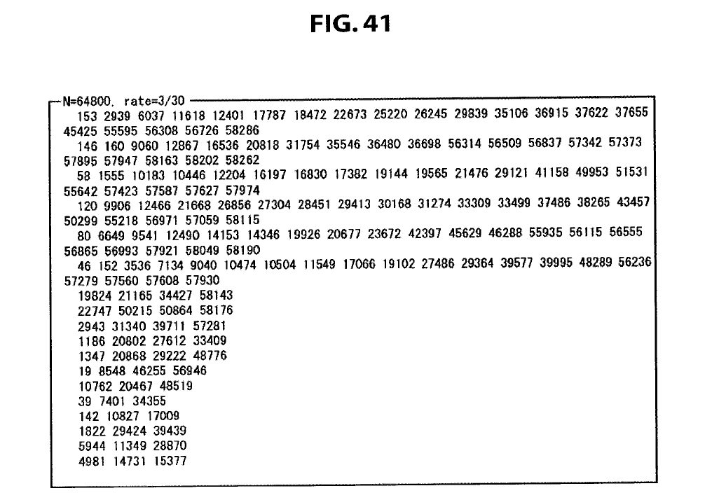

FIG. 41 illustrates a parity check matrix initial value table with respect to the parity check matrix H of the LDPC code with a code length N of 64 k bits and an encoding rate of 3/30.

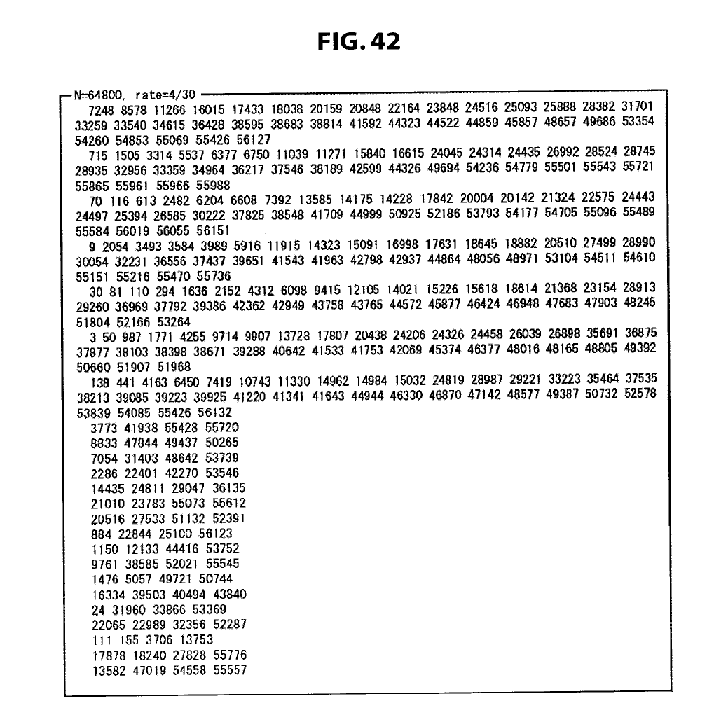

FIG. 42 illustrates a parity check matrix initial value table with respect to the parity check matrix H of the LDPC code with a code length N of 64 k bits and an encoding rate of 4/30.

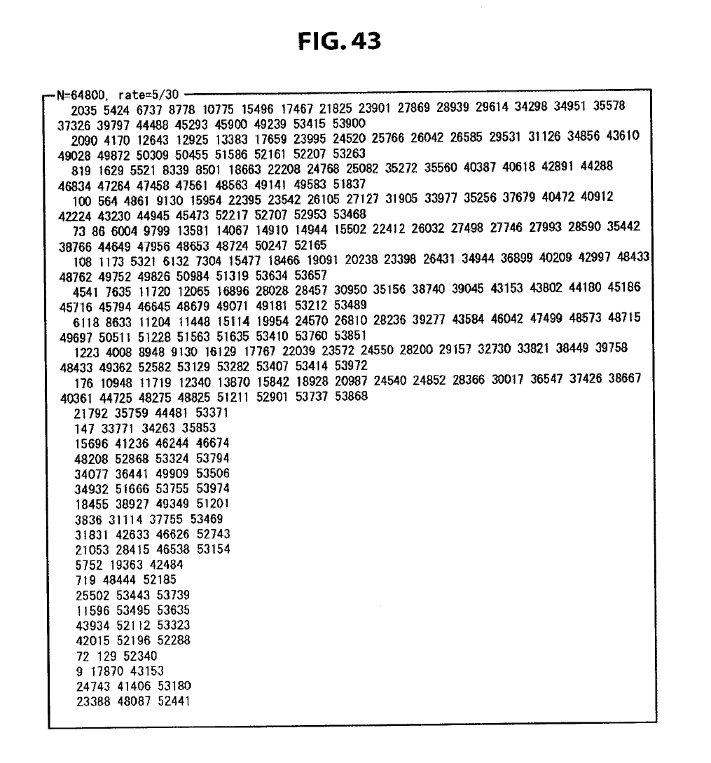

FIG. 43 illustrates a parity check matrix initial value table with respect to the parity check matrix H of the LDPC code with a code length N of 64 k bits and an encoding rate of 5/30.

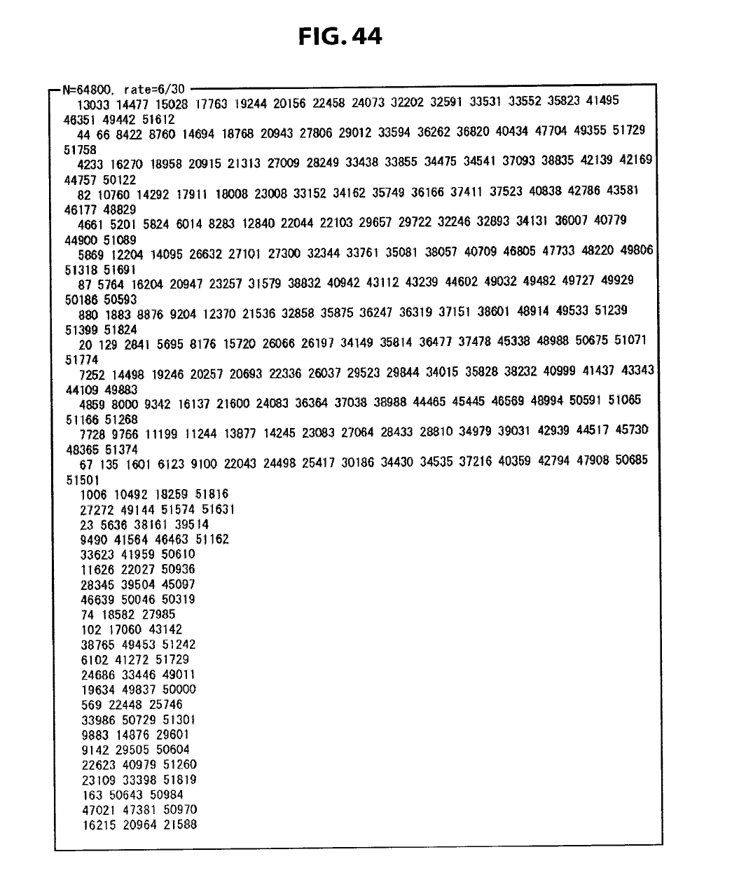

FIG. 44 illustrates a parity check matrix initial value table with respect to the parity check matrix H of the LDPC code with a code length N of 64 k bits and an encoding rate of 6/30.

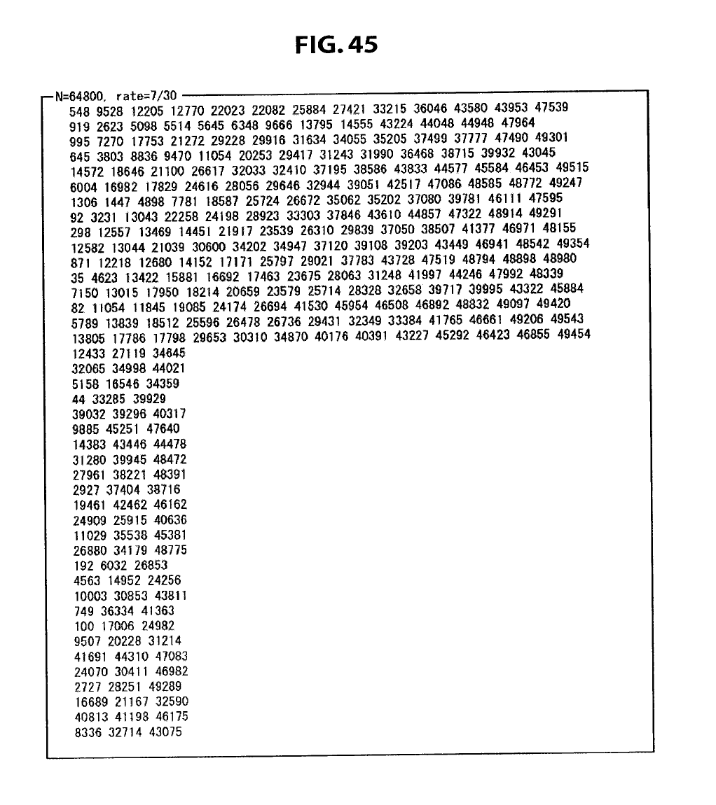

FIG. 45 illustrates a parity check matrix initial value table with respect to the parity check matrix H of the LDPC code with a code length N of 64 k bits and an encoding rate of 7/30.

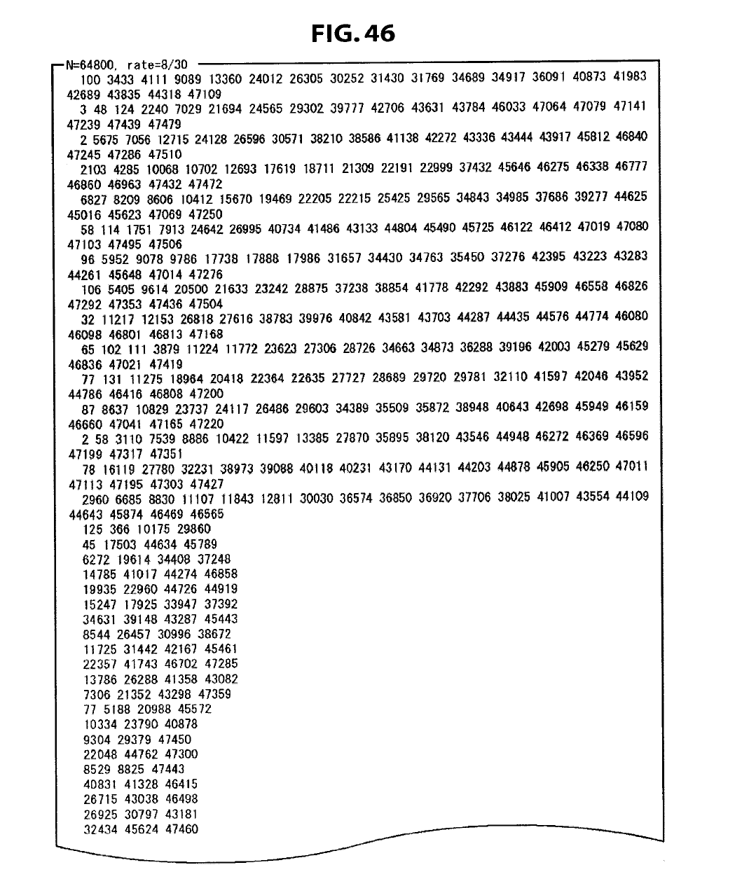

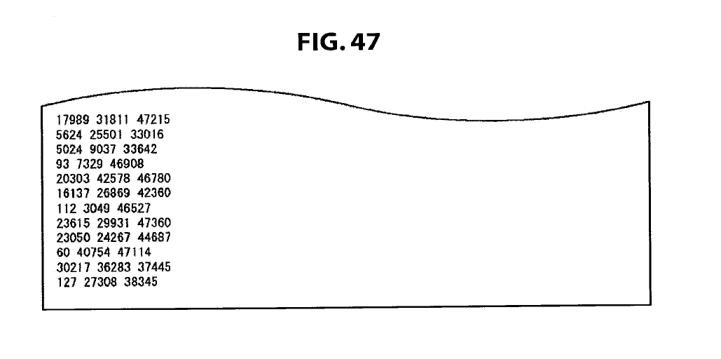

FIGS. 46 and 47 illustrate a parity check matrix initial value table with respect to the parity check matrix H of the LDPC code with a code length N of 64 k bits and an encoding rate of 8/30.

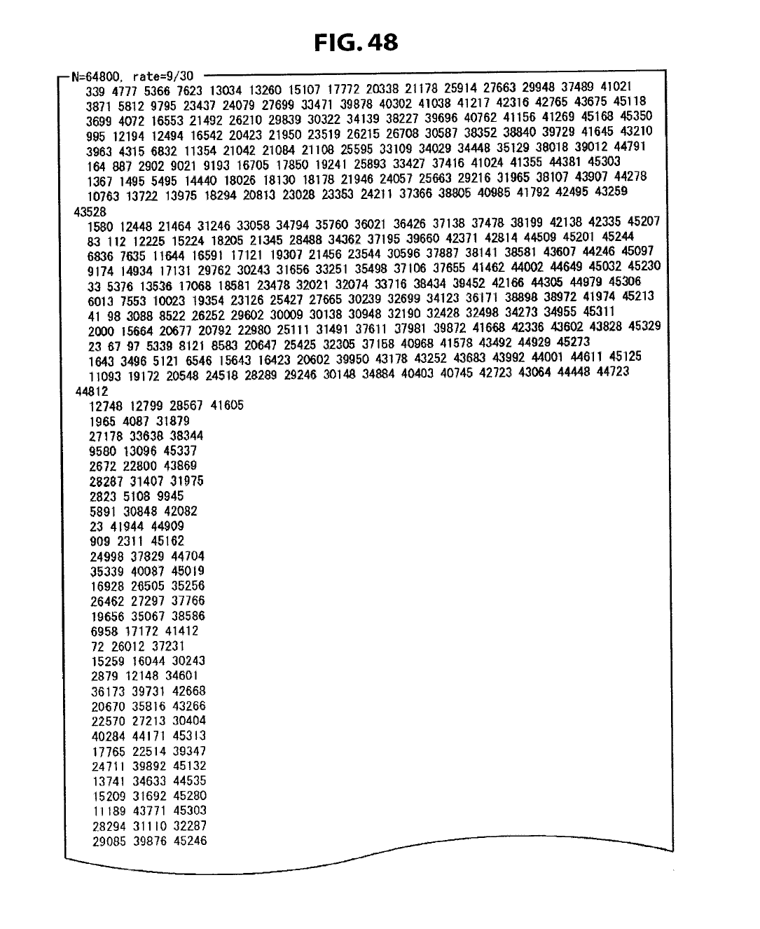

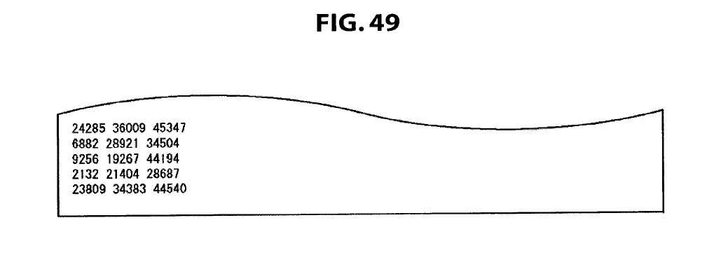

FIGS. 48 and 49 illustrate a parity check matrix initial value table with respect to the parity check matrix H of the LDPC code with a code length N of 64 k bits and an encoding rate of 9/30.

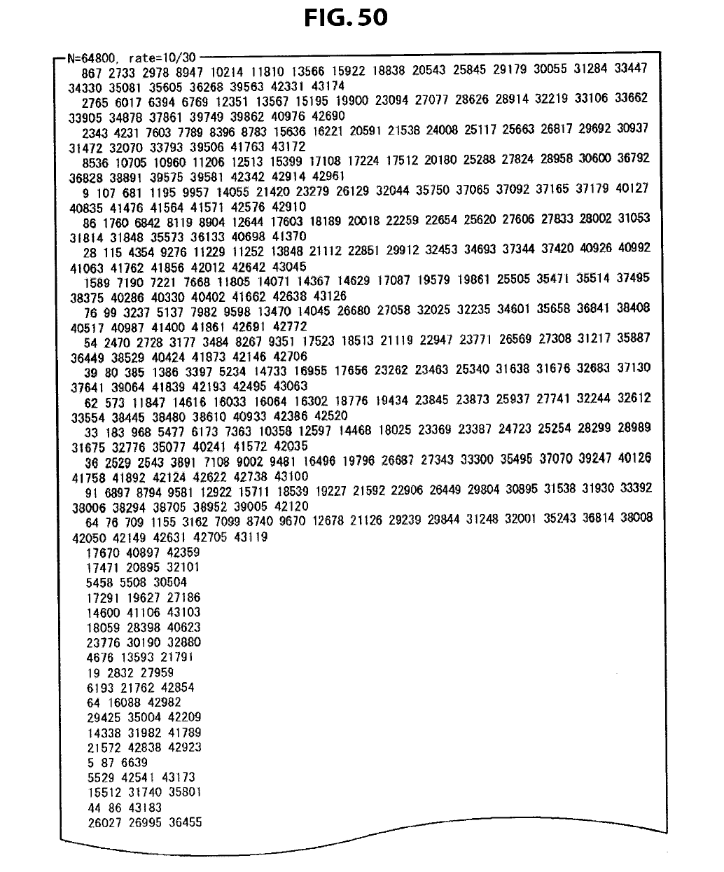

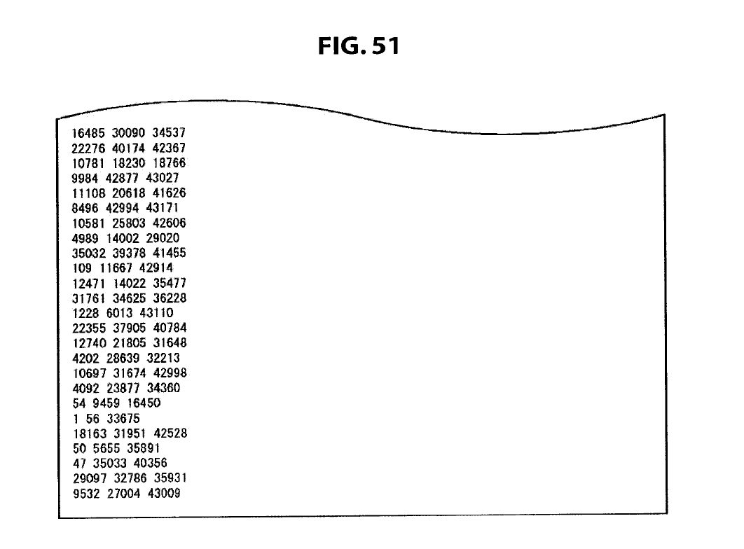

FIGS. 50 and 51 illustrate a parity check matrix initial value table with respect to the parity check matrix H of the LDPC code with a code length N of 64 k bits and an encoding rate of 10/30.

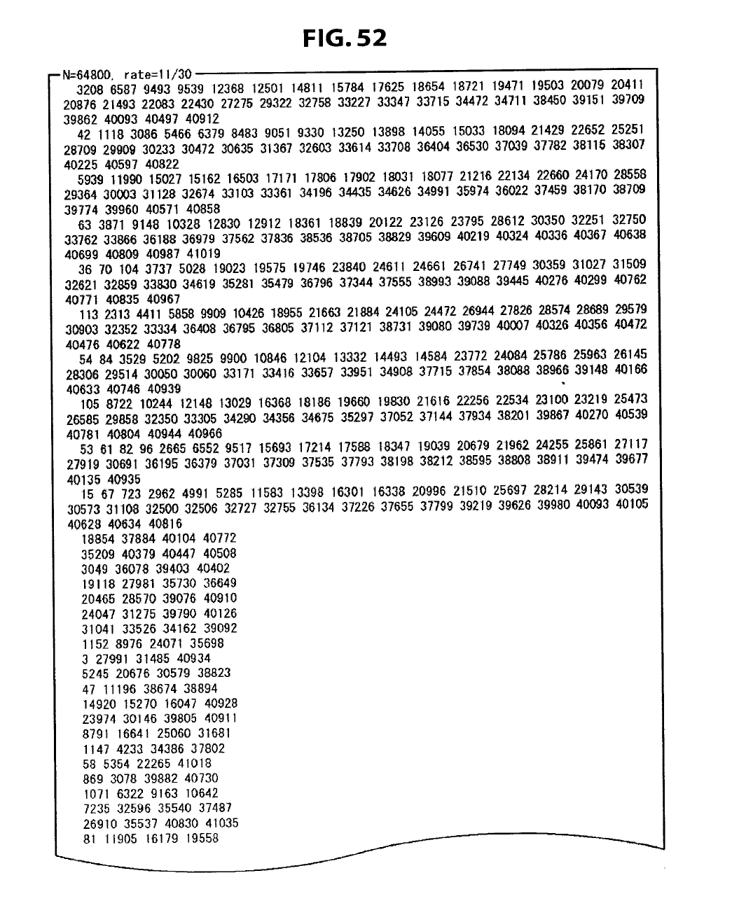

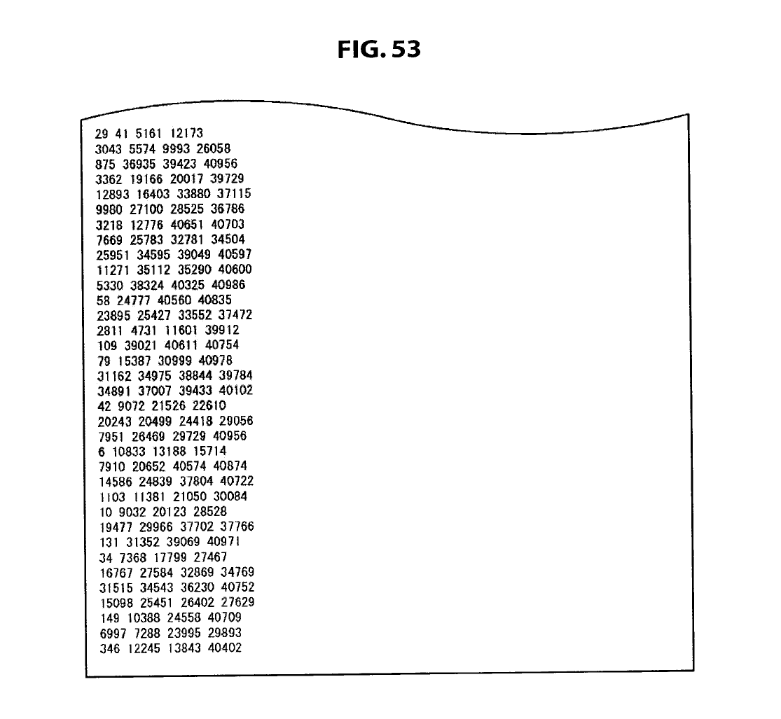

FIGS. 52 and 53 illustrate a parity check matrix initial value table with respect to the parity check matrix H of the LDPC code with a code length N of 64 k bits and an encoding rate of 11/30.

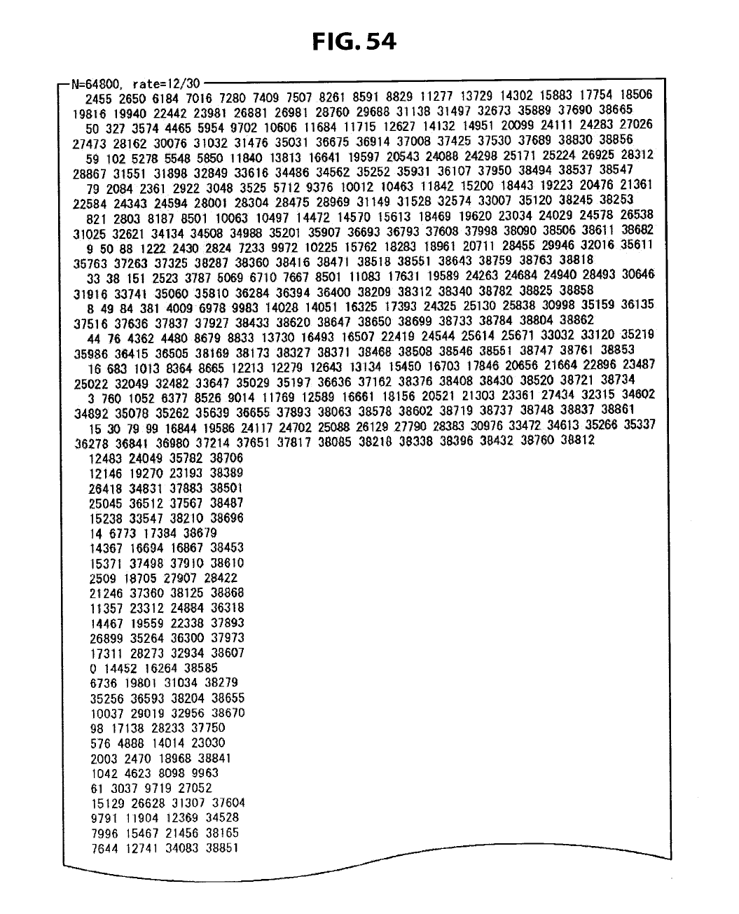

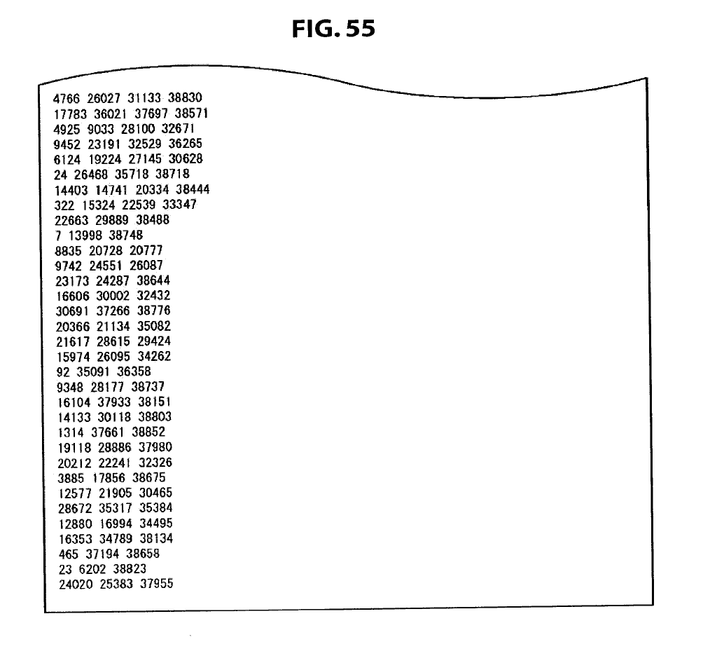

FIGS. 54 and 55 illustrate a parity check matrix initial value table with respect to the parity check matrix H of the LDPC code with a code length N of 64 k bits and an encoding rate of 12/30.

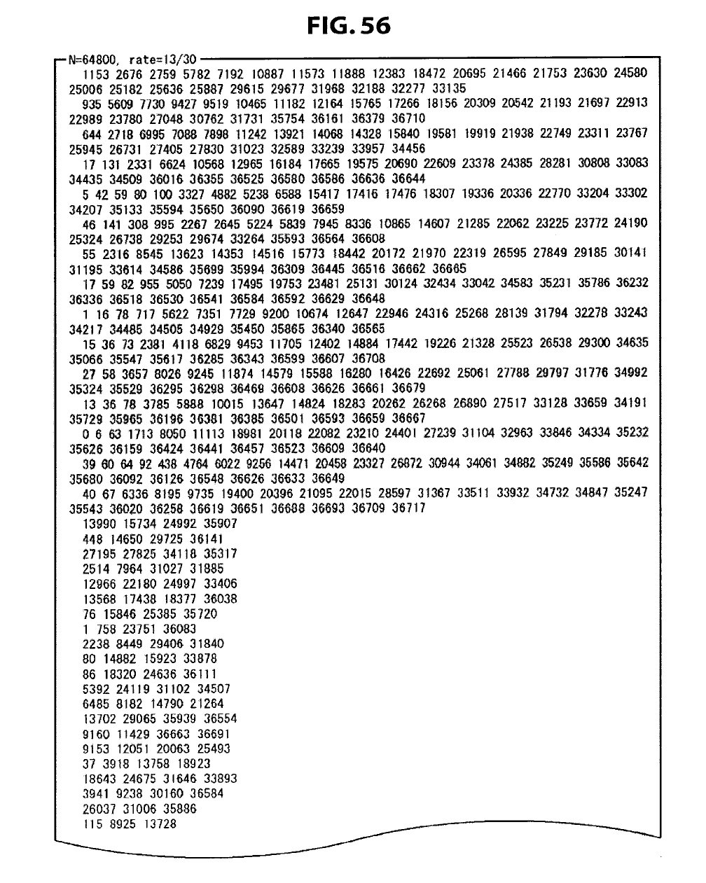

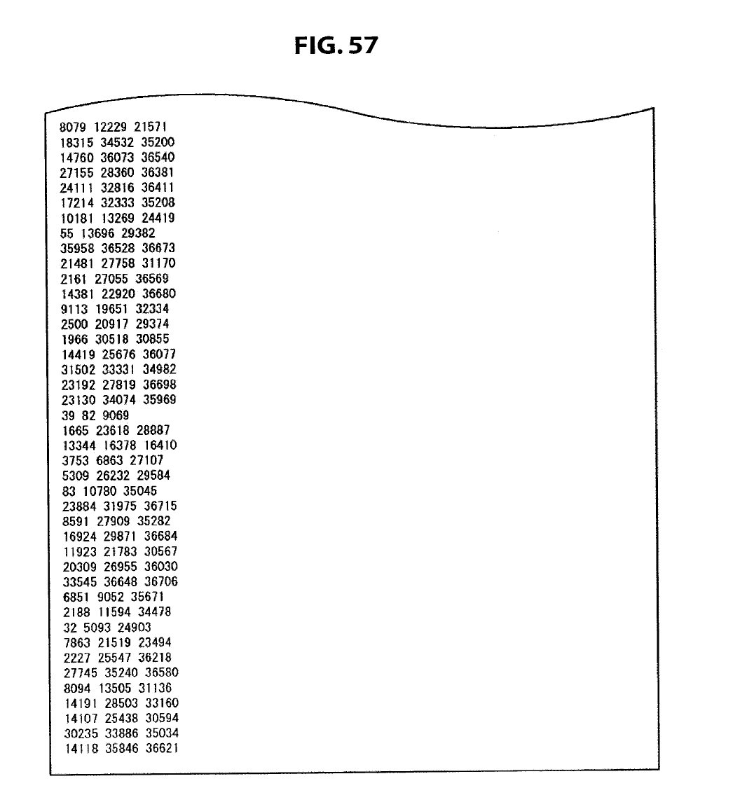

FIGS. 56 and 57 illustrate a parity check matrix initial value table with respect to the parity check matrix H of the LDPC code with a code length N of 64 k bits and an encoding rate of 13/30.

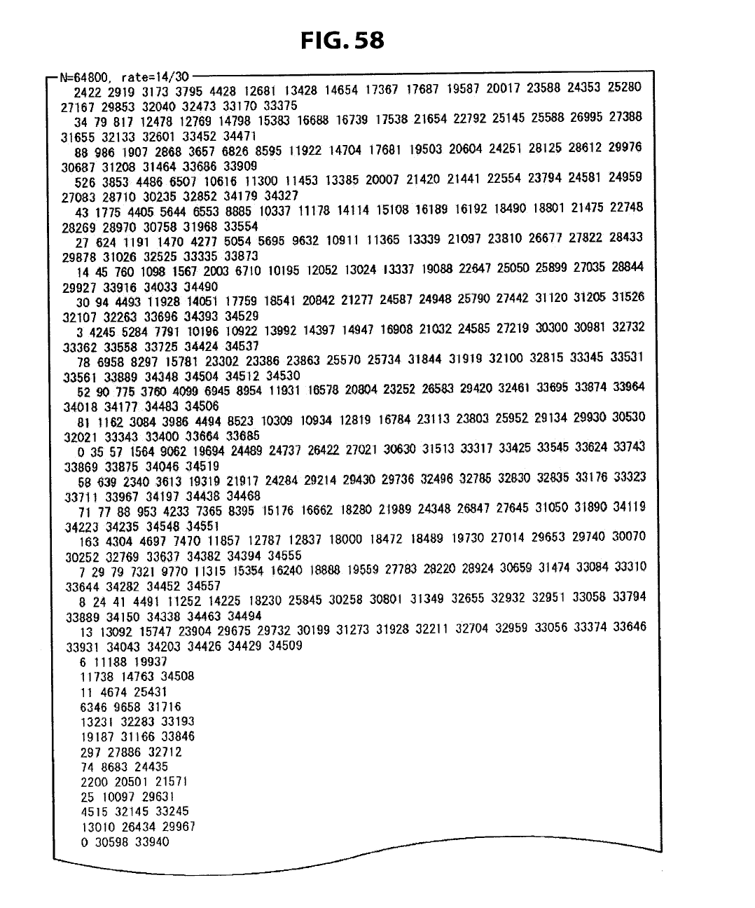

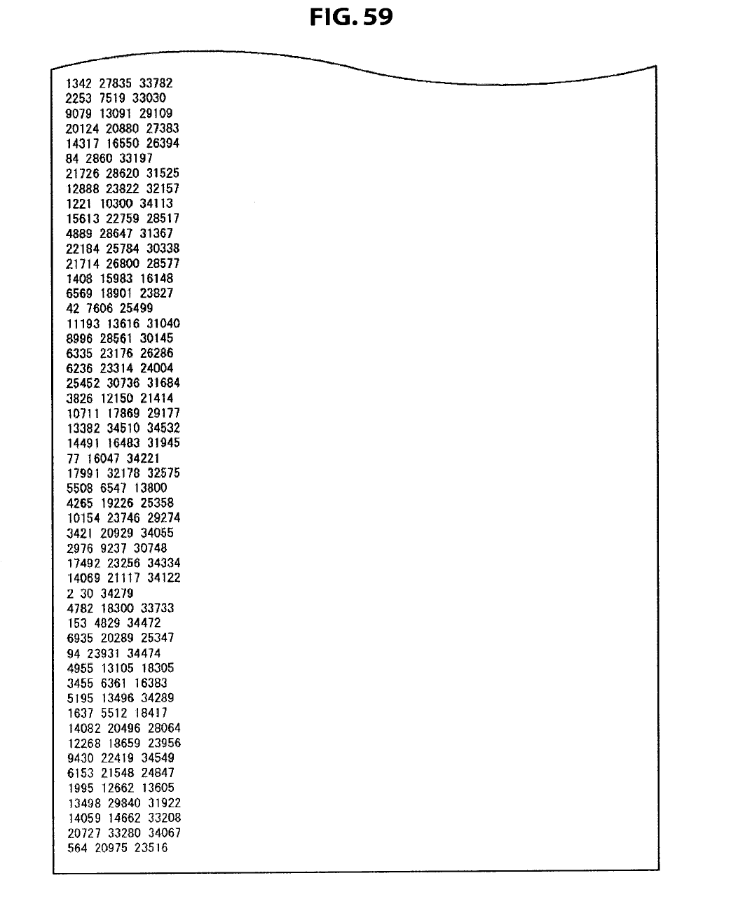

FIGS. 58 and 59 illustrate a parity check matrix initial value table with respect to the parity check matrix H of the LDPC code with a code length N of 64 k bits and an encoding rate of 14/30.

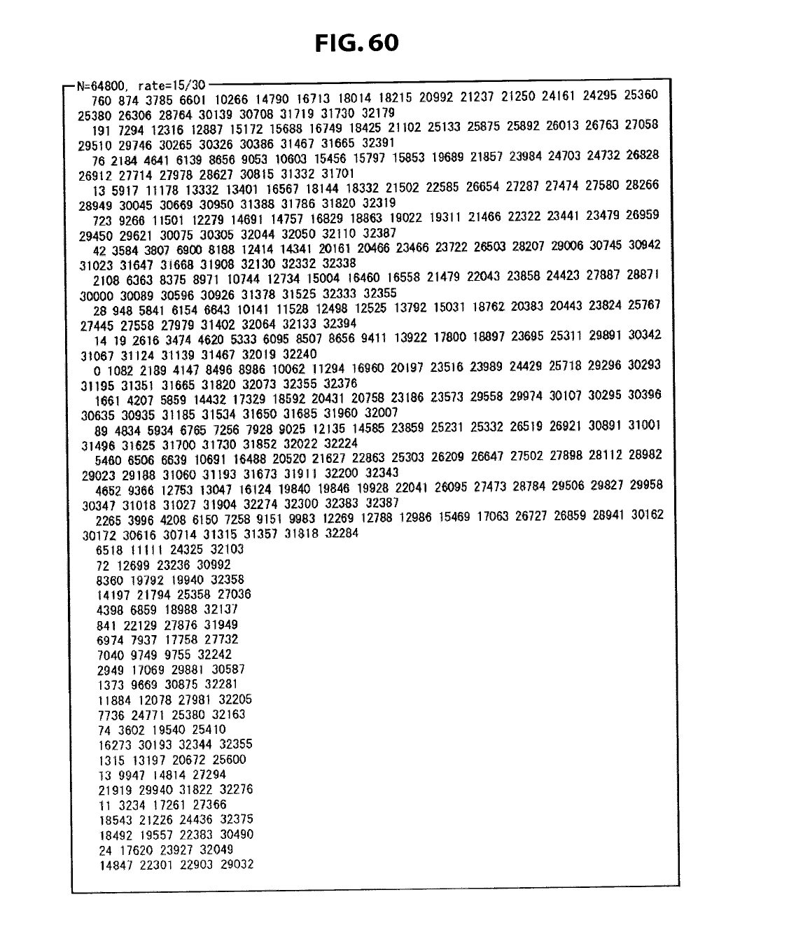

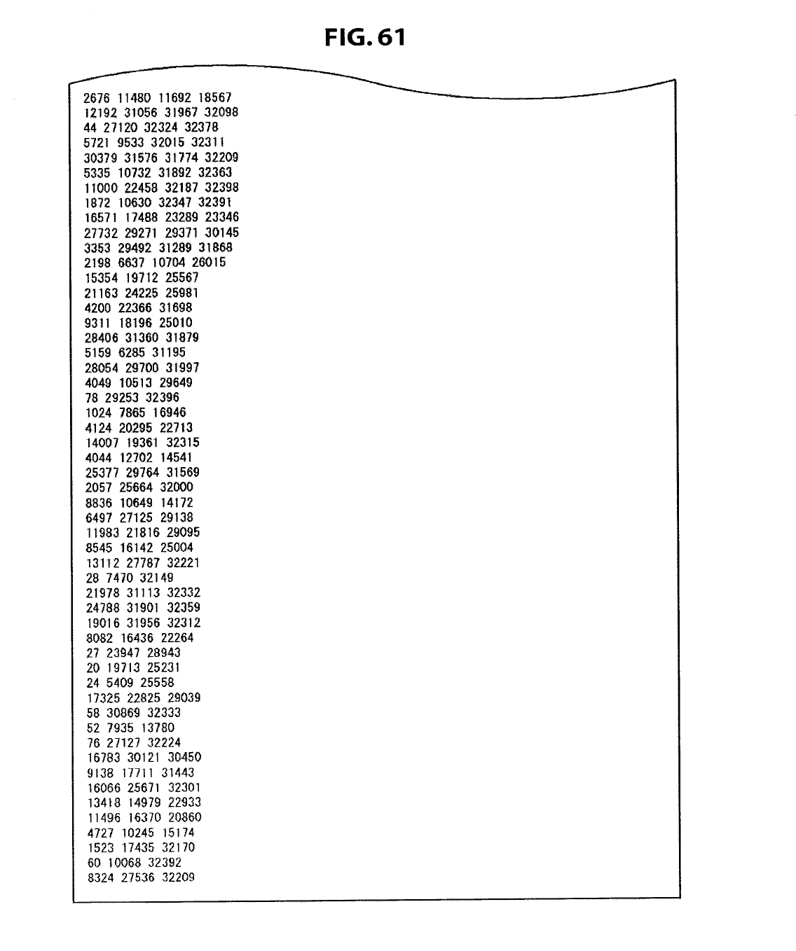

FIGS. 60 and 61 illustrate a parity check matrix initial value table with respect to the parity check matrix H of the LDPC code with a code length N of 64 k bits and an encoding rate of 15/30.

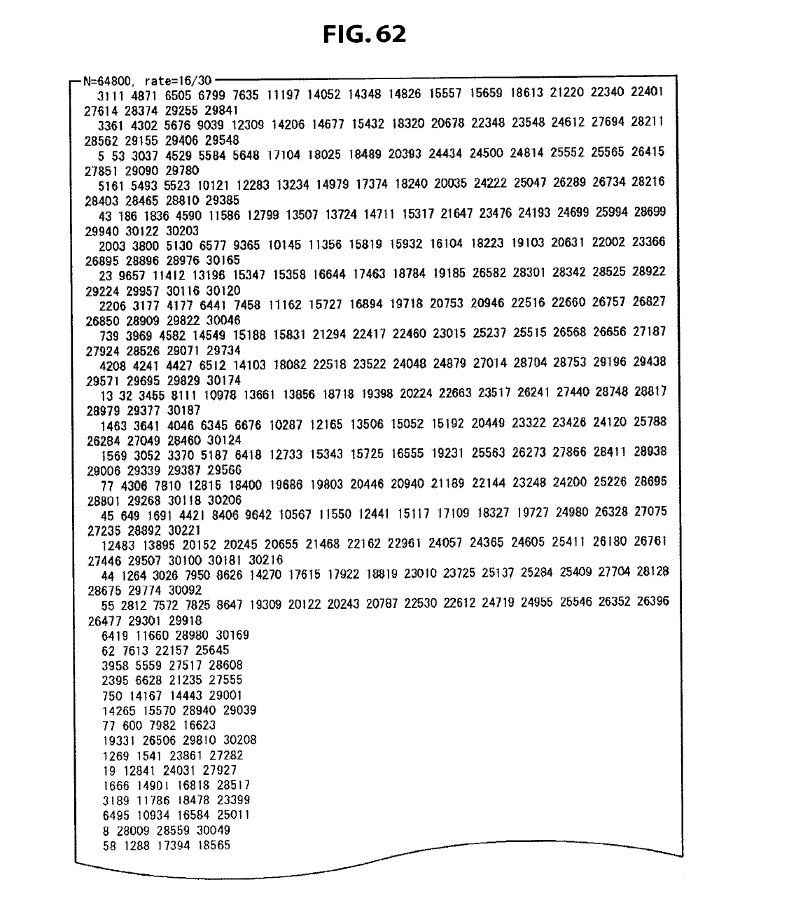

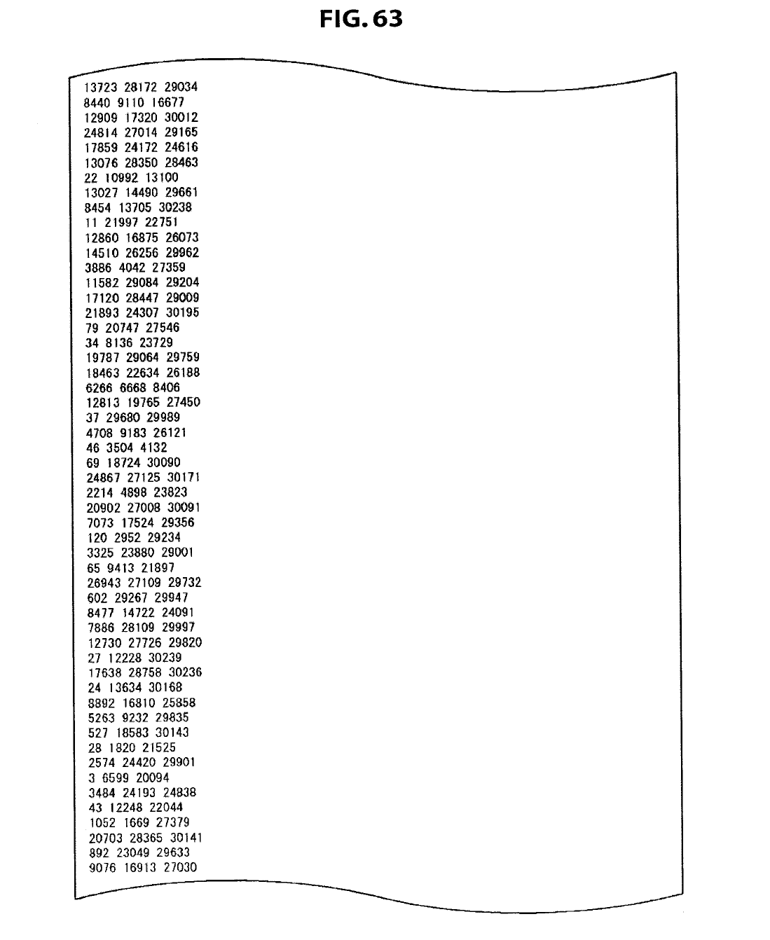

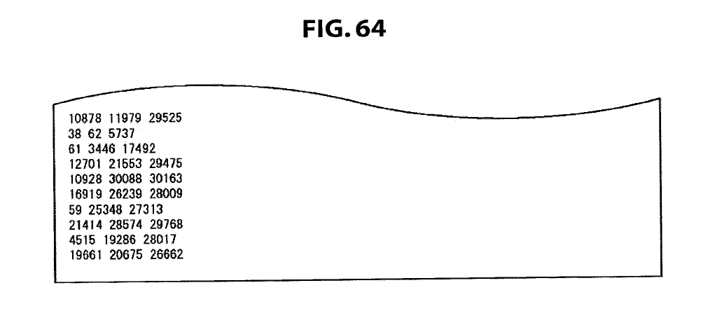

FIGS. 62, 63, and 64 illustrate a parity check matrix initial value table with respect to the parity check matrix H of the LDPC code with a code length N of 64 k bits and an encoding rate of 16/30.

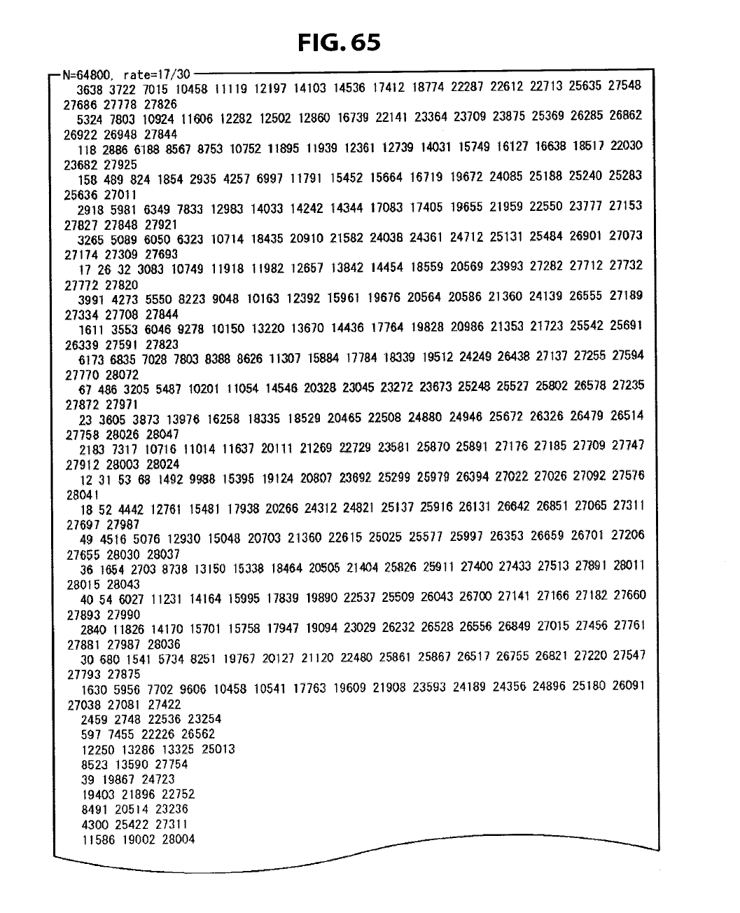

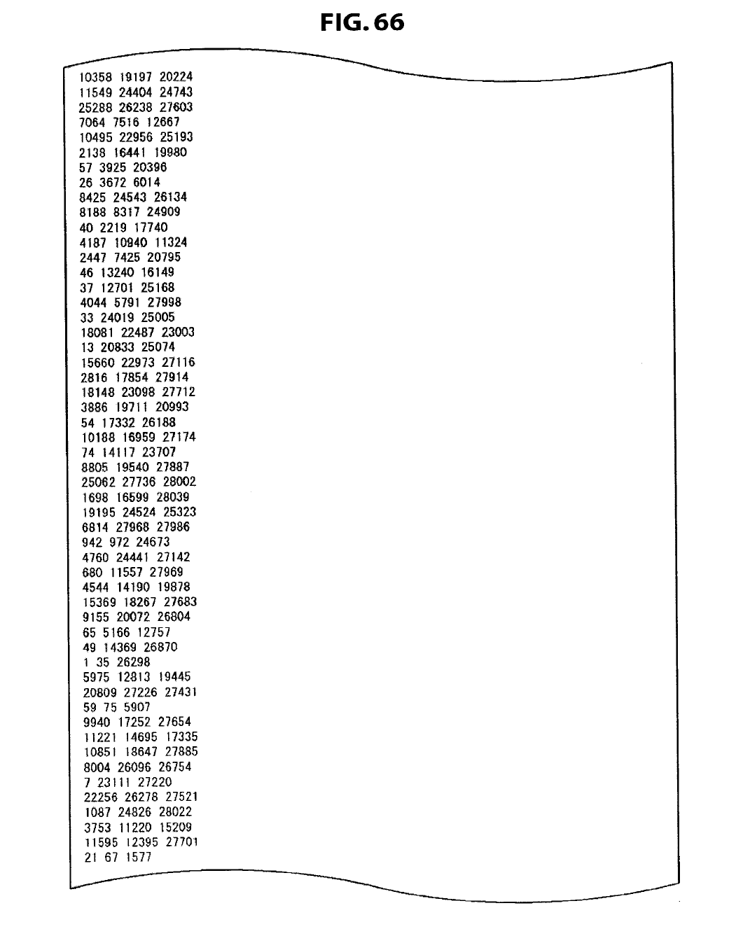

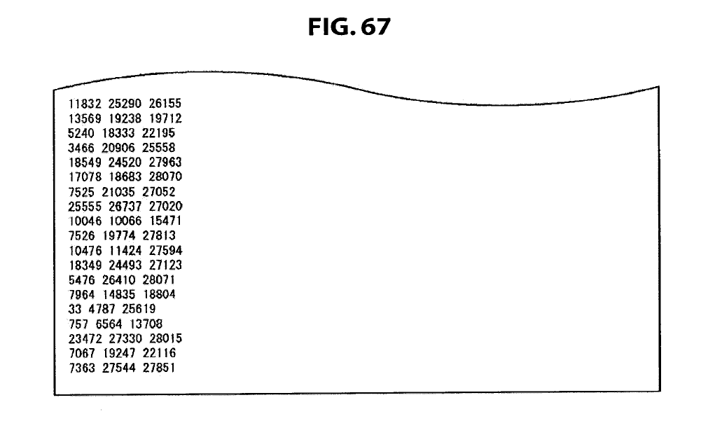

FIGS. 65, 66, and 67 illustrate a parity check matrix initial value table with respect to the parity check matrix H of the LDPC code with a code length N of 64 k bits and an encoding rate of 17/30.

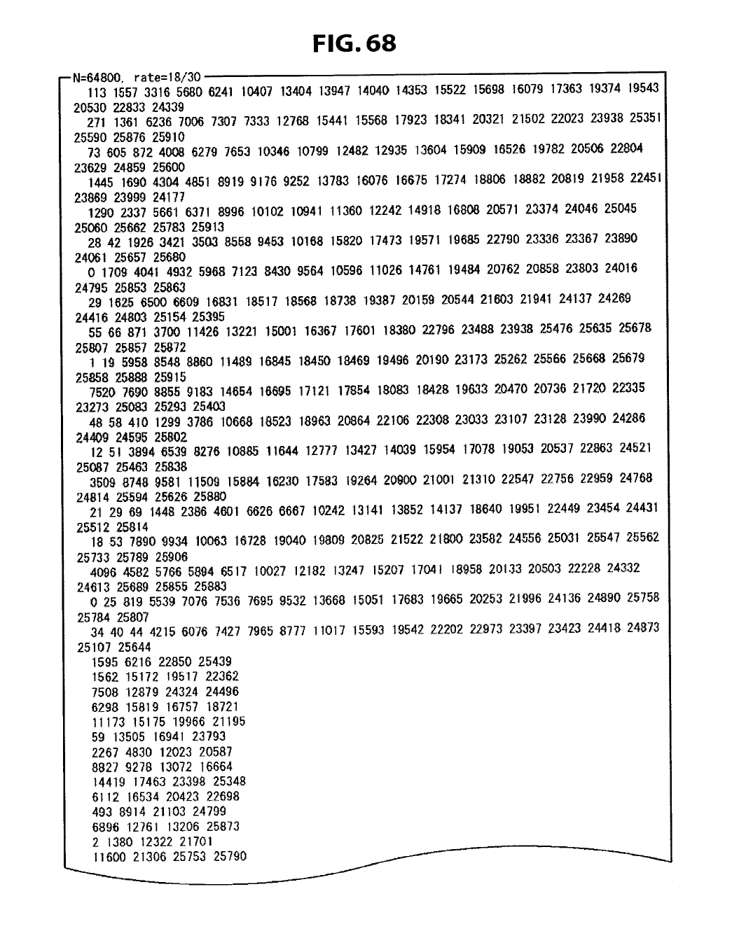

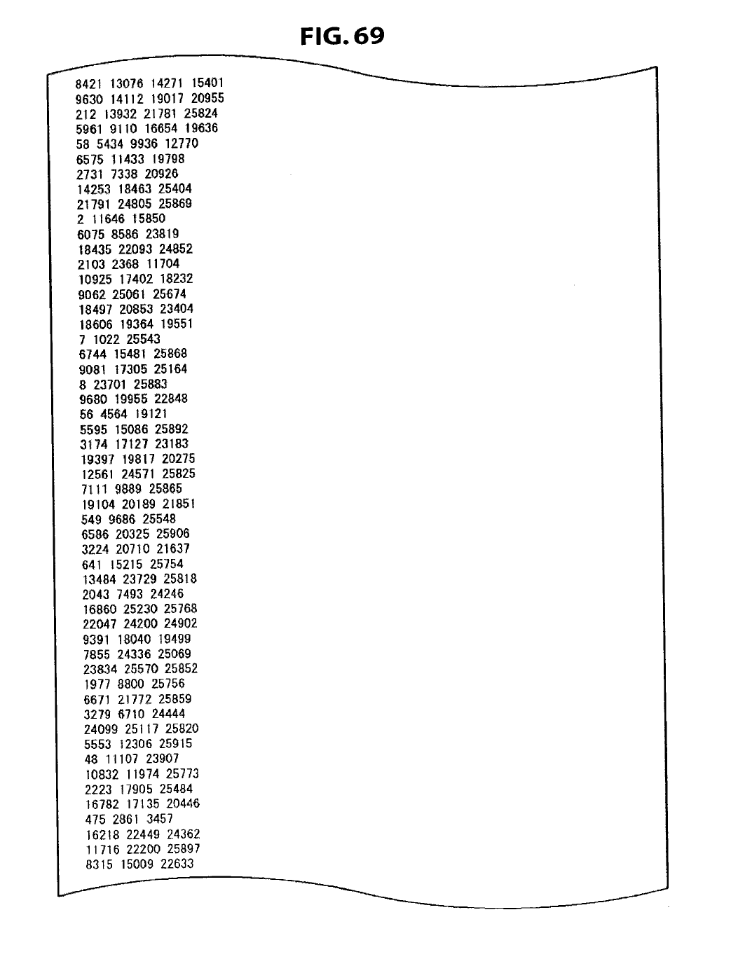

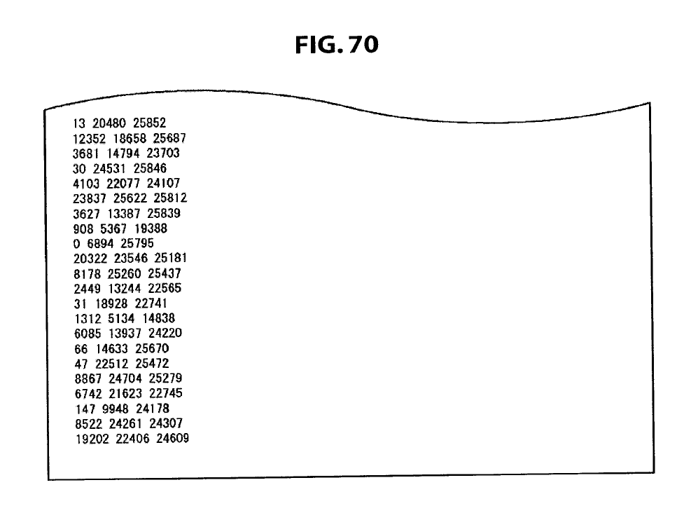

FIGS. 68, 69, and 70 illustrate a parity check matrix initial value table with respect to the parity check matrix H of the LDPC code with a code length N of 64 k bits and an encoding rate of 18/30.

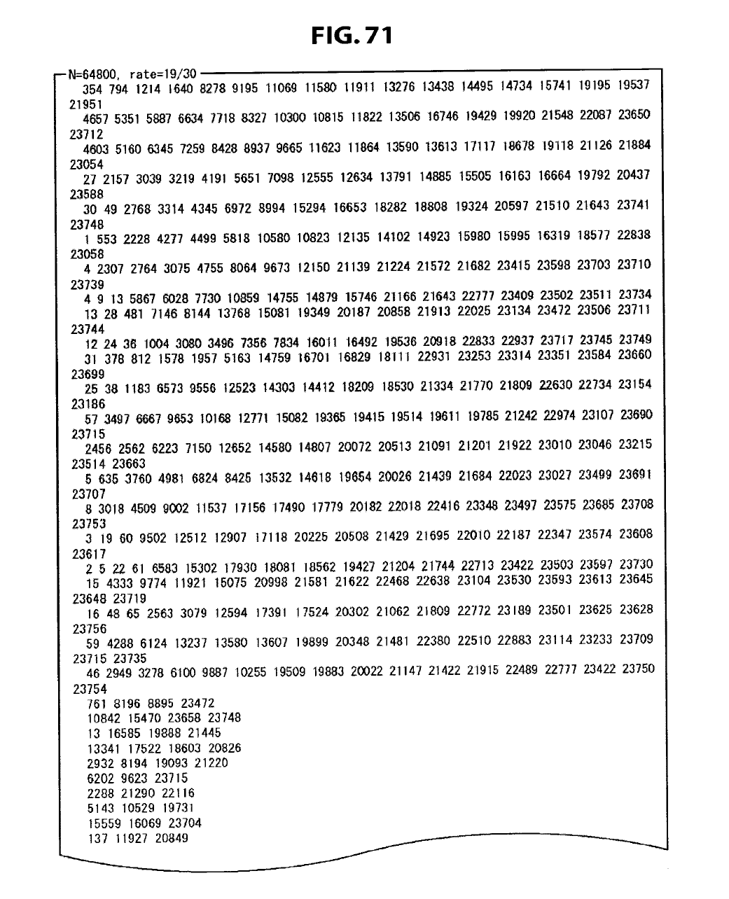

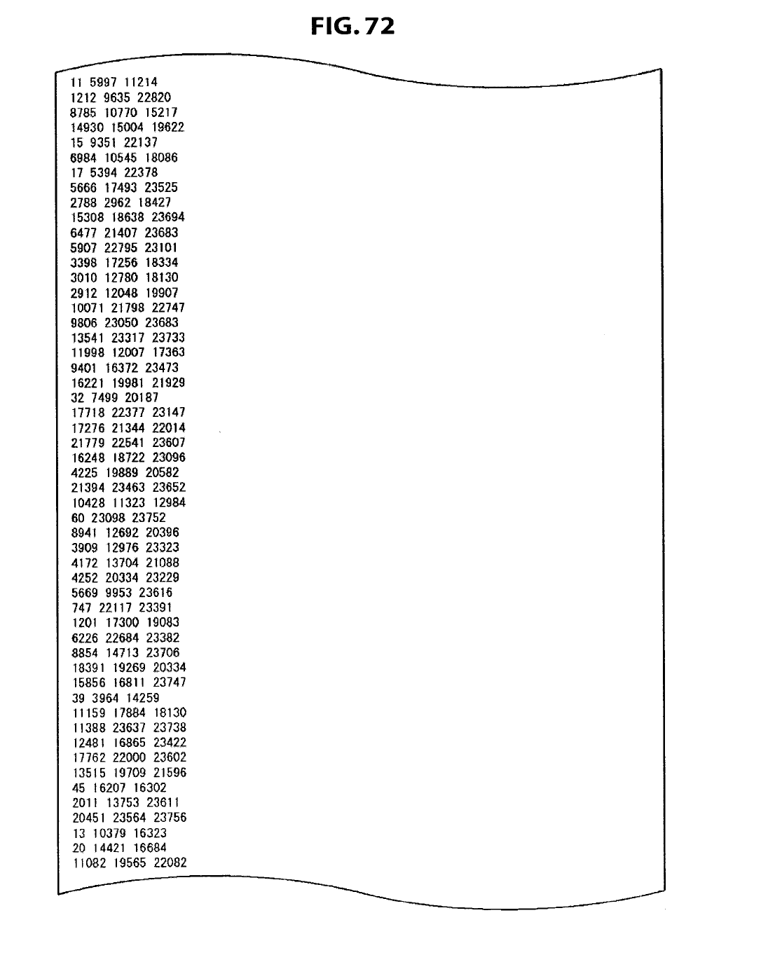

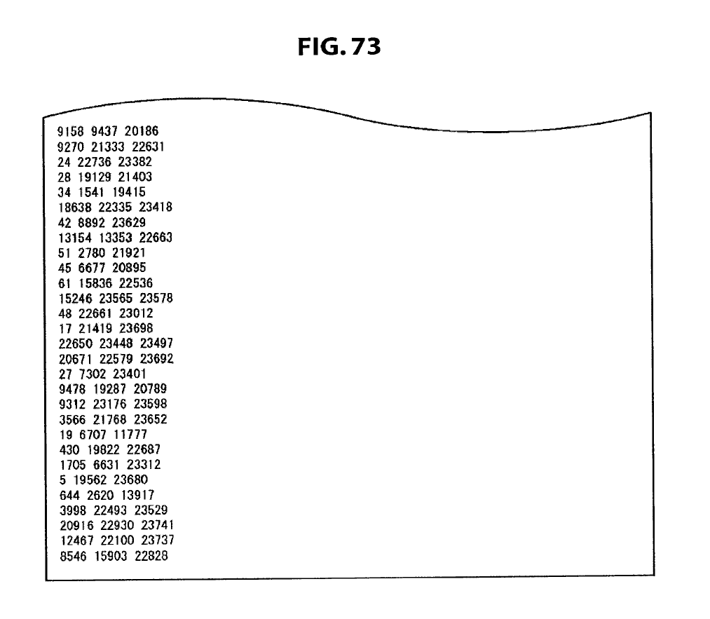

FIGS. 71, 72, and 73 illustrate a parity check matrix initial value table with respect to the parity check matrix H of the LDPC code with a code length N of 64 k bits and an encoding rate of 19/30.

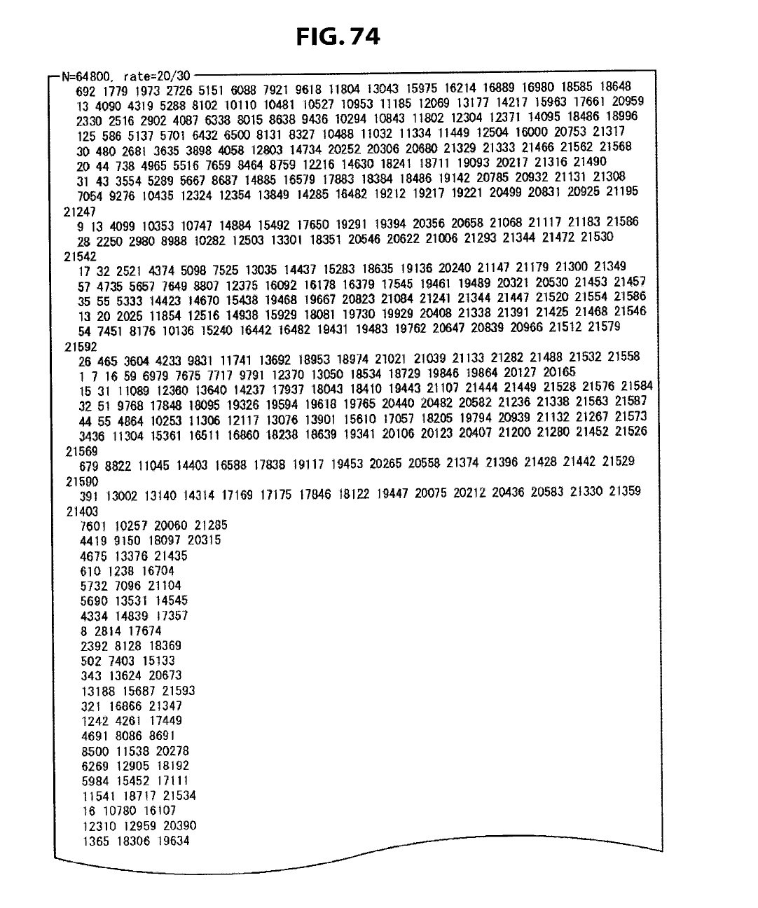

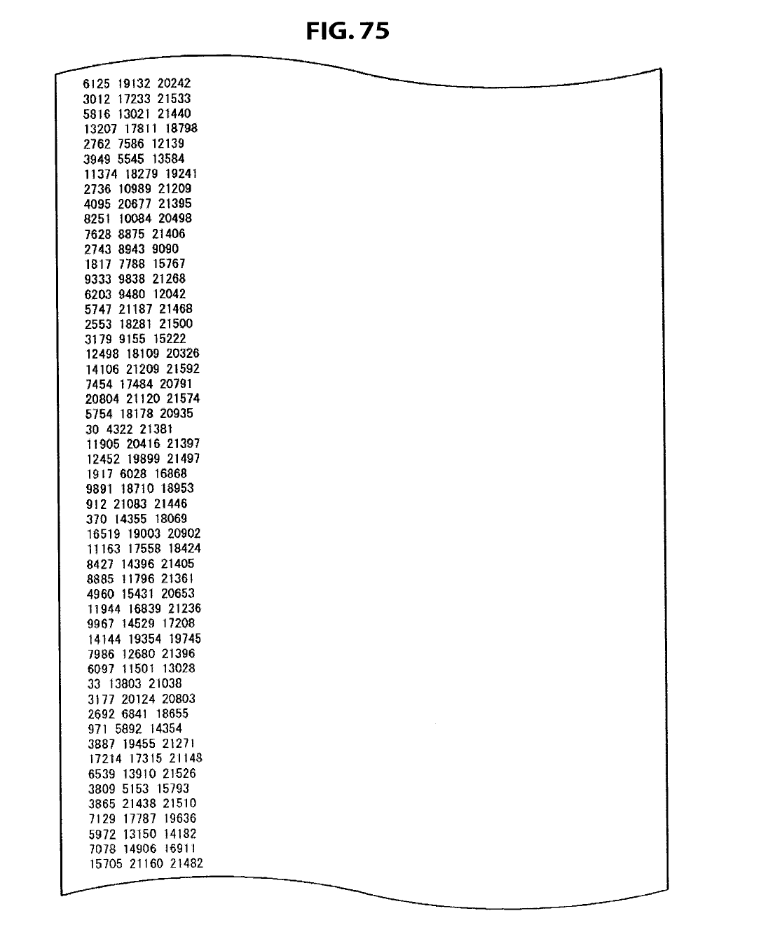

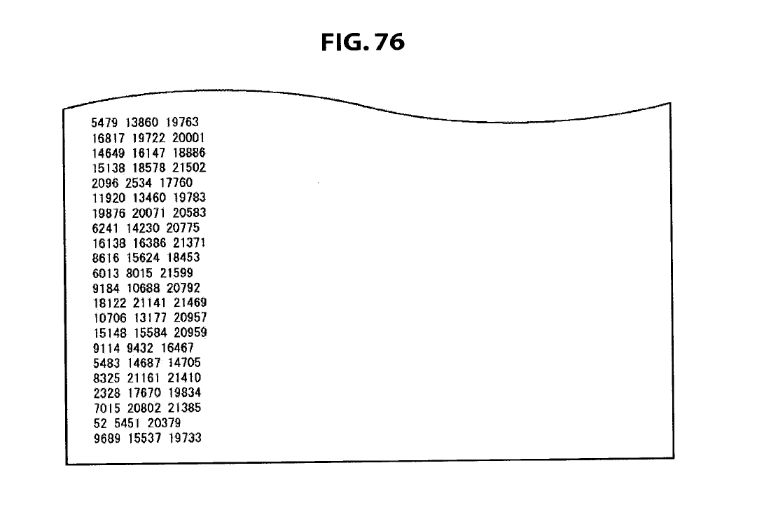

FIGS. 74, 75, and 76 illustrate a parity check matrix initial value table with respect to the parity check matrix H of the LDPC code with a code length N of 64 k bits and an encoding rate of 20/30.

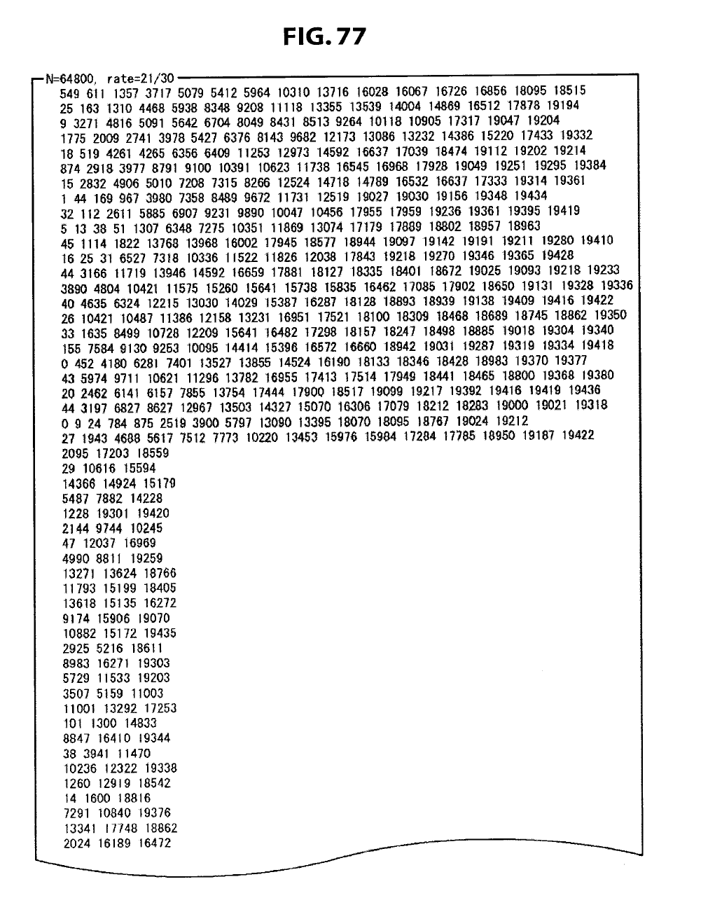

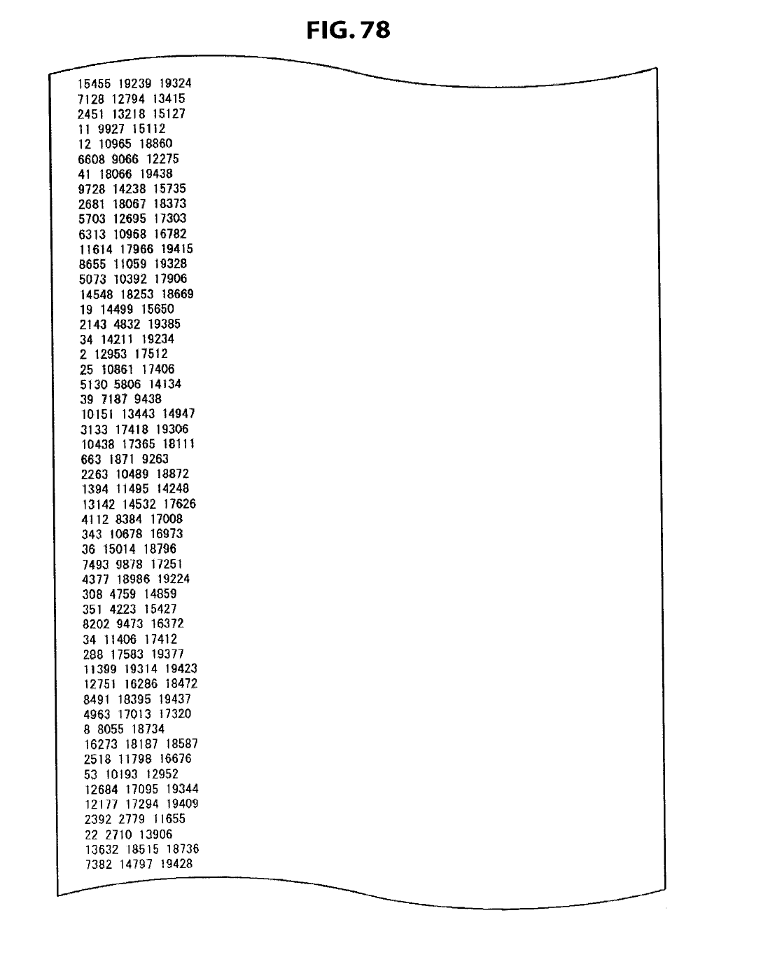

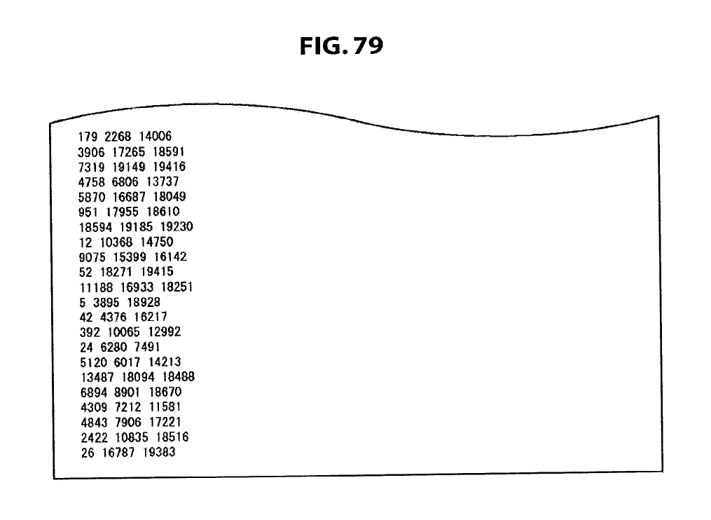

FIGS. 77, 78, and 79 illustrate a parity check matrix initial value table with respect to the parity check matrix H of the LDPC code with a code length N of 64 k bits and an encoding rate of 21/30.

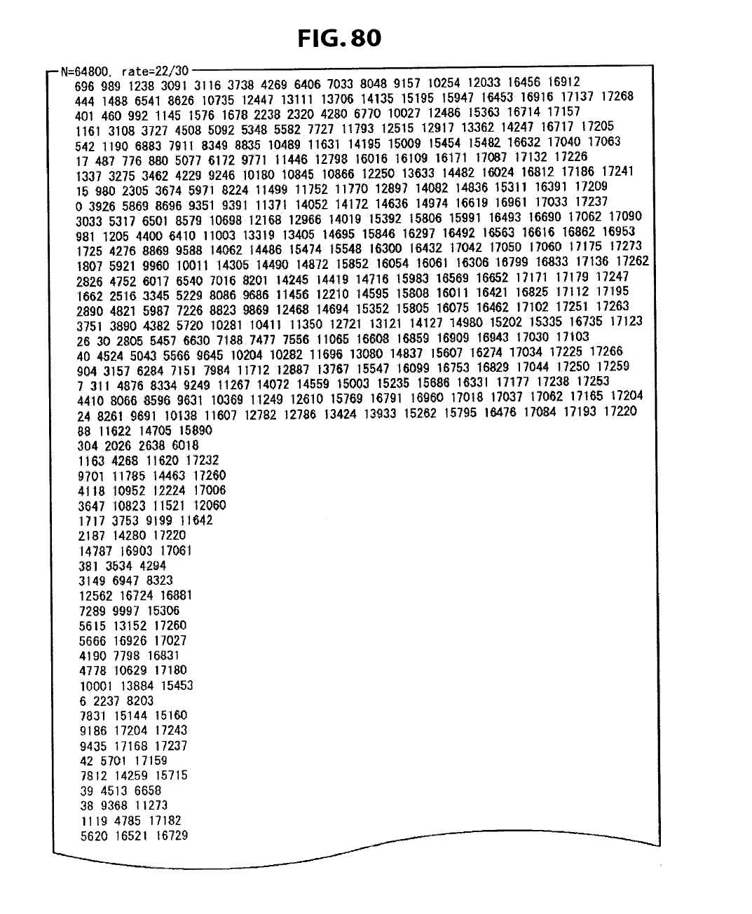

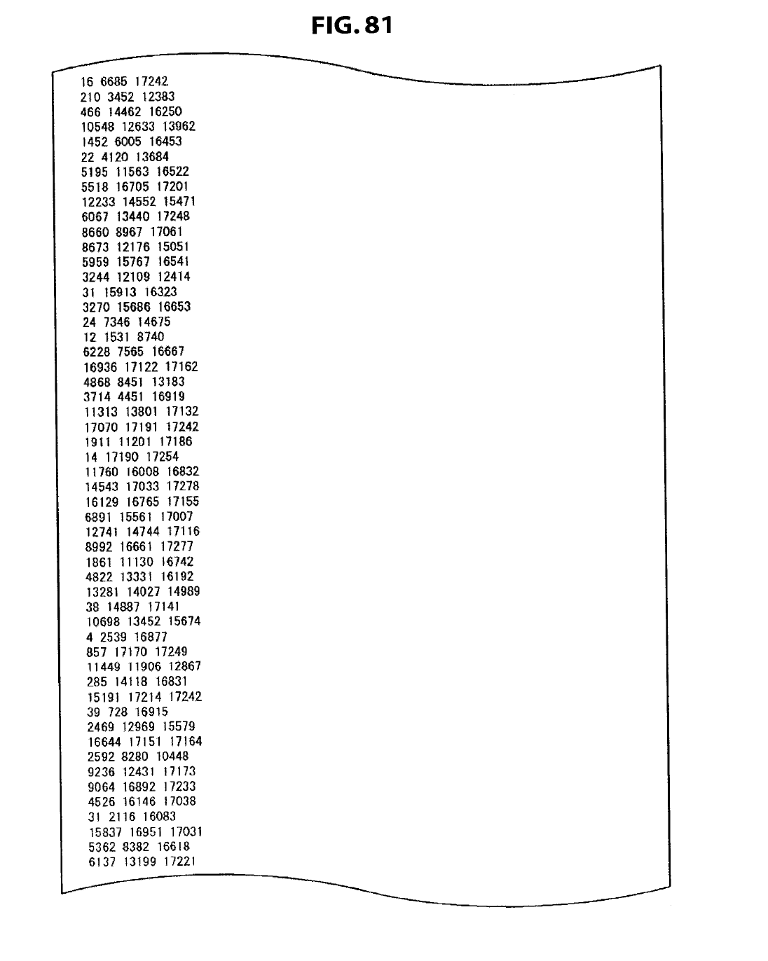

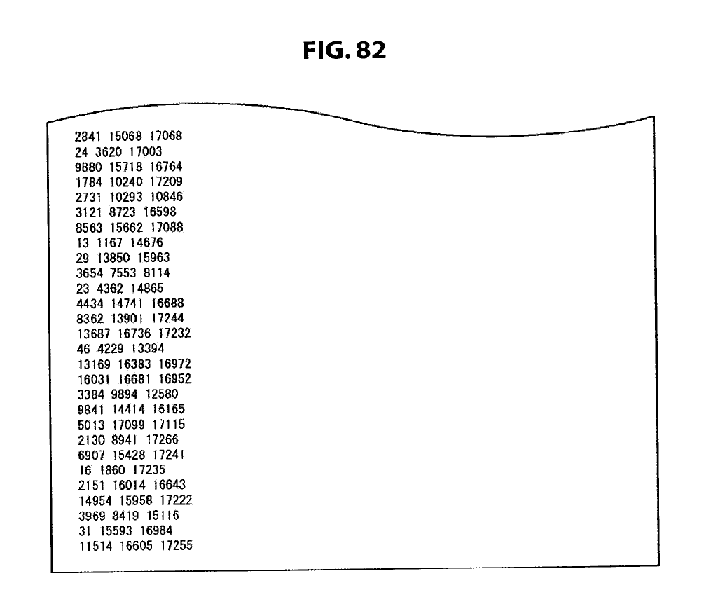

FIGS. 80, 81, and 82 illustrate a parity check matrix initial value table with respect to the parity check matrix H of the LDPC code with a code length N of 64 k bits and an encoding rate of 22/30.

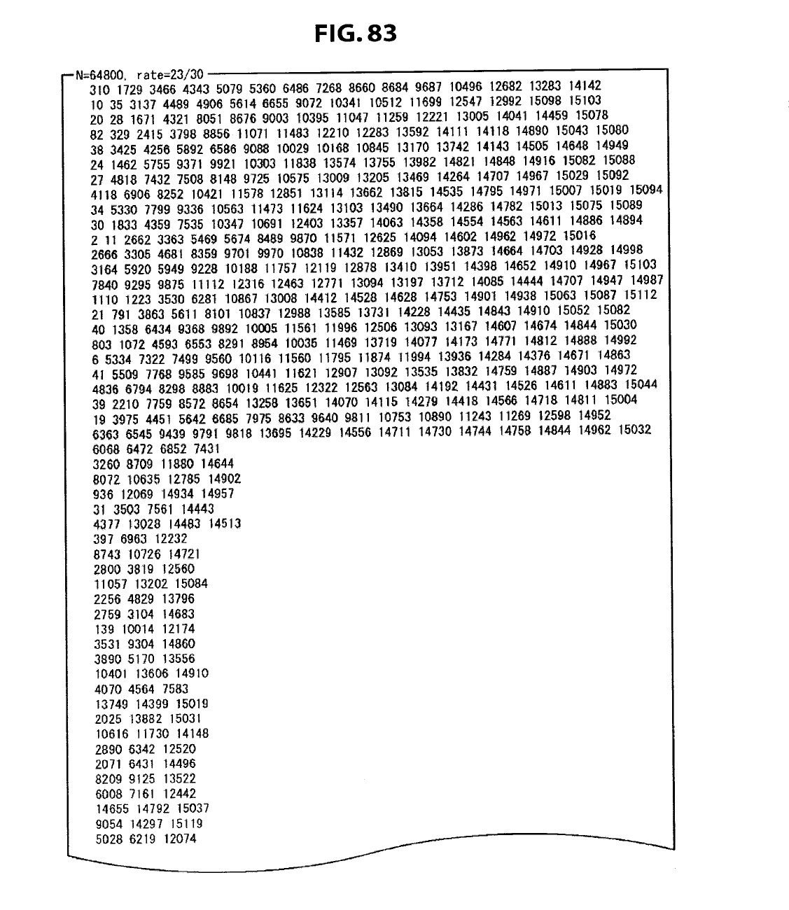

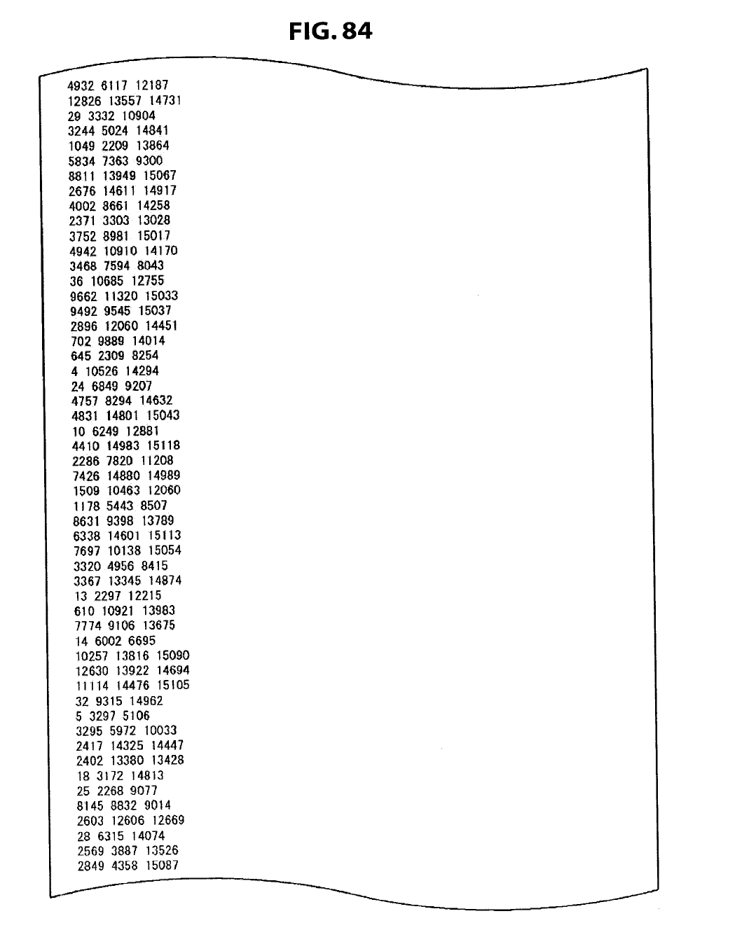

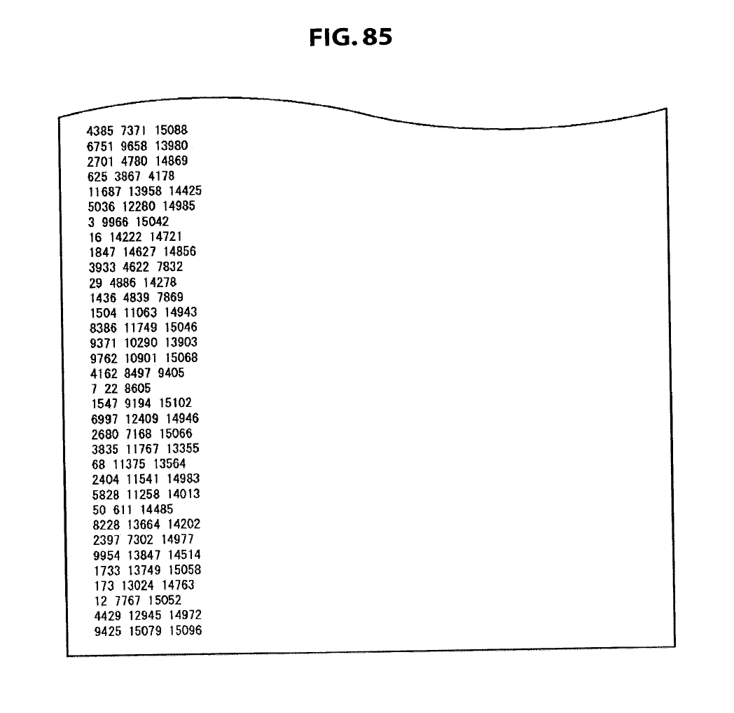

FIGS. 83, 84, and 85 illustrate a parity check matrix initial value table with respect to the parity check matrix H of the LDPC code with a code length N of 64 k bits and an encoding rate of 23/30.

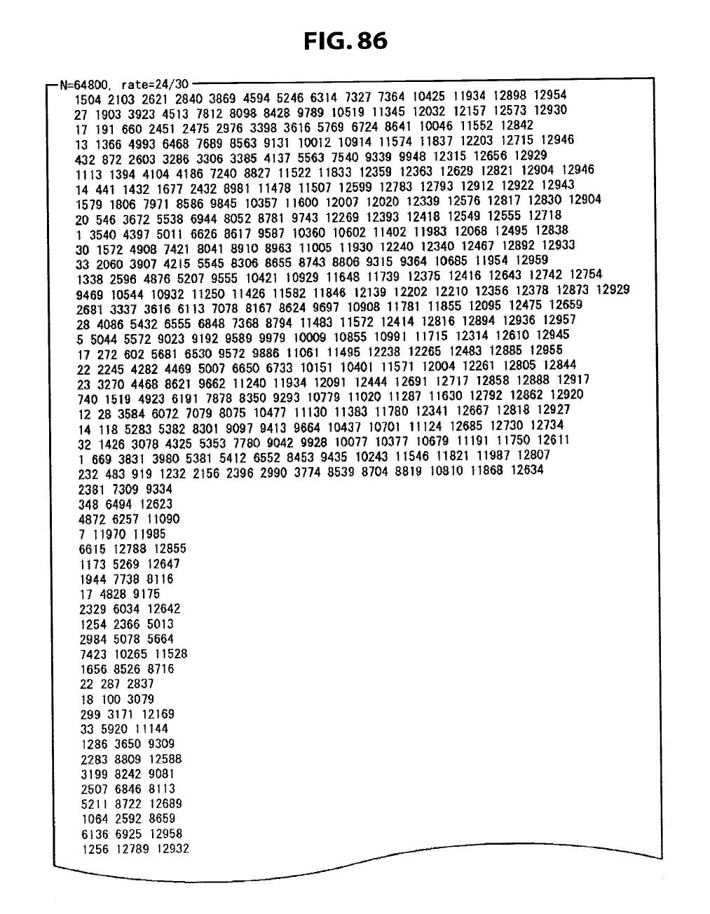

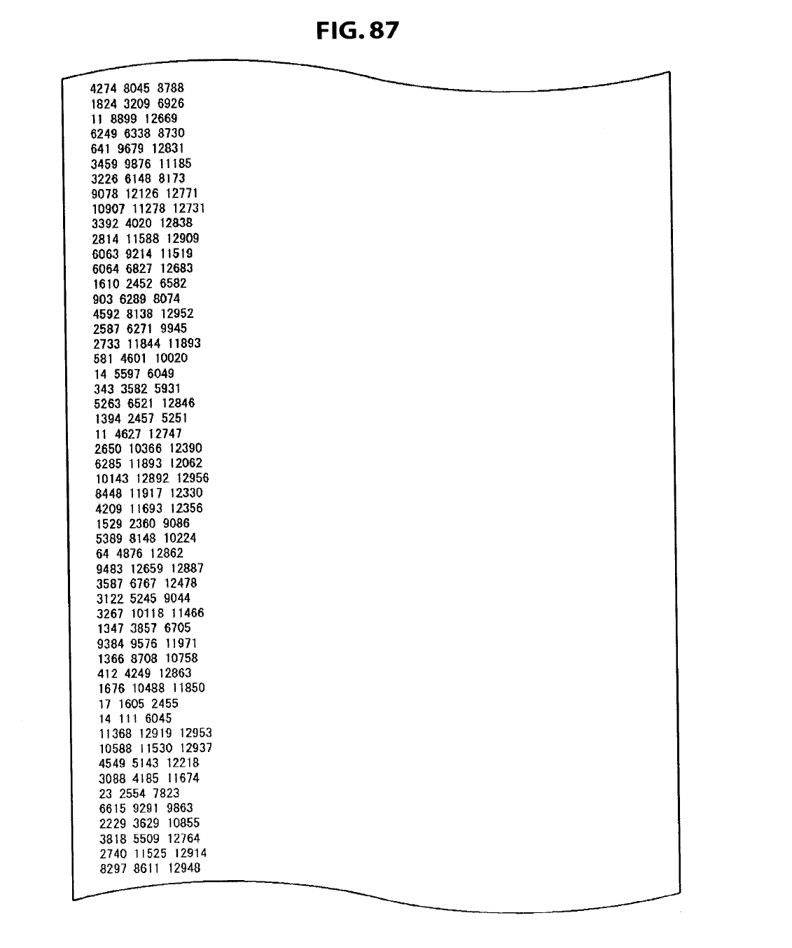

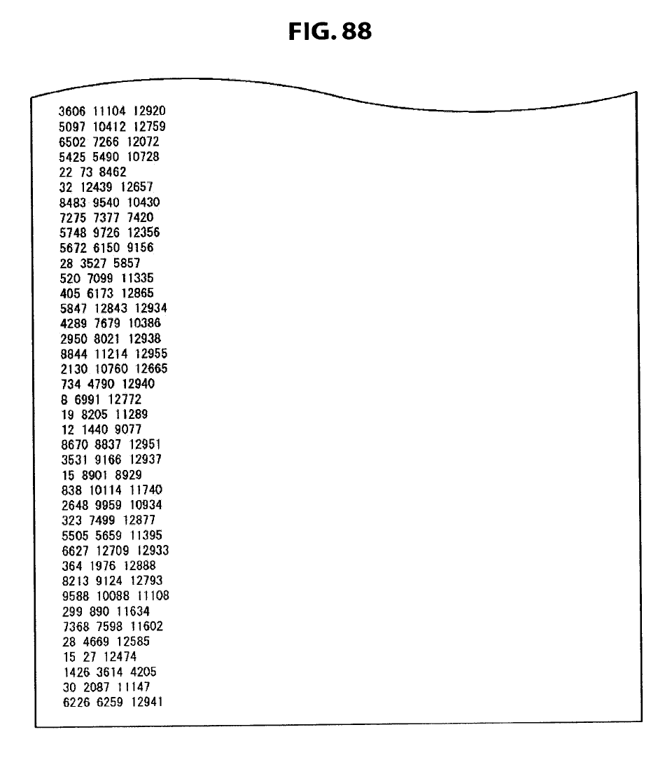

FIGS. 86, 87, and 88 illustrate a parity check matrix initial value table with respect to the parity check matrix H of the LDPC code with a code length N of 64 k bits and an encoding rate of 24/30.

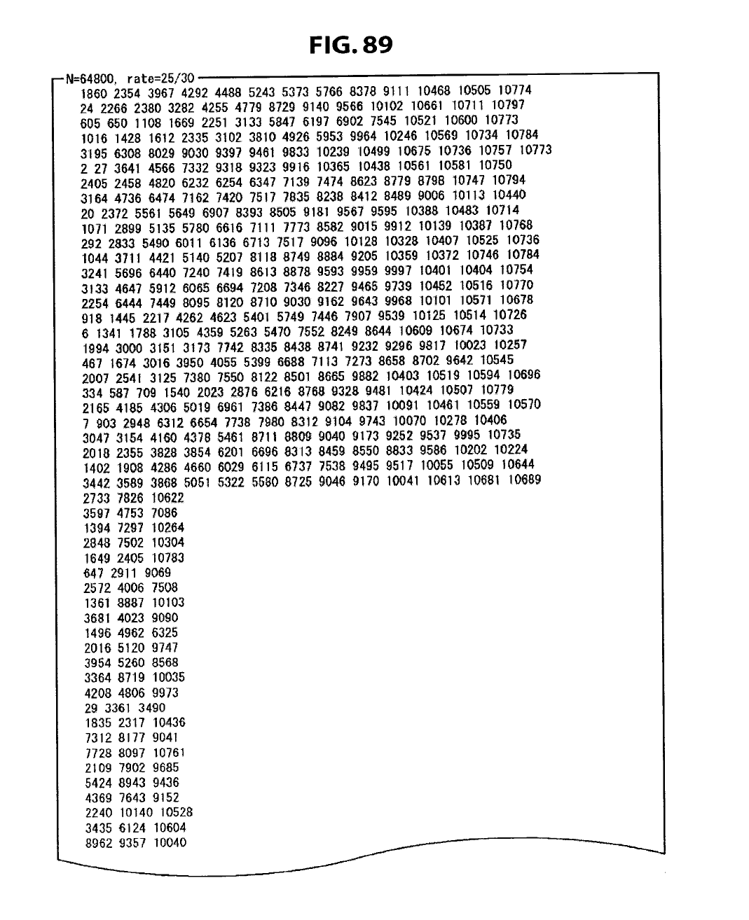

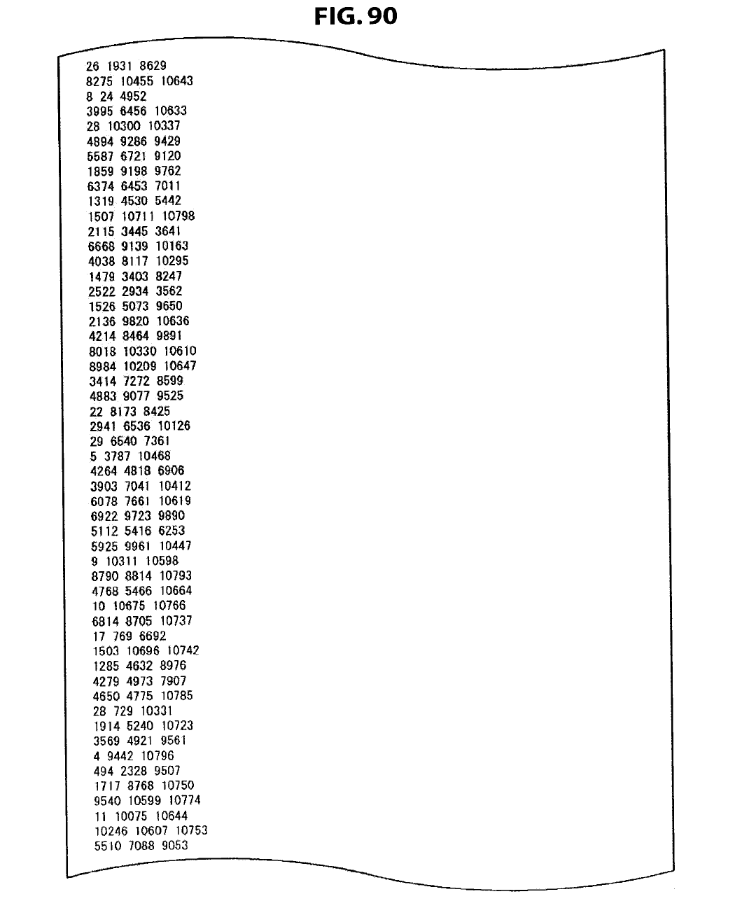

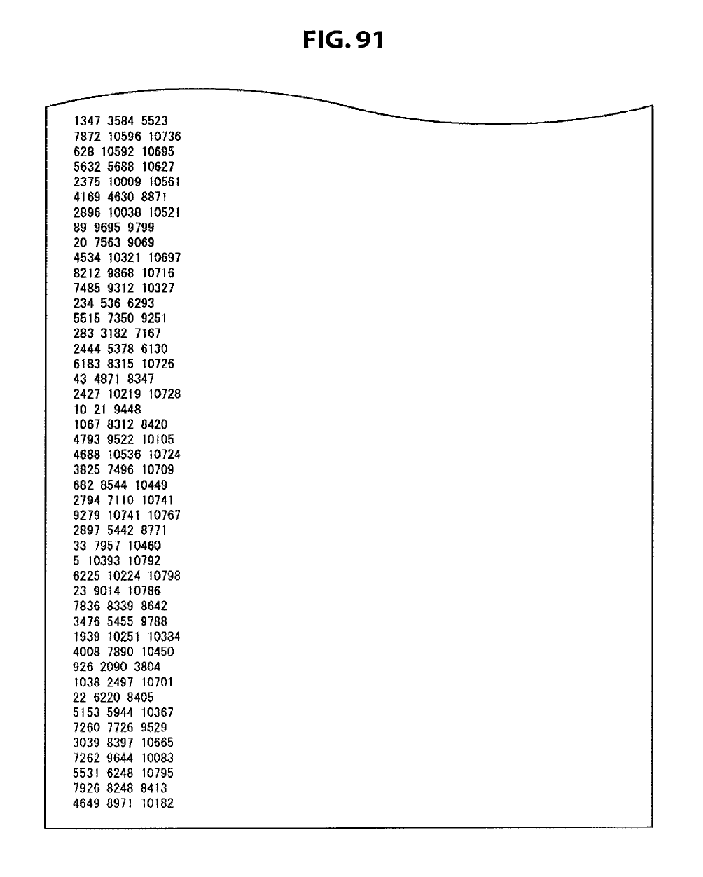

FIGS. 89, 90, and 91 illustrate a parity check matrix initial value table with respect to the parity check matrix H of the LDPC code with a code length N of 64 k bits and an encoding rate of 25/30.

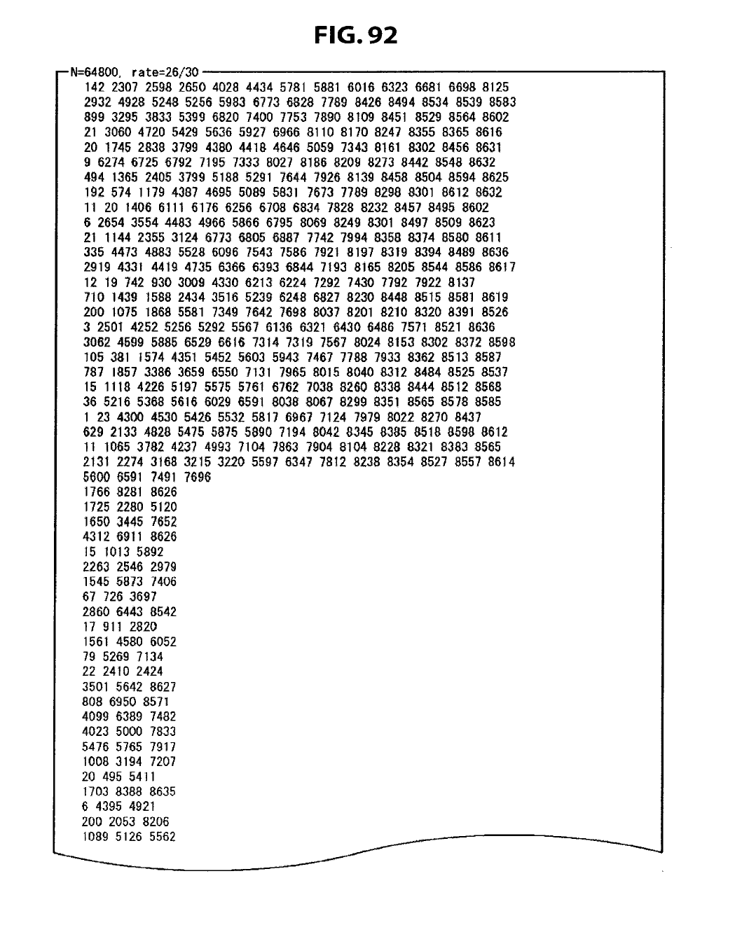

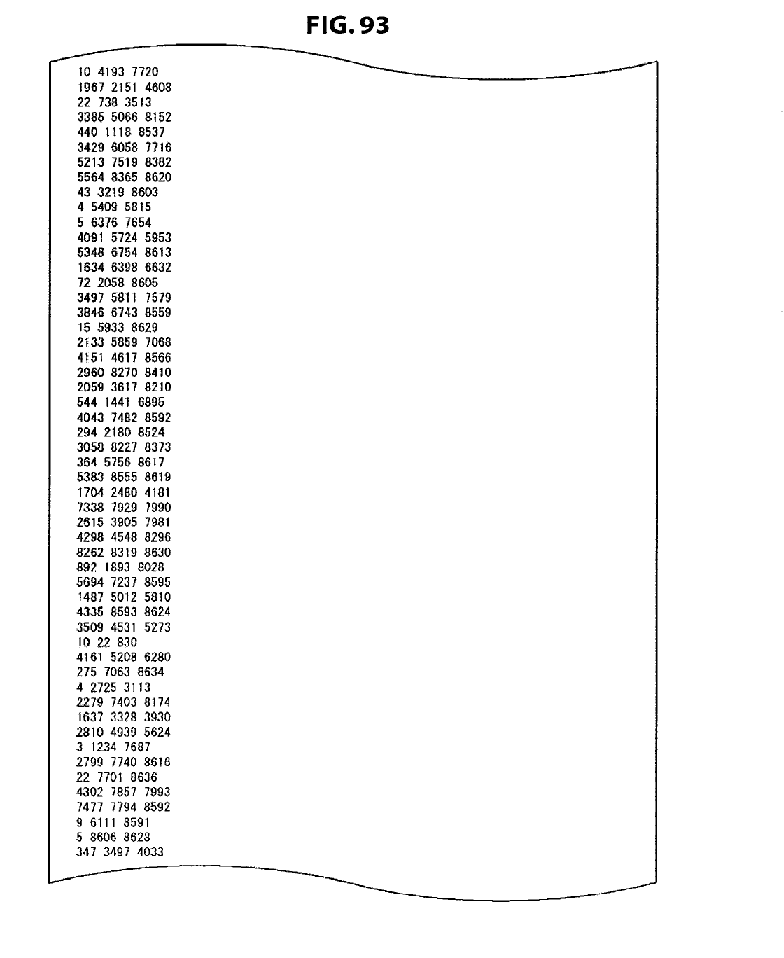

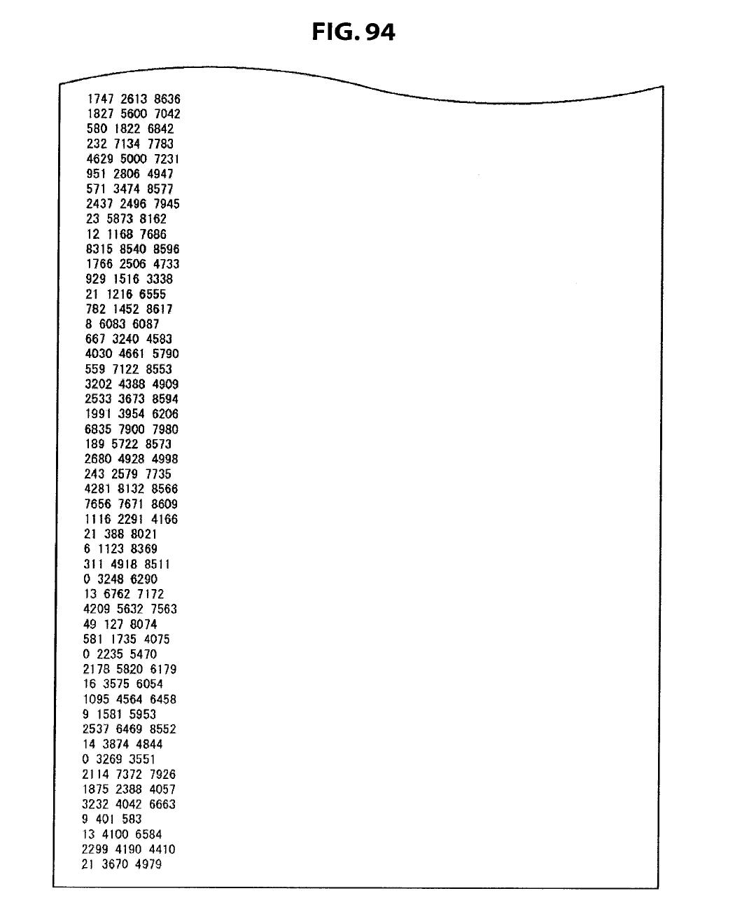

FIGS. 92, 93, and 94 illustrate a parity check matrix initial value table with respect to the parity check matrix H of the LDPC code with a code length N of 64 k bits and an encoding rate of 26/30.

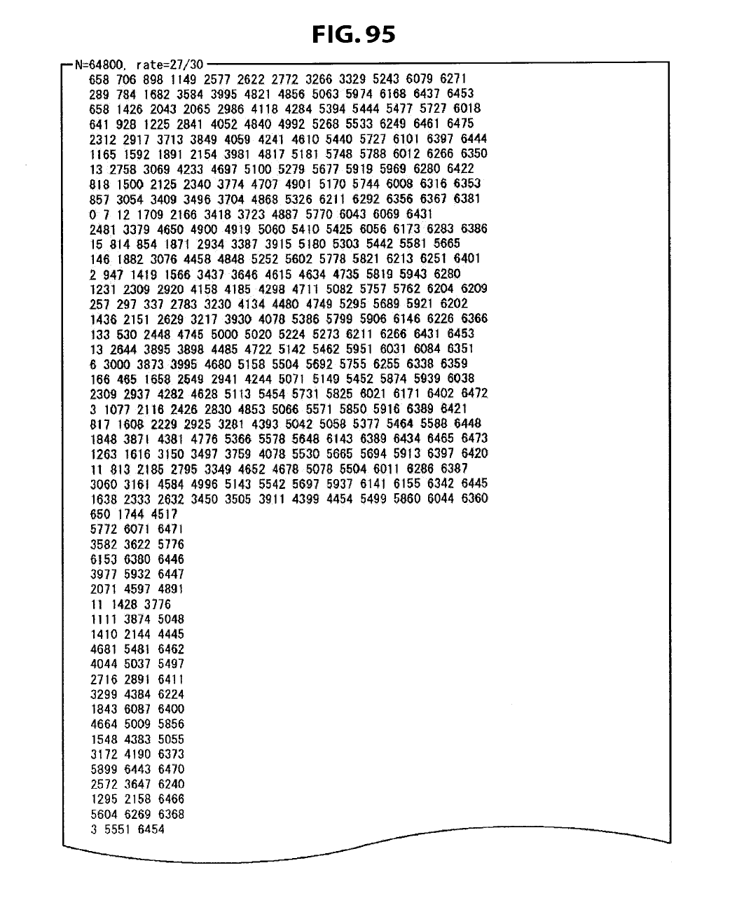

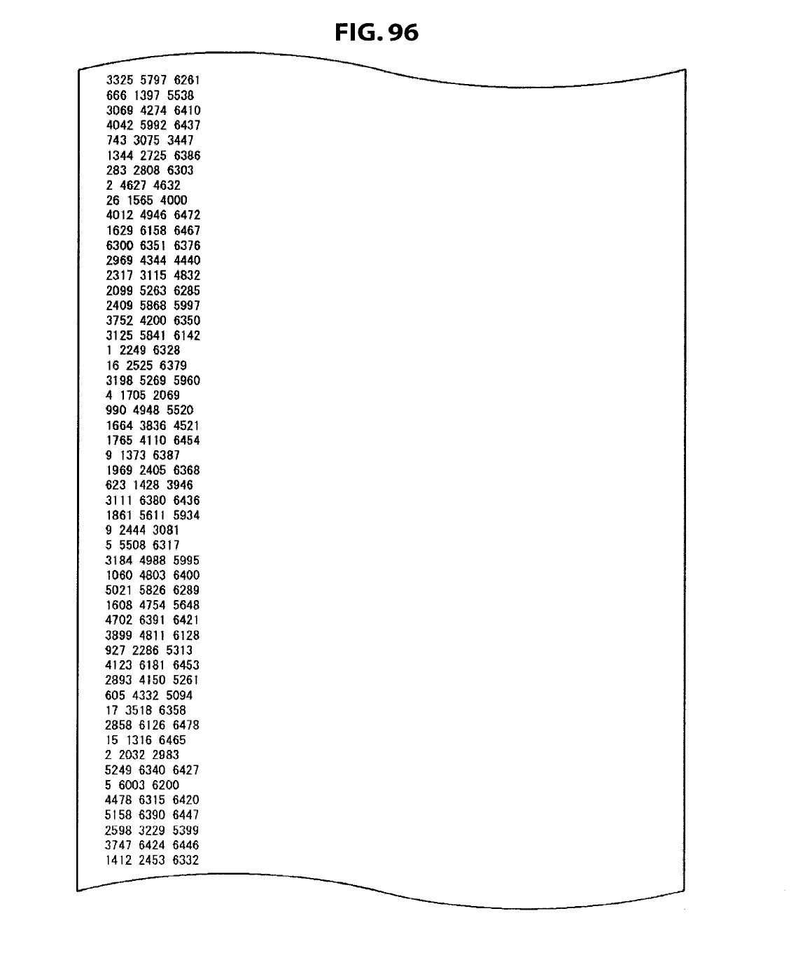

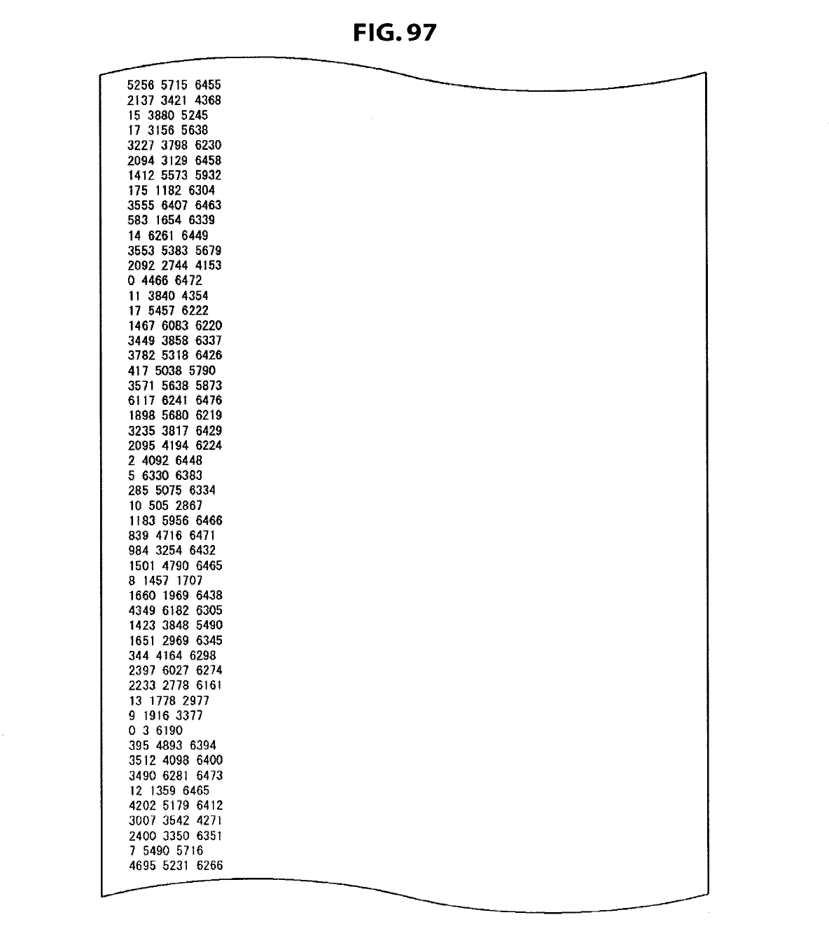

FIGS. 95, 96, and 97 illustrate a parity check matrix initial value table with respect to the parity check matrix H of the LDPC code with a code length N of 64 k bits and an encoding rate of 27/30.

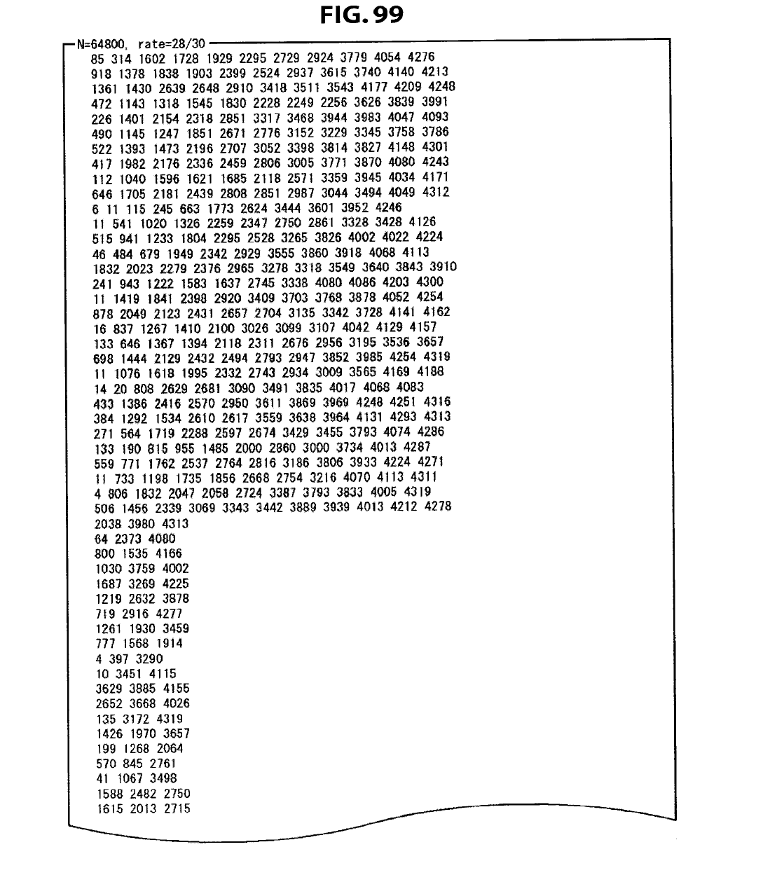

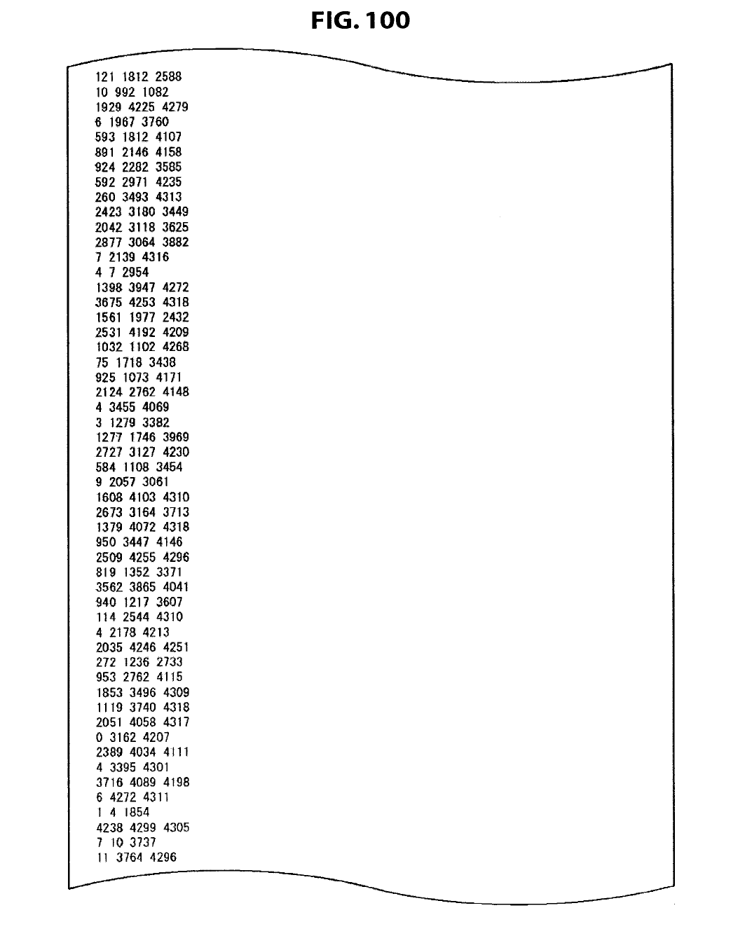

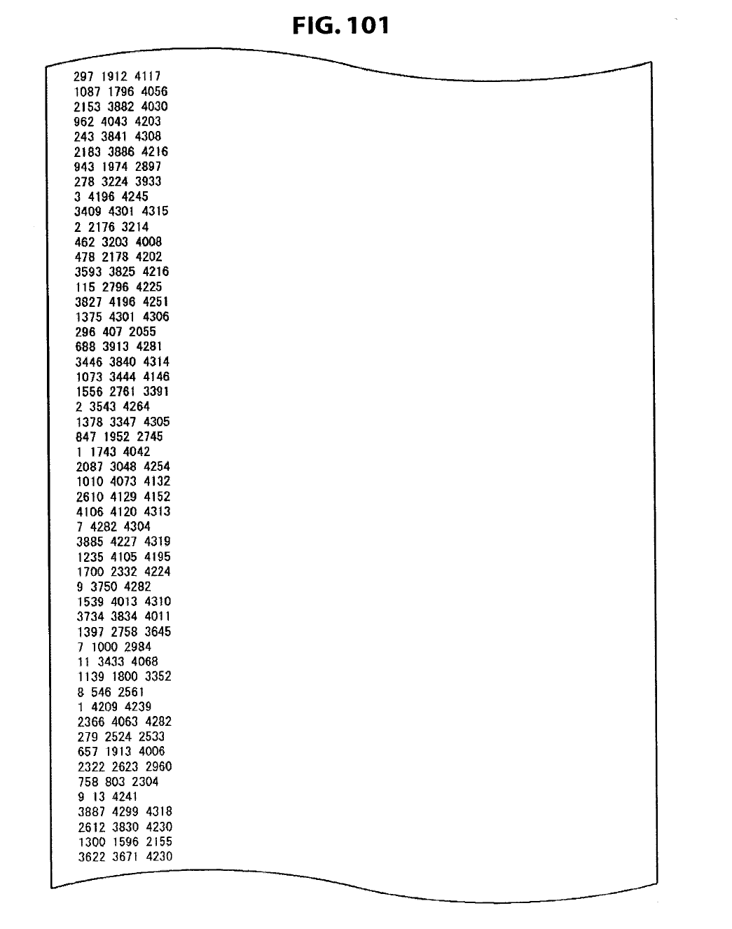

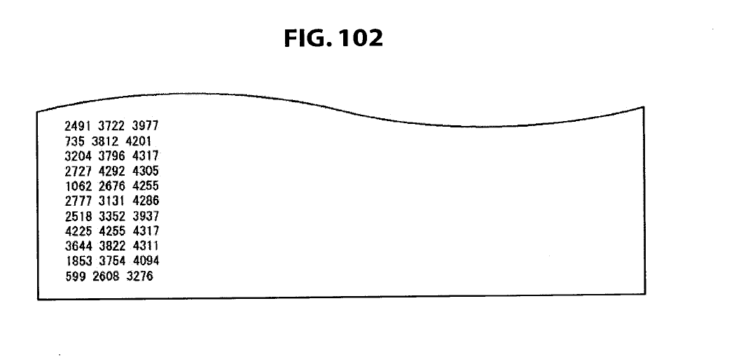

FIGS. 99, 100, 101, and 102 illustrate a parity check matrix initial value table with respect to the parity check matrix H of the LDPC code with a code length N of 64 k bits and an encoding rate of 28/30.

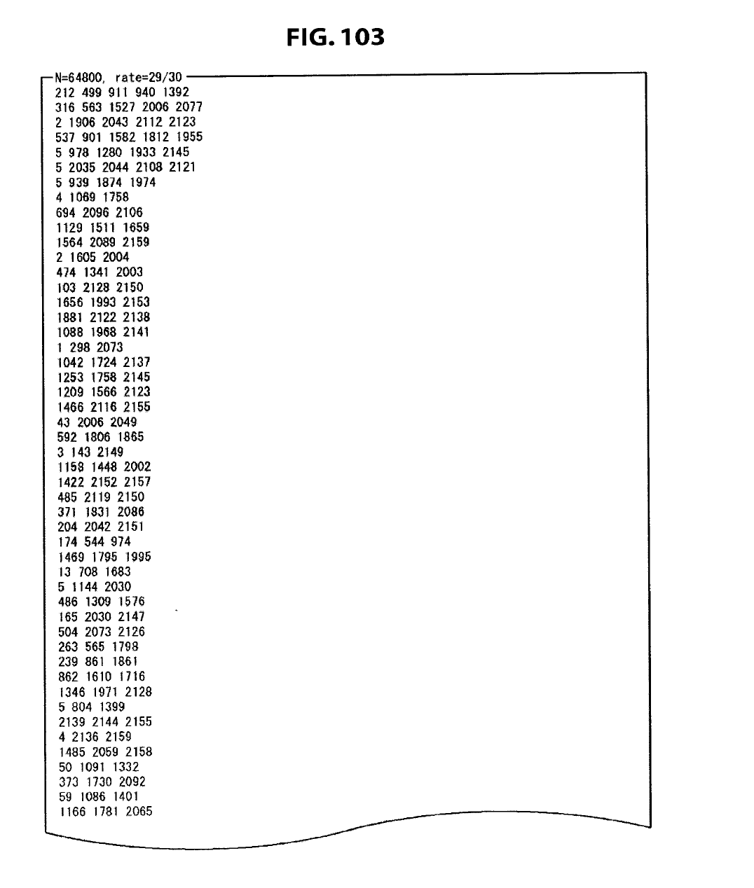

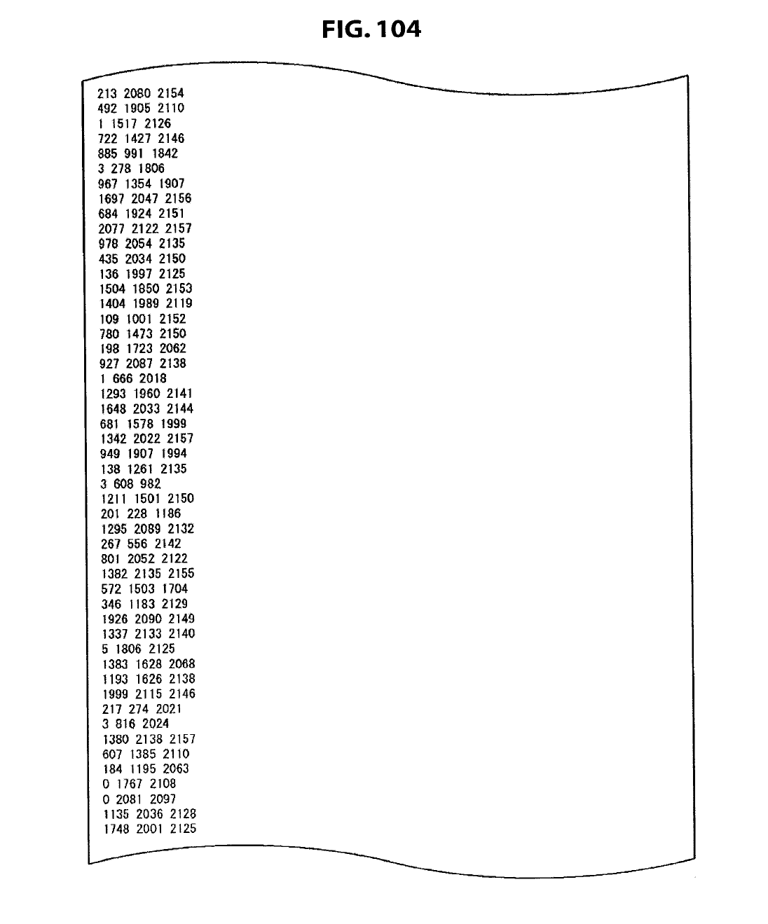

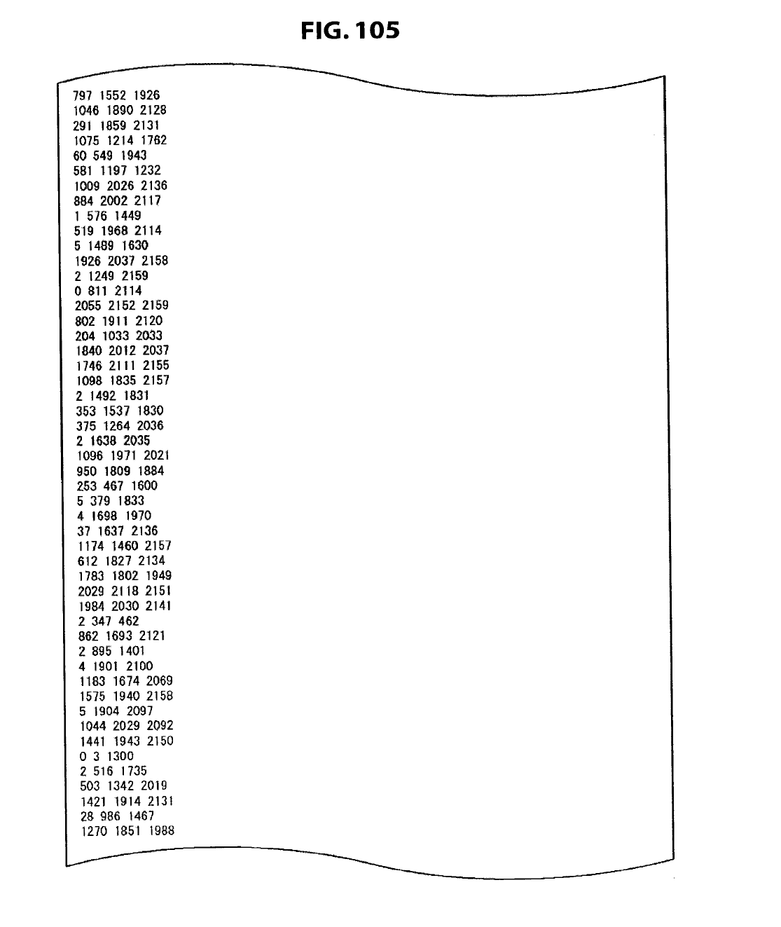

FIGS. 103, 104, 105, and 106 illustrate a parity check matrix initial value table with respect to the parity check matrix H of the LDPC code with a code length N of 64 k bits and an encoding rate of 29/30.

The LDPC encoder 115 (FIG. 8 and FIG. 35) can perform encoding into any (new) LDPC code with a code length N of 64 k among 28 kinds of encoding rates r of 2/30 to 29/30, by the use of the parity check matrix H found from the parity check matrix initial value tables illustrated in FIG. 40 to FIG. 106.

In this case, the parity check matrix initial value tables illustrated in FIG. 40 to FIG. 106 are stored in the storage unit 602 of the LDPC encoder 115 (FIG. 8).

Here, all of LDPC codes with 28 kinds of encoding rates r of 2/30 to 29/30 (found from the parity check matrix initial value tables) in FIG. 40 to FIG. 106 do not have to be necessarily adopted as a new LDPC. That is, as for the LDPC codes with 28 kinds of encoding rates r of 2/30 to 29/30 in FIG. 40 to FIG. 106, LDPC codes of one or more arbitrary encoding rates among them can be adopted as a new LDPC code.

An LDPC code obtained by the use of the parity check matrix H found from the parity check matrix initial value tables in FIG. 40 to FIG. 106 is an LDPC code of good performance.

Here, the LDPC code of good performance is an LDPC code obtained from an appropriate parity check matrix H.

Moreover, the appropriate parity check matrix H is a parity check matrix that satisfies a predetermined condition to make BER (and FER) smaller when an LDPC code obtained from the parity check matrix H is transmitted at low Eₛ/N₀ or E_{b}/Nₒ (signal-to-noise power ratio per bit).

For example, the appropriate parity check matrix H can be found by performing simulation to measure BER when LDPC codes obtained from various parity check matrices that satisfy a predetermined condition are transmitted at low Eₛ/Nₒ.

As a predetermined condition to be satisfied by the appropriate parity check matrix H, for example, an analysis result obtained by a code performance analysis method called density evolution (Density Evolution) is excellent, and a loop of elements of 1 does not exist, which is called cycle 4, and so on.

Here, in the information matrix H_{A}, it is known that the decoding performance of LDPC code is deteriorated when elements of 1 are dense like cycle 4, and therefore it is requested that cycle 4 does not exist, as a predetermined condition to be satisfied by the appropriate parity check matrix H.

Here, the predetermined condition to be satisfied by the appropriate parity check matrix H can be arbitrarily determined from the viewpoint of the improvement in the decoding performance of LDPC code and the facilitation (simplification) of decoding processing of LDPC code, and so on.

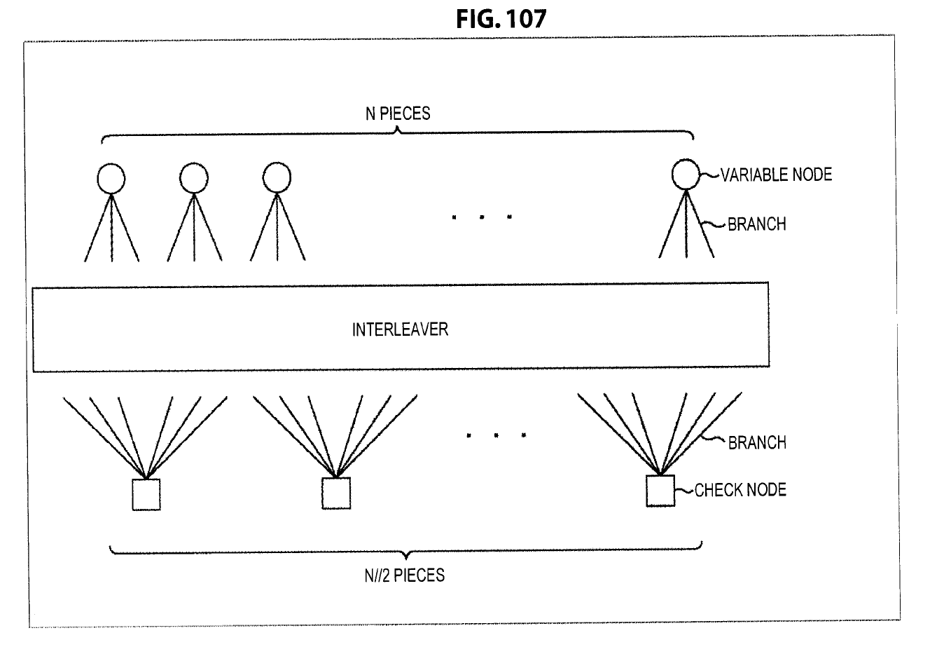

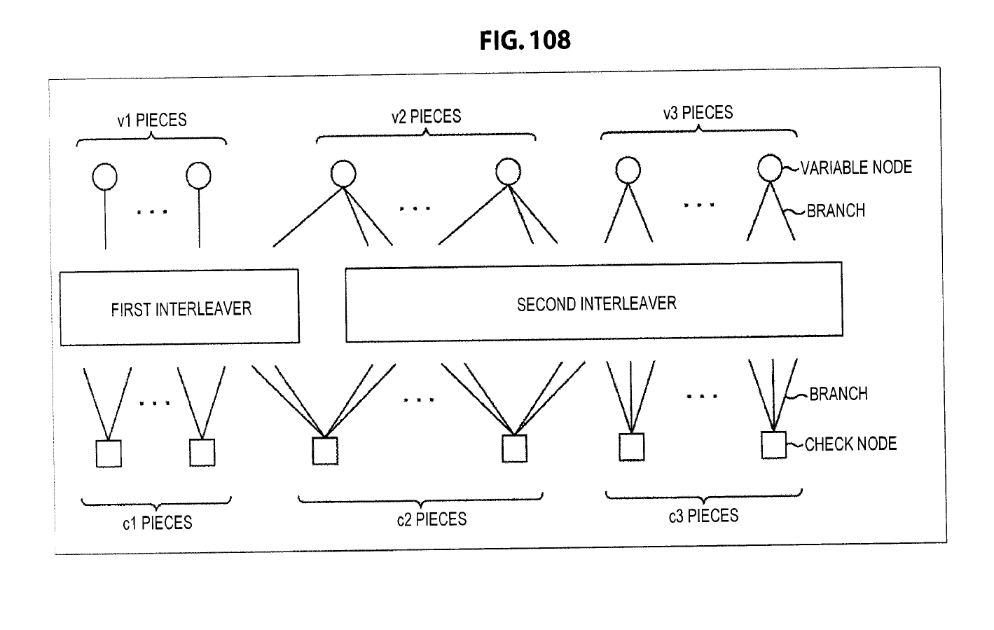

FIG. 107 and FIG. 108 are diagrams to describe the density evolution that can obtain an analytical result as a predetermined condition to be satisfied by the appropriate parity check matrix H.

The density evolution is a code analysis method that calculates the expectation value of the error probability of the entire LDPC code (ensemble) with a code length N of ∞ characterized by a degree sequence described later.

For example, when the dispersion value of noise is gradually increased from 0 on the AWGN channel, the expectation value of the error probability of a certain ensemble is 0 first, but, when the dispersion value of noise becomes equal to or greater than a certain threshold, it is not 0.

According to the density evolution, by comparison of the threshold of the dispersion value of noise (which may also be called a performance threshold) in which the expectation value of the error probability is not 0, it is possible to decide the quality of ensemble performance (appropriateness of the parity check matrix).

Here, as for a specific LDPC code, when an ensemble to which the LDPC code belongs is decided and density evolution is performed for the ensemble, rough performance of the LDPC code can be expected.

Therefore, if an ensemble of good performance is found, an LDPC code of good performance can be found from LDPC codes belonging to the ensemble.

Here, the above-mentioned degree sequence shows at what percentage a variable node or check node having the weight of each value exists with respect to the code length N of an LDPC code.

For example, a regular (3,6) LDPC code with an encoding rate of 1/2 belongs to an ensemble characterized by a degree sequence in which the weight (column weight) of all variable nodes is 3 and the weight (row weight) of all check nodes is 6.

FIG. 107 illustrates a Tanner graph of such an ensemble.

In the Tanner graph of FIG. 107, there are variable nodes shown by circles (sign O) in the diagram only by N pieces equal to the code length N, and there are check nodes shown by quadrangles (sign □) only by N/2 pieces equal to a multiplication value multiplying encoding rate 1/2 by the code length N.

Three branches (edge) equal to the column weight are connected with each variable node, and therefore there are totally 3N branches connected with N variable nodes.

Moreover, six branches (edge) equal to the row weight are connected with each check node, and therefore there are totally 3N branches connected with N/2 check nodes.

In addition, there is one interleaver in the Tanner graph in FIG. 107.

The interleaver randomly rearranges 3N branches connected with N variable nodes and connects each rearranged branch with any of 3N branches connected with N/2 check nodes.

There are (3N)!(=(3N)×(3N−1)× . . . ×1) rearrangement patterns to rearrange 3N branches connected with N variable nodes in the interleaver. Therefore, an ensemble characterized by the degree sequence in which the weight of all variable nodes is 3 and the weight of all check nodes is 6, becomes aggregation of (3N)! LDPC codes.

In simulation to find an LDPC code of good performance (appropriate parity check matrix), an ensemble of a multi-edge type is used in the density evolution.

In the multi edge type, an interleaver through which the branches connected with the variable nodes and the branches connected with the check nodes pass, is divided into plural (multi edge), and, by this means, the ensemble is characterized more strictly.

FIG. 108 illustrates an example of a Tanner graph of an ensemble of the multi-edge type.

In the Tanner graph of FIG. 108, there are two interleavers of the first interleaver and the second interleaver.

Moreover, in the Tanner graph chart of FIG. 108, v1 variable nodes with one branch connected with the first interleaver and no branch connected with the second interleaver exist, v2 variable nodes with one branch connected with the first interleaver and two branches connected with the second interleaver exist, and v3 variable nodes with no branch connected with the first interleaver and two branches connected with the second interleaver exist, respectively.

Furthermore, in the Tanner graph chart of FIG. 108, c1 check nodes with two branches connected with the first interleaver and no branch connected with the second interleaver exist, c2 check nodes with two branches connected with the first interleaver and two branches connected with the second interleaver exist, and c3 check nodes with no branch connected with the first interleaver and three branches connected with the second interleaver exist, respectively.

Here, for example, the density evolution and the mounting thereof are described in “On the Design of Low-Density Parity-Check Codes within 0.0045 dB of the Shannon Limit”, S. Y. Chung, G. D. Forney, T. J. Richardson, R. Urbanke, IEEE Communications Leggers, VOL. 5, NO. 2, February 2001.

In simulation to find (a parity check matrix initial value table of) a new LDPC code, by the density evaluation of the multi-edge type, an ensemble in which a performance threshold that is E_{b}/N₀ (signal-to-noise power ratio per bit) with deteriorating (decreasing) BER is equal to or less than a predetermined value is found, and an LDPC code that decreases BER in a plurality of modulation methods used in DVB-S.2 or the like such as QPSK is selected from LDPC codes belonging to the ensemble as an LDPC code of good performance.

The above-mentioned parity check matrix initial value table of the new LDPC code is a parity check matrix initial value table of an LDPC code with a code length N of 64 k bits found from the above-mentioned simulation.

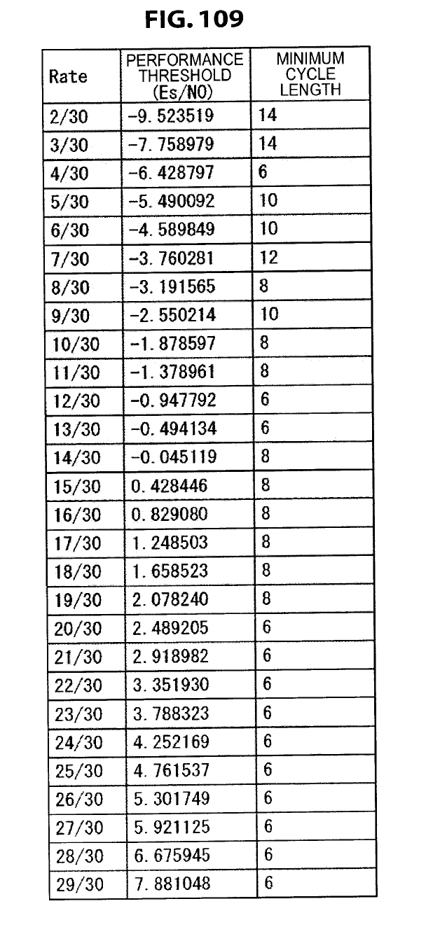

FIG. 109 is a diagram illustrating the minimum cycle length and performance threshold of the parity check matrix H found from the parity check matrix initial value tables of new LDPC codes with 28 kinds of encoding rates of 2/30 to 29/30 and a code length N of 64 k bits in FIG. 40 to FIG. 106.

Here, the minimum cycle length (girth) means the minimum value of the length of a loop (loop length) formed with elements of 1 in the parity check matrix H.

In the parity check matrix H found from the parity check matrix initial value table of the new LDPC code, cycle 4 (a loop of elements of 1 with a loop length of 4) does not exist.

Moreover, since the redundancy of an LDPC code becomes larger as the encoding rate r becomes smaller, the performance threshold tends to improve (decrease) as the encoding rate r decreases.

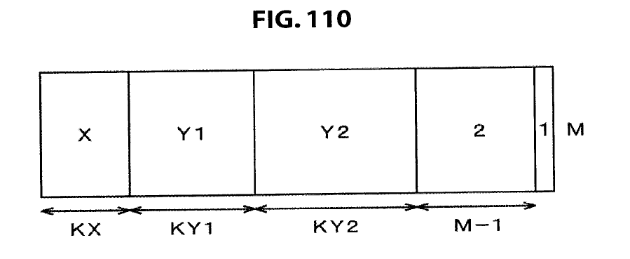

FIG. 110 is a diagram illustrating the parity check matrix H (which may be called a new LDPC code parity check matrix H) of FIG. 40 to FIG. 106 (which is found from a parity check matrix initial value table).

The column weight is X for the KX column from the first column of the new LDPC code parity check matrix H, the column weight is Y1 for the subsequent KY1 column, the column weight is Y2 for the subsequent KY2 column, the column weight is 2 for the subsequent M−1 column, and the column weight is 1 for the last column.

Here, KX+KY1+KY2+M−1+1 is equal to a code length of N=64800 bits.

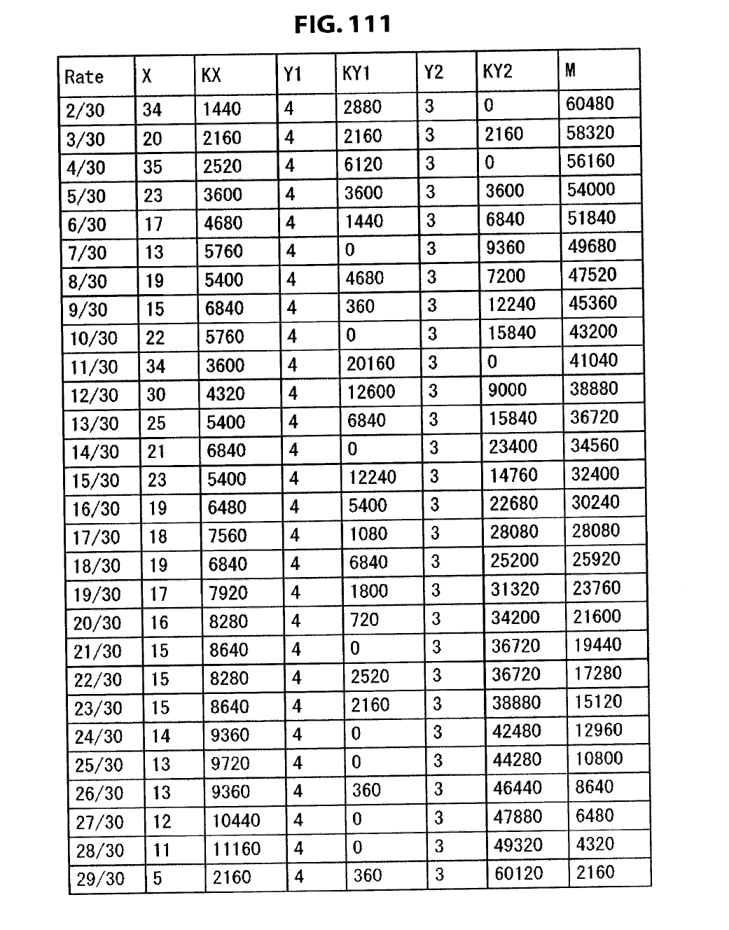

FIG. 111 is a diagram illustrating column numbers KX, KY1, KY2 and M and column weights X, Y1 and Y2 in FIG. 110, for each encoding rate r of a new LDPC code.

As for the new LDPC code parity check matrix H with a code length N of 64 k, similar to the parity check matrix described in FIG. 12 and FIG. 13, the column weight tends to be larger in a column closer to the head side (left side), and therefore a code bit closer to the head of the new LDPC code tends to be more tolerant to errors (have resistance to errors).

Here, shift amount q of cyclic shift, which is performed when a parity check matrix is found from the parity check matrix initial value table of a new LDPC code with a code length N of 64 k as described in FIG. 38, is expressed by an expression q=M/P=M/360.

Therefore, the shift amounts of new LDPC codes with encoding rates of 2/30, 3/30, 4/30, 5/30, 6/30, 7/30, 8/30, 9/30, 10/30, 11/30, 12/30, 13/30, 14/30, 15/30, 16/30, 17/30, 18/30, 19/30, 20/30, 21/30, 22/30, 23/30, 24/30, 25/30, 26/30, 27/30, 28/30 and 29/30 are 168, 162, 156, 150, 144, 138, 132, 126, 120, 114, 108, 102, 96, 90, 84, 78, 72, 66, 60, 54, 48, 42, 36, 30, 24, 18, 12 and 6, respectively.

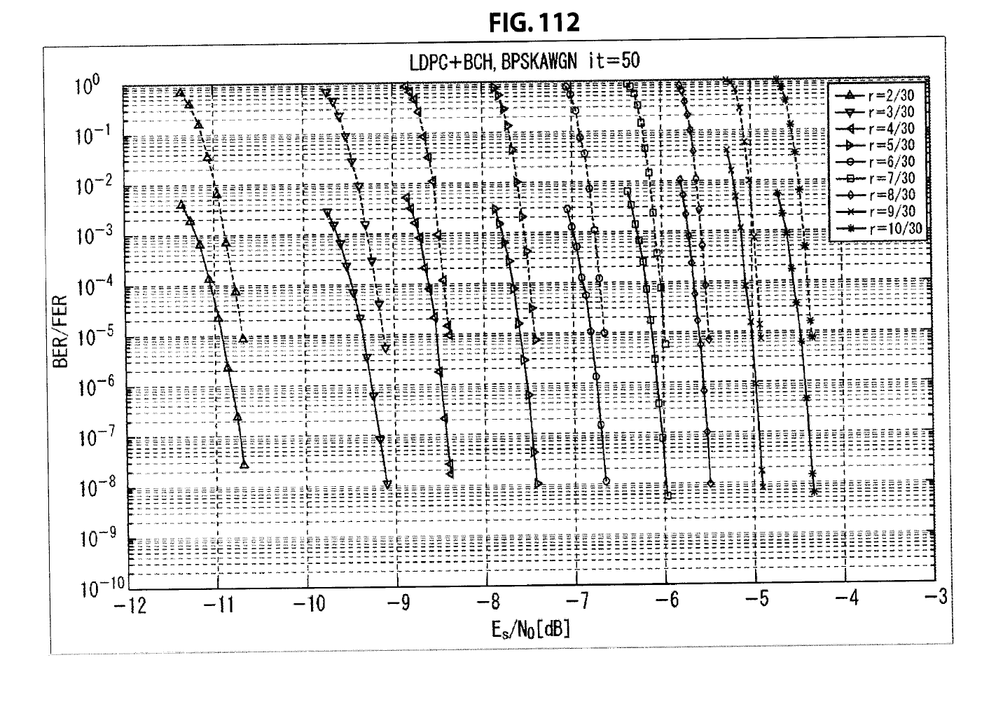

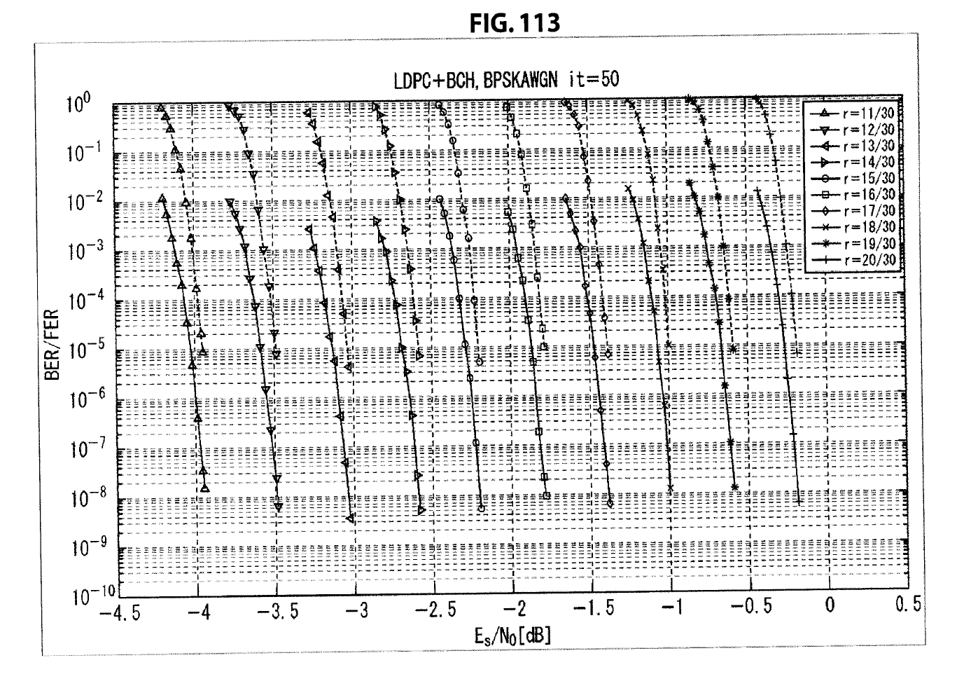

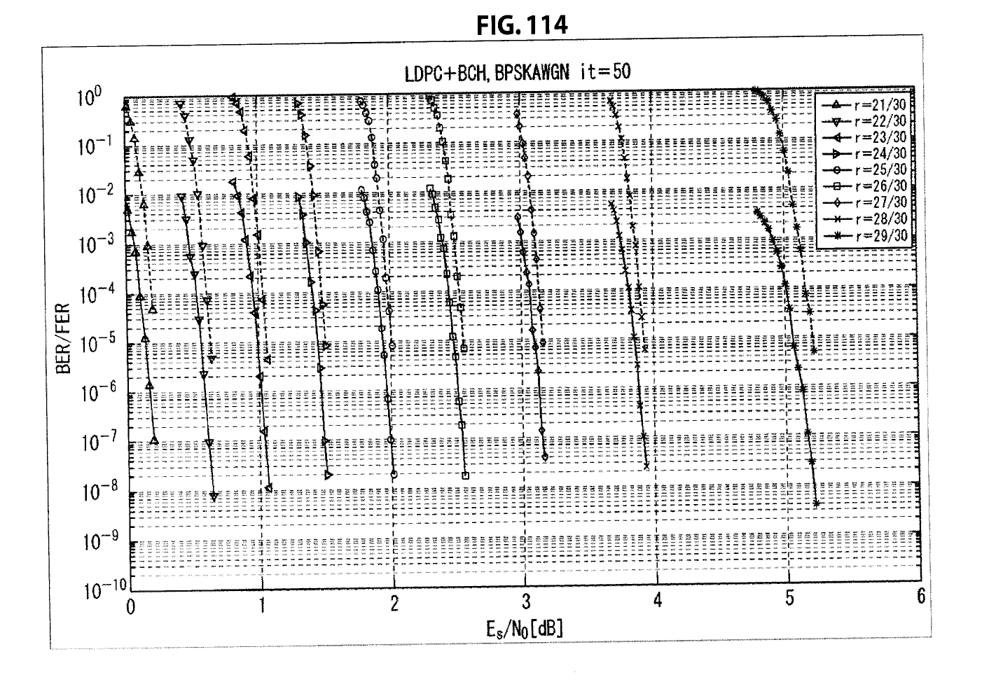

FIG. 112, FIG. 113 and FIG. 114 are diagrams illustrating a simulation result of BER/FER of new LDPC codes of FIG. 40 to FIG. 106.

In the simulation, a communication path (channel) of AWGN is assumed, BPSK is adopted as a modulation method and 50 times are adopted as an iterative decoding number C(it).

In FIG. 112, FIG. 113 and FIG. 114, the horizontal axis shows Eₛ/N₀ and the vertical axis shows BER/FER. Here, the solid line shows BER and the dotted line shows FER.

As for the FER (BER) curves of respective new LDPC codes with 28 kinds of encoding rates of 2/30 to 29/30 in FIG. 112 to FIG. 114, FER is equal to or less than 10⁻⁵ in a range of (about) 15 dB of Eₛ/N₀ from (almost) −10 dB to 5 dB.

According to the simulation, since it is possible to set 28 pieces of ModCod in which FER is equal to or less than 10⁻⁵ in a range of 15 dB in which Eₛ/N₀ is from −10 dB to 5 dB, by considering various modulation methods such as QPSK, 8PSK, 16APSK, 32APSK, 16QAM, 32QAM and 64QAM other than BPSK used in the simulation, it is sufficiently expected that it is possible to set 20 or more pieces of ModCod in which FER is equal to or less than 10⁻⁵ in a range of 7 dB from 5 dB to 12 dB.

Therefore, it is possible to provide an LDPC code of a good error rate, which satisfies the first request of CfT.

Moreover, according to FIG. 112 to FIG. 114, almost all of FER (BER) curves are arranged at relatively equal intervals for each of groups with encoding rates of Low, Medium and High at intervals less than 1 dB. Therefore, for broadcasters who broadcast a program by the transmitting device 11, there is an advantage that a new LDPC code easily selects an encoding rate used for broadcast according to the situation of a channel (communication path 13), and so on.

Here, in the simulation to find the BER/FER curves in FIG. 112 to FIG. 114, information is subjected to BCH encoding and a BCH code obtained as a result is subjected to LDPC encoding.

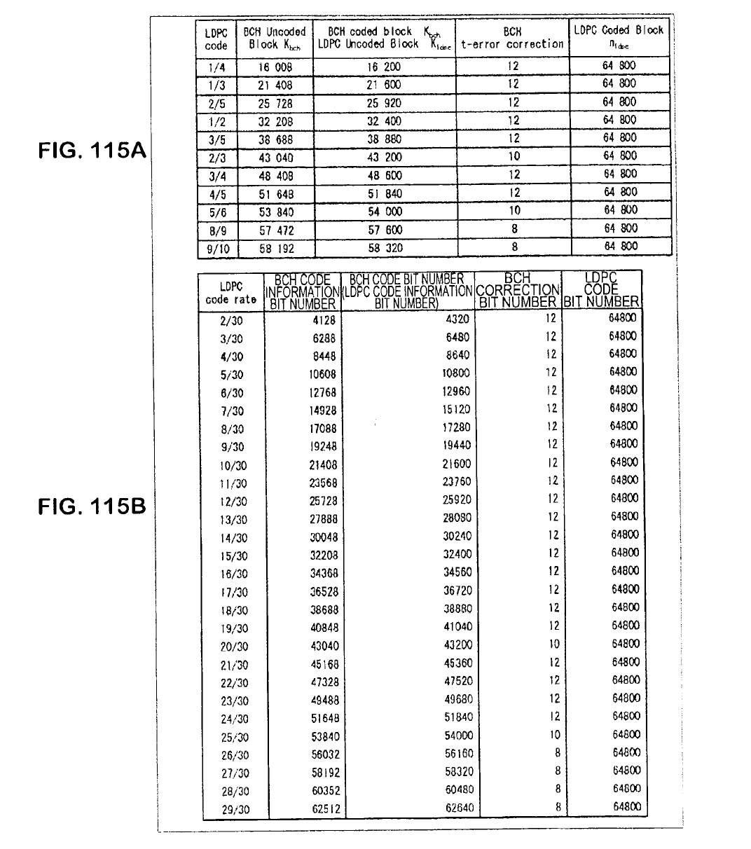

FIG. 115 is a diagram illustrating the BCH encoding used for the simulation.

That is, A of FIG. 115 is a diagram illustrating parameters of the BCH encoding performed before the LDPC encoding for an LDPC code of 64 k defined in DVB-S.2.

In DVB-S.2, by attaching redundancy bits of 192 bits, 160 bits or 128 bits according to the encoding rate of an LDPC code, BCH encoding that enables error correction of 12 bits, 10 bits or 8 bits is performed.

B of FIG. 115 is a diagram illustrating parameters of the BCH encoding used for the simulation.

In the simulation, similar to the case of DVB-S.2, by attaching redundancy bits of 192 bits, 160 bits or 128 bits according to the encoding rate of an LDPC code, the BCH encoding that enables error correction of 12 bits, 10 bits or 8 bits is performed.

[Configuration Example of Receiving Device 12]

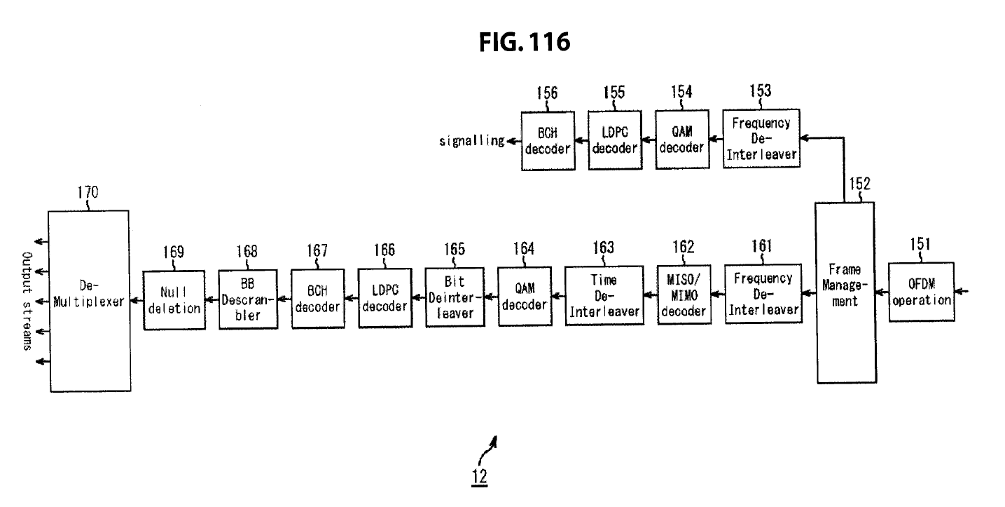

FIG. 116 is a block diagram illustrating a configuration example of the receiving device 12 of FIG. 7.

An OFDM operating unit 151 receives an OFDM signal from the transmitting device 11 (FIG. 7) and executes signal processing of the OFDM signal. Data (symbol) that is obtained by executing the signal processing by the OFDM operating unit 151 is supplied to a frame managing unit 152.

The frame managing unit 152 executes processing (frame interpretation) of a frame configured by the symbol supplied from the OFDM operating unit 151 and supplies a symbol of target data obtained as a result and a symbol of signaling to frequency deinterleavers 161 and 153.

The frequency deinterleaver 153 performs frequency deinterleave in a unit of symbol, with respect to the symbol supplied from the frame managing unit 152, and supplies the symbol to a QAM decoder 154.

The QAM decoder 154 demaps (signal point arrangement decoding) the symbol (symbol arranged on a signal point) supplied from the frequency deinterleaver 153, performs orthogonal demodulation, and supplies data (LDPC code) obtained as a result to a LDPC decoder 155.

The LDPC decoder 155 performs LDPC decoding of the LDPC code supplied from the QAM decoder 154 and supplies LDPC target data (in this case, a BCH code) obtained as a result to a BCH decoder 156.

The BCH decoder 156 performs BCH decoding of the LDPC target data supplied from the LDPC decoder 155 and outputs control data (signaling) obtained as a result.

Meanwhile, the frequency deinterleaver 161 performs frequency deinterleave in a unit of symbol, with respect to the symbol supplied from the frame managing unit 152, and supplies the symbol to a MISO/MIMO decoder 162.

The MISO/MIMO decoder 162 performs spatiotemporal decoding of the data (symbol) supplied from the frequency deinterleaver 161 and supplies the data to a time deinterleaver 163.

The time deinterleaver 163 performs time deinterleave in a unit of symbol, with respect to the data (symbol) supplied from the MISO/MIMO decoder 162, and supplies the data to a QAM decoder 164.

The QAM decoder 164 demaps (signal point arrangement decoding) the symbol (symbol arranged on a signal point) supplied from the time deinterleaver 163, performs orthogonal demodulation, and supplies data (symbol) obtained as a result to a bit deinterleaver 165.

The bit deinterleaver 165 performs bit deinterleave of the data (symbol) supplied from the QAM decoder 164 and supplies an LDPC code obtained as a result to an LDPC decoder 166.

The LDPC decoder 166 performs LDPC decoding of the LDPC code supplied from the bit deinterleaver 165 and supplies LDPC target data (in this case, a BCH code) obtained as a result to a BCH decoder 167.

The BCH decoder 167 performs BCH decoding of the LDPC target data supplied from the LDPC decoder 155 and supplies data obtained as a result to a BB descrambler 168.

The BB descrambler 168 executes BB descramble with respect to the data supplied from the BCH decoder 167 and supplies data obtained as a result to a null deletion unit 169.

The null deletion unit 169 deletes null inserted by the padder 112 of FIG. 8, from the data supplied from the BB descrambler 168, and supplies the data to a demultiplexer 170.

The demultiplexer 170 individually separates one or more streams (target data) multiplexed with the data supplied from the null deletion unit 169, performs necessary processing to output the streams as output streams.

Here, the receiving device 12 can be configured without including part of the blocks illustrated in FIG. 116. That is, for example, in a case where the transmitting device 11 (FIG. 8) is configured without including the time interleaver 118, the MISO/MIMO encoder 119, the frequency interleaver 120 and the frequency interleaver 124, the receiving device 12 can be configured without including the time deinterleaver 163, the MISO/MIMO decoder 162, the frequency deinterleaver 161 and the frequency deinterleaver 153 which are blocks respectively corresponding to the time interleaver 118, the MISO/MIMO encoder 119, the frequency interleaver 120 and the frequency interleaver 124 of the transmitting device 11.

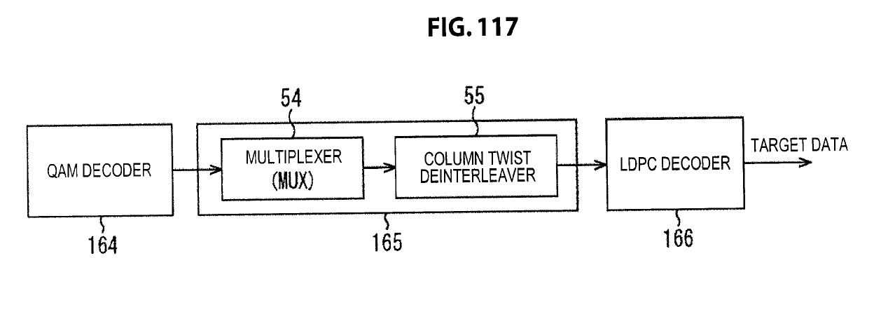

FIG. 117 is a block diagram illustrating a configuration example of the bit deinterleaver 165 of FIG. 116.

The bit deinterleaver 165 includes a multiplexer (MUX) 54 and a column twist deinterleaver 55 and performs (bit) deinterleave of symbol bits of the symbol supplied from the QAM decoder 164 (FIG. 116).

That is, the multiplexer 54 executes reverse interchange processing (reverse processing of the interchange processing) corresponding to the interchange processing executed by the demultiplexer 25 of FIG. 9, that is, reverse interchange processing for returning positions of the code bits (symbol bits) of the LDPC codes interchanged by the interchange processing to original positions, with respect to the symbol bits of the symbol supplied from the QAM decoder 164, and supplies an LDPC code obtained as a result to the column twist deinterleaver 55.

The column twist deinterleaver 55 performs the column twist deinterleave (reverse processing of the column twist interleave) corresponding to the column twist interleave as the rearrangement processing executed by the column twist interleaver 24 of FIG. 9, that is, the column twist deinterleave as the reverse rearrangement processing for returning the code bits of the LDPC codes of which an arrangement is changed by the column twist interleave as the rearrangement processing to the original arrangement, with respect to the LDPC code supplied from the multiplexer 54.

Specifically, the column twist deinterleaver 55 writes the code bits of the LDPC code to a memory for deinterleave having the same configuration as the memory 31 illustrated in FIG. 28, reads the code bits, and performs the column twist deinterleave.

However, in the column twist deinterleaver 55, writing of the code bits is performed in a row direction of the memory for the deinterleave, using read addresses when the code bits are read from the memory 31 as write addresses. In addition, reading of the code bits is performed in a column direction of the memory for the deinterleave, using write addresses when the code bits are written to the memory 31 as read addresses.

The LDPC code that is obtained as a result of the column twist deinterleave is supplied from the column twist deinterleaver 55 to the LDPC decoder 166.

Here, in a case where the parity interleave, the column twist interleave and the interchange processing are performed on an LDPC code supplied from the QAM decoder 164 to the bit deinterleaver 165, all of parity deinterleave (processing opposite to the parity interleave, that is, parity deinterleave that returns the code bits of an LDPC code in which the arrangement is changed by the parity interleave to the original arrangement) corresponding to the parity interleave, reverse interchange processing corresponding to the interchange processing and column twist deinterleave corresponding to the column twist interleave can be performed in the bit deinterleaver 165.

However, the bit deinterleaver 165 in FIG. 117 includes the multiplexer 54 that performs the reverse interchange processing corresponding to the interchange processing and the column twist deinterleaver 55 that performs the column twist deinterleave corresponding to the column twist interleave, but does not include a block that performs the parity deinterleave corresponding to the parity interleave, and the parity deinterleave is not performed.

Therefore, the LDPC code in which the reverse interchange processing and the column twist deinterleave are performed and the parity deinterleave is not performed is supplied from (the column twist deinterleaver 55 of) the bit deinterleaver 165 to the LDPC decoder 166.

The LDPC decoder 166 performs the LDPC decoding of the LDPC code supplied from the bit deinterleaver 165, using a transformed parity check matrix obtained by performing at least column replacement corresponding to the parity interleave with respect to the parity check matrix H used by the LDPC encoder 115 of FIG. 8 to perform the LDPC encoding, and outputs data obtained as a result to a decoding result of LDPC target data.

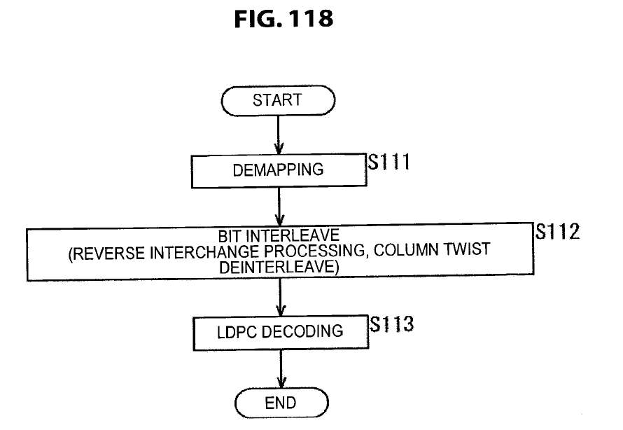

FIG. 118 is a flowchart illustrating processing that is executed by the QAM decoder 164, the bit deinterleaver 165, and the LDPC decoder 166 of FIG. 117.

In step S111, the QAM decoder 164 demaps the symbol (symbol mapped to a signal point) supplied from the time deinterleaver 163, performs orthogonal modulation, and supplies the symbol to the bit deinterleaver 165, and the processing proceeds to step S112.

In step S112, the bit deinterleaver 165 performs deinterleave (bit deinterleave) of the symbol bits of the symbol supplied from the QAM decoder 164 and the processing proceeds to step S113.

That is, in step S112, in the bit deinterleaver 165, the multiplexer 54 executes reverse interchange processing with respect to the symbol bits of the symbol supplied from the QAM decoder 164 and supplies code bits of an LDPC code obtained as a result to the column twist deinterleaver 55.

The column twist deinterleaver 55 performs the column twist deinterleave with respect to the LDPC code supplied from the multiplexer 54 and supplies an LDPC code obtained as a result to the LDPC decoder 166.

In step S113, the LDPC decoder 166 performs the LDPC decoding of the LDPC code supplied from the column twist deinterleaver 55, using a transformed parity check matrix obtained by performing at least column replacement corresponding to the parity interleave with respect to the parity check matrix H used by the LDPC encoder 115 of FIG. 8 to perform the LDPC encoding, and outputs data obtained as a result, as a decoding result of LDPC target data, to the BCH decoder 167.

In FIG. 117, for the convenience of explanation, the multiplexer 54 that executes the reverse interchange processing and the column twist deinterleaver 55 that performs the column twist deinterleave are individually configured, similar to the case of FIG. 9. However, the multiplexer 54 and the column twist deinterleaver 55 can be integrally configured.

In the bit interleaver 116 of FIG. 9, when the column twist interleave is not performed, it is not necessary to provide the column twist deinterleaver 55 in the bit deinterleaver 165 of FIG. 117.

Next, the LDPC decoding that is performed by the LDPC decoder 166 of FIG. 116 will be further described.

In the LDPC decoder 166 of FIG. 116, as described above, the LDPC decoding of the LDPC code from the column twist deinterleaver 55, in which the reverse interchange processing and the column twist deinterleave are performed and the parity deinterleave is not performed, is performed using a transformed parity check matrix obtained by performing at least column replacement corresponding to the parity interleave with respect to the parity check matrix H used by the LDPC encoder 115 of FIG. 8 to perform the LDPC encoding.

In this case, LDPC decoding that can suppress an operation frequency at a sufficiently realizable range while suppressing a circuit scale, by performing the LDPC decoding using the transformed parity check matrix, is previously suggested (for example, refer to JP 4224777B).

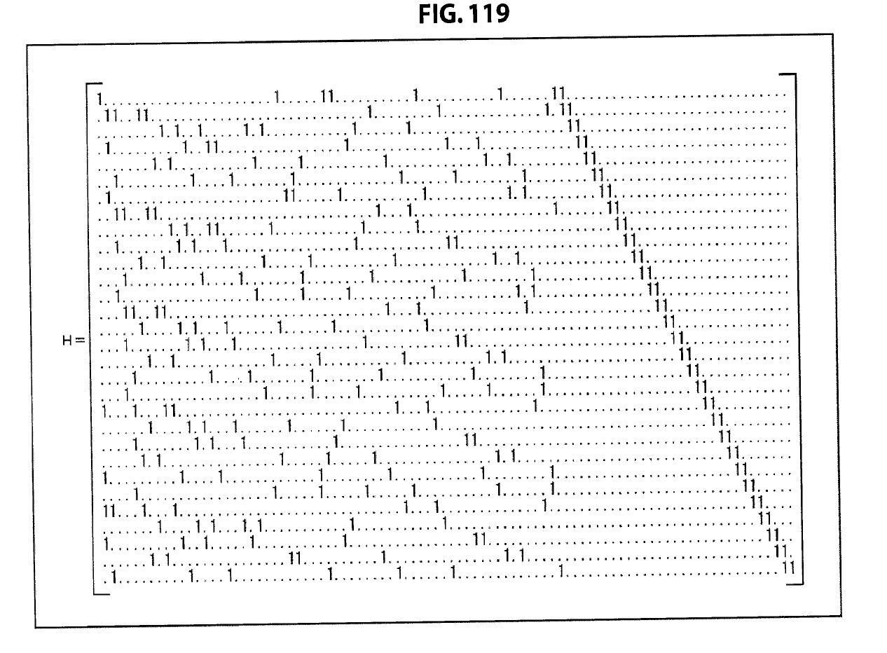

Therefore, first, the previously suggested LDPC decoding using the transformed parity check matrix will be described with reference to FIGS. 119 to 122.

FIG. 119 illustrates an example of a parity check matrix H of an LDPC code in which a code length N is 90 and an encoding rate is 2/3.

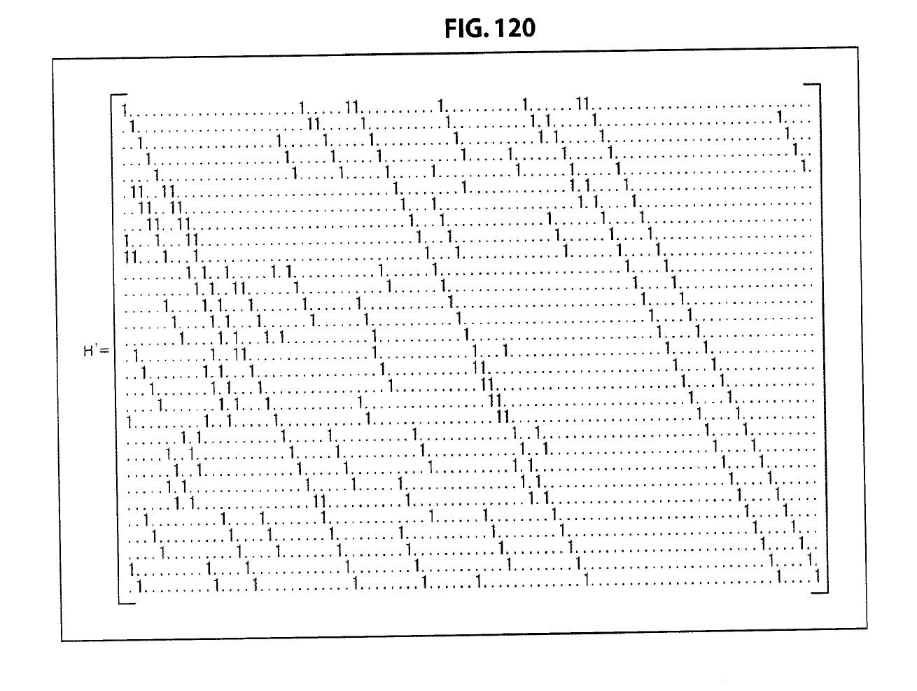

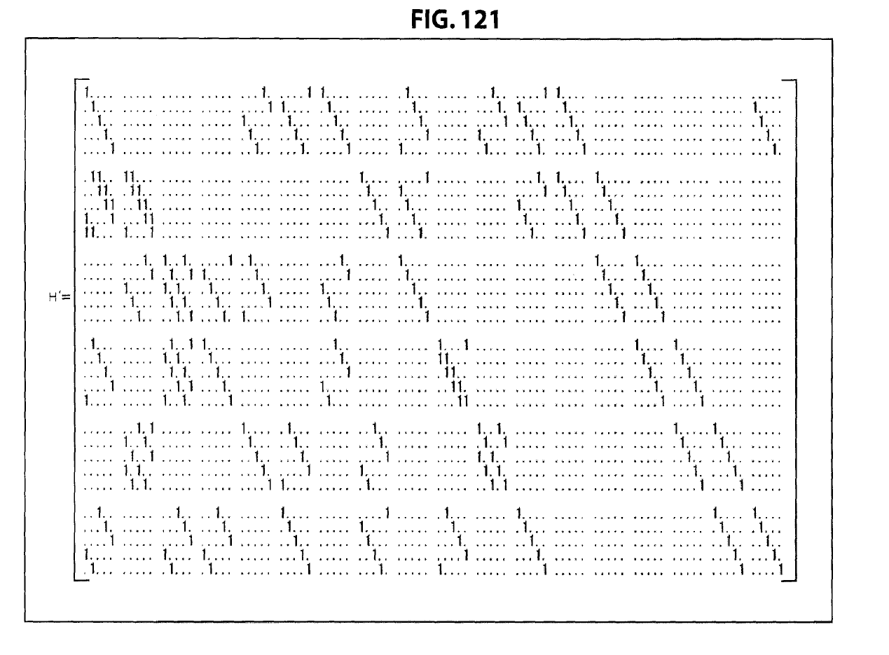

In FIG. 119 (and FIGS. 120 and 121 to be described later), 0 is represented by a period (.).

In the parity check matrix H of FIG. 119, the parity matrix becomes a staircase structure.

FIG. 120 illustrates a parity check matrix H′ that is obtained by executing row replacement of an expression (11) and column replacement of an expression (12) with respect to the parity check matrix H of FIG. 119.

Row Replacement: (6s+t+1)-th row→(5t+s+1)-th row (11)

Column Replacement: (6x+y+61)-th column→(5y+x+61)-th column (12)

In the expressions (11) and (12), s, t, x, and y are integers in ranges of 0<s<5, 0≦t<6, 0≦x<5, and 0≦t<6, respectively.

According to the row replacement of the expression (11), replacement is performed such that the 1st, 7th, 13rd, 19th, and 25th rows having remainders of 1 when being divided by 6 are replaced with the 1st, 2nd, 3rd, 4th, and 5th rows, and the 2nd, 8th, 14th, 20th, and 26th rows having remainders of 2 when being divided by 6 are replaced with the 6th, 7th, 8th, 9th, and 10th rows, respectively.

According to the column replacement of the expression (12), replacement is performed such that the 61st, 67th, 73rd, 79th, and 85th columns having remainders of 1 when being divided by 6 are replaced with the 61st, 62nd, 63rd, 64th, and 65th columns, respectively, and the 62nd, 68th, 74th, 80th, and 86th columns having remainders of 2 when being divided by 6 are replaced with the 66th, 67th, 68th, 69th, and 70th columns, respectively, with respect to the 61st and following columns (parity matrix).

In this way, a matrix that is obtained by performing the replacements of the rows and the columns with respect to the parity check matrix H of FIG. 119 is a parity check matrix H′ of FIG. 120.

In this case, even when the row replacement of the parity check matrix H is performed, the arrangement of the code bits of the LDPC code is not influenced.

The column replacement of the expression (12) corresponds to parity interleave to interleave the (K+qx+y+1)-th code bit into the position of the (K+Py+x+1)-th code bit, when the information length K is 60, the column number P of the unit of the cyclic structure is 5, and the divisor q (=M/P) of the parity length M (in this case, 30) is 6.

Therefore, the parity check matrix H′ in FIG. 120 is a transformed parity check matrix obtained by performing at least column replacement that replaces the K+qx+y+1-th column of the parity check matrix H in FIG. 119 (which may be arbitrarily called an original parity check matrix below) with the K+Py+x+1-th column.

If the parity check matrix H′ of FIG. 120 is multiplied with a result obtained by performing the same replacement as the expression (12) with respect to the LDPC code of the parity check matrix H of FIG. 119, a zero vector is output. That is, if a row vector obtained by performing the column replacement of the expression (12) with respect to a row vector c as the LDPC code (one code word) of the original parity check matrix H is represented as c′, HcT becomes the zero vector from the property of the parity check matrix. Therefore, H′c′T naturally becomes the zero vector.

Thereby, the transformed parity check matrix H′ of FIG. 120 becomes a parity check matrix of an LDPC code c′ that is obtained by performing the column replacement of the expression (12) with respect to the LDPC code c of the original parity check matrix H.

Therefore, the column replacement of the expression (12) is performed with respect to the LDPC code of the original parity check matrix H, the LDPC code c′ after the column replacement is decoded (LDPC decoding) using the transformed parity check matrix H′ of FIG. 120, reverse replacement of the column replacement of the expression (12) is performed with respect to a decoding result, and the same decoding result as the case in which the LDPC code of the original parity check matrix H is decoded using the parity check matrix H can be obtained.

FIG. 121 illustrates the transformed parity check matrix H′ of FIG. 120 with being spaced in units of 5×5 matrixes.

In FIG. 121, the transformed parity check matrix H′ is represented by a combination of a 5×5 (=p×p) unit matrix, a matrix (hereinafter, appropriately referred to as a quasi unit matrix) obtained by setting one or more 1 of the unit matrix to zero, a matrix (hereinafter, appropriately referred to as a shifted matrix) obtained by cyclically shifting the unit matrix or the quasi unit matrix, a sum (hereinafter, appropriately referred to as a sum matrix) of two or more matrixes of the unit matrix, the quasi unit matrix, and the shifted matrix, and a 5×5 zero matrix.

The transformed parity check matrix H′ of FIG. 121 can be configured using the 5×5 unit matrix, the quasi unit matrix, the shifted matrix, the sum matrix, and the zero matrix. Therefore, the 5×5 matrixes (the unit matrix, the quasi unit matrix, the shifted matrix, the sum matrix, and the zero matrix) that constitute the transformed parity check matrix H′ are appropriately referred to as constitutive matrixes hereinafter.

When the LDPC code represented by the parity check matrix represented by the P×P constitutive matrixes is decoded, an architecture in which P check node operations and variable node operations are simultaneously performed can be used.

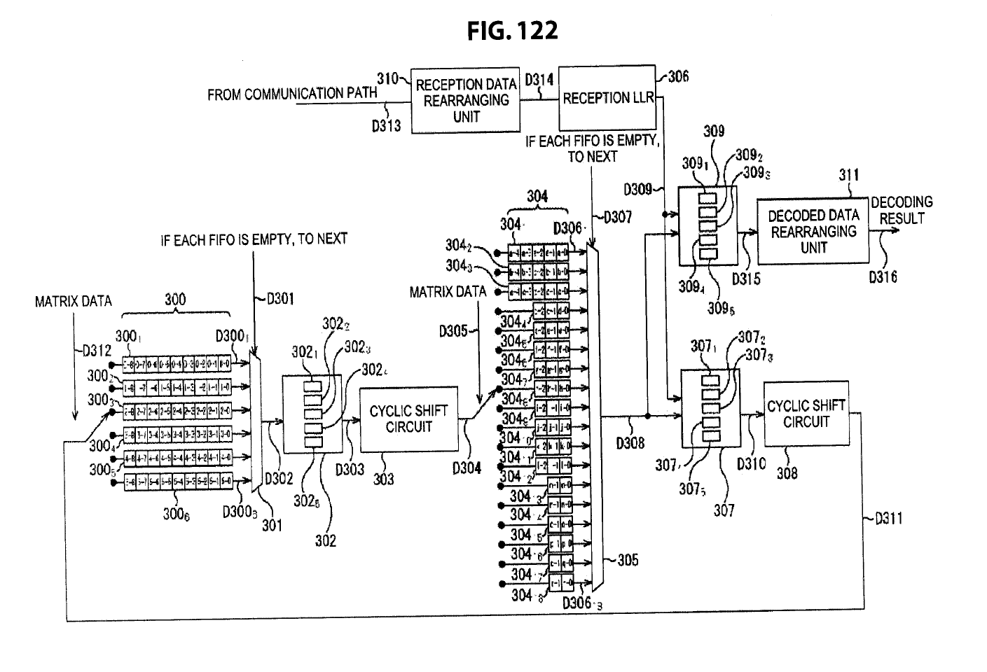

FIG. 122 is a block diagram illustrating a configuration example of a decoding device that performs the decoding.

That is, FIG. 122 illustrates the configuration example of the decoding device that performs decoding of the LDPC code, using the transformed parity check matrix H′ of FIG. 119 obtained by performing at least the column replacement of the expression (12) with respect to the original parity check matrix H of FIG. 121.

The decoding device of FIG. 122 includes a branch data storing memory 300 that includes 6 FIFOs 300₁ to 300₆, a selector 301 that selects the FIFOs 300₁ to 300₆, a check node calculating unit 302, two cyclic shift circuits 303 and 308, a branch data storing memory 304 that includes 18 FIFOs 304₁ to 304₁₈, a selector 305 that selects the FIFOs 304₁ to 304₁₈, a reception data memory 306 that stores reception data, a variable node calculating unit 307, a decoding word calculating unit 309, a reception data rearranging unit 310, and a decoded data rearranging unit 311.

First, a method of storing data in the branch data storing memories 300 and 304 will be described.

The branch data storing memory 300 includes the 6 FIFOs 300₁ to 300₆ that correspond to a number obtained by dividing a row number 30 of the transformed parity check matrix H′ of FIG. 121 by a row number 5 of the constitutive matrix (the column number P of the unit of the cyclic structure). The FIFO 300_{y} (y=1, 2, . . . , and 6) includes a plurality of steps of storage regions. In the storage region of each step, messages corresponding to five branches to be a row number and a column number of the constitutive matrix (the column number P of the unit of the cyclic structure) can be simultaneously read or written. The number of steps of the storage regions of the FIFO 300₃, becomes 9 to be a maximum number of the number (Hamming weight) of 1 of a row direction of the transformed parity check matrix of FIG. 121.

In the FIFO 300₁, data (messages vᵢ from variable nodes) corresponding to positions of 1 in the first to fifth rows of the transformed parity check matrix H′ of

FIG. 121 is stored in a form filling each row in a transverse direction (a form in which 0 is ignored). That is, if a j-th row and an i-th column are represented as (j, i), data corresponding to positions of 1 of a 5×5 unit matrix of (1, 1) to (5, 5) of the transformed parity check matrix H′ is stored in the storage region of the first step of the FIFO 300₁. In the storage region of the second step, data corresponding to positions of 1 of a shifted matrix (shifted matrix obtained by cyclically shifting the 5×5 unit matrix to the right side by 3) of (1, 21) to (5, 25) of the transformed parity check matrix H′ is stored. Similar to the above case, in the storage regions of the third to eighth steps, data is stored in association with the transformed parity check matrix H′. In the storage region of the ninth step, data corresponding to positions of 1 of a shifted matrix (shifted matrix obtained by replacing 1 of the first row of the 5×5 unit matrix with 0 and cyclically shifting the unit matrix to the left side by 1) of (1, 86) to (5, 90) of the transformed parity check matrix H′ is stored.

In the FIFO 300₂, data corresponding to positions of 1 in the sixth to tenth rows of the transformed parity check matrix H′ of FIG. 121 is stored. That is, in the storage region of the first step of the FIFO 300₂, data corresponding to positions of 1 of the first shifted matrix constituting a sum matrix (sum matrix to be a sum of the first shifted matrix obtained by cyclically shifting the 5×5 unit matrix to the right side by 1 and the second shifted matrix obtained by cyclically shifting the 5×5 unit matrix to the right side by 2) of (6, 1) to (10, 5) of the transformed parity check matrix H′ is stored. In addition, in the storage region of the second step, data corresponding to positions of 1 of the second shifted matrix constituting the sum matrix of (6, 1) to (10, 5) of the transformed parity check matrix H′ is stored.

That is, with respect to a constitutive matrix of which the weight is two or more, when the constitutive matrix is represented by a sum of multiple parts of a P×P unit matrix of which the weight is 1, a quasi unit matrix in which one or more elements of 1 in the unit matrix become 0, or a shifted matrix obtained by cyclically shifting the unit matrix or the quasi unit matrix, data (messages corresponding to branches belonging to the unit matrix, the quasi unit matrix, or the shifted matrix) corresponding to the positions of 1 in the unit matrix of the weight of 1, the quasi unit matrix, or the shifted matrix is stored at the same address (the same FIFO among the FIFOs 300₁ to 300₆).

Subsequently, in the storage regions of the third to ninth steps, data is stored in association with the transformed parity check matrix H′, similar to the above case.

In the FIFOs 300₃ to 300₆, data is stored in association with the transformed parity check matrix IT, similar to the above case.

The branch data storing memory 304 includes 18 FIFOs 304₁ to 304₁₈ that correspond to a number obtained by dividing a column number 90 of the transformed parity check matrix H′ by 5 to be a column number of a constitutive matrix (the column number P of the unit of the cyclic structure). The FIFO 304₈ (x=1, 2, . . . , and 18) includes a plurality of steps of storage regions. In the storage region of each step, messages corresponding to five branches corresponding to a row number and a column number of the constitutive matrix (the column number P of the unit of the cyclic structure) can be simultaneously read or written.

In the FIFO 304₁, data (messages uⱼ from check nodes) corresponding to positions of 1 in the first to fifth columns of the transformed parity check matrix H′ of FIG. 121 is stored in a form filling each column in a longitudinal direction (a form in which 0 is ignored). That is, if a j-th row and an i-th column are represented as (j, i), data corresponding to positions of 1 of a 5×5 unit matrix of (1, 1) to (5, 5) of the transformed parity check matrix H′ is stored in the storage region of the first step of the FIFO 304₁. In the storage region of the second step, data corresponding to positions of 1 of the first shifted matrix constituting a sum matrix (sum matrix to be a sum of the first shifted matrix obtained by cyclically shifting the 5×5 unit matrix to the right side by 1 and the second shifted matrix obtained by cyclically shifting the 5×5 unit matrix to the right side by 2) of (6, 1) to (10, 5) of the transformed parity check matrix H′ is stored. In addition, in the storage region of the third step, data corresponding to positions of 1 of the second shifted matrix constituting the sum matrix of (6, 1) to (10, 5) of the transformed parity check matrix H′ is stored.

That is, with respect to a constitutive matrix of which the weight is two or more, when the constitutive matrix is represented by a sum of multiple parts of a P×P unit matrix of which the weight is 1, a quasi unit matrix in which one or more elements of 1 in the unit matrix become 0, or a shifted matrix obtained by cyclically shifting the unit matrix or the quasi unit matrix, data (messages corresponding to branches belonging to the unit matrix, the quasi unit matrix, or the shifted matrix) corresponding to the positions of 1 in the unit matrix of the weight of 1, the quasi unit matrix, or the shifted matrix is stored at the same address (the same FIFO among the FIFOs 304₁ to 304₁₈).

Subsequently, in the storage regions of the fourth and fifth steps, data is stored in association with the transformed parity check matrix H′, similar to the above case. The number of steps of the storage regions of the FIFO 304₁ becomes 5 to be a maximum number of the number (Hamming weight) of 1 of a row direction in the first to fifth columns of the transformed parity check matrix H′.

In the FIFOs 304₂ and 304₃, data is stored in association with the transformed parity check matrix H′, similar to the above case, and each length (the number of steps) is 5. In the FIFOs 304₄ to 304₁₂, data is stored in association with the transformed parity check matrix H′, similar to the above case, and each length is 3. In the FIFOs 304₁₃ to 304₁₈, data is stored in association with the transformed parity check matrix H′, similar to the above case, and each length is 2.

Next, an operation of the decoding device of FIG. 122 will be described.

The branch data storing memory 300 includes the 6 FIFOs 300₁ to 300₆. According to information (matrix data) D312 on which row of the transformed parity check matrix H′ in FIG. 121 five messages D311 supplied from a cyclic shift circuit 308 of a previous step belongs to, the FIFO storing data is selected from the FIFOs 300₁ to 300₆ and the five messages D311 are collectively stored sequentially in the selected FIFO. When the data is read, the branch data storing memory 300 sequentially reads the five messages D300₁ from the FIFO 300₁ and supplies the messages to the selector 301 of a next step. After reading of the messages from the FIFO 300₁ ends, the branch data storing memory 300 reads the messages sequentially from the FIFOs 300₂ to 300₆ and supplies the messages to the selector 301.

The selector 301 selects the five messages from the FIFO from which data is currently read, among the FIFOs 300₁ to 300₆, according to a select signal D301, and supplies the selected messages as messages D302 to the check node calculating unit 302.

The check node calculating unit 302 includes five check node calculators 302₁ to 302₅. The check node calculating unit 302 performs a check node operation according to the expression (7), using the messages D302 (D302₁ to D302₅) (messages vᵢ of the expression 7) supplied through the selector 301, and supplies five messages D303 (D303₁ to D303₅) (messages uⱼ of the expression (7)) obtained as a result of the check node operation to a cyclic shift circuit 303.

The cyclic shift circuit 303 cyclically shifts the five messages D303₁ to D303₅ calculated by the check node calculating unit 302, on the basis of information (matrix data) D305 on how many the unit matrixes (or the quasi unit matrix) becoming the origin in the transformed parity check matrix H′ are cyclically shifted to obtain the corresponding branches, and supplies a result as messages D304 to the branch data storing memory 304.

The branch data storing memory 304 includes the eighteen FIFOs 304₁ to 304₁₈. According to information D305 on which row of the transformed parity check matrix H′ five messages D304 supplied from a cyclic shift circuit 303 of a previous step belongs to, the FIFO storing data is selected from the FIFOs 304₁ to 304₁₈ and the five messages D304 are collectively stored sequentially in the selected FIFO. When the data is read, the branch data storing memory 304 sequentially reads the five messages D304₁ from the FIFO 304₁ and supplies the messages to the selector 305 of a next step. After reading of the messages from the FIFO 304₁ ends, the branch data storing memory 304 reads the messages sequentially from the FIFOs 304₂ to 304₁₈ and supplies the messages to the selector 305.

The selector 305 selects the five messages from the FIFO from which data is currently read, among the FIFOs 304₁ to 304₁₈, according to a select signal D307, and supplies the selected messages as messages D308 to the variable node calculating unit 307 and the decoding word calculating unit 309.

Meanwhile, the reception data rearranging unit 310 rearranges the LDPC code D313, that is corresponding to the parity check matrix H in FIG. 119, received through the communication path 13 by performing the column replacement of the expression (12) and supplies the LDPC code as reception data D314 to the reception data memory 306. The reception data memory 306 calculates a reception LLR (Log Likelihood Ratio) from the reception data D314 supplied from the reception data rearranging unit 310, stores the reception LLR, collects five reception LLRs, and supplies the reception LLRs as reception values D309 to the variable node calculating unit 307 and the decoding word calculating unit 309.

The variable node calculating unit 307 includes five variable node calculators 307₁ to 307₅. The variable node calculating unit 307 performs the variable node operation according to the expression (1), using the messages D308 (D308₁ to D308₅) (messages uⱼ of the expression (1)) supplied through the selector 305 and the five reception values D309 (reception values u₀ᵢ of the expression (1)) supplied from the reception data memory 306, and supplies messages D310 (D310₁ to D310₅) (message vᵢ of the expression (1)) obtained as an operation result to the cyclic shift circuit 308.

The cyclic shift circuit 308 cyclically shifts the messages D310₁ to D310₅ calculated by the variable node calculating unit 307, on the basis of information on how many the unit matrixes (or the quasi unit matrix) becoming the origin in the transformed parity check matrix H′ are cyclically shifted to obtain the corresponding branches, and supplies a result as messages D311 to the branch data storing memory 300.

By circulating the above operation in one cycle, decoding (variable node operation and check node operation) of the LDPC code can be performed once. After decoding the LDPC code by the predetermined number of times, the decoding device of FIG. 122 calculates a final decoding result and outputs the final decoding result, in the decoding word calculating unit 309 and the decoded data rearranging unit 311.

That is, the decoding word calculating unit 309 includes five decoding word calculators 309₁ to 309₅. The decoding word calculating unit 309 calculates a decoding result (decoding word) on the basis of the expression (5), as a final step of multiple decoding, using the five messages D308 (D308₁ to D308₅) (messages uⱼ of the expression) output by the selector 305 and the five reception values D309 (reception values u₀ᵢ of the expression (5)) supplied from the reception data memory 306, and supplies decoded data D315 obtained as a result to the decoded data rearranging unit 311.

The decoded data rearranging unit 311 performs the reverse replacement of the column replacement of the expression (12) with respect to the decoded data D315 supplied from the decoding word calculating unit 309, rearranges the order thereof, and outputs the decoded data as a final decoding result D316.

As mentioned above, by performing one or both of row replacement and column replacement on the parity check matrix (original parity check matrix) and converting it into a parity check matrix (transformed parity check matrix) that can be shown by the combination of a pxp unit matrix, a quasi unit matrix in which one or more elements of 1 thereof become 0, a shifted matrix that cyclically shifts the unit matrix or the quasi unit matrix, a sum matrix that is the sum of two or more of the unit matrix, the quasi unit matrix and the shifted matrix, and a pxp 0 matrix, that is, the combination of constitutive matrixes, as for LDPC code decoding, it becomes possible to adopt architecture that simultaneously performs check node calculation and variable node calculation by P which is the number less than the row number and column number of the parity check matrix. In the case of adopting the architecture that simultaneously performs node calculation (check node calculation and variable node calculation) by P which is the number less than the row number and column number of the parity check matrix, as compared with a case where the node calculation is simultaneously performed by the number equal to the row number and column number of the parity check matrix, it is possible to suppress the operation frequency within a feasible range and perform many items of iterative decoding.

The LDPC decoder 166 that constitutes the receiving device 12 of FIG. 116 performs the LDPC decoding by simultaneously performing P check node operations and variable node operations, similar to the decoding device of FIG. 122.

That is, for the simplification of explanation, if the parity check matrix of the LDPC code output by the LDPC encoder 115 constituting the transmitting device 11 of FIG. 8 is regarded as the parity check matrix H illustrated in FIG. 119 in which the parity matrix becomes a staircase structure, in the parity interleaver 23 of the transmitting device 11, the parity interleave to interleave the (K+qx+y+1)-th code bit into the position of the (K+Py+x+1)-th code bit is performed in a state in which the information K is set to 60, the column number P of the unit of the cyclic structure is set to 5, and the divisor q (=M/P) of the parity length M is set to 6.

Because the parity interleave corresponds to the column replacement of the expression (12) as described above, it is not necessary to perform the column replacement of the expression (12) in the LDPC decoder 166.

For this reason, in the receiving device 12 of FIG. 116, as described above, the LDPC code in which the parity deinterleave is not performed, that is, the LDPC code in a state in which the column replacement of the expression (12) is performed is supplied from the column twist deinterleaver 55 to the LDPC decoder 166. In the LDPC decoder 166, the same processing as the decoding device of FIG. 122, except that the column replacement of the expression (12) is not performed, is executed.

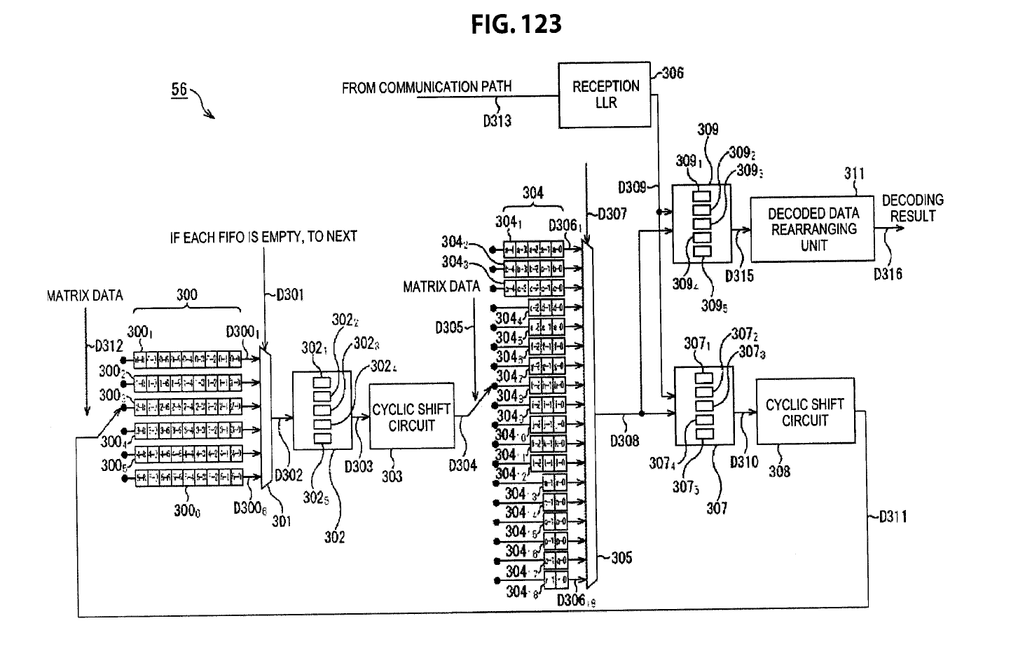

That is, FIG. 123 illustrates a configuration example of the LDPC decoder 166 of FIG. 116.

In FIG. 123, the LDPC decoder 166 has the same configuration as the decoding device of FIG. 122, except that the reception data rearranging unit 310 of FIG. 122 is not provided, and executes the same processing as the decoding device of FIG. 122, except that the column replacement of the expression (12) is not performed. Therefore, explanation of the LDPC decoder is omitted.

As described above, because the LDPC decoder 166 can be configured without providing the reception data rearranging unit 310, a scale can be decreased as compared with the decoding device of FIG. 122.

In FIGS. 119 to 123, for the simplification of explanation, the code length N of the LDPC code is set to 90, the information length K is set to 60, the column number (the row number and the column number of the constitutive matrix) P of the unit of the cyclic structure is set to 5, and the divisor q (=M/P) of the parity length M is set to 6. However, the code length N, the information length K, the column number P of the unit of the cyclic structure, and the divisor q M/P) are not limited to the above values.

That is, in the transmitting device 11 of FIG. 8, the LDPC encoder 115 outputs the LDPC code in which the code length N is set to 64800 or 16200, the information length K is set to N−Pq (=N−M), the column number P of the unit of the cyclic structure is set to 360, and the divisor q is set to M/P. However, the LDPC decoder 166 of FIG. 123 can be applied to the case in which P check node operation and variable node operations are simultaneously performed with respect to the LDPC code and the LDPC decoding is performed.

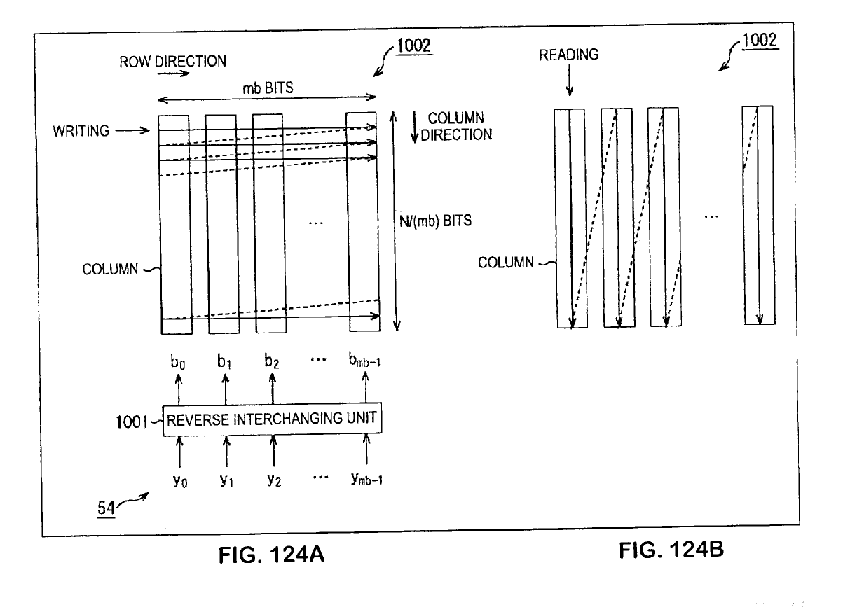

FIG. 124 is an illustration of processing of the multiplexer 54 constituting the bit deinterleaver 165 of FIG. 117.

That is, A of FIG. 124 illustrates a functional configuration example of the multiplexer 54.

The multiplexer 54 includes a reverse interchanging unit 1001 and a memory 1002.

The multiplexer 54 executes reverse interchange processing (reverse processing of the interchange processing) corresponding to the interchange processing executed by the demultiplexer 25 of the transmitting device 11, that is, reverse interchange processing for returning positions of the code bits (symbol bits) of the LDPC codes interchanged by the interchange processing to original positions, with respect to the symbol bits of the symbol supplied from the QAM decoder 164 of the previous step, and supplies an LDPC code obtained as a result to the column twist deinterleaver 55 of the following step.

That is, in the multiplexer 54, symbol bits y₀, y₁, . . . , and y_{mb-1} of mb bits of b symbols are supplied to the reverse interchanging unit 1001 in a unit of the b (consecutive) symbols.

The reverse interchanging unit 1001 performs reverse interchanging for returning the symbol bits y₀, y₁, . . . , and y_{mb-1} of the mb bits to an arrangement of code bits b₀, b₁, . . . , and b_{mb-1} of original mb bits (arrangement of the code bits b₀ to b_{mb-1} before interchanging is performed in the interchanging unit 32 constituting the demultiplexer 25 of the side of the transmitting device 11) and outputs the code bits b₀ to b_{mb-1} of the mb bits obtained as a result.

The memory 1002 has a storage capacity to store the mb bits in a row (transverse) direction and store N/(mb) bits in a column (longitudinal) direction, similar to the memory 31 constituting the demultiplexer 25 of the side of the transmitting device 11. That is, the memory 1002 includes mb columns that store N/(mb) bits.

However, in the memory 1002, writing of the code bits of the LDPC code output by the reverse interchanging unit 1001 is performed in a direction in which reading of the code bits from the memory 31 of the demultiplexer 25 of the transmitting device 11 is performed and reading of the code bits written to the memory 1002 is performed in a direction in which writing of the code bits to the memory 31 is performed.

That is, in the multiplexer 54 of the receiving device 12, as illustrated by A of FIG. 124, writing of the code bits of the LDPC code output by the reverse interchanging unit 1001 in the row direction in a unit of the mb bits is sequentially performed toward the lower rows from the first row of the memory 1002.

If writing of the code bits corresponding to one code length ends, the multiplexer 54 reads the code bits from the memory 1002 in the column direction and supplies the code bits to the column twist deinterleaver 55 of a following step.

In this case, B of FIG. 124 is an illustration of reading of the code bits from the memory 1002.

In the multiplexer 54, reading of the code bits of the LDPC code in the downward direction (column direction) from the upper side of the columns constituting the memory 1002 is performed toward the columns of the rightward direction from the left side.

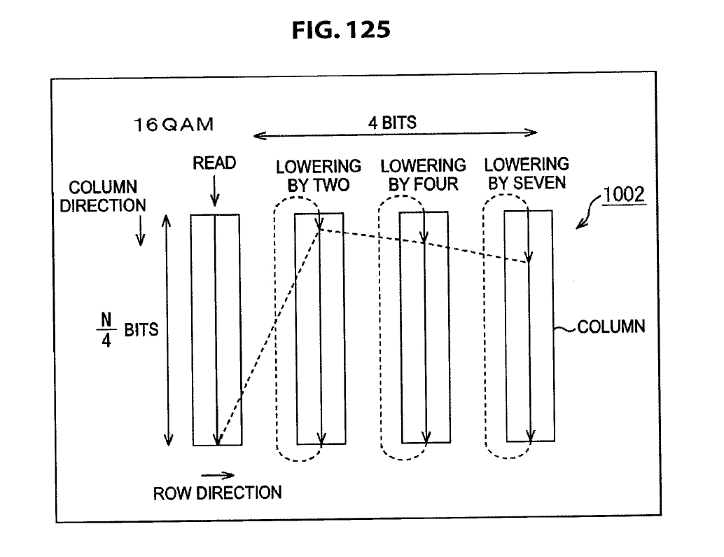

FIG. 125 is an illustration of processing of the column twist deinterleaver 55 constituting the bit deinterleaver 165 of FIG. 117.

That is, FIG. 125 illustrates a configuration example of the memory 1002 of the multiplexer 54.

The memory 1002 has a storage capacity to store the mb bits in the column (longitudinal) direction and store the N/(mb) bits in the row (transverse) direction and includes mb columns.

The column twist deinterleaver 55 writes the code bits of the LDPC code to the memory 1002 in the row direction, controls a read start position when the code bits are read in the column direction, and performs the column twist deinterleave.

That is, in the column twist deinterleaver 55, a read start position to start reading of the code bits is appropriately changed with respect to each of the plurality of columns and the reverse rearrangement processing for returning the arrangement of the code bits rearranged by the column twist interleave to the original arrangement is executed.

In this case, FIG. 125 illustrates a configuration example of the memory 1002 when the modulation method is the 16APSK, the 16QAM or the like and the multiple b is 1, described in FIG. 28. In this case, a bit number m of one symbol is 4 bits and the memory 1002 includes four (=mb) columns.

The column twist deinterleaver 55, (instead of the multiplexer 54), sequentially performs writing of the code bits of the LDPC code output by the reverse interchanging unit 1001 in the row direction, toward the lower rows from the first row of the memory 1002.

If writing of the code bits corresponding to one code length ends, the column twist deinterleaver 55 performs reading of the code bits in the downward direction (column direction) from the upper side of the memory 1002, toward the columns of the rightward direction from the left side.

However, the column twist deinterleaver 55 performs reading of the code bits from the memory 1002, using the write start position to write the code bits by the column twist interleaver 24 of the side of the transmitting device 11 as the read start position of the code bits.

That is, if an address of a position of a head (top) of each column is set to 0 and an address of each position of the column direction is represented by an integer of ascending order, when the modulation method is the 16APSK or the 16QAM and the multiple b is 1, in the column twist deinterleaver 55, a read start position is set as a position of which an address is 0, with respect the leftmost column. With respect the second column (from the left side), a read start position is set as a position of which an address is 2. With respect the third column, a read start position is set as a position of which an address is 4. With respect the fourth column, a read start position is set as a position of which an address is 7.

With respect to the columns in which the read start positions are the positions other than the position of which the address is 0, after reading of the code bits is performed to the lowermost position, the position returns to the head (position of which the address is 0), and reading to the position immediately before the read start position is performed. Then, reading from a next (right) column is performed.

By performing the column twist deinterleave described above, the arrangement of the code bits that are rearranged by the column twist interleave returns to the original arrangement.

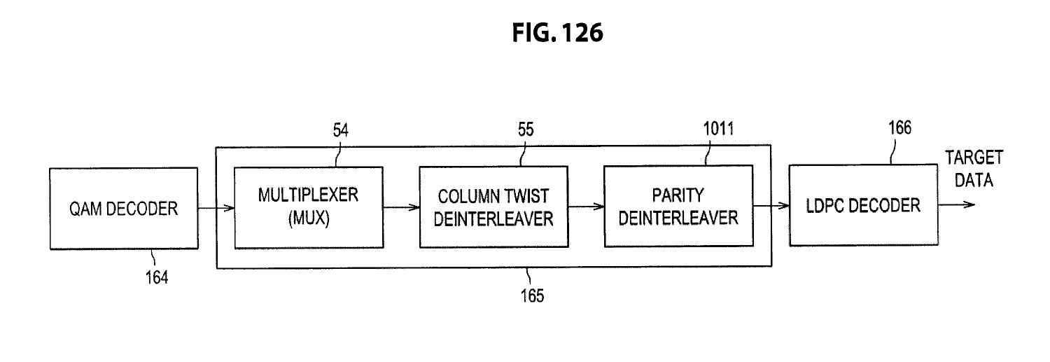

FIG. 126 is a block diagram illustrating another configuration example of the bit deinterleaver 165 of FIG. 116.

In the drawings, portions that correspond to the case of FIG. 117 are denoted with the same reference numerals and explanation thereof is appropriately omitted hereinafter.

That is, the bit deinterleaver 165 of FIG. 126 has the same configuration as the case of FIG. 117, except that a parity deinterleaver 1011 is newly provided.

In FIG. 126, the bit deinterleaver 165 includes a multiplexer (MUX) 54, a column twist deinterleaver 55, and a parity deinterleaver 1011 and performs bit deinterleave of code bits of the LDPC code supplied from the QAM decoder 164.

That is, the multiplexer 54 executes the reverse interchange processing (reverse processing of the interchange processing) corresponding to the interchange processing executed by the demultiplexer 25 of the transmitting device 11, that is, the reverse interchange processing for returning the positions of the code bits interchanged by the interchange processing to the original positions, with respect to the LDPC code supplied from the QAM decoder 164, and supplies an LDPC code obtained as a result to the column twist deinterleaver 55.

The column twist deinterleaver 55 performs the column twist deinterleave corresponding to the column twist interleave as the rearranging processing executed by the column twist interleaver 24 of the transmitting device 11, with respect to the LDPC code supplied from the multiplexer 54.

The LDPC code that is obtained as a result of the column twist deinterleave is supplied from the column twist deinterleaver 55 to the parity deinterleaver 1011.

The parity deinterleaver 1011 performs the parity deinterleave (reverse processing of the parity interleave) corresponding to the parity interleave performed by the parity interleaver 23 of the transmitting device 11, that is, the parity deinterleave to return the arrangement of the code bits of the LDPC code of which an arrangement is changed by the parity interleave to the original arrangement, with respect to the code bits after the column twist deinterleave in the column twist deinterleaver 55.

The LDPC code that is obtained as a result of the parity deinterleave is supplied from the parity deinterleaver 1011 to the LDPC decoder 166.

Therefore, in the bit deinterleaver 165 of FIG. 126, the LDPC code in which the reverse interchange processing, the column twist deinterleave, and the parity deinterleave are performed, that is, the LDPC code that is obtained by the LDPC encoding according to the parity check matrix H is supplied to the LDPC decoder 166.

The LDPC decoder 166 performs LDPC decoding of an LDPC code from the bit deinterleaver 165 by the use of the parity check matrix H used for LDPC encoding by the LDPC encoder 115 of the transmitting device 11. That is, the LDPC decoder 166 performs LDPC decoding of the LDPC code from the bit deinterleaver 165 by the use of the parity check matrix H itself used for LDPC encoding by the LDPC encoder 115 of the transmitting device 11 or by the use of a transformed parity check matrix obtained by performing at least column replacement corresponding to parity interleave with respect to the parity check matrix H.

In FIG. 126, the LDPC code that is obtained by the LDPC encoding according to the parity check matrix H is supplied from (the parity deinterleaver 1011 of) the bit deinterleaver 165 to the LDPC decoder 166. For this reason, when the LDPC decoding of the LDPC code is performed using the parity check matrix H used by the LDPC encoder 115 of the transmitting device 11 to perform the LDPC encoding, the LDPC decoder 166 can be configured by a decoding device performing the LDPC decoding according to a full serial decoding method to sequentially perform operations of messages (a check node message and a variable node message) for each node or a decoding device performing the LDPC decoding according to a full parallel decoding method to simultaneously (in parallel) perform operations of messages for all nodes.

In the LDPC decoder 166, when the LDPC decoding of the LDPC code is performed using the transformed parity check matrix obtained by performing at least the column replacement corresponding to the parity interleave with respect to the parity check matrix H used by the LDPC encoder 115 of the transmitting device 11 to perform the LDPC encoding, the LDPC decoder 166 can be configured by a decoding device (FIG. 122) that is a decoding device of an architecture simultaneously performing P (or divisor of P other than 1) check node operations and variable node operations and has the reception data rearranging unit 310 to perform the same column replacement as the column replacement to obtain the transformed parity check matrix with respect to the LDPC code and rearrange the code bits of the LDPC code.

In FIG. 126, for the convenience of explanation, the multiplexer 54 executing the reverse interchange processing, the column twist deinterleaver 55 performing the column twist deinterleave, and the parity deinterleaver 1011 performing the parity deinterleave are individually configured. However, two or more elements of the multiplexer 54, the column twist deinterleaver 55, and the parity deinterleaver 1011 can be integrally configured, similar to the parity interleaver 23, the column twist interleaver 24, and the demultiplexer 25 of the transmitting device 11.

Moreover, in a case where the bit interleaver 116 (FIG. 8) of the transmitting device 11 is configured without including the parity interleaver 23 and the column twist interleaver 24, in FIG. 126, the bit deinterleaver 165 can be configured without including the column twist deinterleaver 55 and the parity deinterleaver 1011.

Even in this case, the LDPC decoder 166 can be configured with a decoding device of a full serial decoding method to perform LDPC decoding by the use of the parity check matrix H itself, a decoding device of a full parallel decoding method to perform LDPC decoding by the use of the parity check matrix H itself, and a decoding device (FIG. 122) having the reception data rearranging unit 310 that performs LDPC decoding by P simultaneous check node calculations and variable node calculations by the use of the transformed parity check matrix H′.

[Configuration Example of Reception System]

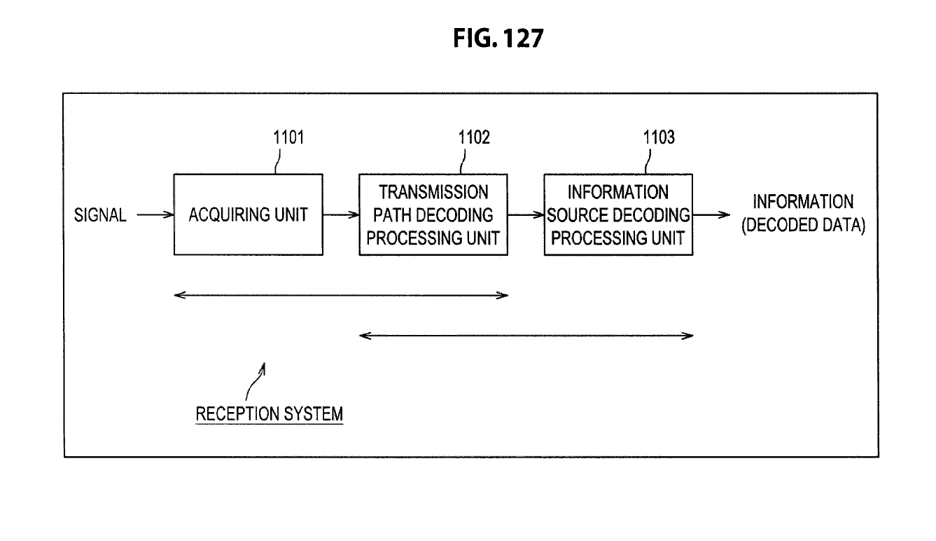

FIG. 127 is a block diagram illustrating a first configuration example of a reception system that can be applied to the receiving device 12.

In FIG. 127, the reception system includes an acquiring unit 1101, a transmission path decoding processing unit 1102, and an information source decoding processing unit 1103.

The acquiring unit 1101 acquires a signal including an LDPC code obtained by performing at least LDPC encoding with respect to LDPC target data such as image data or sound data of a program, through a transmission path (communication path) not illustrated in the drawings, such as terrestrial digital broadcasting, satellite digital broadcasting, a CATV network, the Internet, or other networks, and supplies the signal to the transmission path decoding processing unit 1102.

In this case, when the signal acquired by the acquiring unit 1101 is broadcast from a broadcasting station through a ground wave, a satellite wave, or a CATV (Cable Television) network, the acquiring unit 1101 is configured using a tuner and an STB (Set Top Box). When the signal acquired by the acquiring unit 1101 is transmitted from a web server by multicasting like an IPTV (Internet Protocol Television), the acquiring unit 1101 is configured using a network 1/F (Interface) such as an NIC (Network Interface Card).

The transmission path decoding processing unit 1102 corresponds to the receiving device 12. The transmission path decoding processing unit 1102 executes transmission path decoding processing including at least processing for correcting error generated in a transmission path, with respect to the signal acquired by the acquiring unit 1101 through the transmission path, and supplies a signal obtained as a result to the information source decoding processing unit 1103.

That is, the signal that is acquired by the acquiring unit 1101 through the transmission path is a signal that is obtained by performing at least error correction encoding to correct the error generated in the transmission path. The transmission path decoding processing unit 1102 executes transmission path decoding processing such as error correction processing, with respect to the signal.

As the error correction encoding, for example, LDPC encoding or BCH encoding exists. In this case, as the error correction encoding, at least the LDPC encoding is performed.

The transmission path decoding processing includes demodulation of a modulation signal.

The information source decoding processing unit 1103 executes information source decoding processing including at least processing for extending compressed information to original information, with respect to the signal on which the transmission path decoding processing is executed.

That is, compression encoding that compresses information may be performed with respect to the signal acquired by the acquiring unit 1101 through the transmission path to decrease a data amount of an image or a sound corresponding to information. In this case, the information source decoding processing unit 1103 executes the information source decoding processing such as the processing (extension processing) for extending the compressed information to the original information, with respect to the signal on which the transmission path decoding processing is executed.

When the compression encoding is not performed with respect to the signal acquired by the acquiring unit 1101 through the transmission path, the processing for extending the compressed information to the original information is not executed in the information source decoding processing unit 1103.

In this case, as the extension processing, for example, MPEG decoding exists. In the transmission path decoding processing, in addition to the extension processing, descramble may be included.

In the reception system that is configured as described above, in the acquiring unit 1101, a signal in which the compression encoding such as the MPEG encoding and the error correction encoding such as the LDPC encoding are performed with respect to data such as an image or a sound is acquired through the transmission path and is supplied to the transmission path decoding processing unit 1102.

In the transmission path decoding processing unit 1102, the same processing as the receiving device 12 executes as the transmission path decoding processing with respect to the signal supplied from the acquiring unit 1101 and a signal obtained as a result is supplied to the information source decoding processing unit 1103.

In the information source decoding processing unit 1103, the information source decoding processing such as the MPEG decoding is executed with respect to the signal supplied from the transmission path decoding processing unit 1102 and an image or a sound obtained as a result is output.

The reception system of FIG. 127 described above can be applied to a television tuner to receive television broadcasting corresponding to digital broadcasting.

Each of the acquiring unit 1101, the transmission path decoding processing unit 1102, and the information source decoding processing unit 1103 can be configured as one independent device (hardware (IC (Integrated Circuit) and the like) or software module).

With respect to the acquiring unit 1101, the transmission path decoding processing unit 1102, and the information source decoding processing unit 1103, each of a set of the acquiring unit 1101 and the transmission path decoding processing unit 1102, a set of the transmission path decoding processing unit 1102 and the information source decoding processing unit 1103, and a set of the acquiring unit 1101, the transmission path decoding processing unit 1102, and the information source decoding processing unit 1103 can be configured as one independent device.

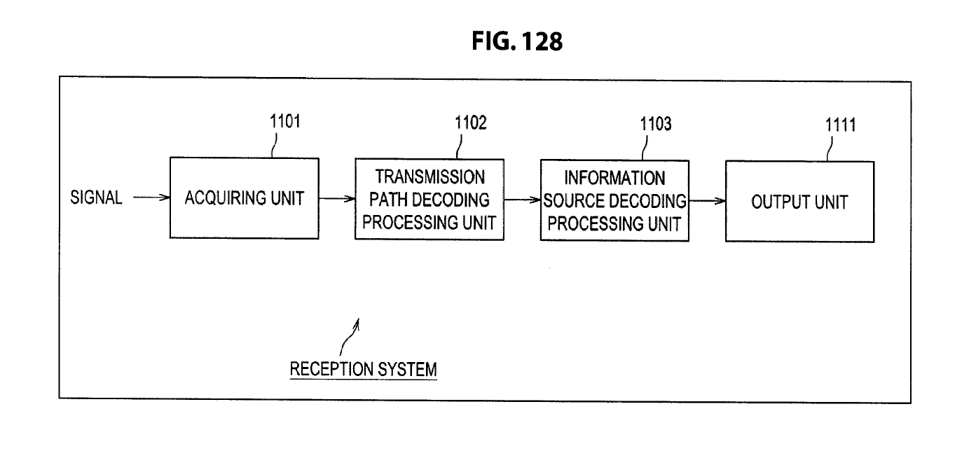

FIG. 128 is a block diagram illustrating a second configuration example of the reception system that can be applied to the receiving device 12.

In the drawings, portions that correspond to the case of FIG. 127 are denoted with the same reference numerals and explanation thereof is appropriately omitted hereinafter.

The reception system of FIG. 128 is common to the case of FIG. 127 in that the acquiring unit 1101, the transmission path decoding processing unit 1102, and the information source decoding processing unit 1103 are provided and is different from the case of FIG. 127 in that an output unit 1111 is newly provided.

The output unit 1111 is a display device to display an image or a speaker to output a sound and outputs an image or a sound corresponding to a signal output from the information source decoding processing unit 1103. That is, the output unit 1111 displays the image or outputs the sound.

The reception system of FIG. 128 described above can be applied to a TV (television receiver) receiving television broadcasting corresponding to digital broadcasting or a radio receiver receiving radio broadcasting.

When the compression encoding is not performed with respect to the signal acquired in the acquiring unit 1101, the signal that is output by the transmission path decoding processing unit 1102 is supplied to the output unit 1111.

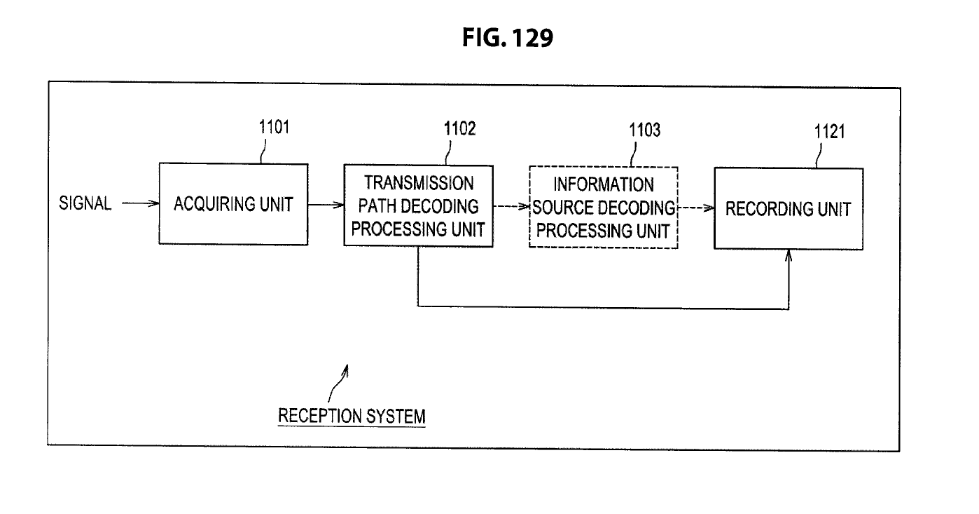

FIG. 129 is a block diagram illustrating a third configuration example of the reception system that can be applied to the receiving device 12.

In the drawings, portions that correspond to the case of FIG. 127 are denoted with the same reference numerals and explanation thereof is appropriately omitted hereinafter.

The reception system of FIG. 129 is common to the case of FIG. 127 in that the acquiring unit 1101 and the transmission path decoding processing unit 1102 are provided.

However, the reception system of FIG. 129 is different from the case of FIG. 127 in that the information source decoding processing unit 1103 is not provided and a recording unit 1121 is newly provided.

The recording unit 1121 records (stores) a signal (for example, TS packets of TS of MPEG) output by the transmission path decoding processing unit 1102 on recording (storage) media such as an optical disk, a hard disk (magnetic disk), and a flash memory.

The reception system of FIG. 129 described above can be applied to a recorder that records television broadcasting.

In FIG. 129, the reception system is configured by providing the information source decoding processing unit 1103 and can record the signal obtained by executing the information source decoding processing by the information source decoding processing unit 1103, that is, the image or the sound obtained by decoding, by the recording unit 1121.

[Embodiment of Computer]

Next, the series of processing described above can be executed by hardware or can be executed by software. In the case in which the series of processing is executed by the software, a program configuring the software is installed in a general-purpose computer.

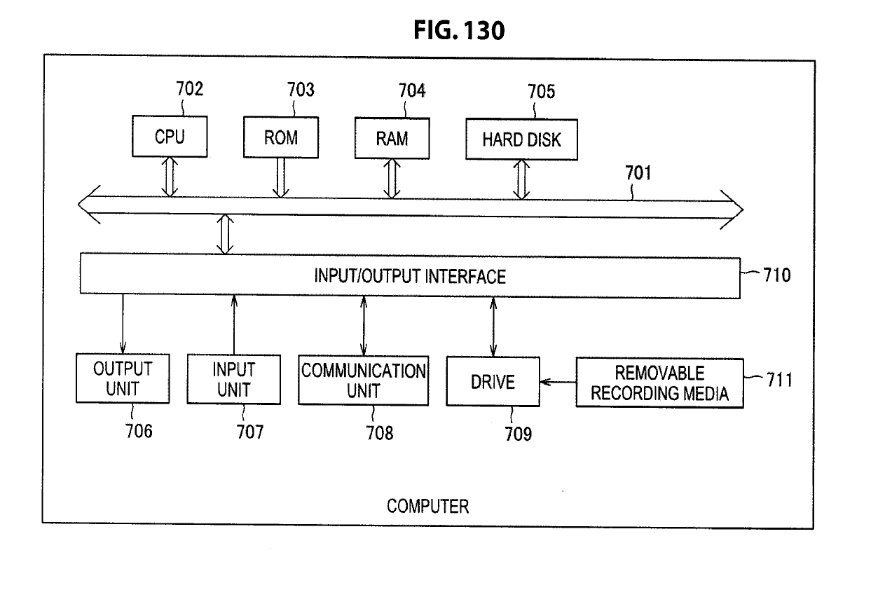

Therefore, FIG. 130 illustrates a configuration example of an embodiment of the computer in which a program executing the series of processing is installed.

The program can be previously recorded on a hard disk 705 and a ROM 703 corresponding to recording media embedded in the computer.

Alternatively, the program can be temporarily or permanently stored (recorded) on removable recording media 711 such as a flexible disk, a CD-ROM (Compact Disc Read Only Memory), an MO (Magneto Optical) disk, a DVD (Digital Versatile Disc), a magnetic disk, and a semiconductor memory. The removable recording media 711 can be provided as so-called package software.

The program is installed from the removable recording media 711 to the computer. In addition, the program can be transmitted from a download site to the computer by wireless through an artificial satellite for digital satellite broadcasting or can be transmitted to the computer by wire through a network such as a LAN (Local Area Network) or the Internet. The computer can receive the program transmitted as described above by a communication unit 708 and install the program in the embedded hard disk 705.

The computer includes a CPU (Central Processing Unit) 702 embedded therein. An input/output interface 710 is connected to the CPU 702 through a bus 701. If a user operates an input unit 707 configured using a keyboard, a mouse, and a microphone and a command is input through the input/output interface 710, the CPU 702 executes the program stored in the ROM (Read Only Memory) 703, according to the command. Alternatively, the CPU 702 loads the program stored in the hard disk 705, the program transmitted from a satellite or a network, received by the communication unit 708, and installed in the hard disk 705, or the program read from the removable recording media 711 mounted to a drive 709 and installed in the hard disk 705 to the RAM (Random Access Memory) 704 and executes the program. Thereby, the CPU 702 executes the processing according to the flowcharts described above or the processing executed by the configurations of the block diagrams described above. In addition, the CPU 702 outputs the processing result from the output unit 706 configured using an LCD (Liquid Crystal Display) or a speaker, transmits the processing result from the communication unit 708, and records the processing result on the hard disk 705, through the input/output interface 710, according to necessity.

In the present specification, it is not necessary to process the processing steps describing the program for causing the computer to execute the various processing in time series according to the order described as the flowcharts and processing executed in parallel or individually (for example, parallel processing or processing using an object) is also included.

The program may be processed by one computer or may be processed by a plurality of computers in a distributed manner. The program may be transmitted to a remote computer and may be executed.

An embodiment of the disclosure is not limited to the embodiments described above, and various changes and modifications may be made without departing from the scope of the disclosure.

That is, for example, (the parity check matrix initial value table of) the above-described new LDPC code can be used even if the communication path 13 (FIG. 7) is any of a satellite circuit, a ground wave, a cable (wire circuit) and others.

In addition, the new LDPC code can also be used for data transmission other than digital broadcasting.

### REFERENCE SIGNS LIST

11 transmitting device
12 receiving device
23 parity interleaver
24 column twist interleaver
25 demultiplexer
31 memory
32 interchanging unit
54 multiplexer
55 column twist interleaver
111 mode adaptation/multiplexer
112 padder
113 BB scrambler
114 BCH encoder
115 LDPC encoder
116 bit interleaver
117 QAM encoder
118 time interleaver
119 MISO/MIMO encoder
120 frequency interleaver
121 BCH encoder
122 LDPC encoder
123 QAM encoder
124 frequency interleaver
131 frame builder/resource allocation unit
132 OFDM generating unit
151 OFDM operating unit
152 frame managing unit
153 frequency deinterleaver
154 QAM decoder
155 LDPC decoder
156 BCH decoder
161 frequency deinterleaver
162 MISO/MIMO decoder
163 time deinterleaver
164 QAM decoder
165 bit deinterleaver
166 LDPC decoder
167 BCH decoder
168 BB descrambler
169 null deletion unit
170 demultiplexer
300 branch data storing memory
301 selector
302 check node calculating unit
303 cyclic shift circuit
304 branch data storing memory
305 selector
306 reception data memory
307 variable node calculating unit
308 cyclic shift circuit
309 decoding word calculating unit
310 reception data rearranging unit
311 decoded data rearranging unit
601 encoding processing unit
602 storage unit
611 encoding rate setting unit
612 initial value table reading unit
613 parity check matrix generating unit
614 information bit reading unit
615 encoding parity operation unit
616 control unit
701 bus
702 CPU
703 ROM
704 RAM
705 hard disk
706 output unit
707 input unit
708 communication unit
709 drive
710 input/output interface
711 removable recording media
1001 reverse interchanging unit
1002 memory
1011 parity deinterleaver
1101 acquiring unit
1101 transmission path decoding processing unit
1103 information source decoding processing unit
1111 output unit
1121 recording unit

1. A data processing device comprising:
an encoding unit configured to encode an information bit into an LDPC code with a code length of 64800 bits and an encoding rate of 7/30, based on a parity check matrix of an LDPC (Low Density Parity Check) code, wherein
the LDPC code includes an information bit and a parity bit,
the parity check matrix includes an information matrix part corresponding to the information bit and a parity matrix part corresponding to the parity bit,
the information matrix part is shown by a parity check matrix initial value table, and
the parity check matrix initial value table is a table showing positions of elements of 1 of the information matrix part every 360 columns and is expressed as follows
548 9528 12205 12770 22023 22082 25884 27421 33215 36046 43580 43953 47539
919 2623 5098 5514 5645 6348 9666 13795 14555 43224 44048 44948 47964
995 7270 17753 21272 29228 29916 31634 34055 35205 37499 37777 47490 49301
645 3803 8836 9470 11054 20253 29417 31243 31990 36468 38715 39932 43045
14572 18646 21100 26617 32033 32410 37195 38586 43833 44577 45584 46453 49515
6004 16982 17829 24616 28056 29646 32944 39051 42517 47086 48585 48772 49247
1306 1447 4898 7781 18587 25724 26672 35062 35202 37080 39781 46111 47595
92 3231 13043 22258 24198 28923 33303 37846 43610 44857 47322 48914 49291
298 12557 13469 14451 21917 23539 26310 29839 37050 38507 41377 46971 48155
12582 13044 21039 30600 34202 34947 37120 39108 39203 43449 46941 48542 49354
871 12218 12680 14152 17171 25797 29021 37783 43728 47519 48794 48898 48980
35 4623 13422 15881 16692 17463 23675 28063 31248 41997 44246 47992 48339
7150 13015 17950 18214 20659 23579 25714 28328 32658 39717 39995 43322 45884
82 11054 11845 19085 24174 26694 41530 45954 46508 46892 48832 49097 49420
5789 13839 18512 25596 26478 26736 29431 32349 33384 41765 46661 49206 49543
13805 17786 17798 29653 30310 34870 40176 40391 43227 45292 46423 46855 49454
12433 27119 34645
32065 34998 44021
5158 16546 34359
44 33285 39929
39032 39296 40317
9885 45251 47640
14383 43446 44478
31280 39945 48472
27961 38221 48391
2927 37404 38716
19461 42462 46162
24909 25915 40636
11029 35538 45381
26880 34179 48775
192 6032 26853
4563 14952 24256
10003 30853 43811
749 36334 41363
100 17006 24982
9507 20228 31214
41691 44310 47083
24070 30411 46982
2727 28251 49289
16689 21167 32590
40813 41198 46175
8336 32714 43075.

2. The data processing device according to claim 1, wherein
when a row of the parity check matrix initial value table is expressed as i and a parity length of the LDPC code is expressed as M, a 2+360×(i−1)-th column of the parity check matrix is a column subjected to cyclic shift of a 1+360×(i−1)-th column of the parity check matrix showing the positions of the elements of 1 in the parity check matrix initial value table by q=M/360 in a downward direction.

3. The data processing device according to claim 2, wherein
as for the 1+360×(i−1)-th column of the parity check matrix, an i-th row of the parity check matrix initial value table shows a row number of an element of 1 of the 1+360×(i−1)-th column of the parity check matrix, and
as for each of columns from the 2+360×(i−1)-th column to a 360×i-th column which are columns other than the 1+360×(i−1)-th column of the parity check matrix, when a numerical value of an i-th row and j-th column of the parity check matrix initial value table is expressed as hi,j and a row number of a j-th element of 1 of a w-th column of the parity check matrix H is expressed as Hw-j, the row number Hw-j of the element of 1 in the w-th column which is a column other than the 1+360×(i−1)-th column of the parity check matrix is expressed by an expression Hw-j=mod {hi,j+mod((w−1),360)×M/360,M).

4. The data processing device according to claim 2, wherein
the q is 138.

5. The data processing device according to claim 1, further comprising:
a parity interleave unit configured to interleave only a parity bit of a code bit of the LDPC code.

6. The data processing device according to claim 1, further comprising:
a column twist interleave unit configured to perform column twist interleave by shifting a code bit of the LDPC code in a column direction and storing the code bit.

7. The data processing device according to claim 1, further comprising:
an interchange unit configured to interchange a code bit of the LDPC code with a symbol bit of a symbol corresponding to any of a predetermined number of signal points defined by a predetermined digital modulation method.

8. The data processing device according to claim 7, wherein
the interchange unit interchanges the code bit stored in a column direction and read in a row direction.

9. The data processing device according to claim 1, wherein
the parity check matrix is a parity check matrix without cycle 4.

10. The data processing device according to claim 1, wherein
the parity check matrix is a parity check matrix of an LDPC code belonging to an ensemble of an LDPC code in which a performance threshold that is Eb/N0 with decreasing BER is equal to or less than a predetermined value, which is detected by density evolution of a multi-edge type.

11. A data processing method comprising:
an encoding step of encoding an information bit into an LDPC code with a code length of 64800 bits and an encoding rate of 7/30, based on a parity check matrix of an LDPC (Low Density Parity Check) code, wherein
the LDPC code includes an information bit and a parity bit,
the parity check matrix includes an information matrix part corresponding to the information bit and a parity matrix part corresponding to the parity bit,
the information matrix part is shown by a parity check matrix initial value table, and
the parity check matrix initial value table is a table showing positions of elements of 1 of the information matrix part every 360 columns and is expressed as follows
548 9528 12205 12770 22023 22082 25884 27421 33215 36046 43580 43953 47539
919 2623 5098 5514 5645 6348 9666 13795 14555 43224 44048 44948 47964
995 7270 17753 21272 29228 29916 31634 34055 35205 37499 37777 47490 49301
645 3803 8836 9470 11054 20253 29417 31243 31990 36468 38715 39932 43045
14572 18646 21100 26617 32033 32410 37195 38586 43833 44577 45584 46453 49515
6004 16982 17829 24616 28056 29646 32944 39051 42517 47086 48585 48772 49247
1306 1447 4898 7781 18587 25724 26672 35062 35202 37080 39781 46111 47595
92 3231 13043 22258 24198 28923 33303 37846 43610 44857 47322 48914 49291
298 12557 13469 14451 21917 23539 26310 29839 37050 38507 41377 46971 48155
12582 13044 21039 30600 34202 34947 37120 39108 39203 43449 46941 48542 49354
871 12218 12680 14152 17171 25797 29021 37783 43728 47519 48794 48898 48980
35 4623 13422 15881 16692 17463 23675 28063 31248 41997 44246 47992 48339
7150 13015 17950 18214 20659 23579 25714 28328 32658 39717 39995 43322 45884
82 11054 11845 19085 24174 26694 41530 45954 46508 46892 48832 49097 49420
5789 13839 18512 25596 26478 26736 29431 32349 33384 41765 46661 49206 49543
13805 17786 17798 29653 30310 34870 40176 40391 43227 45292 46423 46855 49454
12433 27119 34645
32065 34998 44021
5158 16546 34359
44 33285 39929
39032 39296 40317
9885 45251 47640
14383 43446 44478
31280 39945 48472
27961 38221 48391
2927 37404 38716
19461 42462 46162
24909 25915 40636
11029 35538 45381
26880 34179 48775
192 6032 26853
4563 14952 24256
10003 30853 43811
749 36334 41363
100 17006 24982
9507 20228 31214
41691 44310 47083
24070 30411 46982
2727 28251 49289
16689 21167 32590
40813 41198 46175
8336 32714 43075.

12. The data processing method according to claim 11, wherein
when a row of the parity check matrix initial value table is expressed as i and a parity length of the LDPC code is expressed as M, a 2+360×(i−1)-th column of the parity check matrix is a column subjected to cyclic shift of a 1+360×(i−1)-th column of the parity check matrix showing the positions of the elements of 1 in the parity check matrix initial value table by q=M/360 in a downward direction.

13. The data processing method according to claim 12, wherein
as for the 1+360×(i−1)-th column of the parity check matrix, an i-th row of the parity check matrix initial value table shows a row number of an element of 1 of the 1+360×(i−1)-th column of the parity check matrix, and
as for each of columns from the 2+360×(i−1)-th column to a 360×i-th column which are columns other than the 1+360×(i−1)-th column of the parity check matrix, when a numerical value of an i-th row and j-th column of the parity check matrix initial value table is expressed as hi,j and a row number of a j-th element of 1 of a w-th column of the parity check matrix H is expressed as Hw-j, the row number Hw-j of the element of 1 in the w-th column which is a column other than the 1+360×(i−1)-th column of the parity check matrix is expressed by an expression Hw-j=mod {hi,j+mod((w−1),360)×M/360,M).

14. The data processing method according to claim 12, wherein
the q is 138.

15. The data processing method according to claim 11, comprising:
interleaving only a parity bit of a code bit of the LDPC code.

16. The data processing method according to claim 11, comprising:
performing column twist interleave by shifting a code bit of the LDPC code in a column direction and storing the code bit.

17. The data processing method according to claim 11, comprising:
interchanging a code bit of the LDPC code with a symbol bit of a symbol corresponding to any of a predetermined number of signal points defined by a predetermined digital modulation method.

18. The data processing method according to claim 17, wherein
in the interchange of the code bit, the code bit that is stored in a column direction and read in a row direction is interchanged.

19. The data processing method according to claim 11, wherein
the parity check matrix is a parity check matrix without cycle 4.

20. The data processing method according to claim 11, wherein
the parity check matrix is a parity check matrix of an LDPC code belonging to an ensemble of an LDPC code in which a performance threshold that is Eb/N0 with decreasing BER is equal to or less than a predetermined value, which is detected by density evolution of a multi-edge type.

21. A data processing device comprising:
a decoding unit configured to decode an LDPC code with a code length of 64800 bits and an encoding rate of 7/30, based on a parity check matrix of an LDPC (Low Density Parity Check) code, wherein
the LDPC code includes an information bit and a parity bit,
the parity check matrix includes an information matrix part corresponding to the information bit and a parity matrix part corresponding to the parity bit,
the information matrix part is shown by a parity check matrix initial value table, and
the parity check matrix initial value table is a table showing positions of elements of 1 of the information matrix part every 360 columns and is expressed as follows
548 9528 12205 12770 22023 22082 25884 27421 33215 36046 43580 43953 47539
919 2623 5098 5514 5645 6348 9666 13795 14555 43224 44048 44948 47964
995 7270 17753 21272 29228 29916 31634 34055 35205 37499 37777 47490 49301
645 3803 8836 9470 11054 20253 29417 31243 31990 36468 38715 39932 43045
14572 18646 21100 26617 32033 32410 37195 38586 43833 44577 45584 46453 49515
6004 16982 17829 24616 28056 29646 32944 39051 42517 47086 48585 48772 49247
1306 1447 4898 7781 18587 25724 26672 35062 35202 37080 39781 46111 47595
92 3231 13043 22258 24198 28923 33303 37846 43610 44857 47322 48914 49291
298 12557 13469 14451 21917 23539 26310 29839 37050 38507 41377 46971 48155
12582 13044 21039 30600 34202 34947 37120 39108 39203 43449 46941 48542 49354
871 12218 12680 14152 17171 25797 29021 37783 43728 47519 48794 48898 48980
35 4623 13422 15881 16692 17463 23675 28063 31248 41997 44246 47992 48339
7150 13015 17950 18214 20659 23579 25714 28328 32658 39717 39995 43322 45884
82 11054 11845 19085 24174 26694 41530 45954 46508 46892 48832 49097 49420
5789 13839 18512 25596 26478 26736 29431 32349 33384 41765 46661 49206 49543
13805 17786 17798 29653 30310 34870 40176 40391 43227 45292 46423 46855 49454
12433 27119 34645
32065 34998 44021
5158 16546 34359
44 33285 39929
39032 39296 40317
9885 45251 47640
14383 43446 44478
31280 39945 48472
27961 38221 48391
2927 37404 38716
19461 42462 46162
24909 25915 40636
11029 35538 45381
26880 34179 48775
192 6032 26853
4563 14952 24256
10003 30853 43811
749 36334 41363
100 17006 24982
9507 20228 31214
41691 44310 47083
24070 30411 46982
2727 28251 49289
16689 21167 32590
40813 41198 46175
8336 32714 43075.

22-54. (canceled)
